(19) United States
(12) Patent Application Publication
(10) Pub. No.: US 2016/0190473 A1
(43) Pub. Date: Jun. 30, 2016

(54) ORGANIC LIGHT-EMITTING DEVICE

(71) Applicant: SAMSUNG DISPLAY CO., LTD., Yongin-City (KR)

(72) Inventors: Sehun KIM, Yongin-City (KR); Mikyung KIM, Yongin-City (KR); Kwanhee LEE, Yongin-City (KR); Hyein JEONG, Yongin-City (KR); Changwoong CHU, Yongin-City (KR)

(21) Appl. No.: 14/740,393

(22) Filed: Jun. 16, 2015

(30) Foreign Application Priority Data
Dec. 26, 2014 (KR) 10-2014-0191124

(51) Int. Cl. H01L 51/00; C09K 11/02

(52) U.S. Cl. CPC H01L 51/0072; C09K 11/025; H01L 51/0067; H01L 51/0071; H01L 51/0061; H01L 51/006; H01L 51/5012

(57) ABSTRACT

An organic light-emitting device including a first electrode; a second electrode facing the first electrode; and an organic layer between the first electrode and the second electrode, the organic layer including an emission layer, wherein the organic layer includes a first compound and a second compound, the first compound being represented by one of the following Formulae 1-1 to 1-3, and the second compound being represented by one of the following Formulae 2-1 and 2-2:

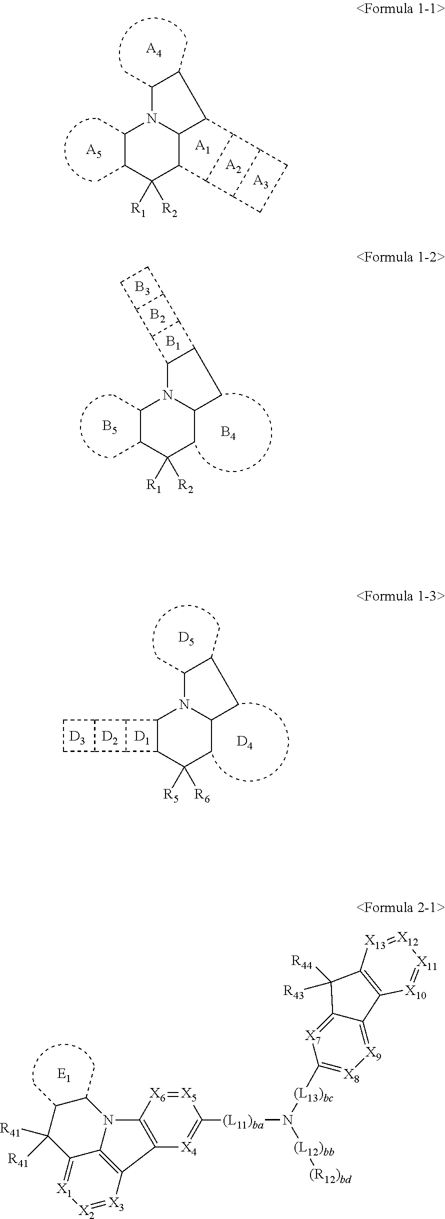

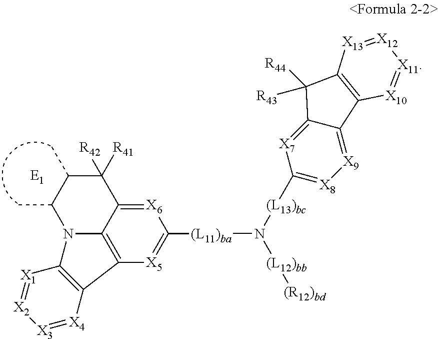

### CROSS-REFERENCE TO RELATED APPLICATION

Korean Patent Application No. 10-2014-0191124, filed on Dec. 26, 2014, in the Korean Intellectual Property Office, and entitled: “Organic Light-Emitting Device,” is incorporated by reference herein in its entirety.

### BACKGROUND

1. Field

Embodiments relate to an organic light-emitting device.

2. Description of the Related Art

Organic light-emitting devices (OLEDs) are self-emission devices that have wide viewing angles, high contrast ratios, and short response times. In addition, the OLEDs exhibit excellent luminance, driving voltage, and response speed characteristics, and produce full-color images.

The organic light-emitting device may include a first electrode disposed on a substrate, and a hole transport region, an emission layer, an electron transport region, and a second electrode, which are sequentially disposed on the first electrode. Holes provided from the first electrode may move toward the emission layer through the hole transport region, and electrons provided from the second electrode may move toward the emission layer through the electron transport region. The holes and the electrons are recombined in the emission layer to produce excitons. These excitons change from an excited state to a ground state to thereby generate light.

### SUMMARY

Embodiments are directed to an organic light-emitting device having a high efficiency and long lifespan.

According to one or more exemplary embodiments, an organic light-emitting device includes a first electrode; a second electrode facing the first electrode; and an organic layer disposed between the first electrode and the second electrode and including an emission layer, wherein the organic layer includes a first compound and a second compound, the first compound is represented by one of Formulae 1-1 to 1-3, and the second compound is represented by one of Formulae 2-1 and 2-2:

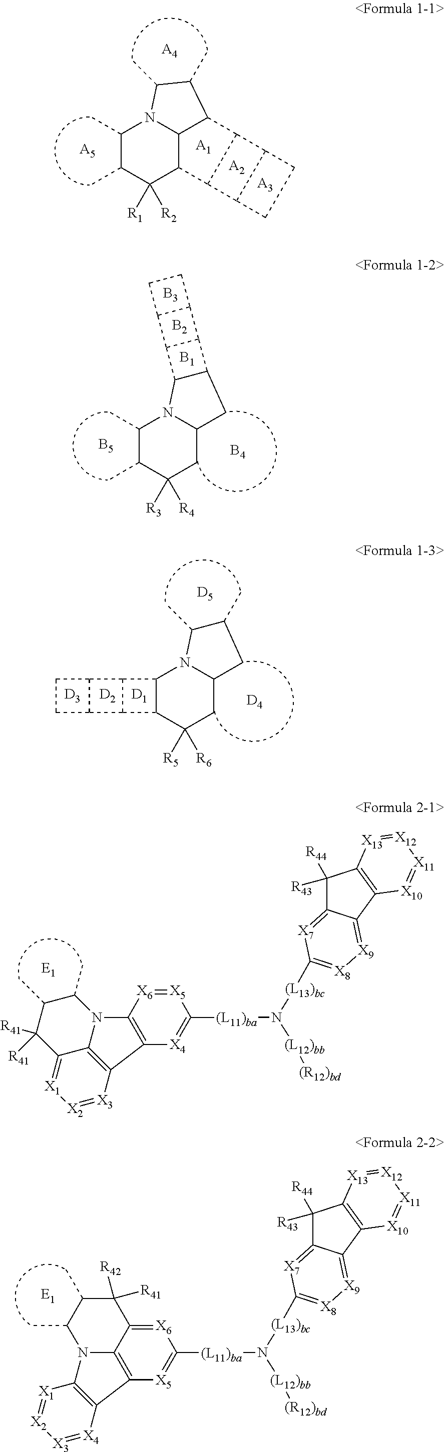

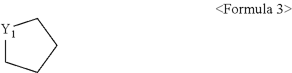

wherein, in Formulae 1-1 to 1-3, 2-1, and 2-2,

ring A₁, ring A, and ring A₃ are condensed together, ring B₁, ring B₂, and ring B₃ are condensed together, and ring D₁, ring D₂, and ring D₃ are condensed together;

ring A₂, ring B₂, and ring C₂ are each independently represented by Formula 3, where, in Formula 3, Y₁ is O, S, or N-(L₁)ₐₐ-(R₁₁)_{ab};

rings A₁, A₃ to A₅, B₁, B₃ to B₅, D₁, D₃ to D₅, and E₁ are each independently a substituted or unsubstituted benzene ring or a substituted or unsubstituted naphthalene ring;

X₁ is N or C(R₅₁), X₂ is N or C(R₅₂), X₃ is N or C(R₅₃), X₄ is N or C(R₅₄), X₅ is N or C(R₅₅), X₆ is N or C(R₅₆), X₇ is N or C(R₅₇), X₈ is N or C(R₅₈), X₉ is N or C(R₅₉), X₁₀ is N or C(R₆₁), X₁₁ is N or C(R₆₂), X₁₂ is N or C(R₆₂), and X₁₃ is N or C(R₆₃);

R₁ to R₆ and R₄₁ to R₄₄ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, where R₁ and R₂, R₃ and R₄, R₅ and R₆, R₄₁ and R₄₂, and R₄₃ and R₄₄ are non-ring forming substituents which are not linked to each other and do not form a ring;

L₁ and L₁₁ to L₁₃ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group;

aa and ba to be are each independently selected from 0, 1, 2, and 3, wherein, when aa is not 0, *-(L₁)ₐₐ-*′ is a single bond, when ba is 0, *-(L₁₁)_{ba}-*′ is a single bond, when bb is 0, *-(L₁₂)_{bb}-*′ is a single bond, when be is 0, *-(L₁₃)_{bc}-*′ is a single bond, when aa is 2 or greater, two or more L₁(s) are identical to or different from each other, when ba is 2 or greater, two or more L₁₁(s) are identical to or different from each other, when bb is 2 or greater, two or more L₁₂(s) are identical to or different from each other, and, when bc is 2 or greater, two or more L₁₃(s) are identical to or different from each other;

R₁₁, R₁₂, and R₅₁ to R₆₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and N(Q₆)(Q₇);

ab and bd are each independently selected from 1, 2, and 3, wherein, when ab is 2 or greater, two or more R₁₁(s) are identical to or different from each other, and, when bd is 2 or greater, two or more R₁₂(s) are identical to or different from each other;

at least one substituent of the substituted benzene ring, substituted naphthalene ring, substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group is selected from

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇); and

—Si(Q₃₁)(Q₃₂)(Q₃₃), —B(Q₃₄)(Q₃₅), and —N(Q₃₆)(Q₃₇),

wherein Q₁ to Q₇, Q₁₁ to Q₁₇, Q₂₁ to Q₂₇, and Q₃₁ to Q₃₇ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

### BRIEF DESCRIPTION OF THE DRAWING

Features will be apparent to those of skill in the art by describing in detail exemplary embodiments with reference to the attached drawing in which:

FIG. 1 illustrates a schematic view of an organic light-emitting device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

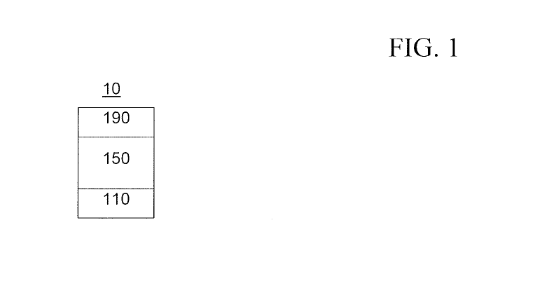

FIG. 1 illustrates a schematic cross-sectional view of an organic light-emitting device (OLED) 10 according to an exemplary embodiment. Referring to FIG. 1, the organic light-emitting device 10 may include a first electrode 110, an organic layer 150, and a second electrode 190.

Referring to FIG. 1, a substrate may be additionally disposed under the first electrode 110 or on the second electrode 190. The substrate may be a glass substrate or transparent plastic substrate, each with excellent mechanical strength, thermal stability, transparency, surface smoothness, ease of handling, and water resistance.

The first electrode 110 may be formed by depositing or sputtering a material for forming a first electrode on the substrate. When the first electrode 110 is an anode, the material for the first electrode may be selected from materials with a high work function to facilitate hole injection. The first electrode 110 may be a reflective electrode, a semi-transmissive electrode, or a transmissive electrode. The material for the first electrode 110 may be a transparent and highly conductive material, and examples of such a material are indium tin oxide (ITO), indium zinc oxide (IZO), tin oxide (SnO₂), and zinc oxide (ZnO). When the first electrode 110 is a semi-transmissive electrode or a reflective electrode, as a material for forming the first electrode 110, at least one material selected from magnesium (Mg), aluminum (Al), aluminum-lithium (Al—Li), calcium (Ca), magnesium-indium (Mg—In), and magnesium-silver (Mg—Ag) may be used.

The first electrode 110 may have a single-layer structure, or a multi-layer structure including a plurality of layers. For example, the first electrode 110 may have a triple-layer structure of ITO/Ag/ITO, but embodiments are not limited thereto.

An organic layer 150, including an emission layer, may be disposed on the first electrode 110. The organic layer 150 may include a hole transport region disposed between the first electrode 110 and the emission layer and an electron transport region disposed between the emission layer and the second electrode 190.

The organic layer 150 may include a first compound and a second compound. In an implementation, the first compound may be represented by one of the following Formulae 1-1 to 1-3, and the second compound may be represented by one of the following Formulae 2-1 and 2-2.

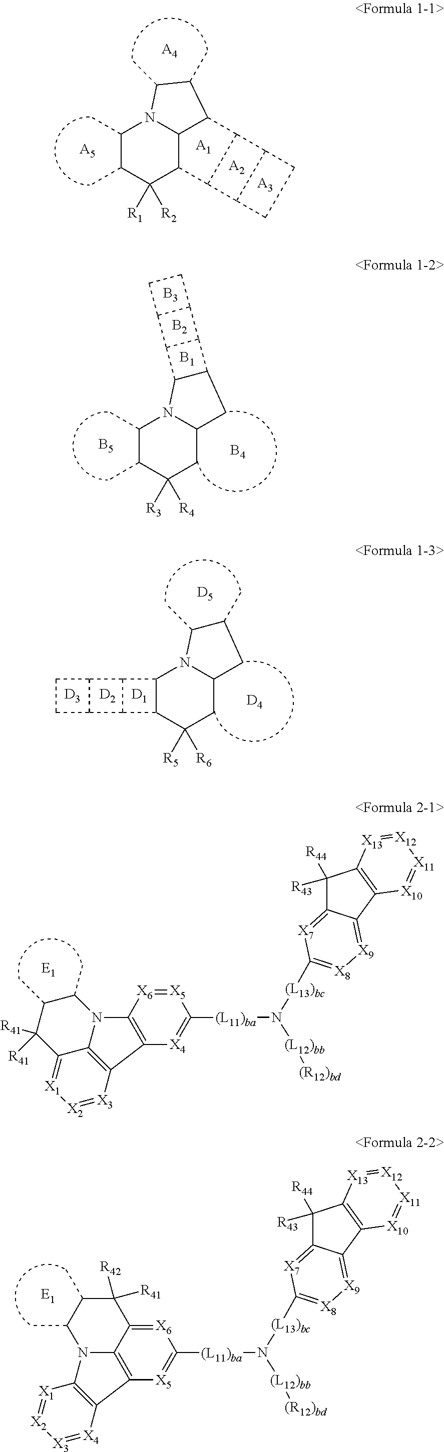

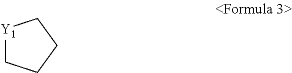

In Formulae 1-1 to 1-3,

ring A₁, ring A, and ring A₃ may be condensed together, ring B₁, ring B₂, and ring B₃ may be condensed together, and ring D₁, ring D₂, and ring D₃ may be condensed together;

ring A₂, ring B₂, and ring D₂ are each independently represented by Formula 3, wherein, in Formula 3, Y₁ is O, S, or N-(L₁)ₐₐ-(R₁₁)_{ab};

rings A₁, A₃ to A₅, B₁, B₃ to B₅, D₁, D₃ to D₅, and E₁ are each independently a substituted or unsubstituted benzene ring or a substituted or unsubstituted naphthalene ring;

X₁ is N or C(R₅₁), X₂ is N or C(R₅₂), X₃ is N or C(R₅₃), X₄ is N or C(R₅₄), X₅ is N or C(R₅₅), X₆ is N or C(R₅₆), X₇ is N or C(R₅₇), X₈ is N or C(R₅₈), X₉ is N or C(R₅₉), X₁₀ is N or C(R₆₁), X₁₁ is N or C(R₆₂), X₁₂ is N or C(R₆₂), and X₁₃ is N or C(R₆₃); and

R₁ to R₆ and R₄₁ to R₄₄ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein R₁ and R₂, R₃ and R₄, R₅ and R₆, R₄₁ and R₄₂, and R₄₃ and R₄₄ may be each a pair of non-ring forming substituents which are not linked to each other and do not form a ring.

In some embodiments, in Formulae 1-1 to 1-3, 2-1, and 2-2,

R₁ to R₆ and R₄₁ to R₄₄ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₁-C₆₀ alkoxy group, and a substituted or unsubstituted C₆-C₆₀ aryl group.

In some embodiments, in Formulae 1-1 to 1-3, 2-1, and 2-2,

R₁ to R₆ and R₄₁ to R₄₄ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, and a naphthyl group;

a phenyl group, a naphthyl group, a fluorenyl group, a phenanthrenyl group, an anthracenyl group, a fluoranthenyl group, a triphenylenyl group, a pyrenyl group, and a chrysenyl group; and

a phenyl group, a naphthyl group, a fluorenyl group, a phenanthrenyl group, an anthracenyl group, a fluoranthenyl group, a triphenylenyl group, a pyrenyl group, and a chrysenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, and a chrysenyl group, but embodiments are not limited thereto.

For example, in Formulae 1-1 to 1-3, 2-1, and 2-2,

R₁ to R₆ and R₄₁ to R₄₄ may be a methyl group or a phenyl group.

In Formulae 1-1 to 1-3, 2-1, and 2-2,

L₁ and L₁₁ to L₁₃ may be each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group; and

aa and ba to bc are each independently selected from 0, 1, 2, and 3, and when aa is 0, *-(L₁)ₐₐ-*′ is a single bond, when ba is 0, *-(L₁₁)_{ba}-*′ is a single bond, when bb is 0, *-(L₁₂)_{bb}-*′ is a single bond, when be is 0, *-(L₁₃)_{bc}-*′ is a single bond, when aa is 2 or greater, two or more L₁(s) are identical to or different from each other, when ba is 2 or greater, two or more L₁₁(s) are identical to or different from each other, when bb is 2 or greater, two or more L₁₂(s) are identical to or different from each other, and when be is 2 or greater, two or more L₁₃(s) are identical to or different from each other.

In some embodiments, in Formulae 1-1 to 1-3, 2-1, and 2-2,

L₁ and L₁₁ to L₁₃ may be each independently selected from

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group; and

a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a phenylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group.

In some embodiments, in Formulae 1-1 to 1-3, 2-1, and 2-2,

L₁ and L₁₁ to L₁₃ may be each independently selected from

a phenylene group, a naphthylene group, a fluorenylene group, a phenanthrenylene group, an anthracenylene group, a triphenylenylene group, a pyrenylene group, and a chrysenylene group; and

a phenylene group, a naphthylene group, a fluorenylene group, a phenanthrenylene group, an anthracenylene group, a triphenylenylene group, a pyrenylene group, and a chrysenylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a triphenylenyl group, a pyrenyl group, and a chrysenyl group.

In some embodiments, in Formulae 1-1 to 1-3 and 2-1 and 2-2,

L₁ and L₁₁ to L₁₃ may be each independently represented by one of Formulae 4-1 to 4-19:

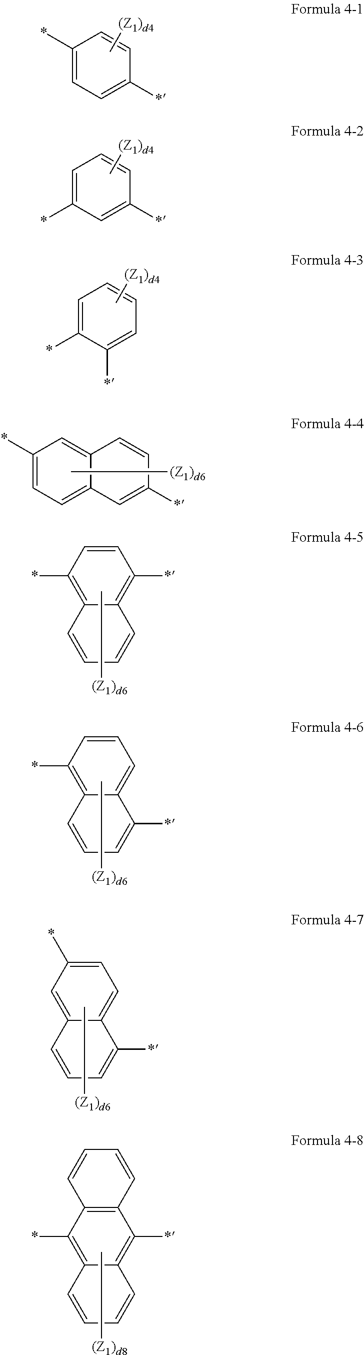

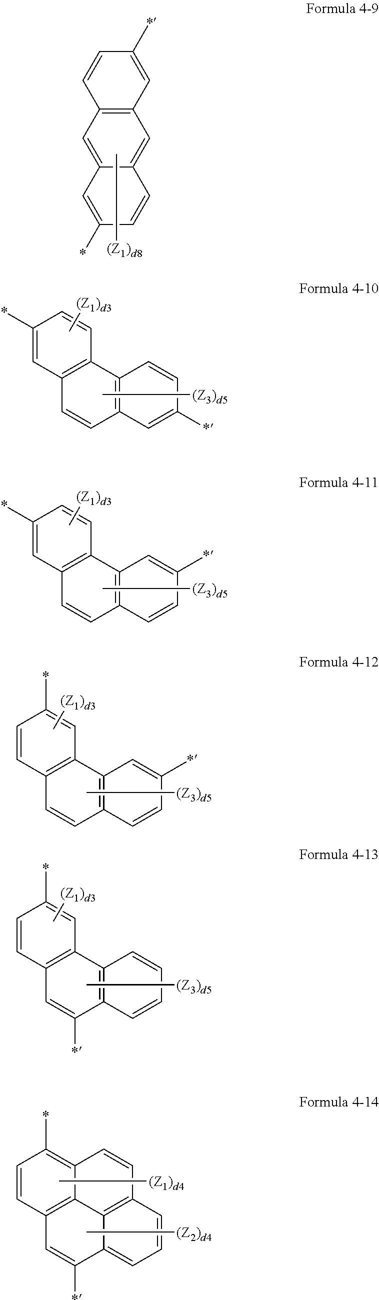

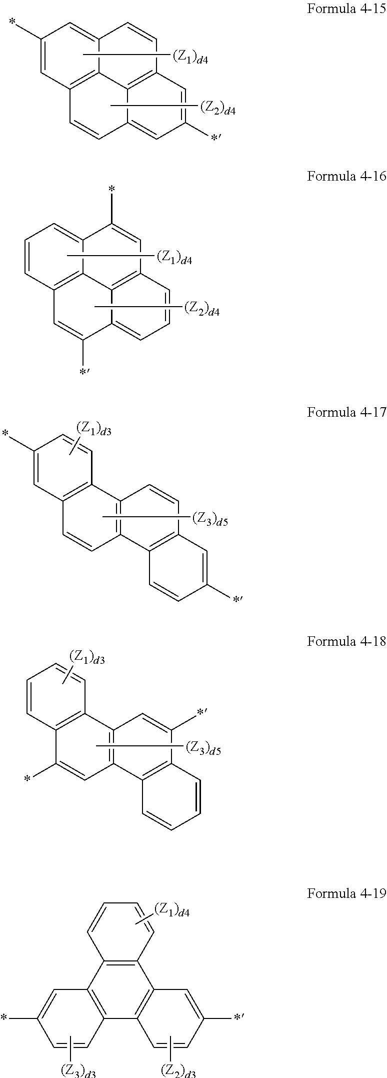

In Formulae 4-1 to 4-19,

Z₁ to Z₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group,

d3 is an integer selected from 1 to 3, d4 is an integer selected from 1 to 4, d5 is an integer selected from 1 to 5, d6 is an integer selected from 1 to 6, d8 is an integer selected from 1 to 8, and * and *′ are a binding site to a neighboring atom.

In some embodiments, in Formulae 1-1 to 1-3, 2-1, and 2-2,

L₁, L₁₁, and L₁₂ are each independently represented by one of Formulae 5-1 to 5-16, aa and bb may be each independently 0 or 1, ba may be 1 or 2, and be may be 0, but embodiments are not limited thereto:

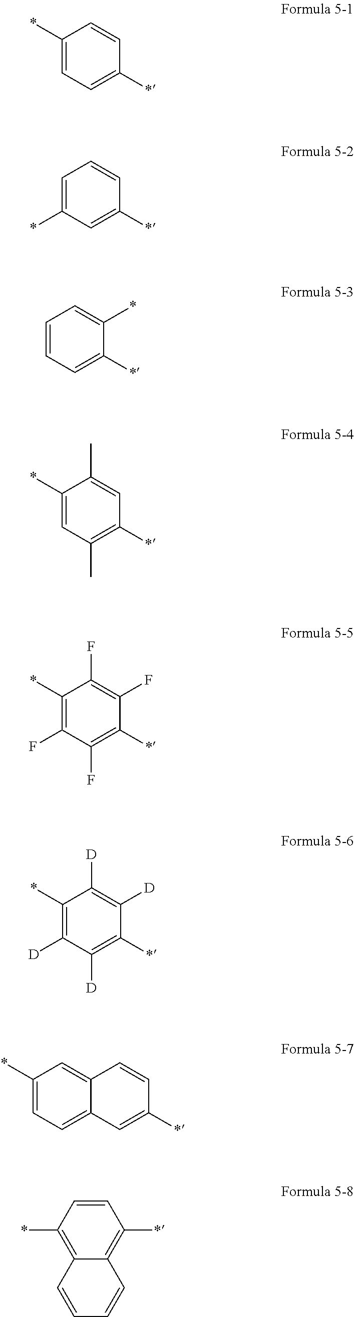

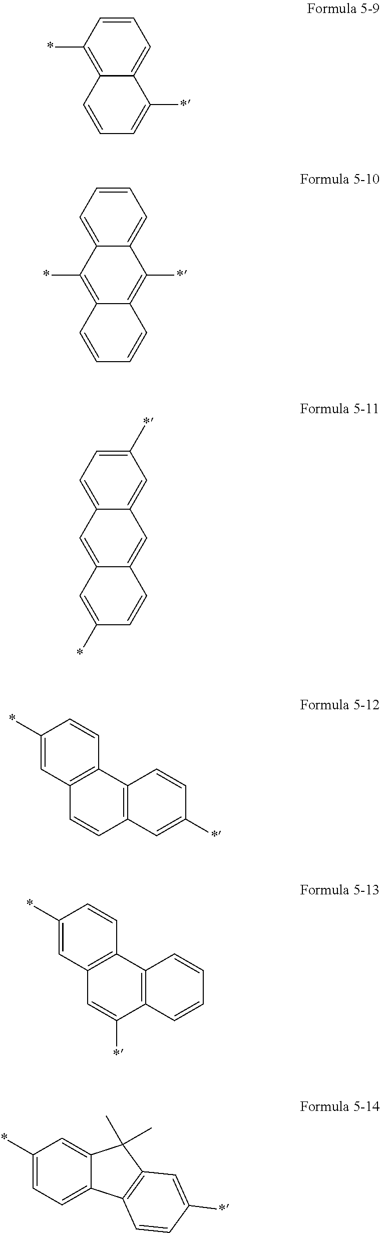

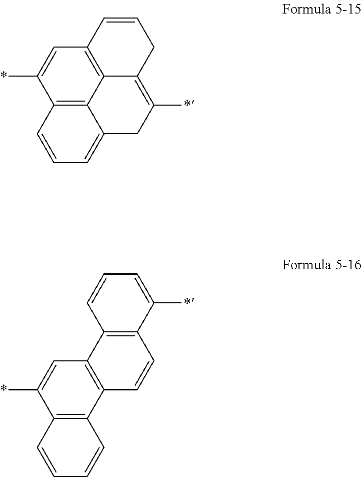

In Formulae 5-1 to 5-16, * and *′ are a binding site to a neighboring atom.

For example, in Formulae 1-1 to 1-3, 2-1, and 2-2,

L₁, L₁₁, and L₁₂ may be each independently represented by one of Formulae 6-1 and 6-2, where aa and bb may be each independently 0 or 1, ba may be 1 or 2, and be may be 0:

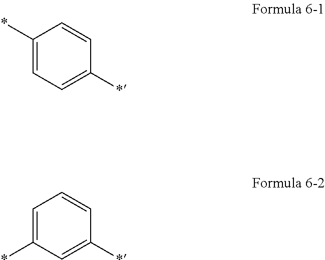

In Formulae 1-1 to 1-3, 2-1, and 2-2,

R₁₁, R₁₂, and R₅₁ to R₆₃ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and N(Q₆)(Q₇);

ab and bd may be each independently selected from 1, 2, and 3, when ab is 2 or greater; two or more R₁₁(s) may be identical to or different from each other; and when bd is 2 or greater, two or more R₁₂(s) may be identical to or different from each other, but embodiments are not limited thereto.

In some embodiments, the first compound may be represented by one of Formulae 1-1(A), 1-1(B), 1-2(A), 1-2(B), 1-3(A), and 1-3(B).

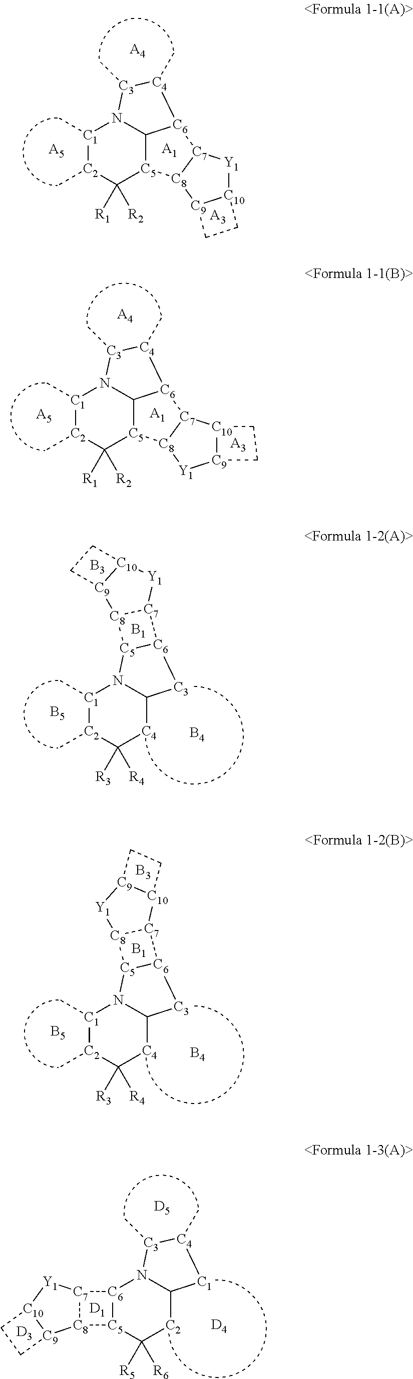

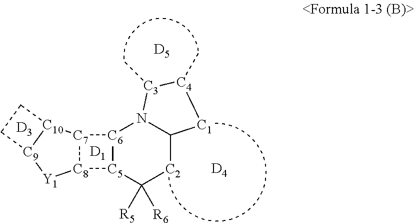

In Formulae 1-1(A), 1-1(B), 1-2(A), 1-2(B), 1-3(A), and 1-3(B),

C₁ to C₁₀ are each independently numbered to indicate chemically distinct carbon atoms,

ring A₁ is represented by one of Formulae 5-1(1) and 5-1(2),

ring B₁ is represented by one of Formulae 5-2(1) to 5-2(5),

ring D₁ is represented by one of Formulae 5-3(1) to 5-3(5),

ring A₃ is represented by one of Formulae 6-1(1) to 6-1(4),

ring B₃ is represented by one of Formulae 6-2(1) to 6-2(4),

ring D₃ is represented by one of Formulae 6-3(1) to 6-3(4),

ring A₄ is represented by one of Formulae 7-1(1) to 7-1(4),

ring B₄ is represented by one of Formulae 7-2(1) to 7-2(3),

ring D₄ is represented by one of Formulae 7-3(1) to 7-3(3),

rings A₅ and B₅ are each independently represented by one of Formulae 8-1(1) to 8-1(4), and

ring D₅ is represented by one of Formulae 8-3(1) to 8-3(4).

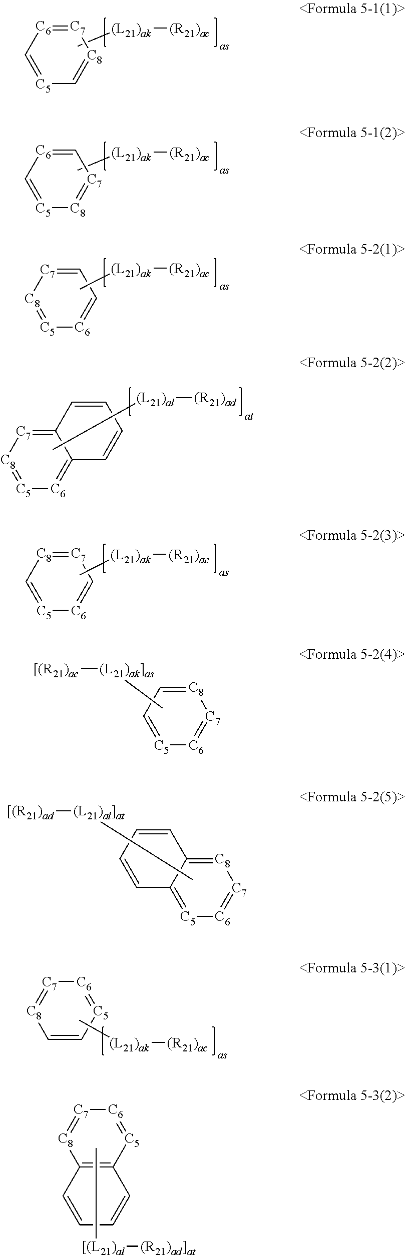

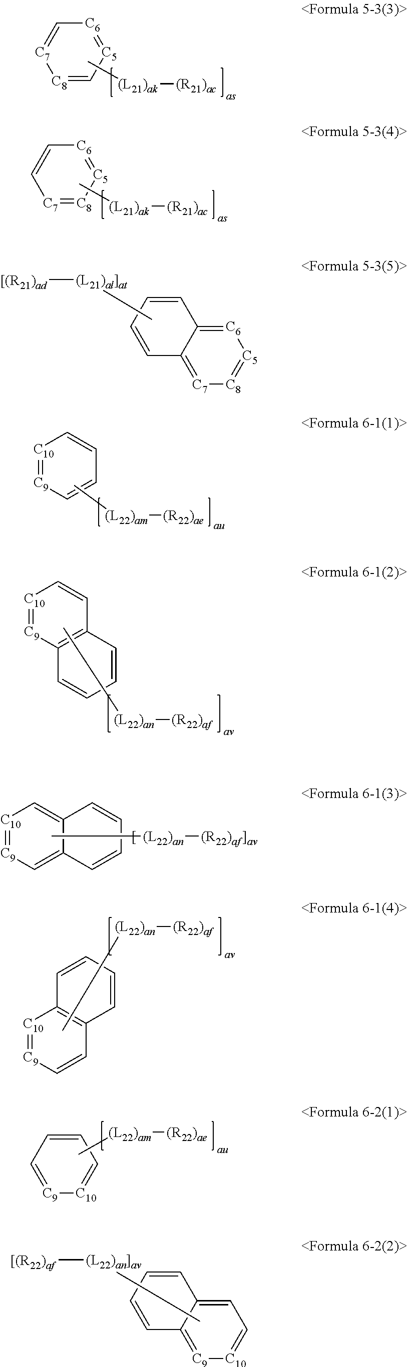

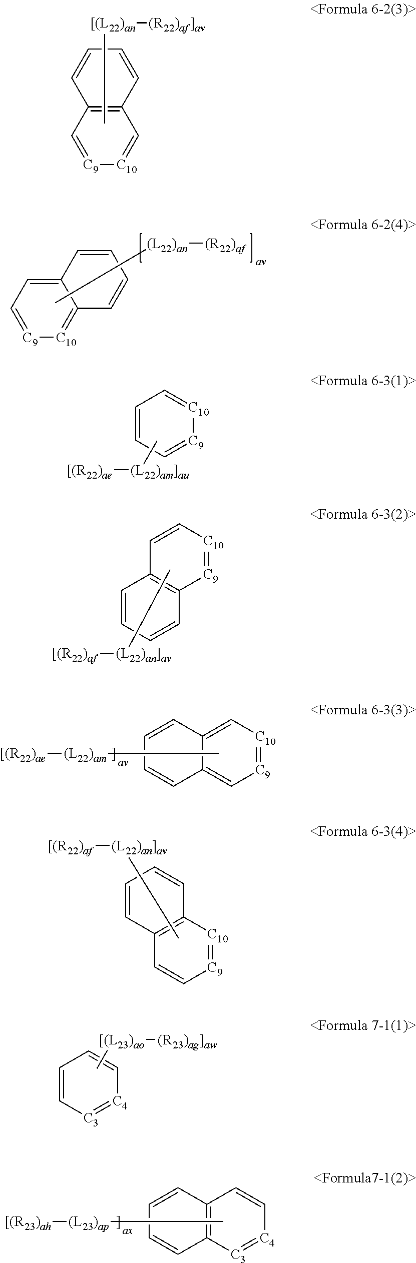

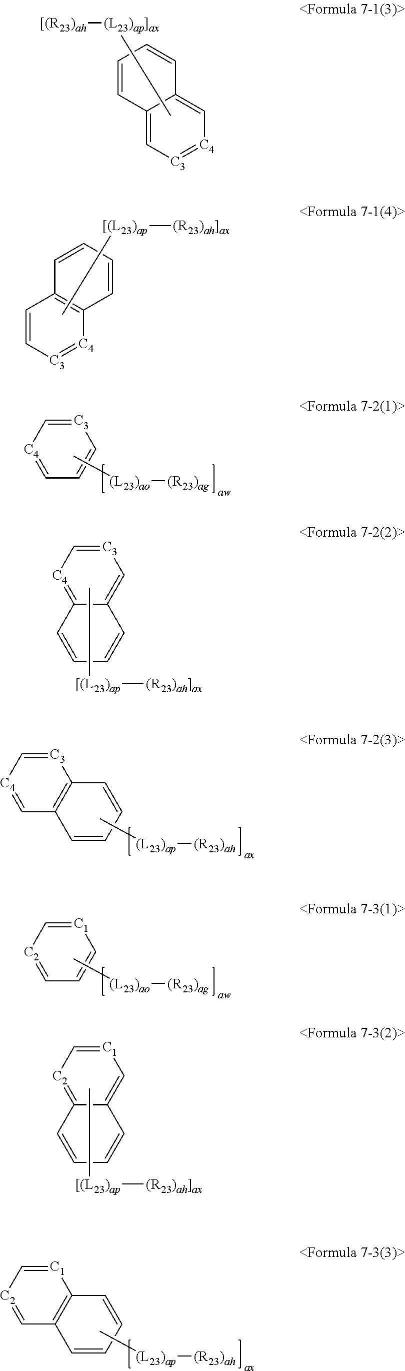

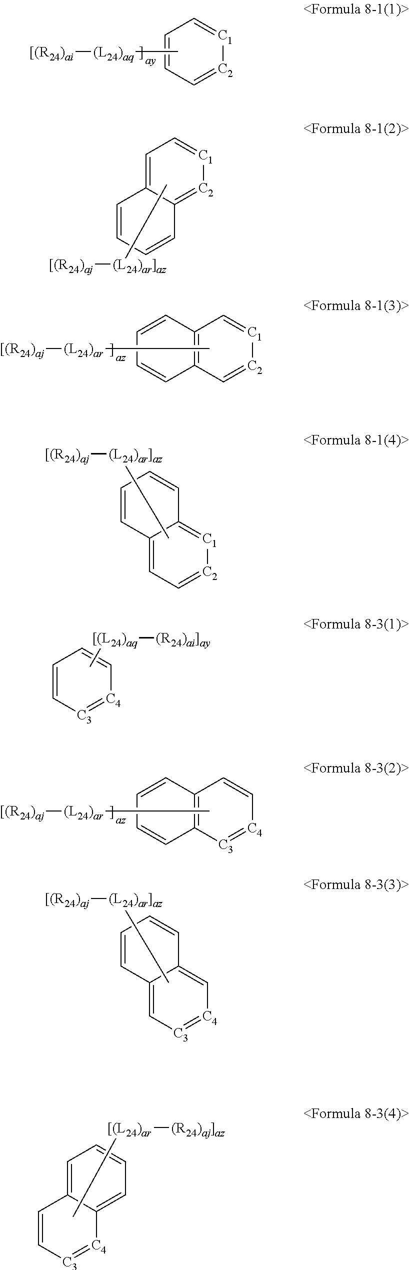

In Formulae 5-1(1) and 5-1(2), 5-2(1) to 5-2(5), 5-3(1) to 5-3(5), 6-1(1) to 6-1(4), 6-2(1) to 6-2(4), 6-3(1) to 6-3(4), 7-1(1) to 7-1(4), 7-2(1) to 7-2(3), 7-3(1) to 7-3(3), 8-1(1) to 8-1(4), and 8-3(1) to 8-3(4),

L₂₁ to L₂₄ are each independently the same as defined in connection with L₁;

ak to ar are each independently selected from 0, 1, 2, and 3;

R₂₁ to R₂₄ are each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and N(Q₆)(Q₇);

ac to aj may be each independently selected from 0, 1, 2, and 3, and, when ac is 2 or greater, two or more R₂₁(s) are identical to or different from each other, when ad is 2 or greater, two or more R₂₁(s) are identical to or different from each other, when ae is 2 or greater, two or more R₂₂(s) are identical to or different from each other, when af is 2 or greater, two or more R₂₂(s) are identical to or different from each other, when ag is 2 or greater, two or more R₂₃(s) are identical to or different from each other, when ai is 2 or greater, two or more R₂₄(s) are identical to or different from each other, when ah is 2 or greater, two or more R₂₃(s) are identical to or different from each other, when ai is 2 or greater, two or more R₂₄(s) are identical to or different from each other, and, when aj is 2 or greater, two or more R₂₄(s) are identical to or different from each other;

as may be selected from 0, 1, and 2, and, when as is 2 or greater, two or more *-[(L₂₁)ₐₖ-(R₂₁)_{ac}](S) may be identical to or different from each other;

at, au, aw, and ay may be each independently selected from 0, 1, 2, 3, and 4, and, when at is 2 or greater, two or more *-[(L₂₁)_{ad}-(R₂₁)ₐₗ](S) are identical to or different from each other, when au is 2 or greater, two or more *-[(L₂₂)ₐₘ-(R₂₂)ₐₑ](s) are identical to or different from each other, when aw is 2 or greater, two or more *-[(L₂₃)ₐₒ-(R₂₃)_{ag}](s) are identical to or different from each other, and, when ay is 2 or greater, two or more *-[(L₂₄)_{aq}-(R₂₄)ₐᵢ](s) are identical to or different from each other; and

av, ax, and az may be each independently selected from 0, 1, 2, 3, 4, 5, and 6, and, when av is 2 or greater, two or more *-[(L₂₂)ₐₙ-(R₂₂)ₐᵣ](s) are identical to or different from each other, when ax is 2 or greater, two or more *-[(L₂₃)ₐₚ-(R₂₃)ₐₕ](s) are identical to or different from each other, and, when az is 2 or greater, two or more *-[(L₂₄)ₐᵣ-(R₂₄)ₐⱼ](s) are identical to or different from each other.

In some embodiments, in Formulae 1-1(A), 1-1(B), 1-2(A), 1-2(B), 1-3(A), and 1-3(B),

R₁₁ and R₂₁ to R₂₄ are each independently selected from a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinyl group, a benzimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group; and

a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinyl group, a benzimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, phenanthridinyl, acridinyl, phenanthrolinyl, phenazinyl, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, but embodiments are not limited thereto.

For example, in Formulae 1-1(A), 1-1(B), 1-2(A), 1-2(B), 1-3(A), and 1-3(B), R₁₁ and R₂₁ to R₂₄ may be each independently selected from groups represented by Formulae 7-1 to 7-44:

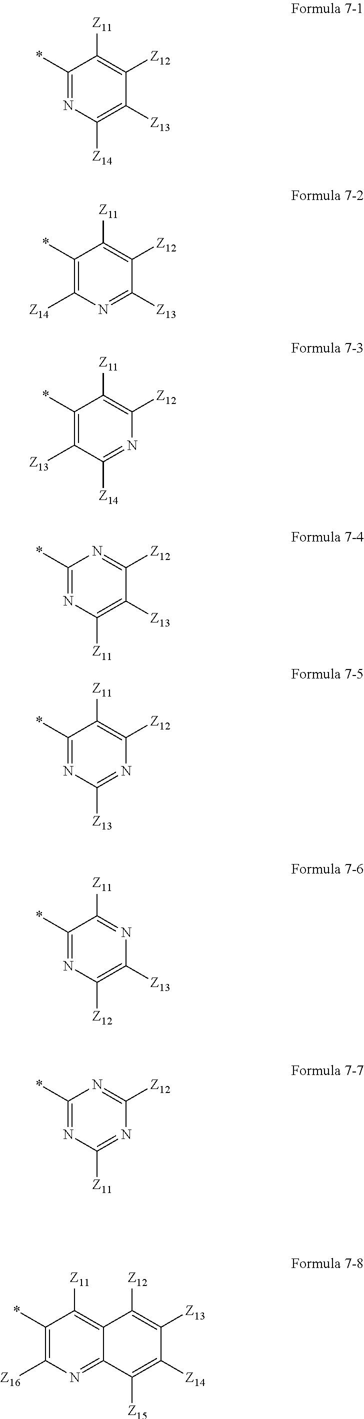

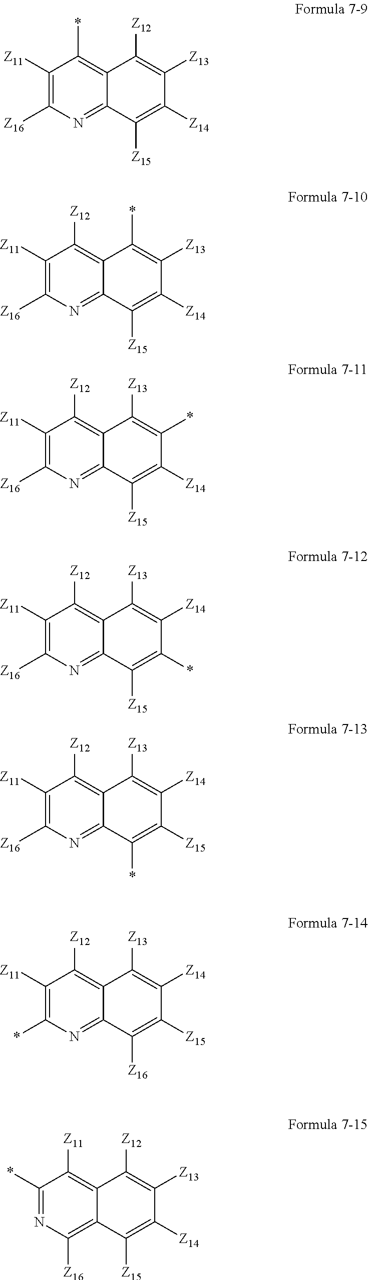

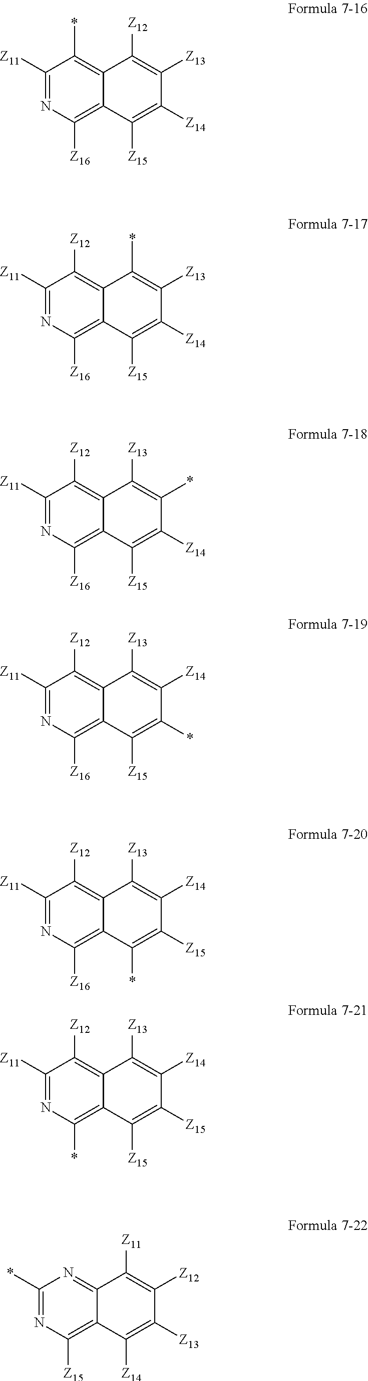

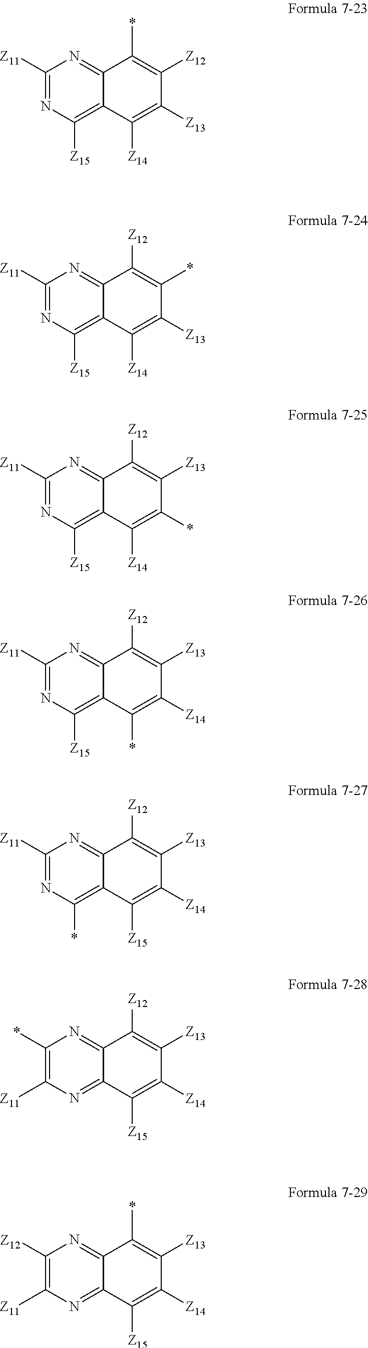

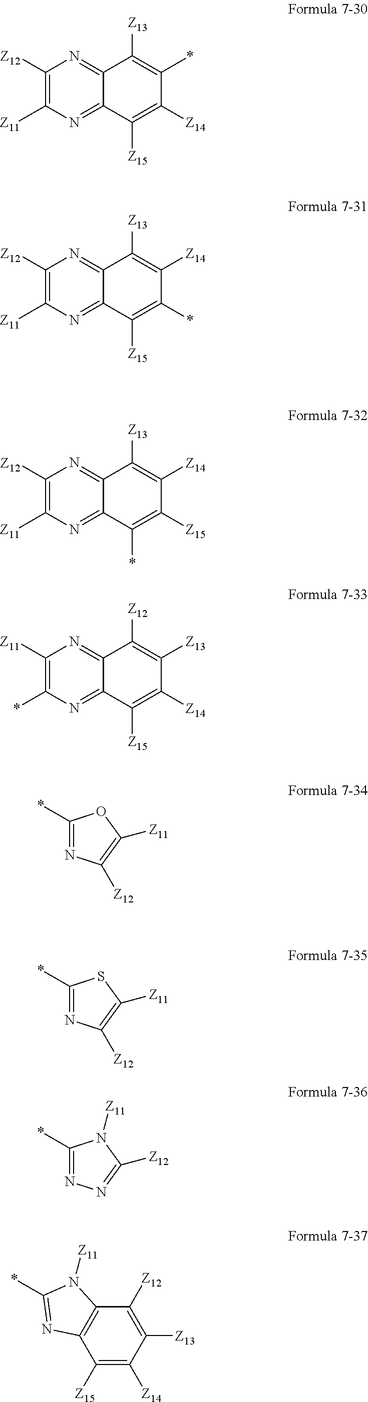

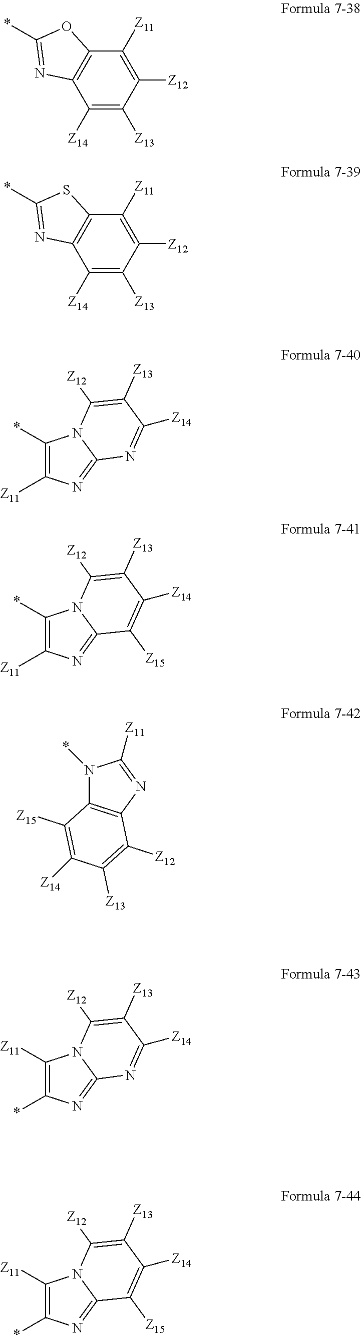

In Formulae 7-1 to 7-44,

Z₁₁ to Z₁₆ are each independently selected from a hydrogen, a deuterium, —F, —Cl, —Br, —I, a hydroxyl group, a cyano group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, phenanthridinyl, acridinyl, phenanthrolinyl, phenazinyl, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, and * is a binding site to a neighboring atom.

In some embodiments, in Formulae 1-1(A), 1-1(B), 1-2(A), 1-2(B), 1-3(A), and 1-3(B), wherein, in Formula 3, Y₁ is N-(L₁)ₐₐ-(R₁₁)_{ab},

L may be represented by one of Formulae 5-1 to 5-16, aa may be 0 or 1, R₁₁ is represented by one of Formulae 8-1 to 8-11, and ab may be 1:

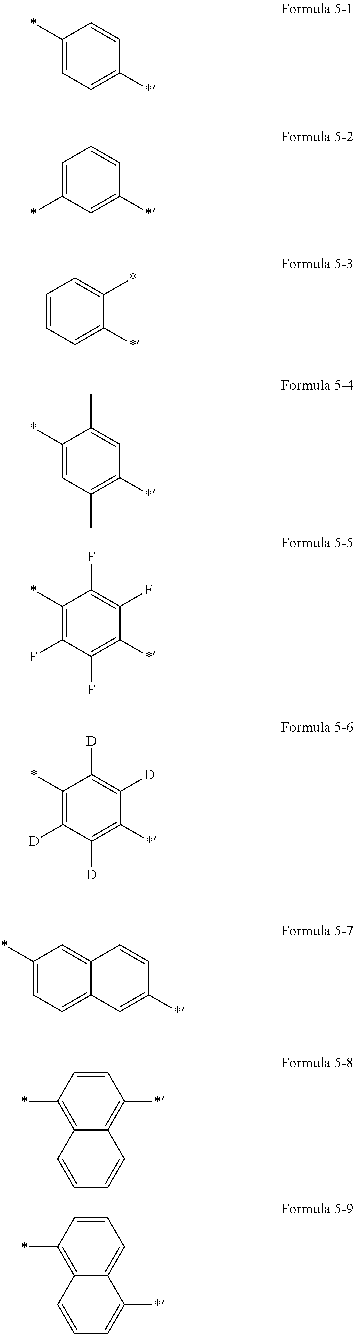

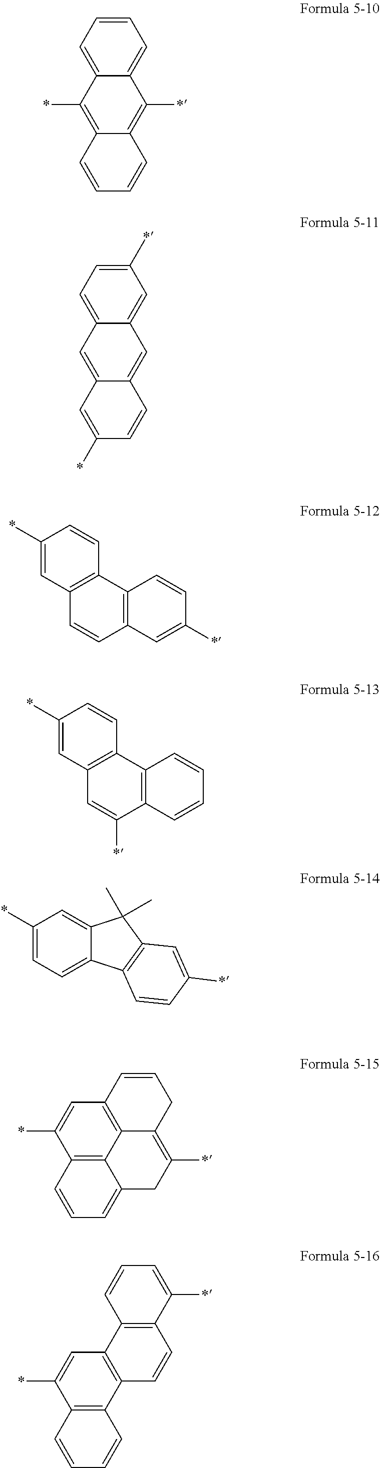

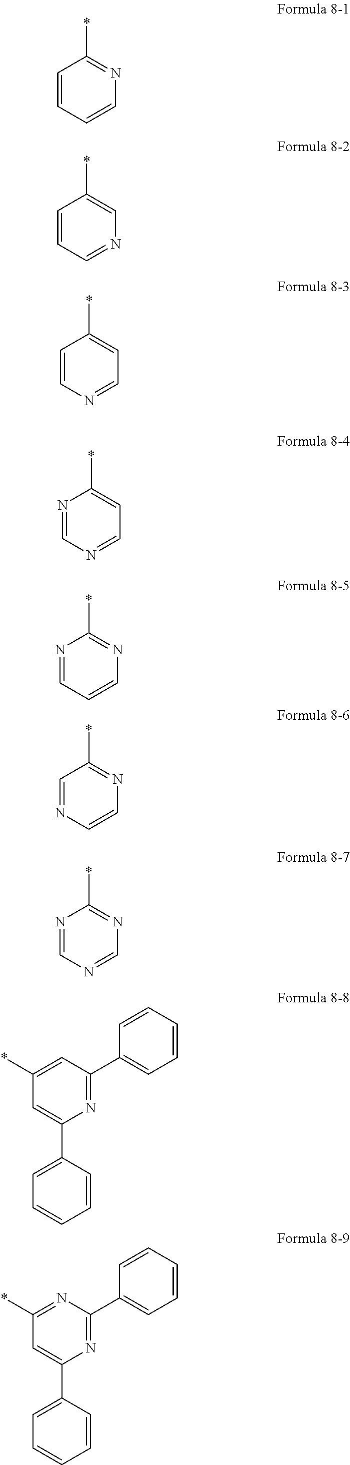

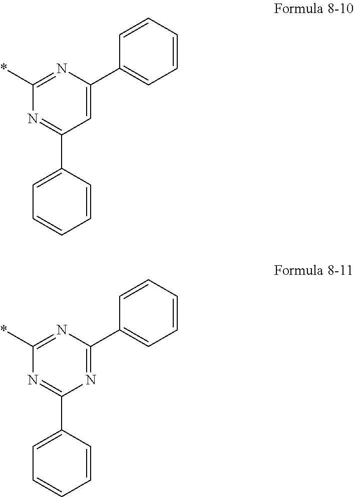 [SMILES: *c1nc(-c2ccccc2)cc(-c2ccccc2)n1 ; *c1nc(-c2ccccc2)nc(-c2ccccc2)n1]

In Formulae 5-1 to 5-16 and 8-1 to 8-11, * and *′ are a binding site to a neighboring atom.

In Formulae 1-1(A), 1-1(B), 1-2(A), 1-2(B), 1-3(A), and 1-3(B),

wherein, in Formula 3, Y₁ is S or O,

ring A₅ and ring B₅ may be each independently represented by one of Formulae 8-1(1) to 8-1(4), and ring D₅ may be represented by one of Formulae 8-3(1) to 8-3(4):

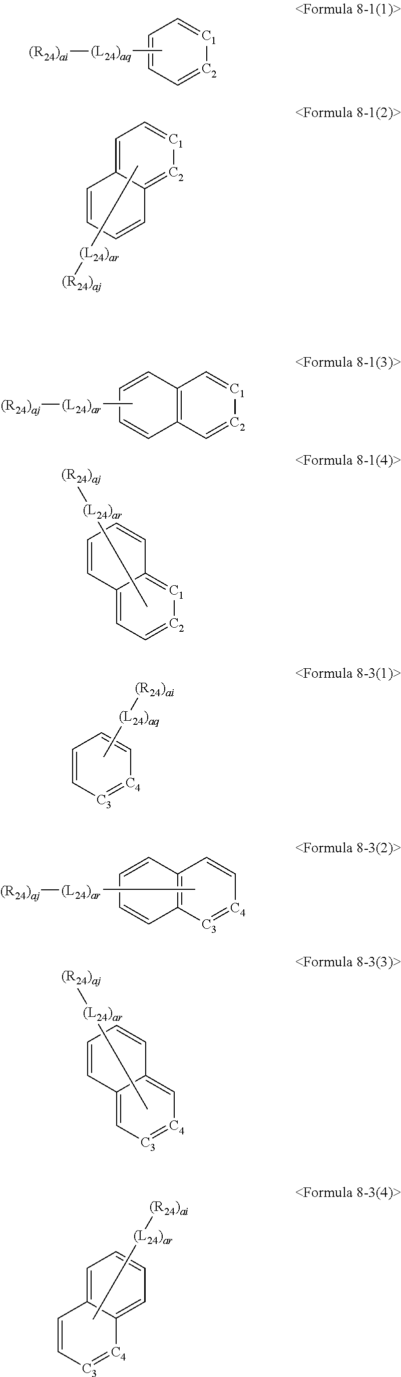

In Formulae 8-1(1) to 8-1(4) and Formulae 8-3(1) to 8-3(4),

L₂₄ is represented by one of Formulae 5-1 to 5-16;

aq and ar are each independently 0 or 1;

R₂₄ is represented by one of Formulae 8-1 to 8-11;

ai and aj are each independently 1:

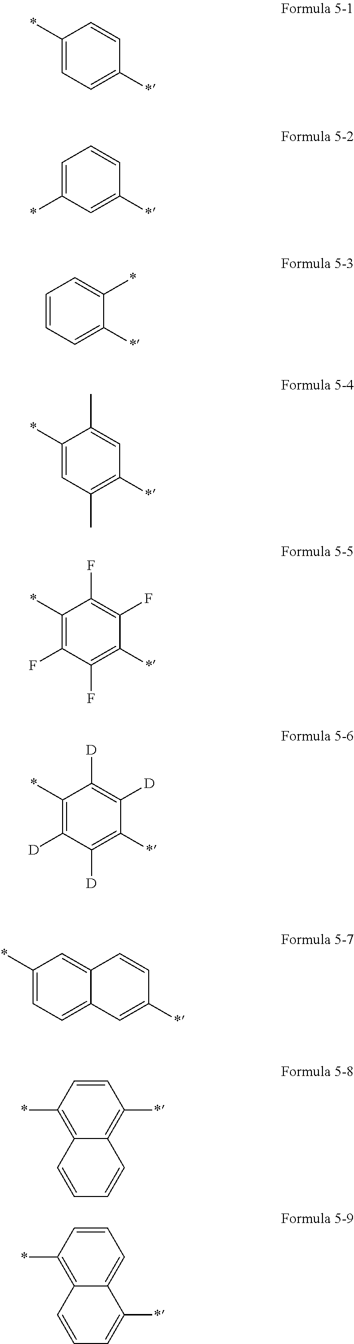

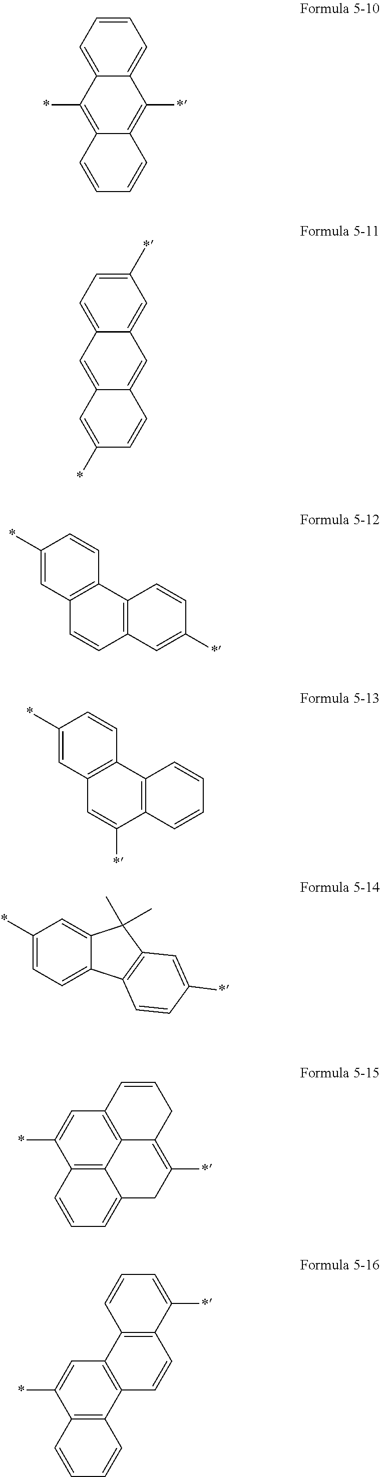

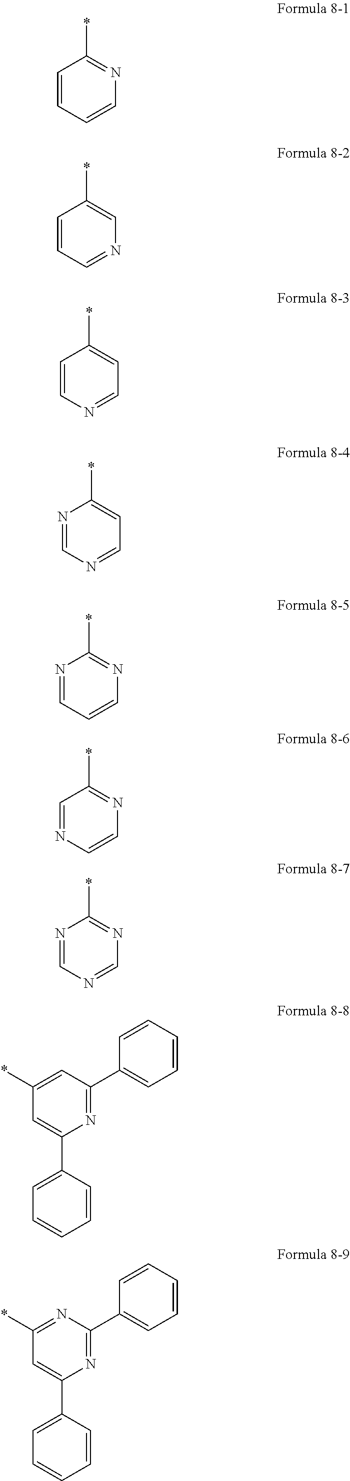

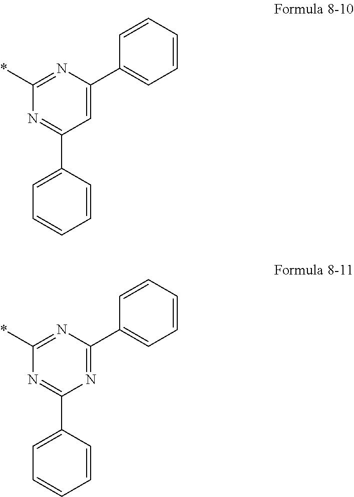 [SMILES: *c1nc(-c2ccccc2)cc(-c2ccccc2)n1 ; *c1nc(-c2ccccc2)nc(-c2ccccc2)n1]

In Formulae 5-1 to 5-16 and 8-1 to 8-11, * and *′ are a binding site to a neighboring atom.

In some embodiments, the first compound may be represented by Formula 1-1(A), 1-2(A), or 1-3(A), wherein, in Formulae 1-1(A), 1-2(A), and 1-3(A),

ring A₁ is represented by one of Formulae 5-1(1) and 5-1(2),

ring B₁ is represented by one of Formulae 5-2(1) and 5-2(3),

ring D₁ is represented by one of Formulae 5-3(1) and 5-3(3),

ring A₃ is represented by one of Formulae 6-1(1) and 6-1(2),

ring B₃ is represented by one of Formulae 6-2(1) and 6-2(2),

ring D₃ is represented by one of Formulae 6-3(1) and 6-3(4),

ring A₄ is represented by one of Formulae 7-1 (1) and 7-1(3),

ring B₄ is represented by one of Formulae 7-2(1) and 7-2(3),

ring D₄ is represented by one of Formulae 7-3(1) and 7-3(2),

ring A₅ is represented by one of Formulae 8-1(1) and 8-1(3),

ring B₅ is represented by one of Formulae 8-2(1) and 8-2(3), and

ring D₅ is represented by one of Formulae 8-3(1) and 8-3(4).

In some embodiments, the second compound may be represented by one of Formulae 2-1(A) and 2-2(A):

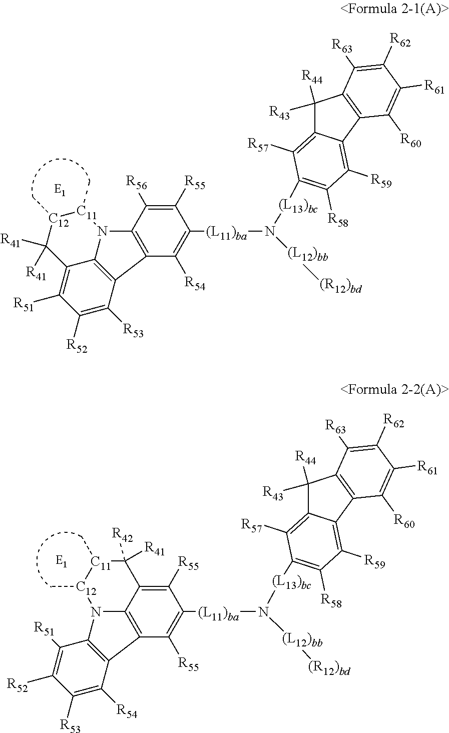

In Formulae 2-1(A) and 2-2(A), C₁₁ and C₁₂ are each independently numbered to indicate chemically distinct carbon atoms,

ring E₁ is represented by one of Formulae 9-1(1) to 9-1(4),

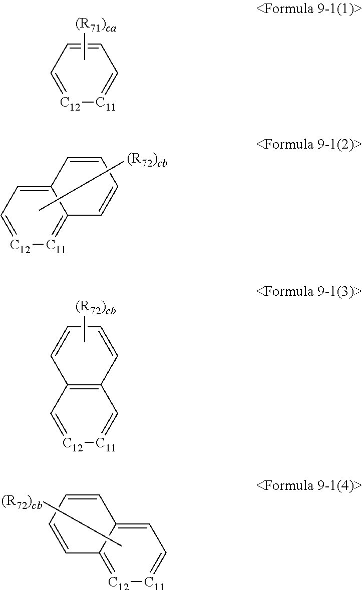

In Formulae 2-1(A), 2-2(A), and 9-1(1) to 9-1(4),

R₄₁ to R₄₄ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, and a naphthyl group;

a phenyl group, a naphthyl group, a fluorenyl group, a phenanthrenyl group, an anthracenyl group, a fluoranthenyl group, a triphenylenyl group, a pyrenyl group, and a chrysenyl group; and

a phenyl group, a naphthyl group, a fluorenyl group, a phenanthrenyl group, an anthracenyl group, a fluoranthenyl group, a triphenylenyl group, a pyrenyl group, and a chrysenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, and a chrysenyl group, but embodiments are not limited thereto.

For example, in Formulae 2-1(A), 2-2(A), and 9-1(1) to 9-1(4),

R₄₁ to R₄₄ may be each independently a methyl group or a phenyl group.

In some embodiments, in Formulae 2-1(A) and 2-2(A),

L₁₁ to L₁₃ may be each independently represented by one of Formulae 5-1 to 5-16;

ba may be 1 or 2, bb and be may be each independently 0 or 1, and, when ba is 2, the two L₁₁(s) are identical to or different from each other;

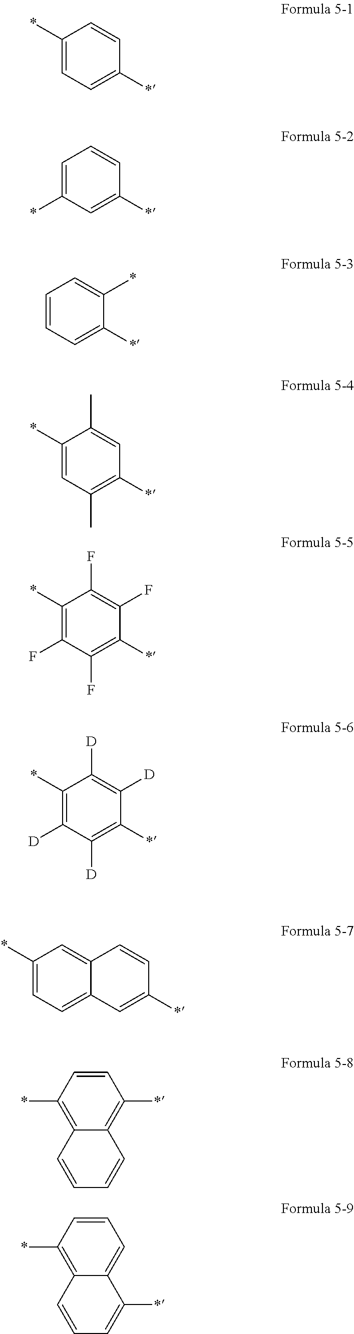

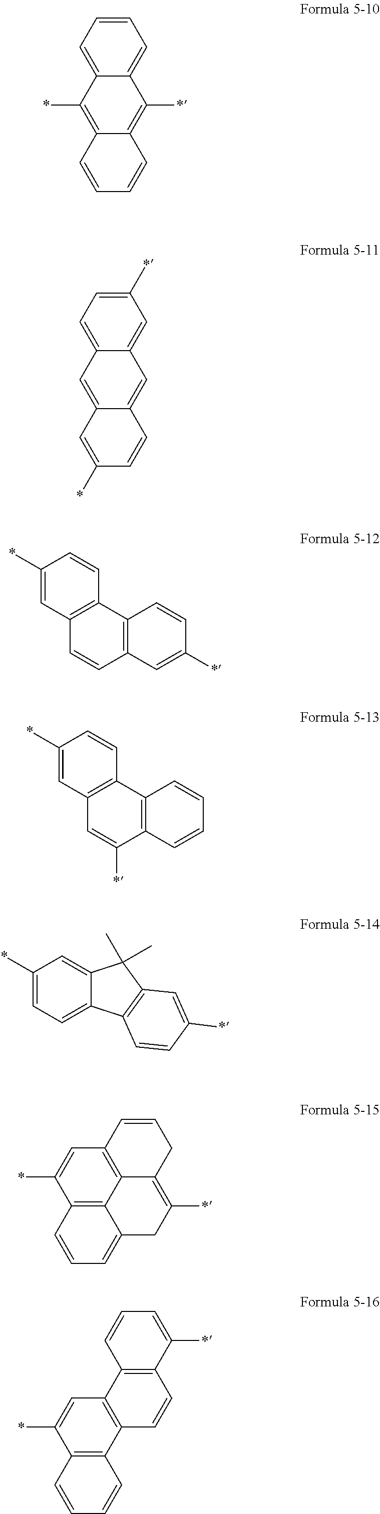

In Formulae 5-1 to 5-16, * and *′ are a binding site to a neighboring atom.

In some embodiments, in Formulae 2-1(A), 2-2(A), and 9-1(1) to 9-1(4),

R₁₂ may be selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, a dibenzocarbazolyl group, and —Si(Q₃₁)(Q₃₂)(Q₃₃),

wherein Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group; and

bd is selected from 1, 2, and 3, and, when bd is 2 or greater, two or more R₁₂(s) may be identical to or different from each other, but embodiments are not limited thereto.

For example, in Formulae 2-1(A), 2-2(A), and 9-1(1) to 9-1(4),

R₁₂ may be represented by one of Formulae 9-1 to 9-6:

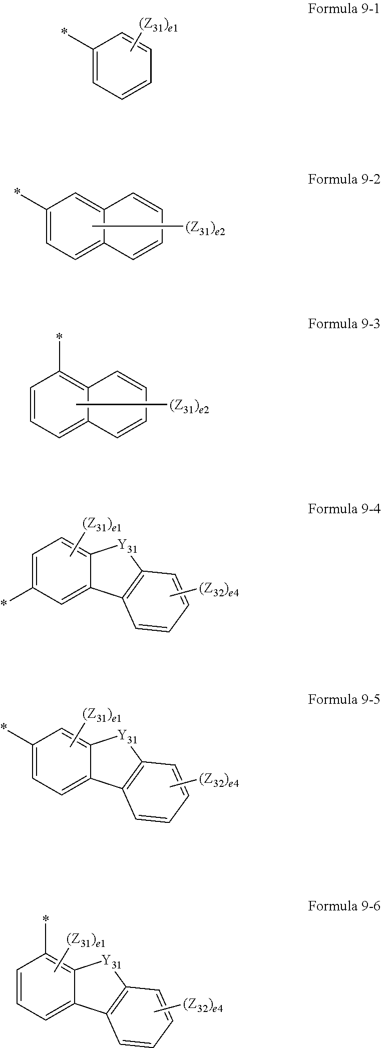

In Formulae 9-1 to 9-6,

Y₃₁ is C(Z₃₃)(Z₃₄) or N(Z₃₅);

Z₃₁ to Z₃₅ are each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, and a phosphoric acid or a salt thereof;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, and a naphthyl group; and

—Si(Q₃₁)(Q₃₂)(Q₃₃),

wherein Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group; and

e1 is an integer selected from 1 to 5, e2 is an integer selected from 1 to 7, e3 is an integer selected from 1 to 3, e4 is an integer selected from 1 to 4, and * is a binding site to a neighboring atom.

For example, in Formulae 2-1(A), 2-2(A), and 9-1(1) to 9-1(4),

R₁₂ may be one of Formulae 11-1 to 11-15:

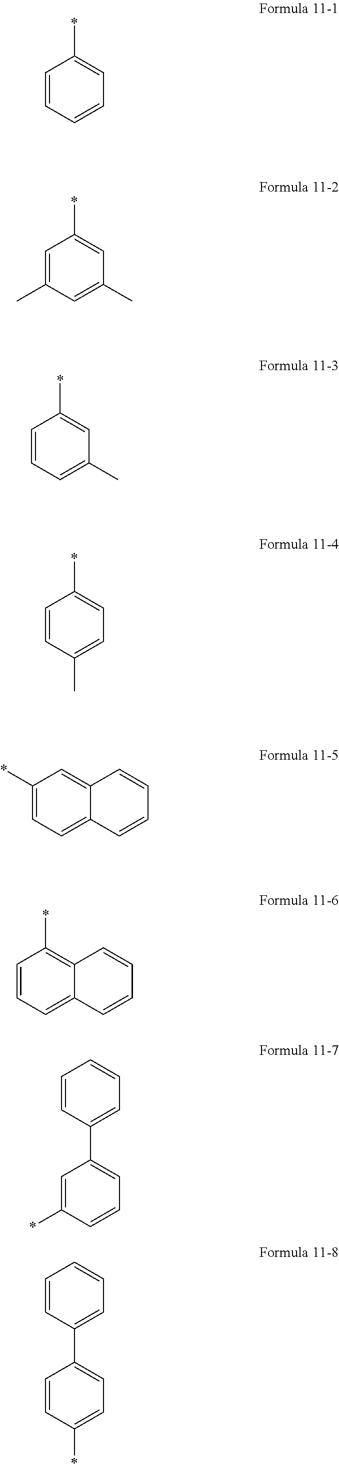

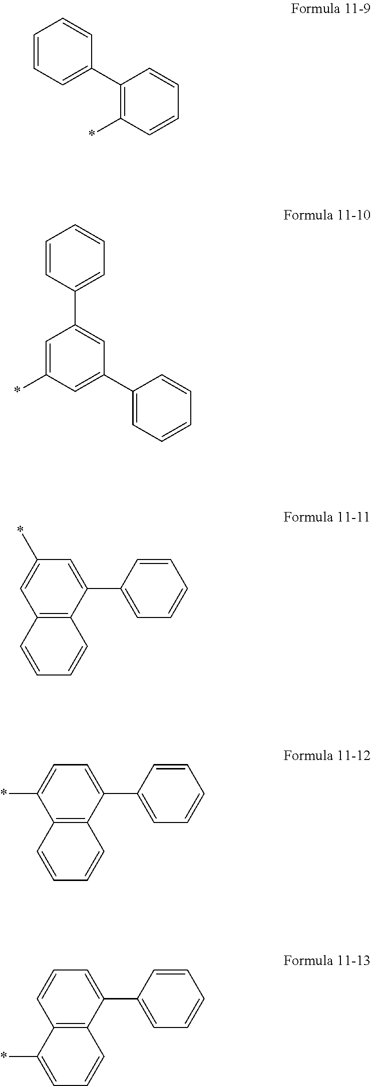 [SMILES: *c1ccccc1-c1ccccc1 ; *c1cc(-c2ccccc2)cc(-c2ccccc2)c1 ; *c1cc(-c2ccccc2)c2ccccc2c1 ; *c1ccc(-c2ccccc2)c2ccccc12 ; *c1cccc2c(-c3ccccc3)cccc12]

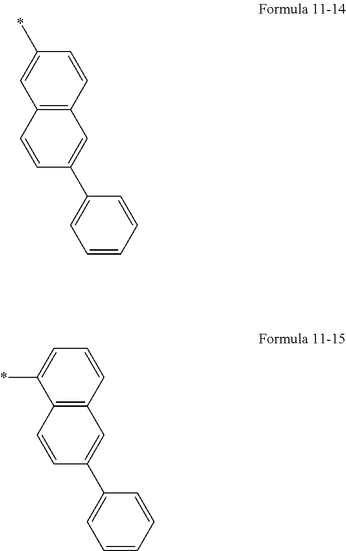 [SMILES: *c1ccc2cc(-c3ccccc3)ccc2c1 ; *c1cccc2cc(-c3ccccc3)ccc12]

In Formulae 11-1 to 11-15, * is a binding site to a neighboring atom.

For example, in Formulae 2-1(A), 2-2(A), and 9-1(1) to 9-1(4),

R₁₂ is one of Formulae 11-1 to 11-6, and bd may be 1.

In some embodiments, in Formulae 2-1(A), 2-2(A), and 9-1(1) to 9-1(4).

R₅₁ to R₆₃, R₇₁, and R₇₂ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₁-C₂₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃) —B(Q₄)(Q₅), and N(Q₆)(Q₇),

ca is selected from 0, 1, 2, 3, and 4, and, when ca is 2 or greater, two or more R₇₁(s) may be identical to or different from each other, but embodiments are not limited thereto.

For example, in Formulae 2-1(A), 2-2(A), and 9-1(1) to 9-1(4),

R₅₁ to R₆₃, R₇₁, and R₇₂ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, and one of Formulae 10-1 to 10-17:

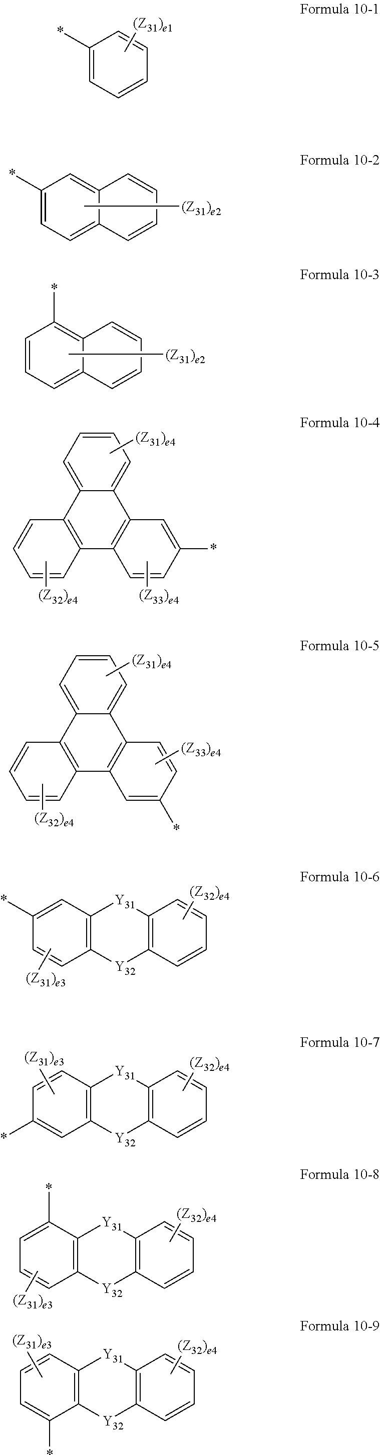

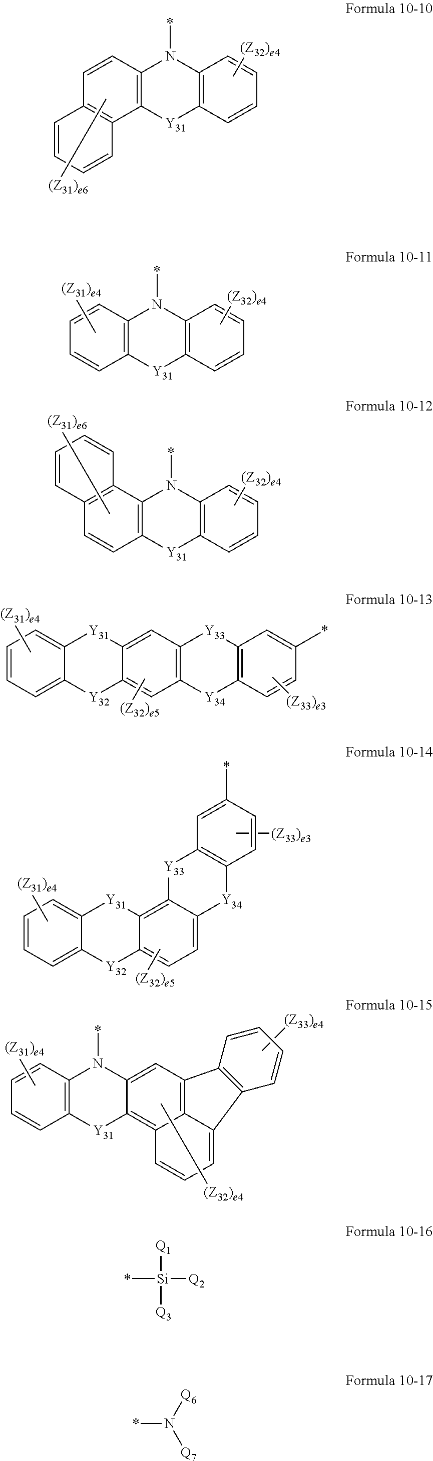

In Formulae 10-1 to 10-17,

Y₃₁ to Y₃₄ are each independently a single bond, O, S, C(Z₃₄)(Z₃₅), N(Z₃₆), or Si(Z₃₇)(Z₃₈);

Z₃₁ to Z₃₈ are each independently a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, and a phosphoric acid or a salt thereof;

a C₆-C₂₀ aryl group, a C₁-C₂₀ heteroaryl group, a monovalent non-aromatic condensed polycyclic group, and a monovalent non-aromatic condensed heteropolycyclic group; and

a C₆-C₂₀ aryl group, a C₁-C₂₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group;

Q₁ to Q₃, Q₆, and Q₇ of Formulae 10-16 and 10-17 may each independently be selected from:

a C₆-C₂₀ aryl group, a C₁-C₂₀ heteroaryl group, a monovalent non-aromatic condensed polycyclic group, and a monovalent non-aromatic condensed heteropolycyclic group; and

a C₆-C₂₀ aryl group, a C₁-C₂₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group:

e1 is an integer selected from 1 to 5, e2 is an integer selected from 1 to 7, e3 is an integer selected from 1 to 3, e4 is an integer selected from 1 to 4, e5 is an integer of 1 or 2, e6 is an integer selected from 1 to 6, and * is a binding site to a neighboring atom.

For example, in Formulae 10-1 to 10-17,

Z₃₁ to Z₃₈ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group; and

Q₁ to Q₃, Q₆, and Q₇ of Formulae 10-16 and 10-17 may each independently be selected from a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group.

For example, R₅₁ to R₆₃ and R₇₁ and R₇₂ may each independently be selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, and one of groups represented by Formulae 12-1 to 12-49:

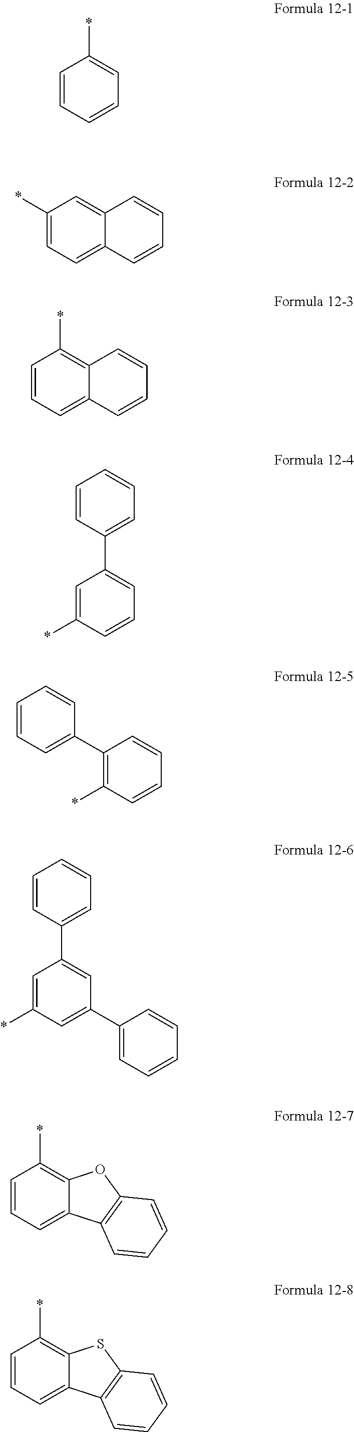

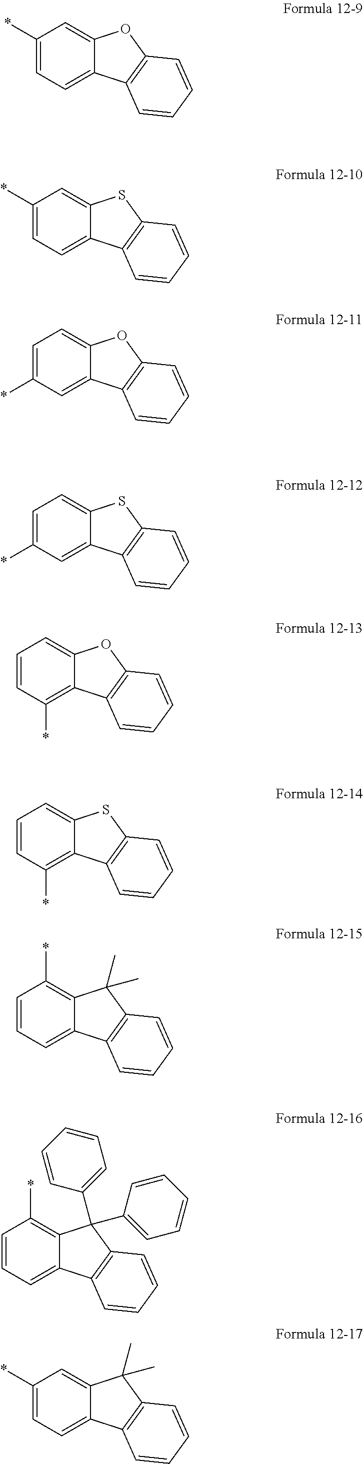

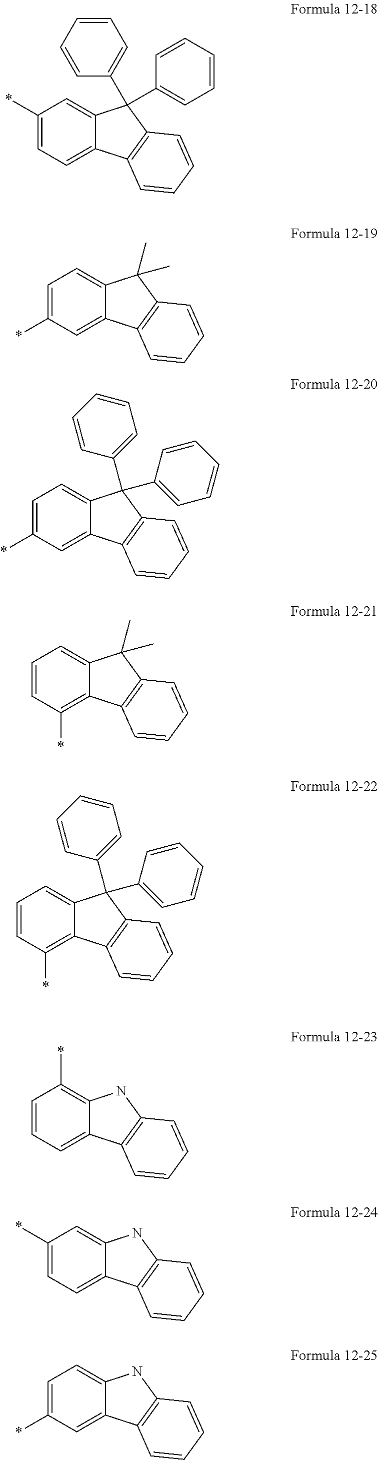

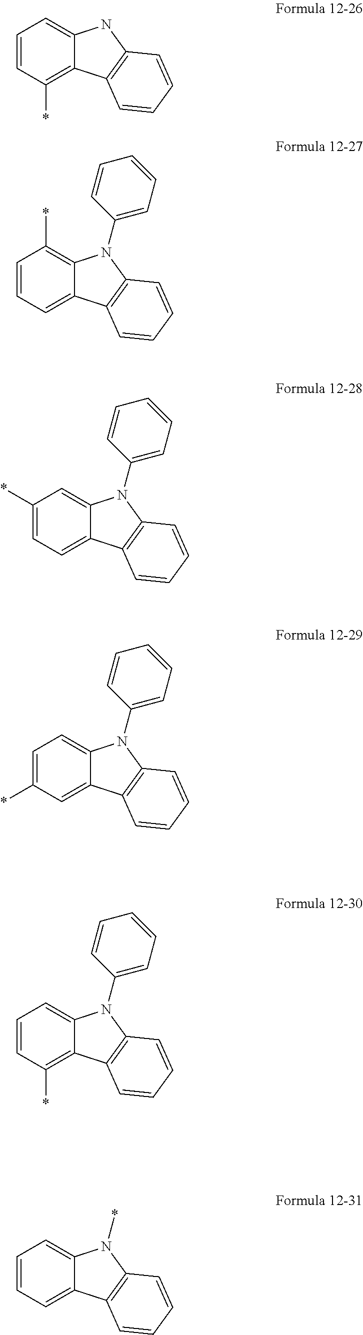 [SMILES: *c1cccc2[nH]c3ccccc3c12 ; *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1 ; *n1c2ccccc2c2ccccc21]

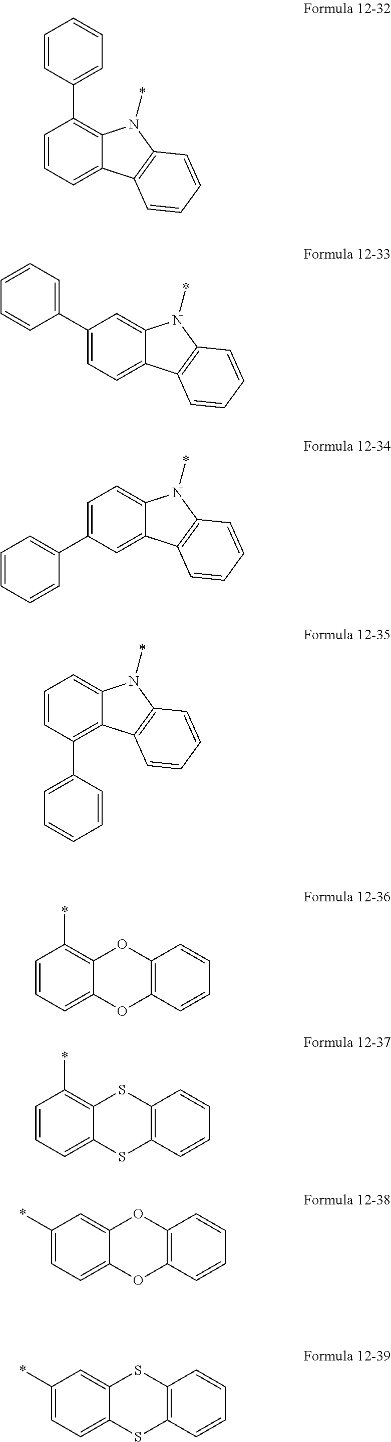

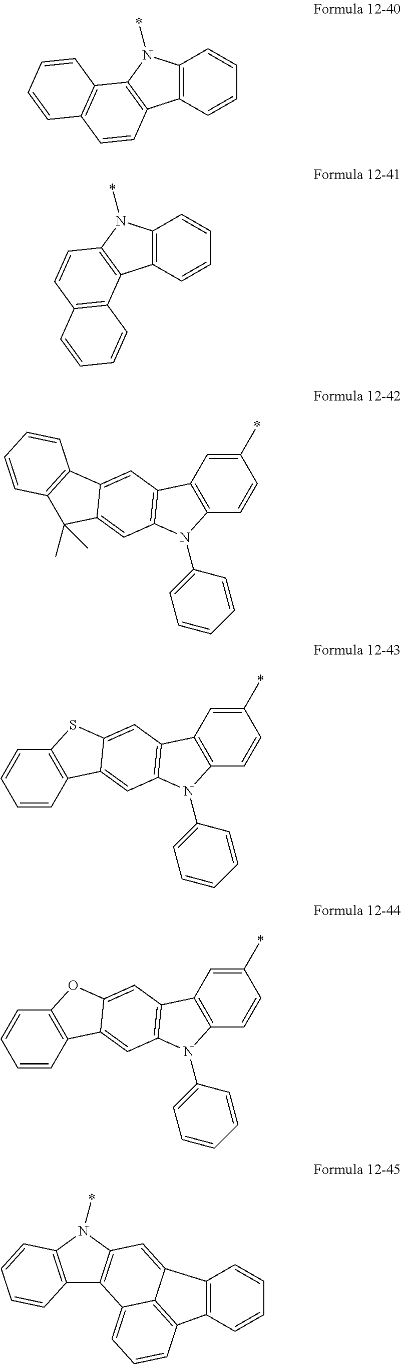 [SMILES: *n1c2ccccc2c2ccc3ccccc3c21 ; *n1c2ccccc2c2c3ccccc3ccc21 ; *c1ccc2c(c1)c1cc3c(cc1n2-c1ccccc1)C(C)(C)c1ccccc1-3 ; *c1ccc2c(c1)c1cc3sc4ccccc4c3cc1n2-c1ccccc1 ; *c1ccc2c(c1)c1cc3oc4ccccc4c3cc1n2-c1ccccc1 ; *n1c2ccccc2c2c3cccc4c3c(cc21)-c1ccccc1-4]

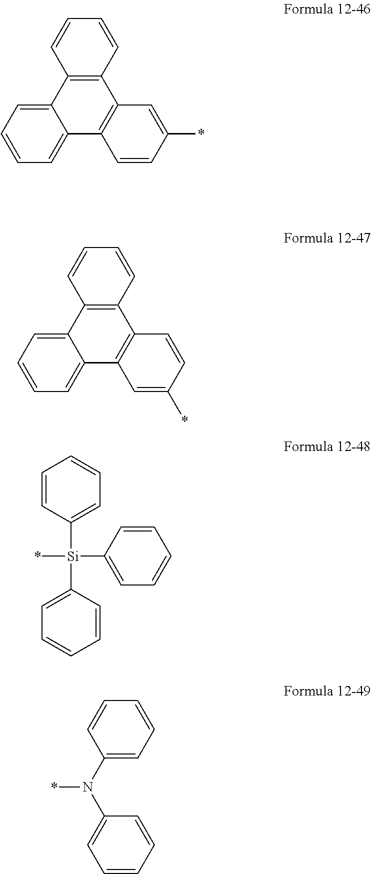 [SMILES: *c1ccc2c3ccccc3c3ccccc3c2c1 ; *c1ccc2c3ccccc3c3ccccc3c2c1 ; *[Si](c1ccccc1)(c1ccccc1)c1ccccc1 ; *N(c1ccccc1)c1ccccc1]

In Formulae 12-1 to 12-49, * is a binding site to a neighboring atom.

For example, in Formulae 2-1(A), 2-2(A), and 9-1(1) to 9-1(4),

R₇₁ and R₇₂ may be each independently Formula 12-1, and ca and cb may be each independently 0 or 1.

In some embodiments, the first compound may be represented by one selected from Formulae 1-1(A-1) to 1-1(A-20), 1-1(B-1) to 1-1(B-20), 1-2(A-1) to 1-2(A-27), 1-2(B-1) to 1-2(B-19), 1-3(A-1) to 1-3(A-29), and 1-3(B-1) to 1-3(B-27), and the second compound may be represented by one selected from Formulae 2-1(1) to 2-1(4) and 2-2(1) to 2-2(4), but embodiments are not limited thereto:

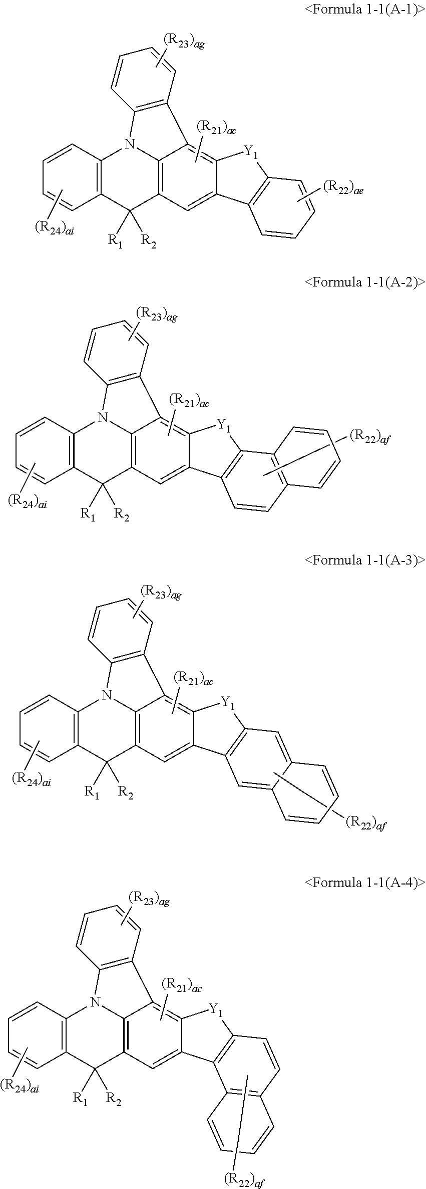

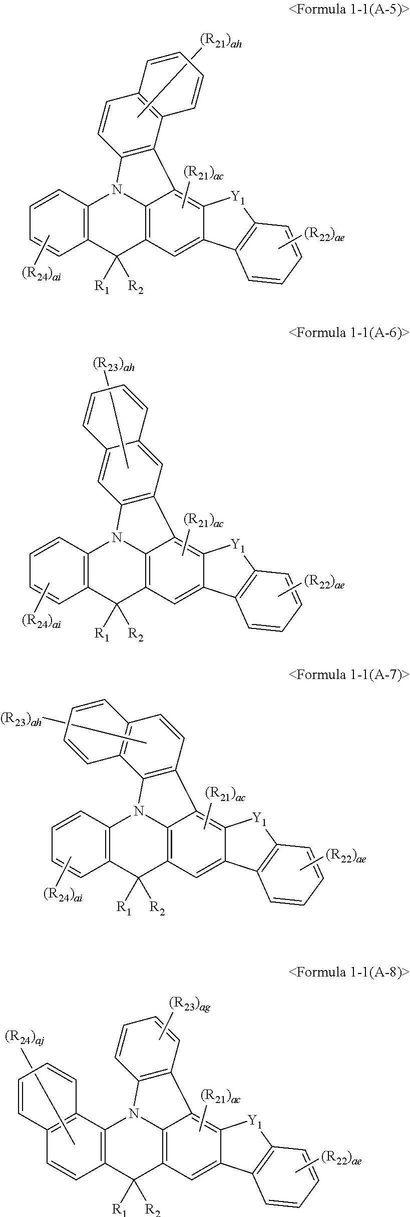

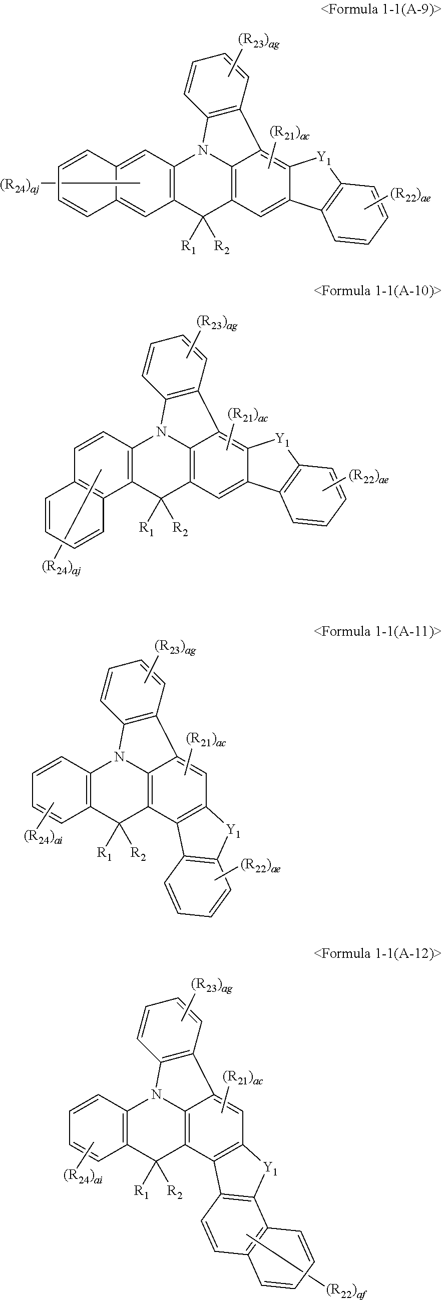

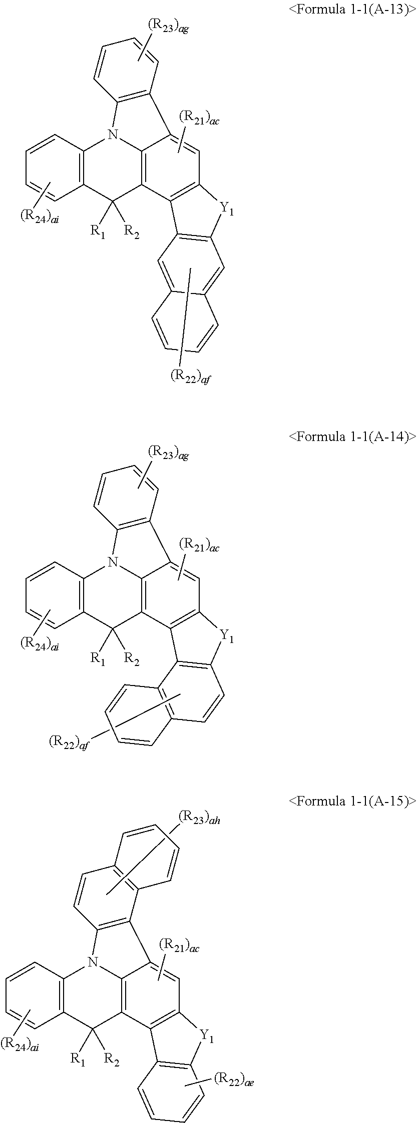

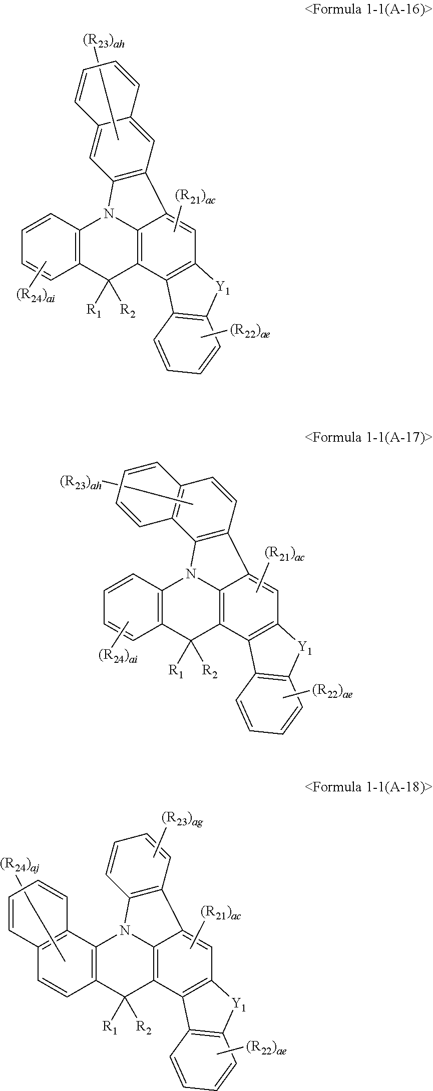

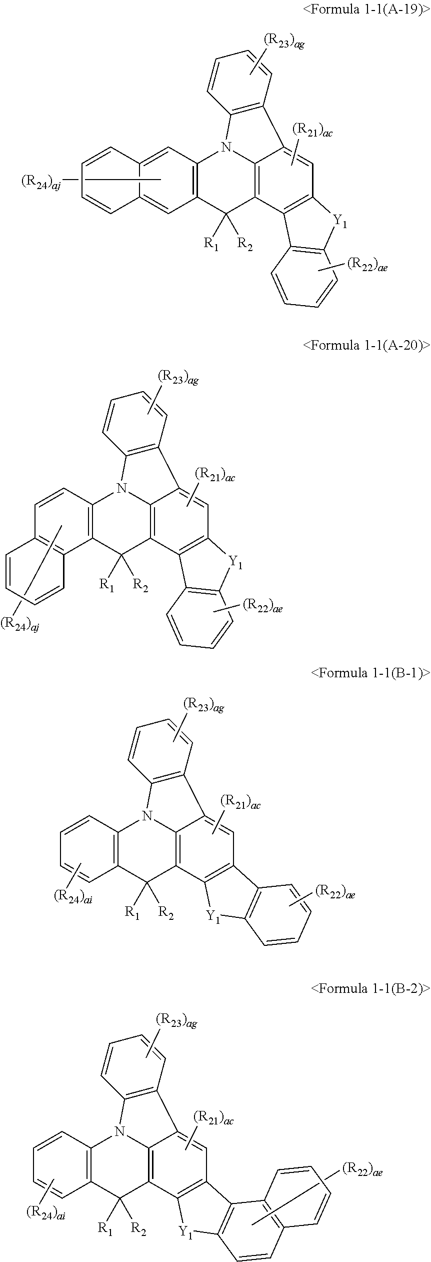

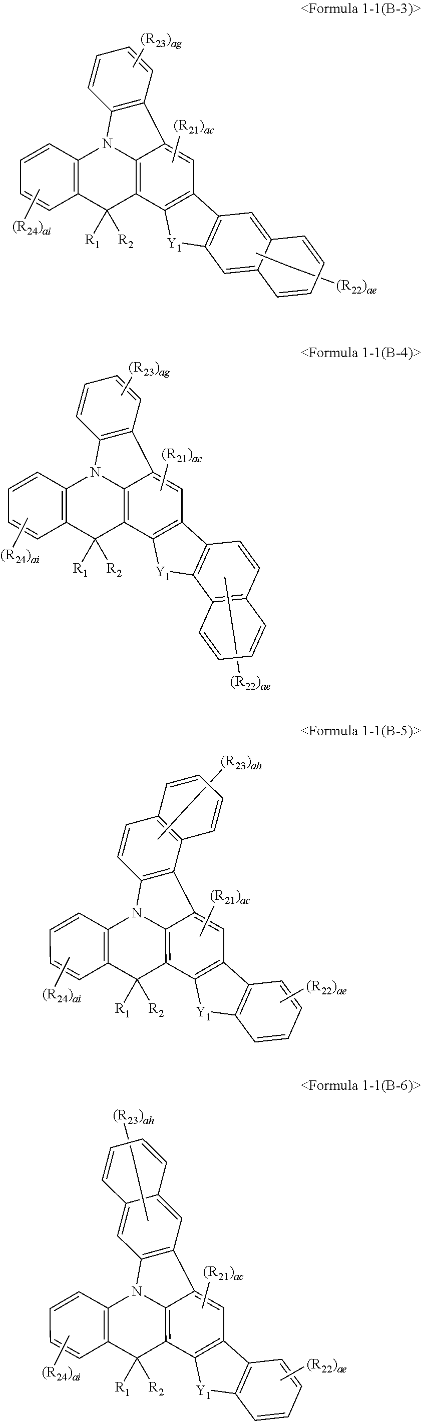

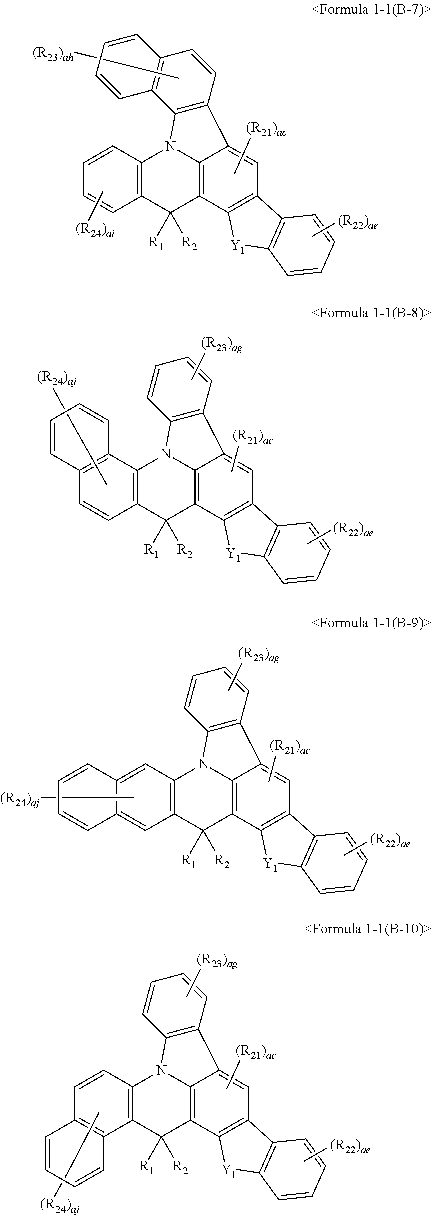

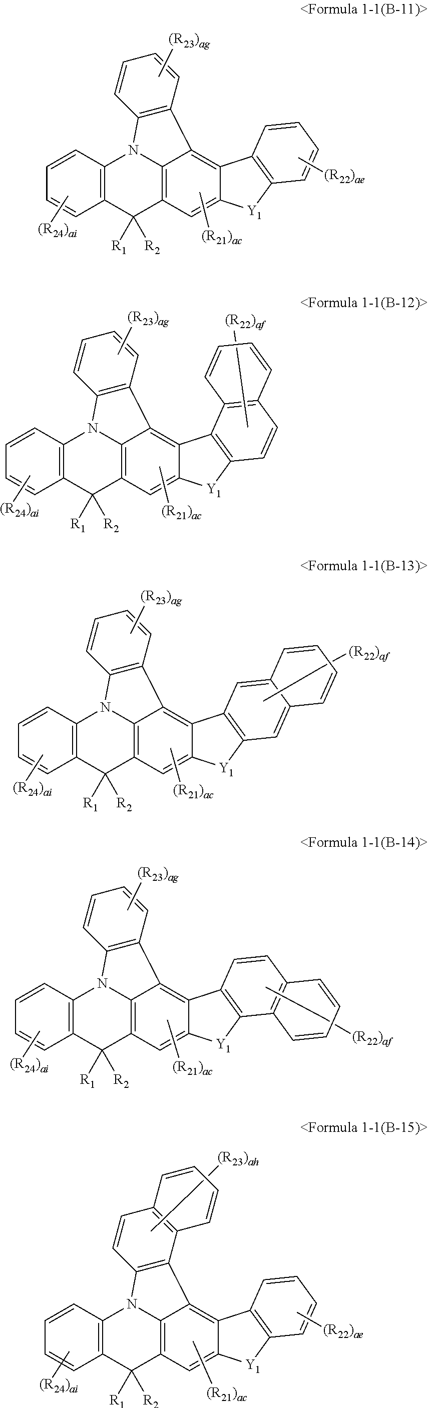

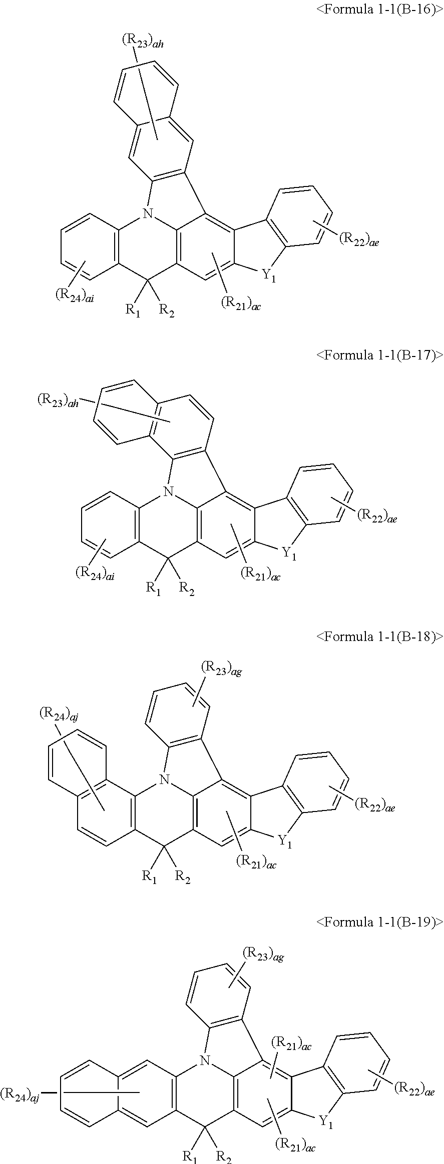

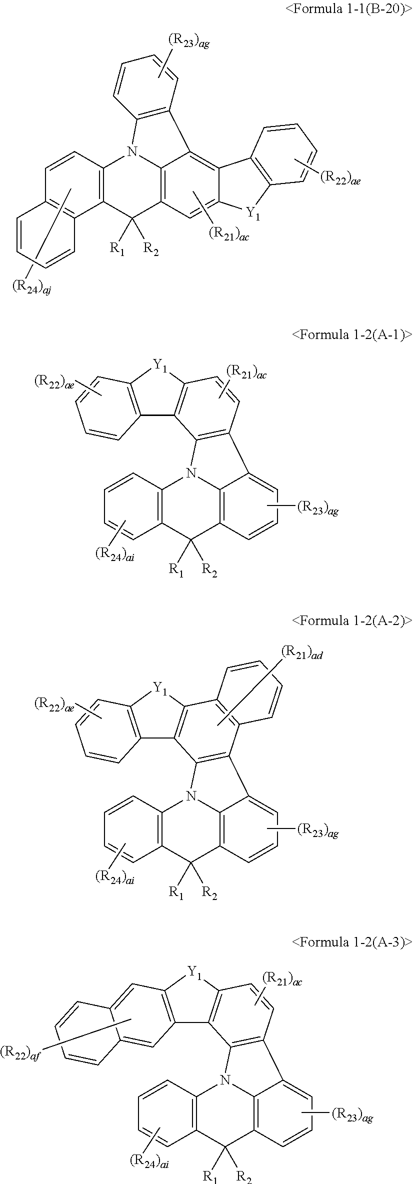

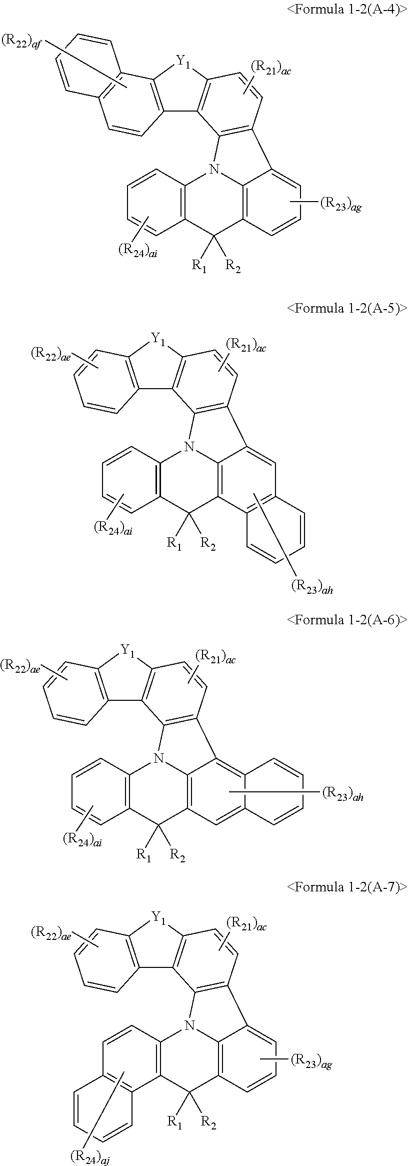

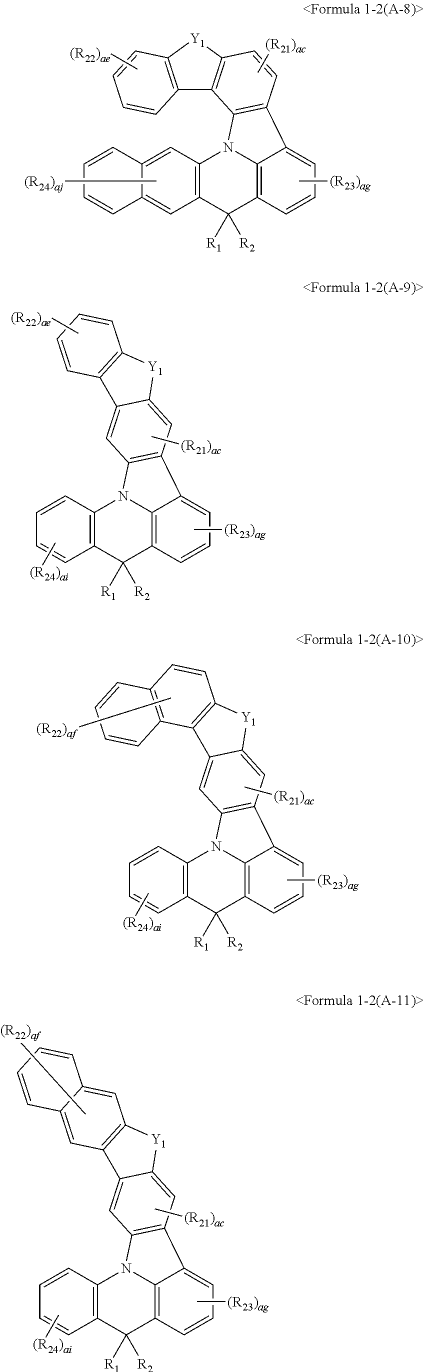

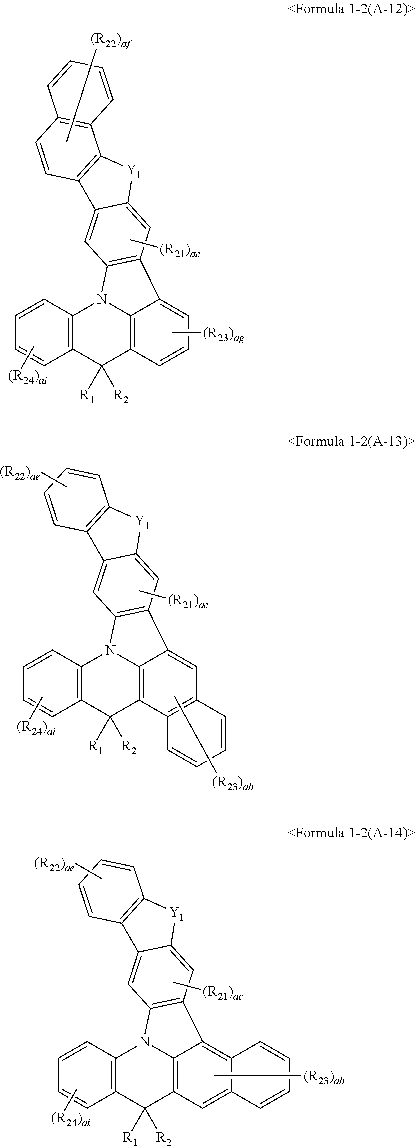

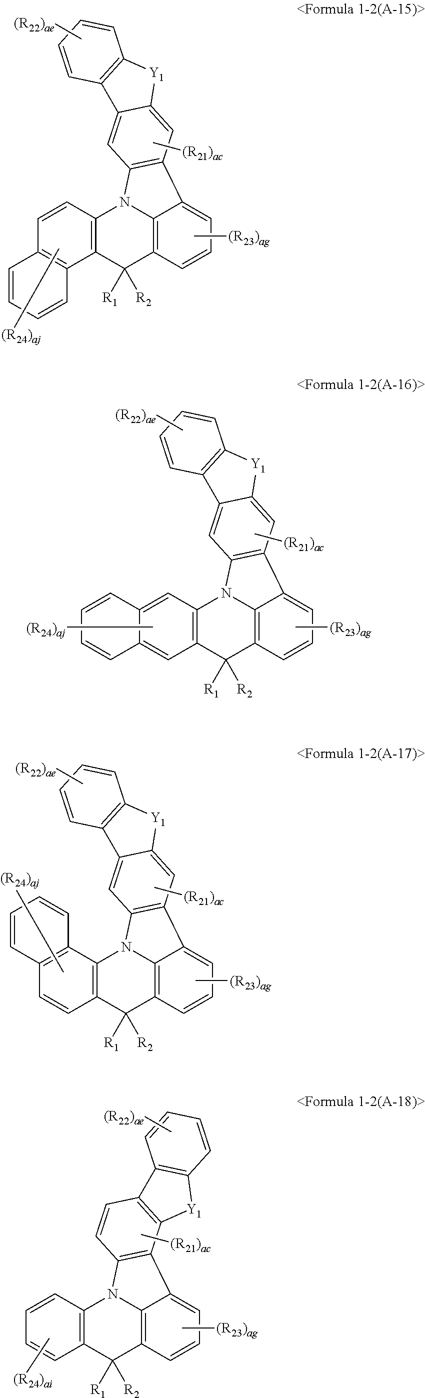

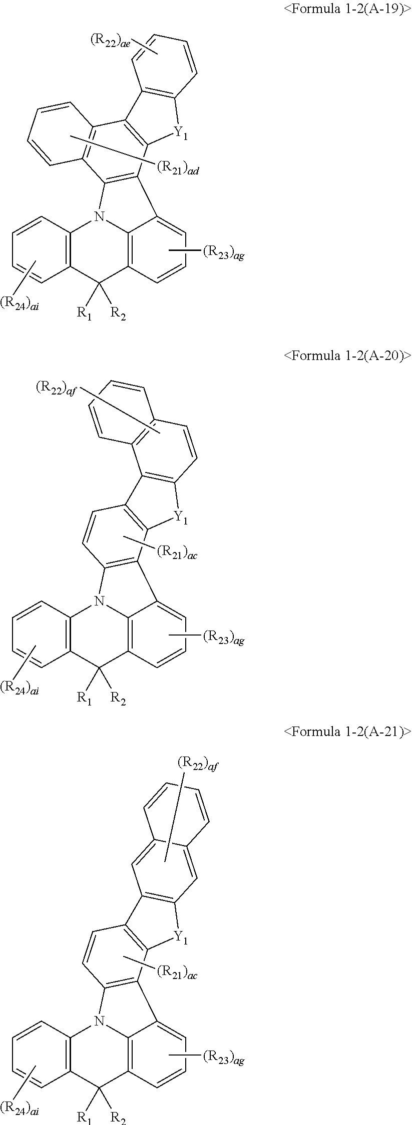

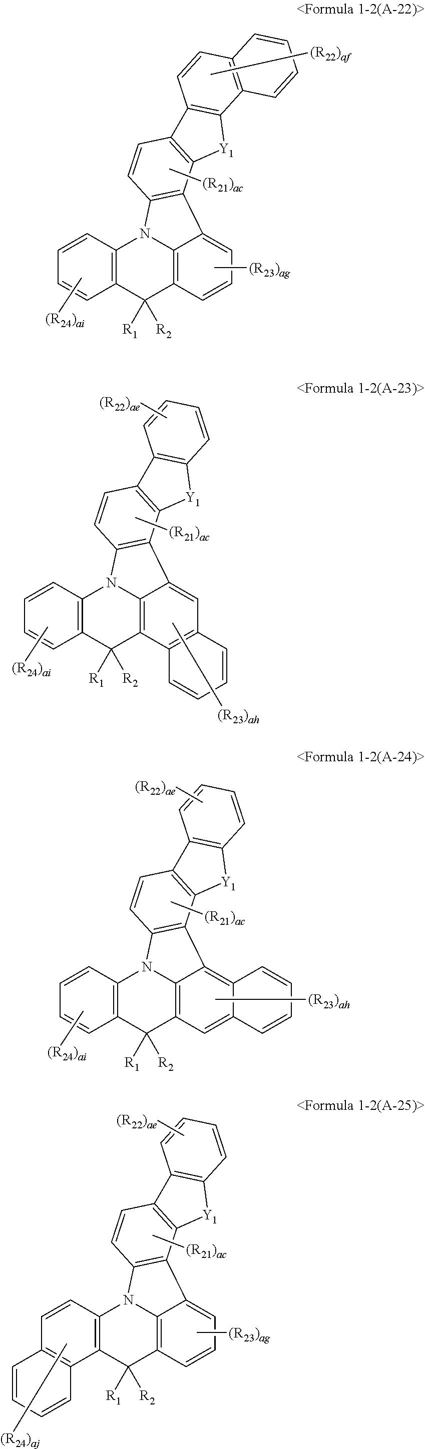

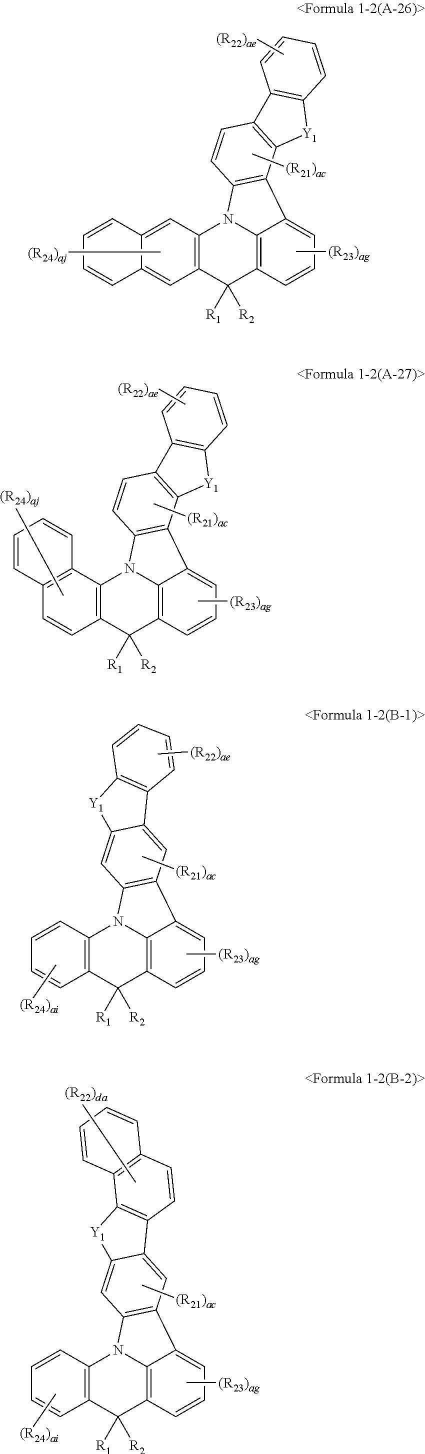

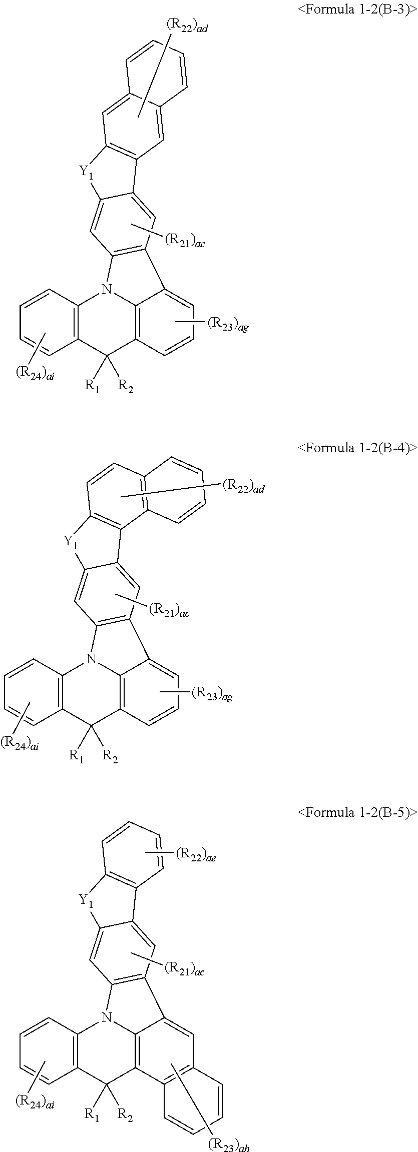

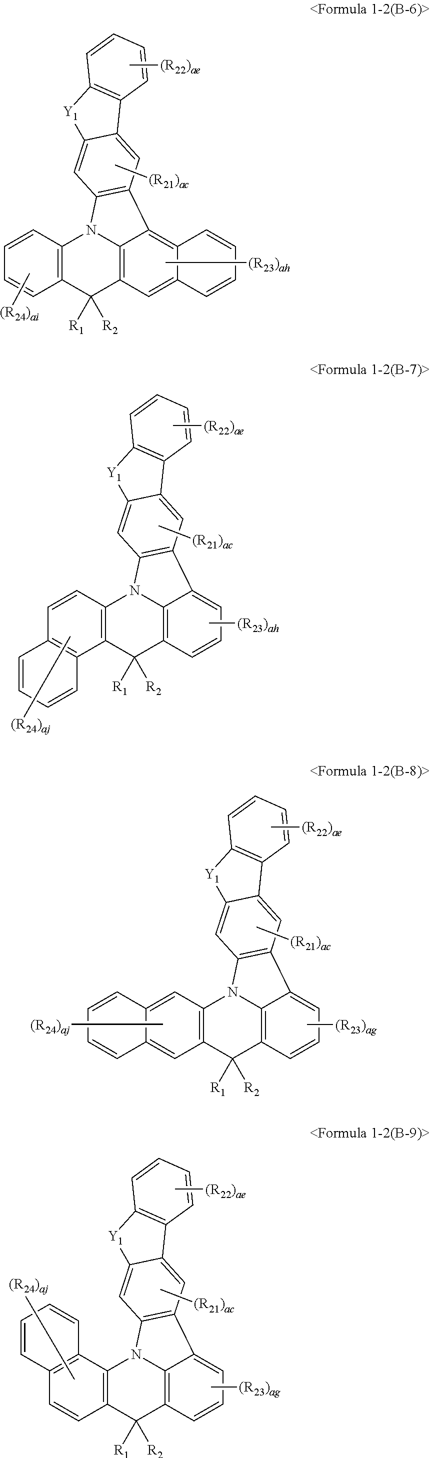

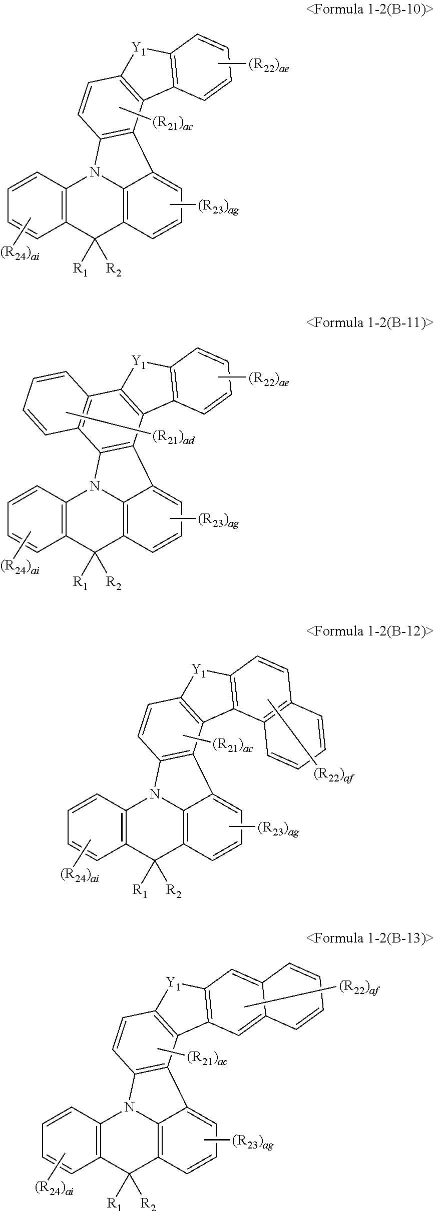

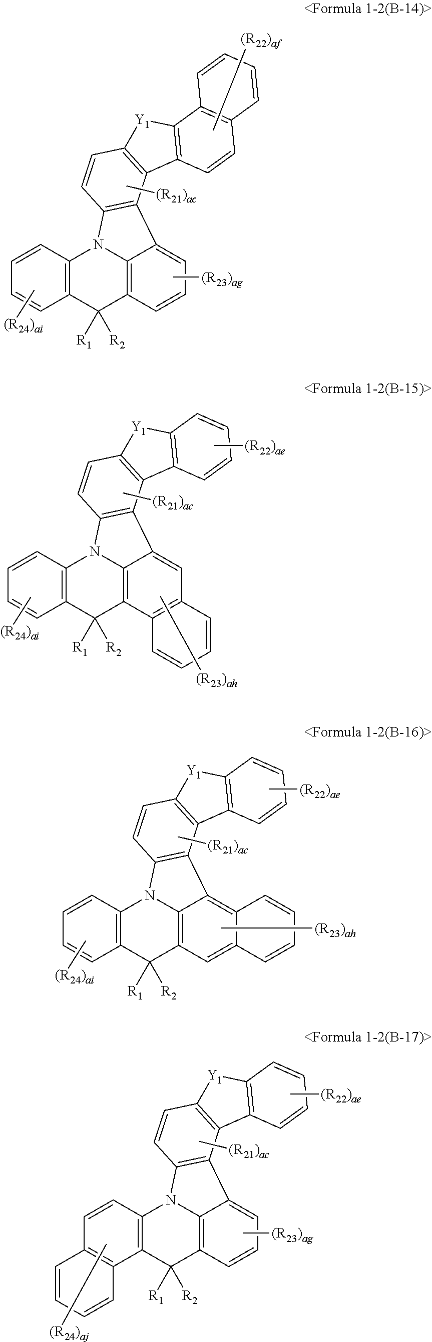

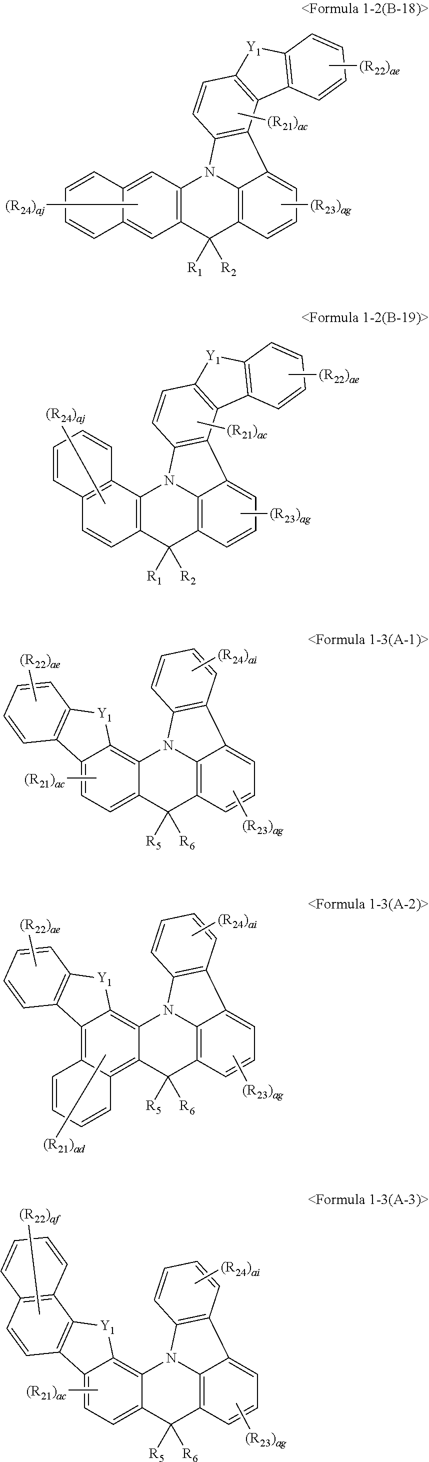

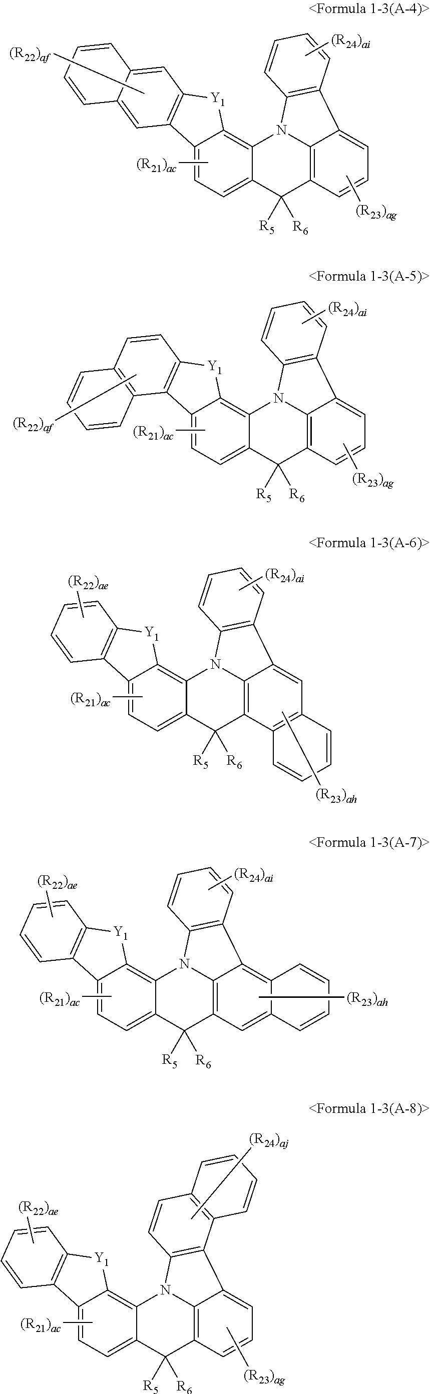

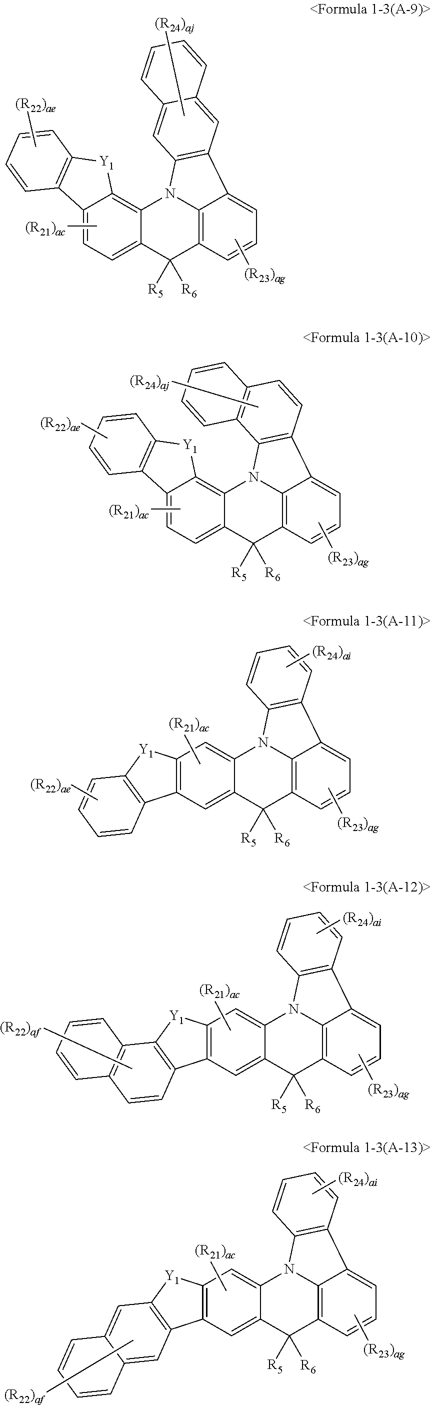

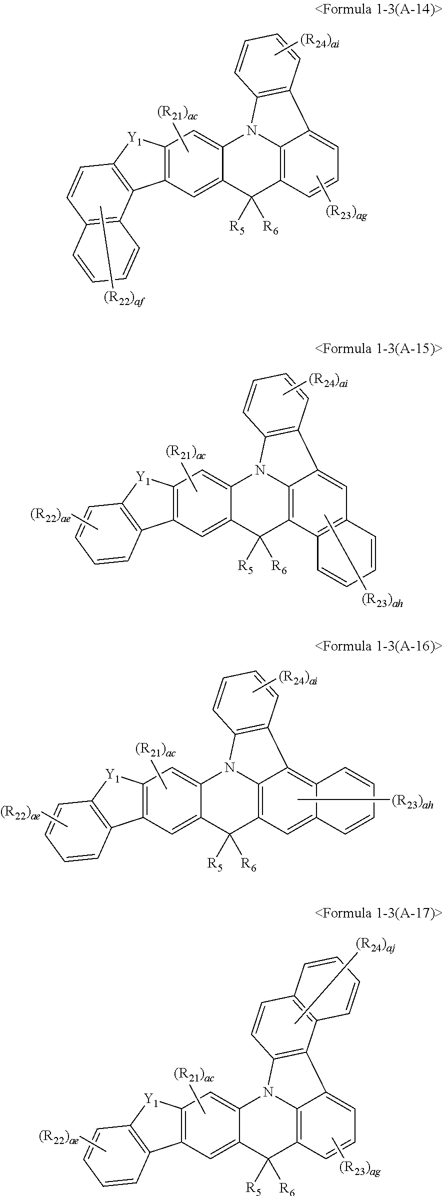

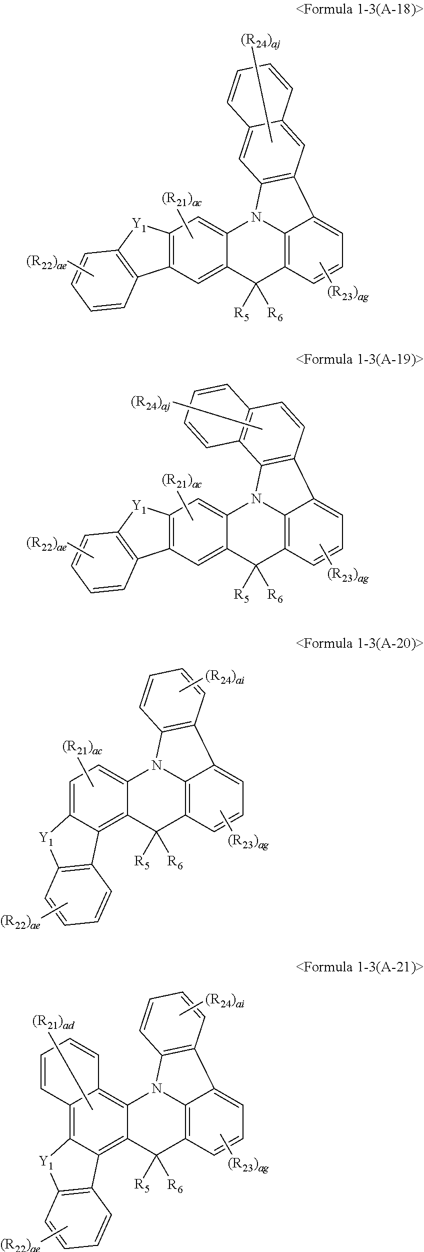

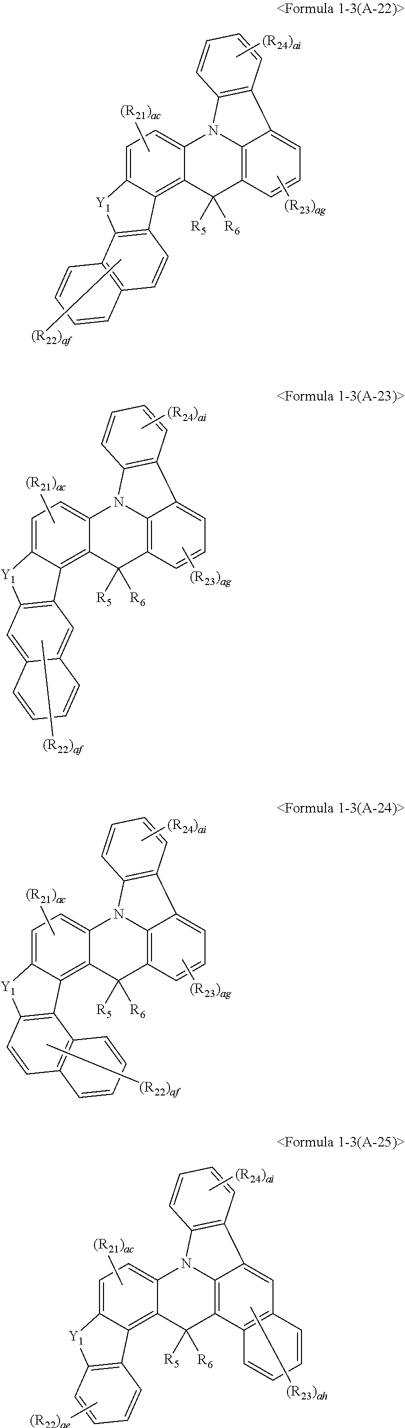

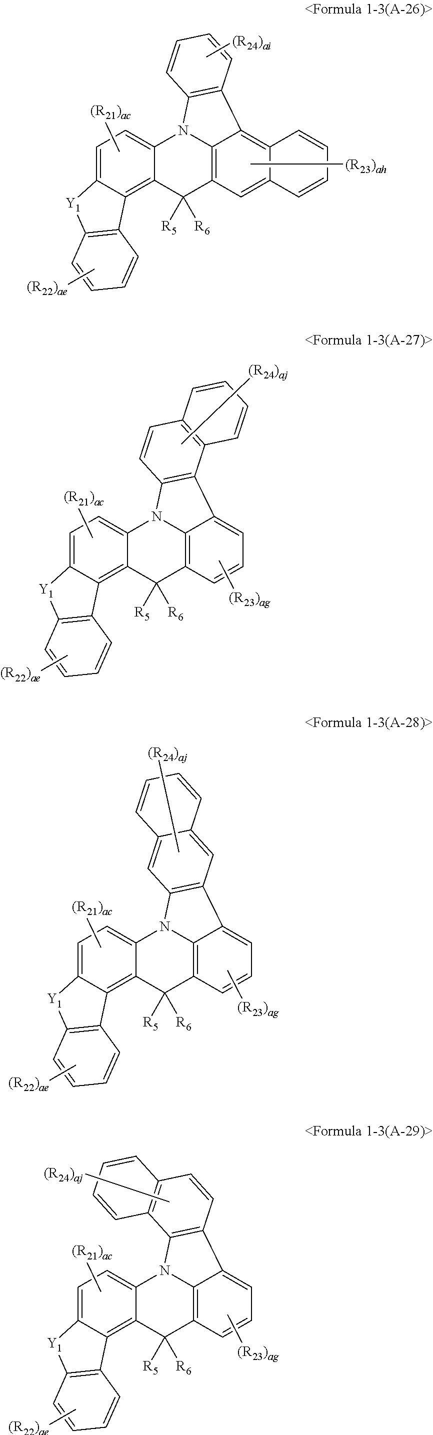

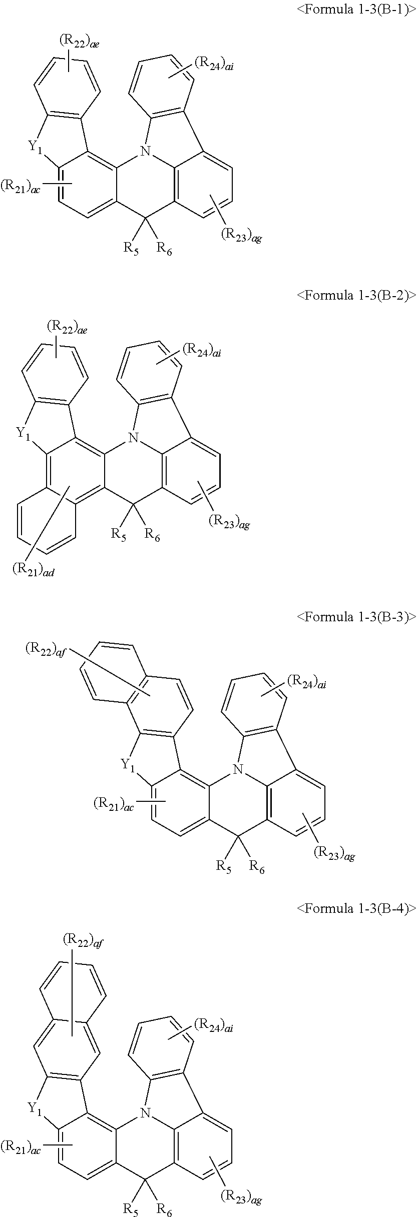

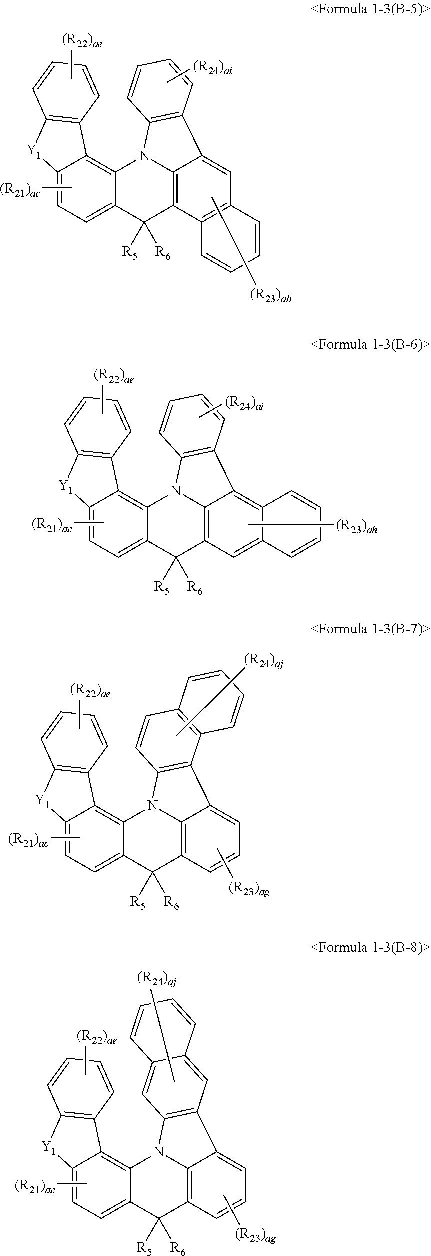

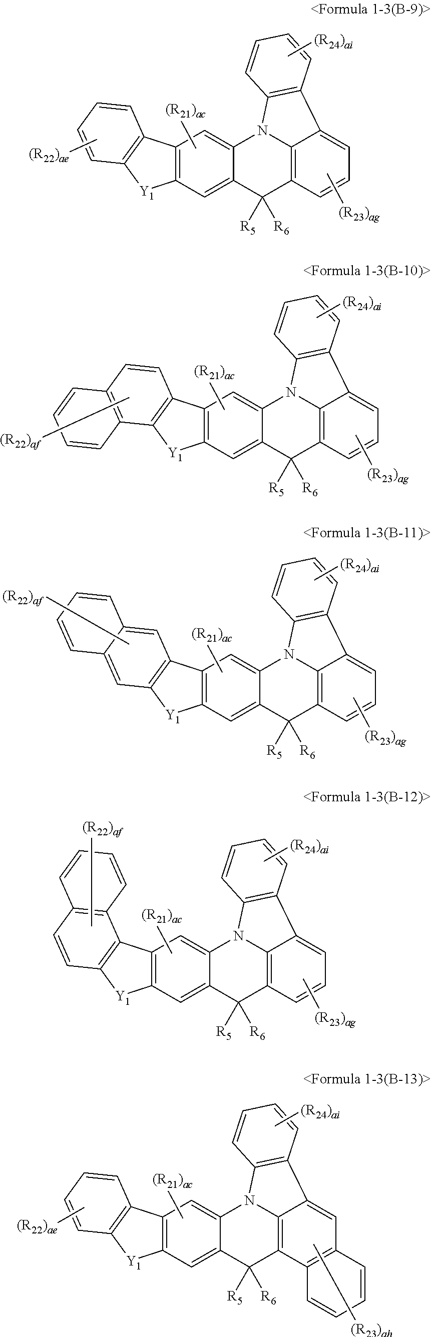

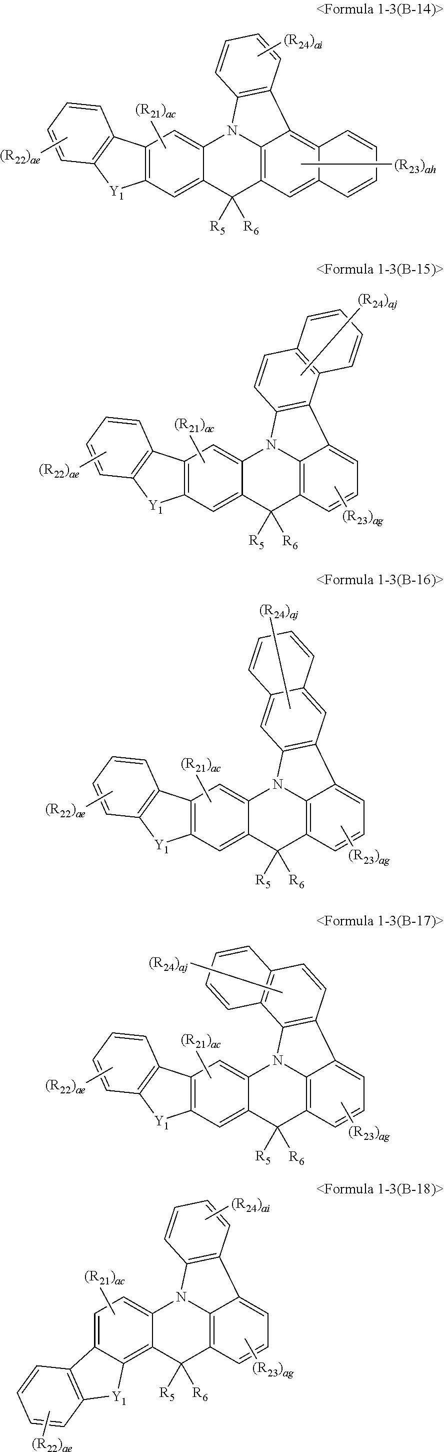

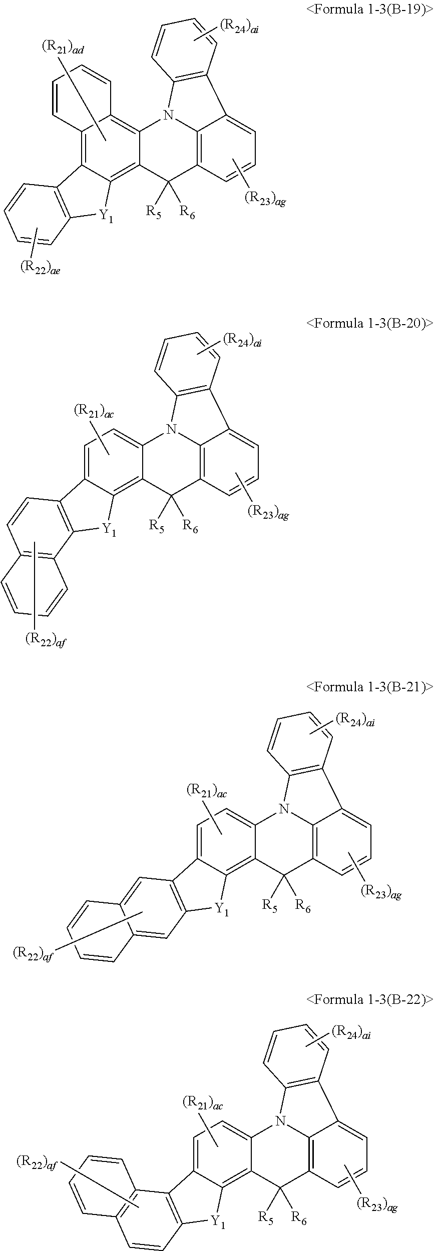

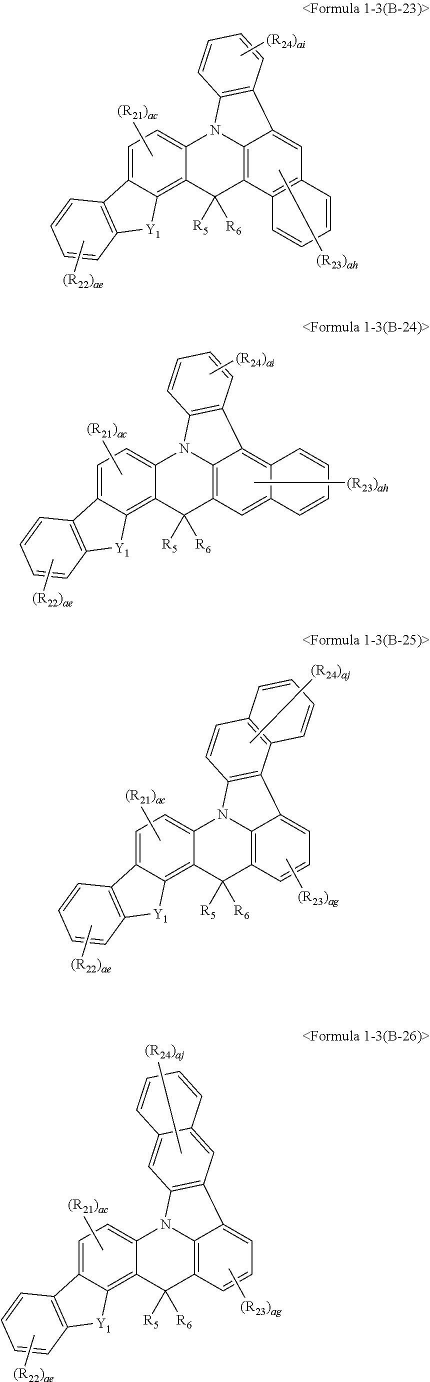

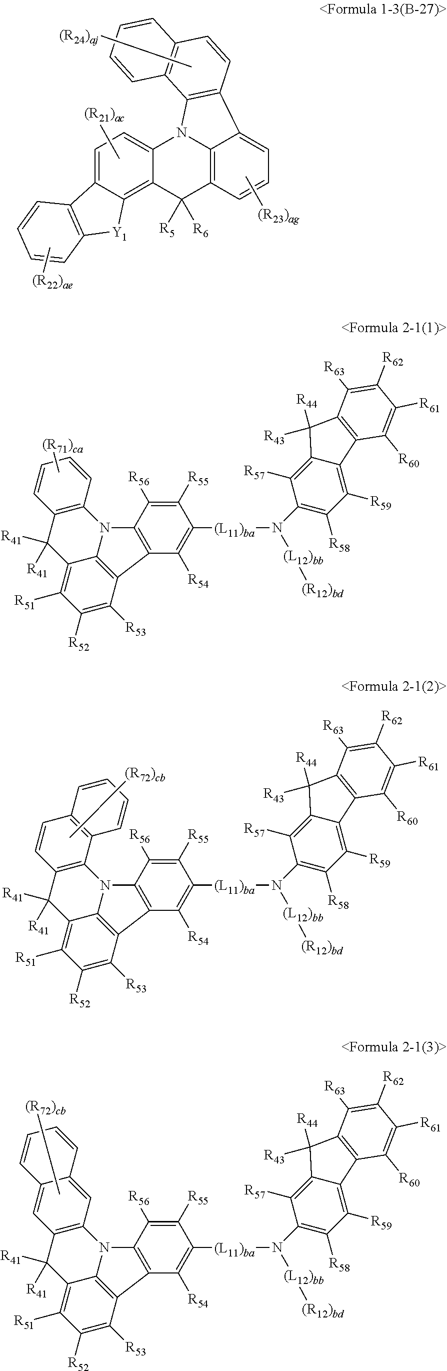

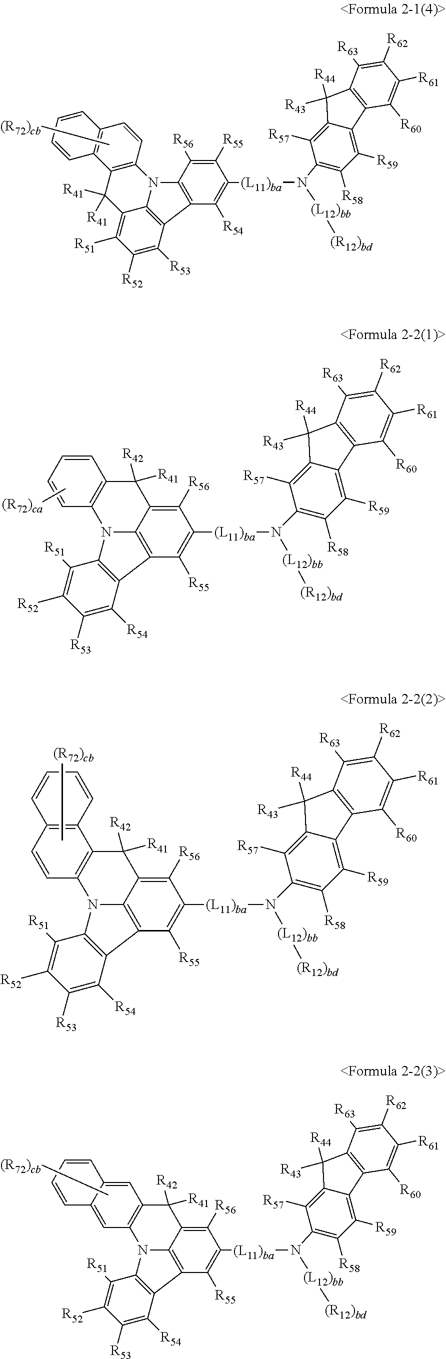

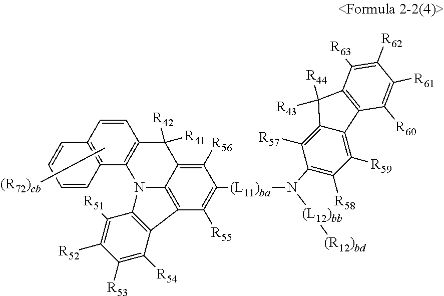

In Formulae 1-1(A-1) to 1-1(A-20), 1-1(B-1) to 1-1(B-20), 1-2(A-1) to 1-2(A-27), 1-2(B-1) to 1-2(B-19), 1-3(A-1) to 1-3(A-29), and 1-3(B-1) to 1-3(B-27),

Y₁, R₁ to R₆, and R₂₁ to R₂₄ are the same as described herein:

ac is selected from 0, 1, and 2, and when ac is 2 or greater, two or more R₂₁(s) are identical to or different from each other;

ad, ae, ag, and ai are each independently selected from 0, 1, 2, 3, and 4, and, when ad is 2 or greater, two or more R₂₁(s) are identical to or different from each other, when ae is 2 or greater, two or more R₂₂(s) are identical to or different from each other, when ag is 2 or greater, two or more R₂₃(s) are identical to or different from each other, and when ai is 2 or greater, two or more R₂₄(s) are identical to or different from each other;

af, ah, and aj are each independently selected from 0, 1, 2, 3, 4, 5, and 6, and when af is 2 or greater, two or more R₂₂(s) are identical to or different from each other, when ah is 2 or greater, two or more R₂₃(s) are identical to or different from each other, and, when aj is 2 or greater, two or more R₂₄(s) are identical to or different from each other; and

in Formulae 2-1(1) to 2-1(4) and 2-2(1) to 2-2(4), L₁₁, L₁₂, R₁₂, R₄₁ to R₄₄, R₅₁ to R₆₃, R₇₁ and R₇₂, ba, bb, bd, ca, and cb are the same as described herein.

For example, the first compound may be one of Compounds 1 to 37, and the second compound may be one of Compounds 101 to 122 and 151 to 172, but embodiments are not limited thereto:

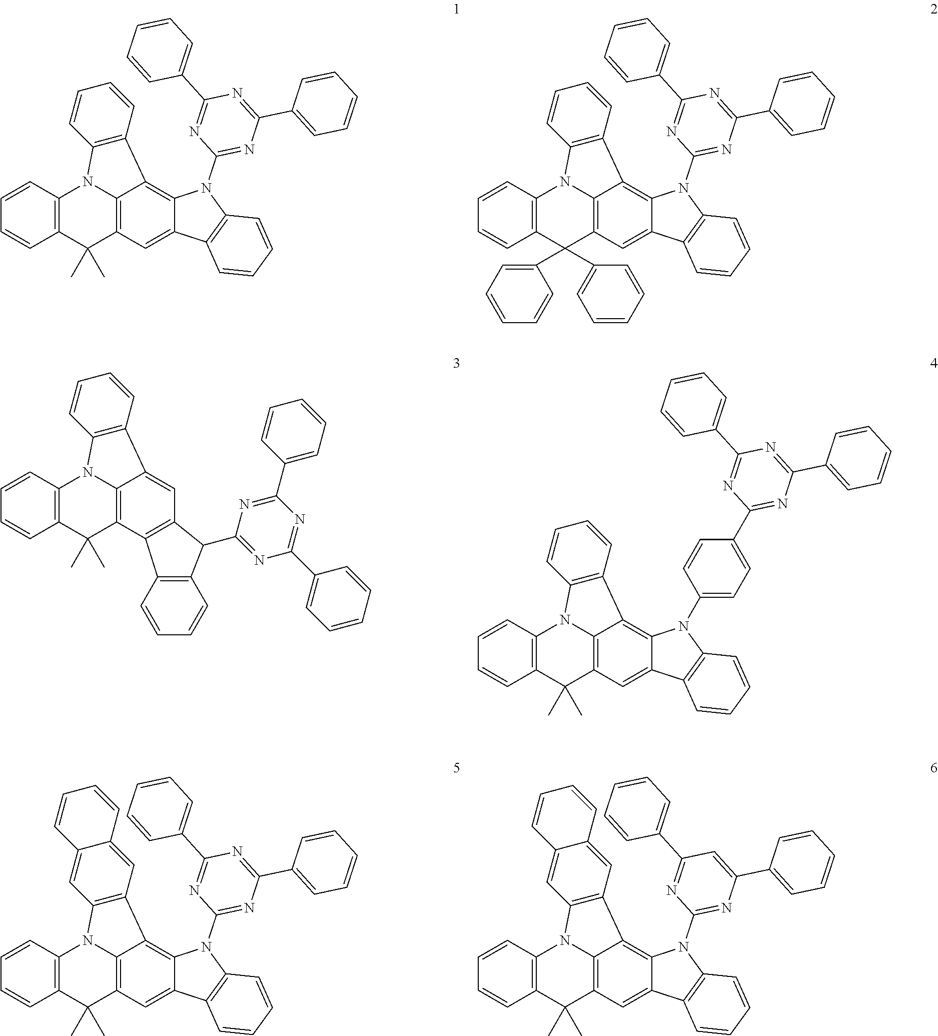

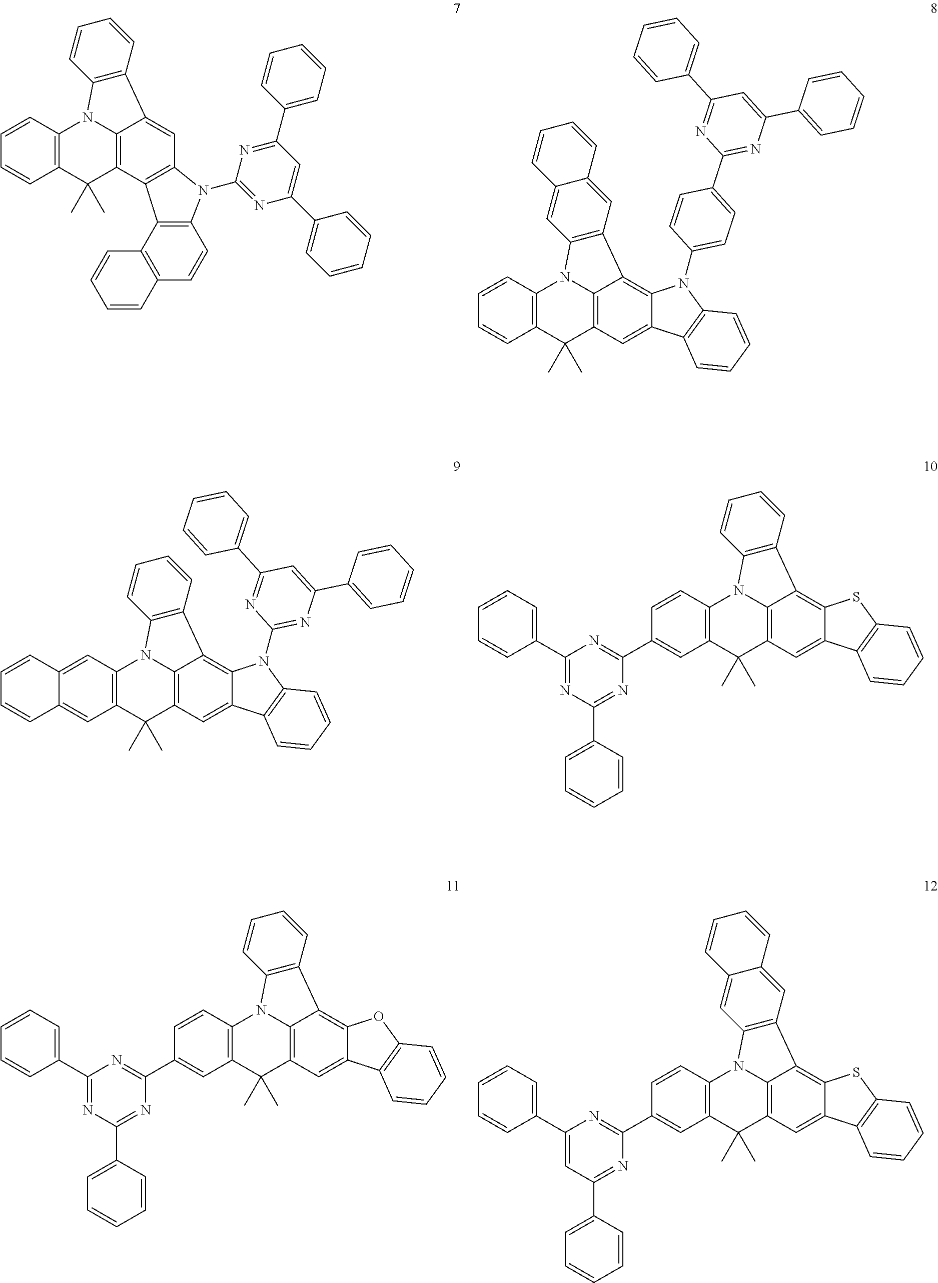

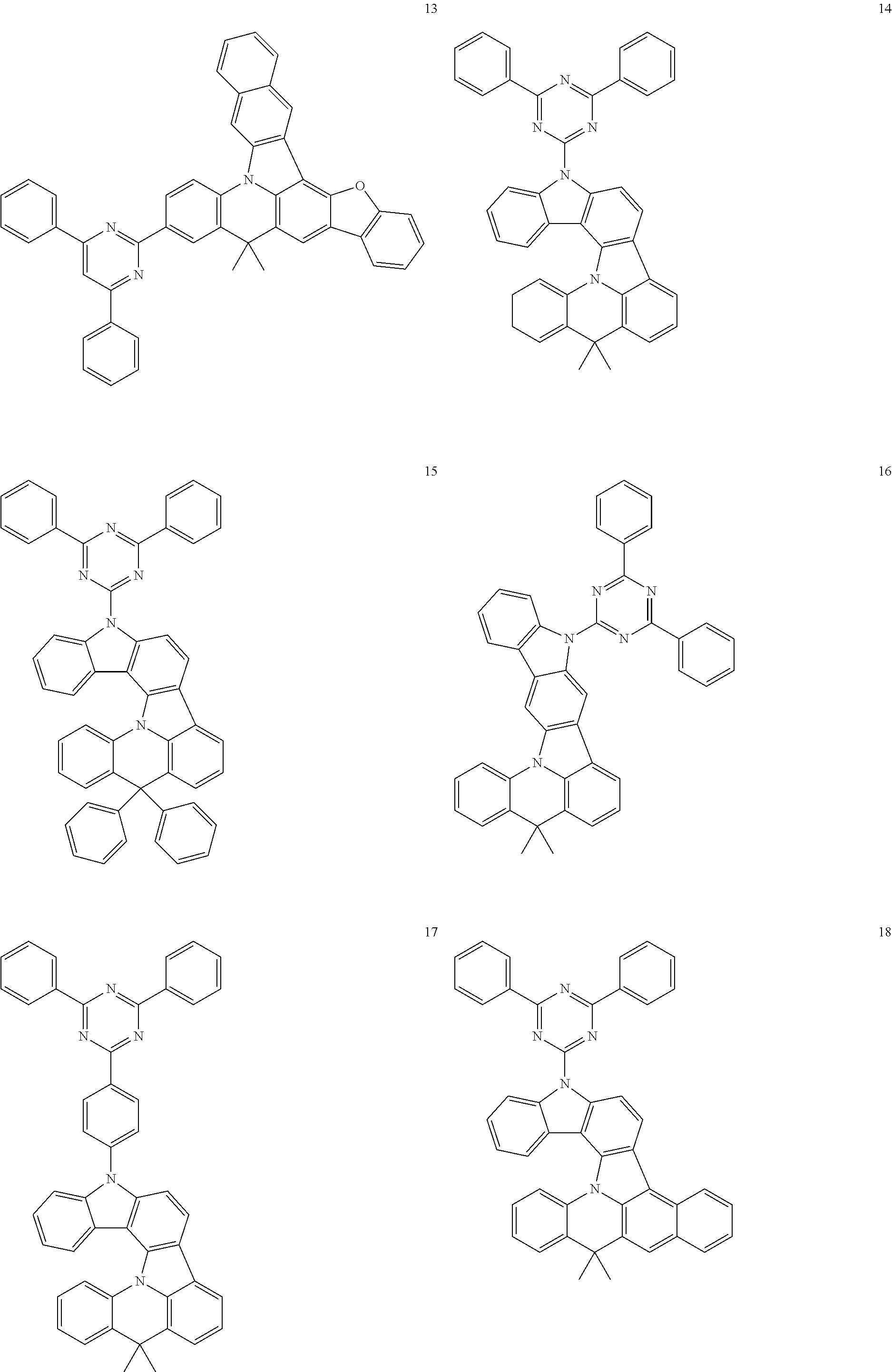

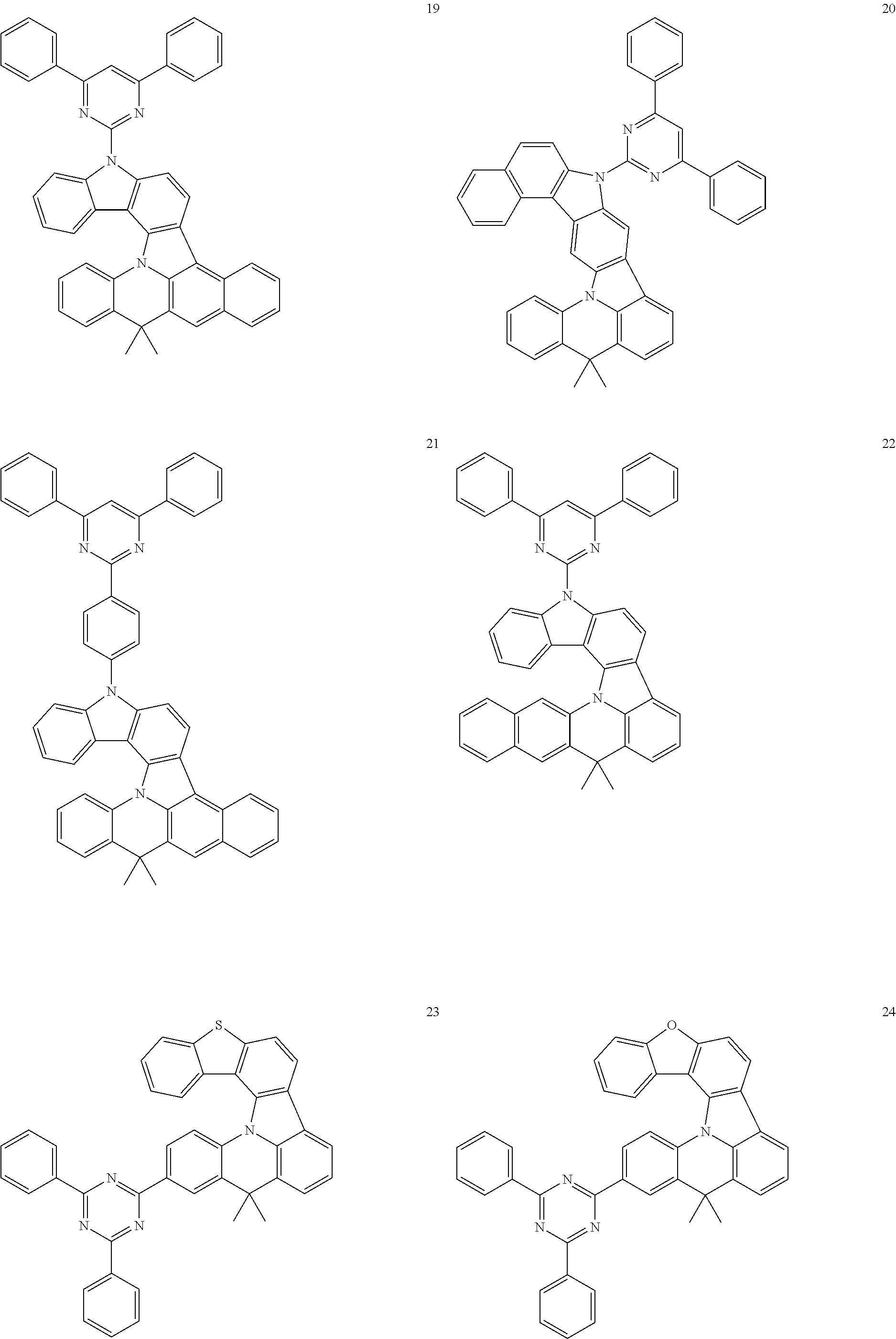

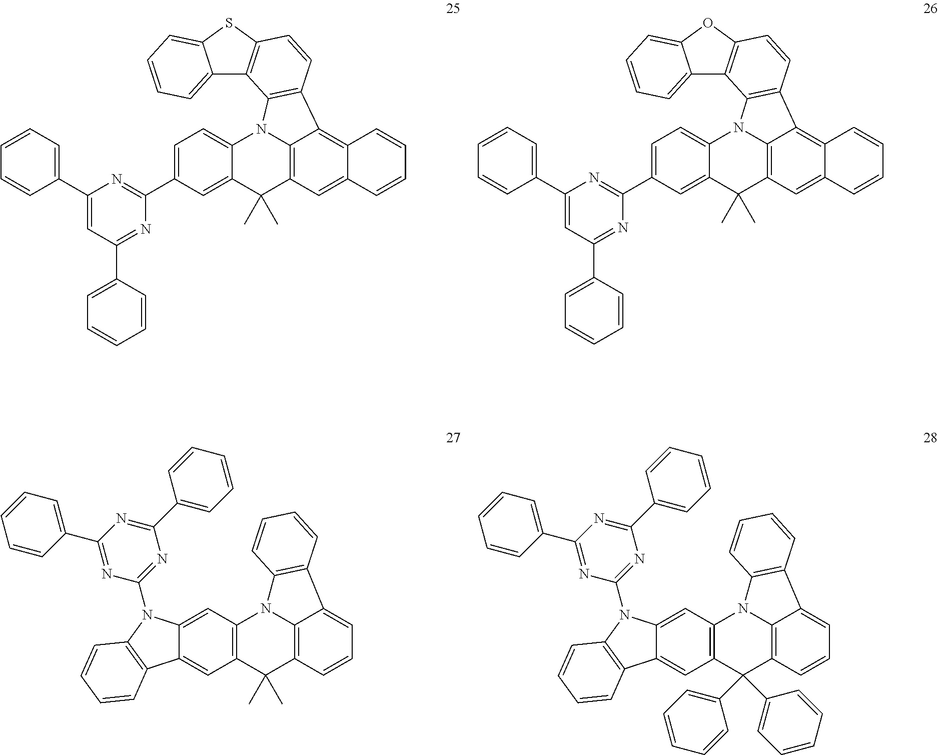 [SMILES: CC1(C)c2cc(-c3nc(-c4ccccc4)cc(-c4ccccc4)n3)ccc2-n2c3c1cc1ccccc1c3c1ccc3sc4ccccc4c3c12 ; CC1(C)c2cc(-c3nc(-c4ccccc4)cc(-c4ccccc4)n3)ccc2-n2c3c1cc1ccccc1c3c1ccc3oc4ccccc4c3c12 ; CC1(C)c2cc3c4ccccc4n(-c4nc(-c5ccccc5)nc(-c5ccccc5)n4)c3cc2-n2c3ccccc3c3cccc1c32 ; c1ccc(-c2nc(-c3ccccc3)nc(-n3c4ccccc4c4cc5c(cc43)-n3c4ccccc4c4cccc(c43)C5(c3ccccc3)c3ccccc3)n2)cc1]

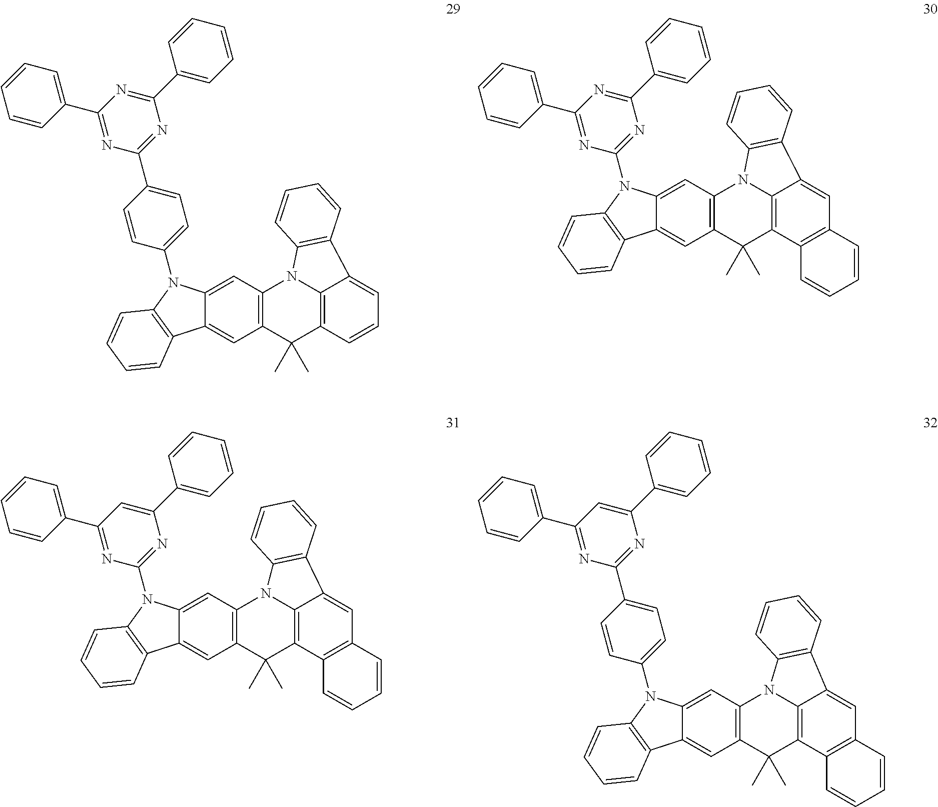 [SMILES: CC1(C)c2cc3c4ccccc4n(-c4ccc(-c5nc(-c6ccccc6)nc(-c6ccccc6)n5)cc4)c3cc2-n2c3ccccc3c3cccc1c32 ; CC1(C)c2cc3c4ccccc4n(-c4nc(-c5ccccc5)nc(-c5ccccc5)n4)c3cc2-n2c3ccccc3c3cc4ccccc4c1c32 ; CC1(C)c2cc3c4ccccc4n(-c4nc(-c5ccccc5)cc(-c5ccccc5)n4)c3cc2-n2c3ccccc3c3cc4ccccc4c1c32 ; CC1(C)c2cc3c4ccccc4n(-c4ccc(-c5nc(-c6ccccc6)cc(-c6ccccc6)n5)cc4)c3cc2-n2c3ccccc3c3cc4ccccc4c1c32]

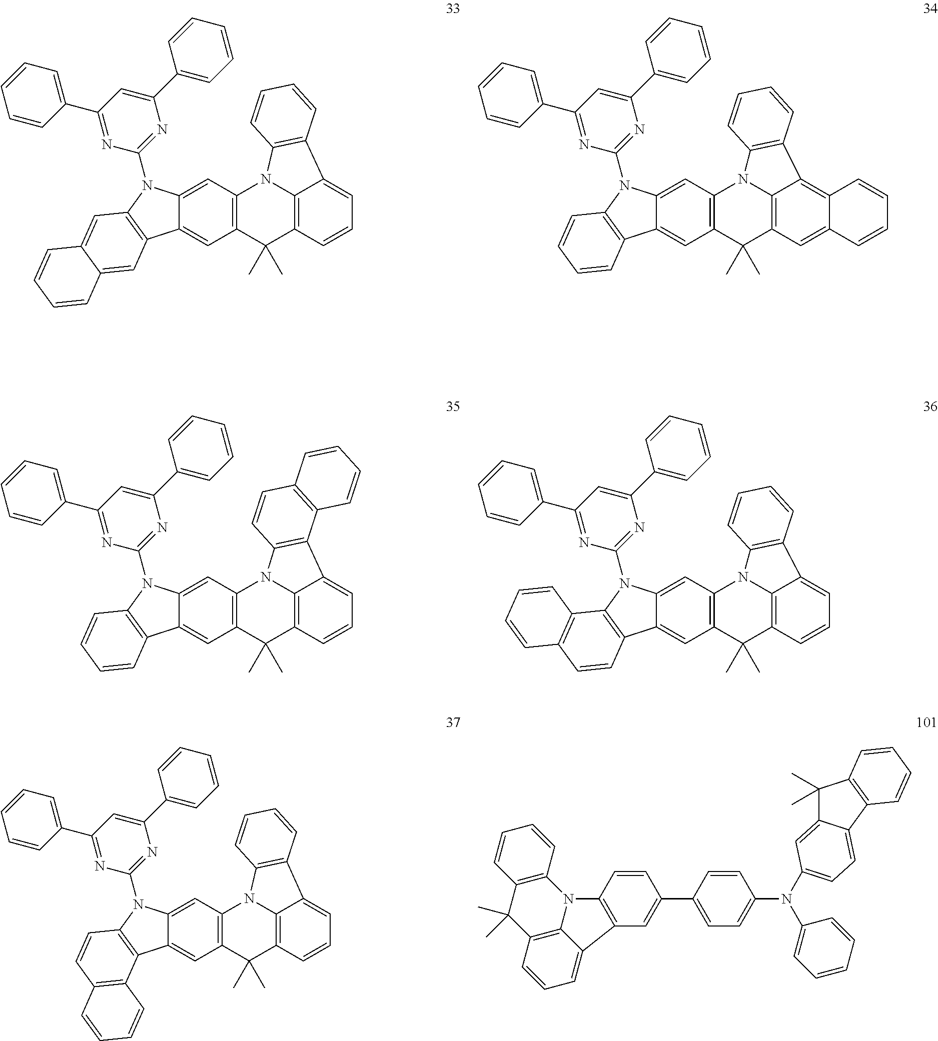

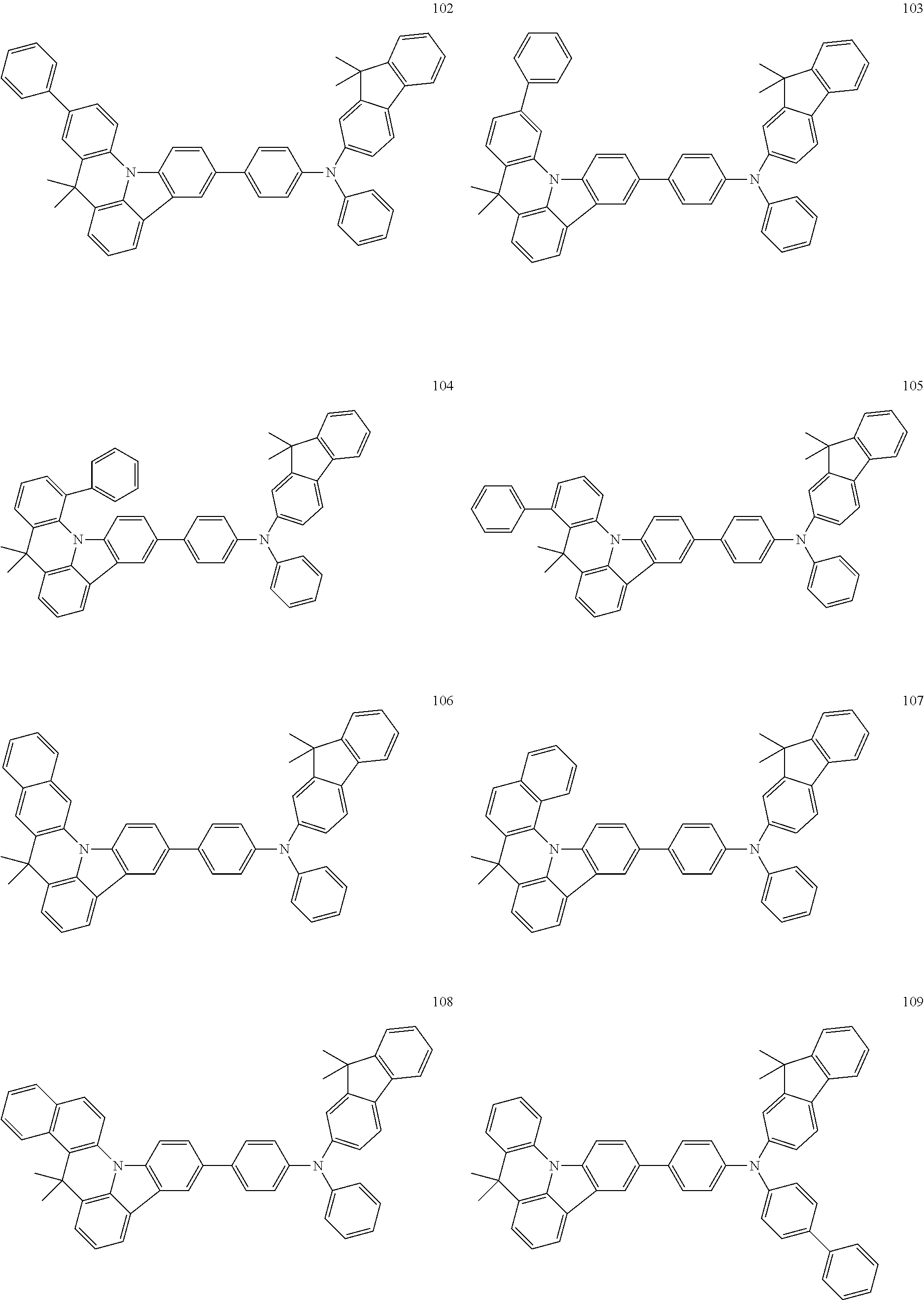

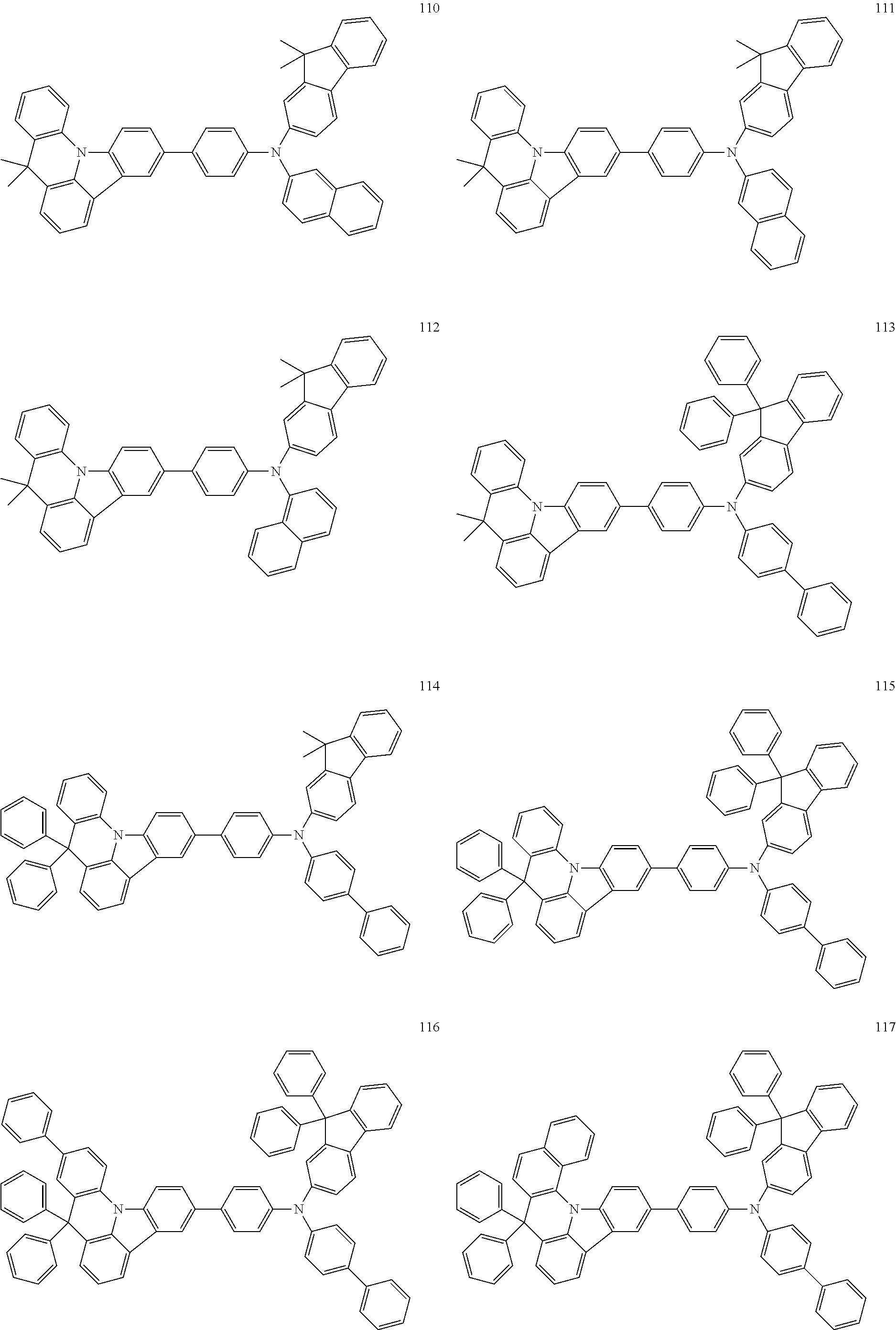

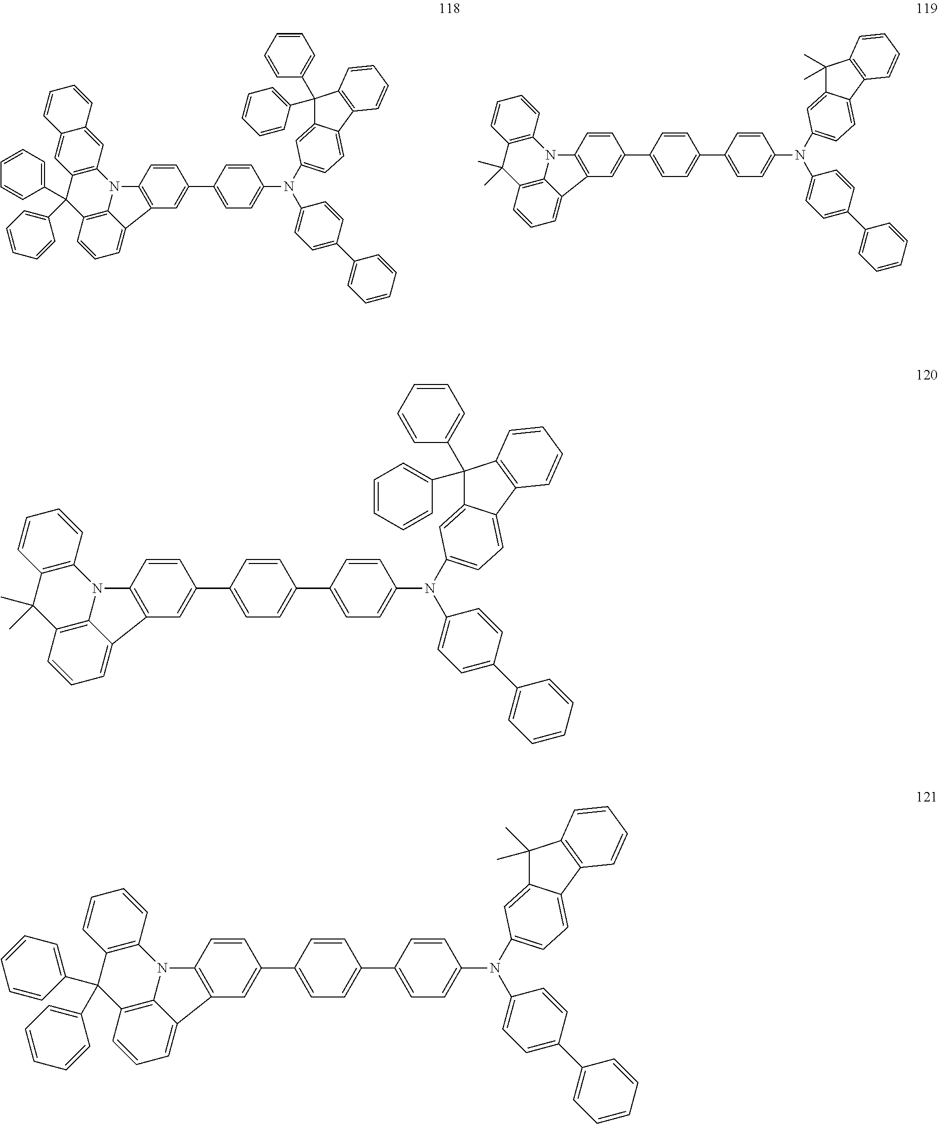 [SMILES: c1ccc(-c2ccc(N(c3ccc(-c4ccc5c(c4)c4cccc6c4n5-c4cc5ccccc5cc4C6(c4ccccc4)c4ccccc4)cc3)c3ccc4c(c3)C(c3ccccc3)(c3ccccc3)c3ccccc3-4)cc2)cc1 ; CC1(C)c2ccccc2-c2ccc(N(c3ccc(-c4ccccc4)cc3)c3ccc(-c4ccc(-c5ccc6c(c5)c5cccc7c5n6-c5ccccc5C7(C)C)cc4)cc3)cc21 ; CC1(C)c2ccccc2-n2c3ccc(-c4ccc(-c5ccc(N(c6ccc(-c7ccccc7)cc6)c6ccc7c(c6)C(c6ccccc6)(c6ccccc6)c6ccccc6-7)cc5)cc4)cc3c3cccc1c32 ; CC1(C)c2ccccc2-c2ccc(N(c3ccc(-c4ccccc4)cc3)c3ccc(-c4ccc(-c5ccc6c(c5)c5cccc7c5n6-c5ccccc5C7(c5ccccc5)c5ccccc5)cc4)cc3)cc21]

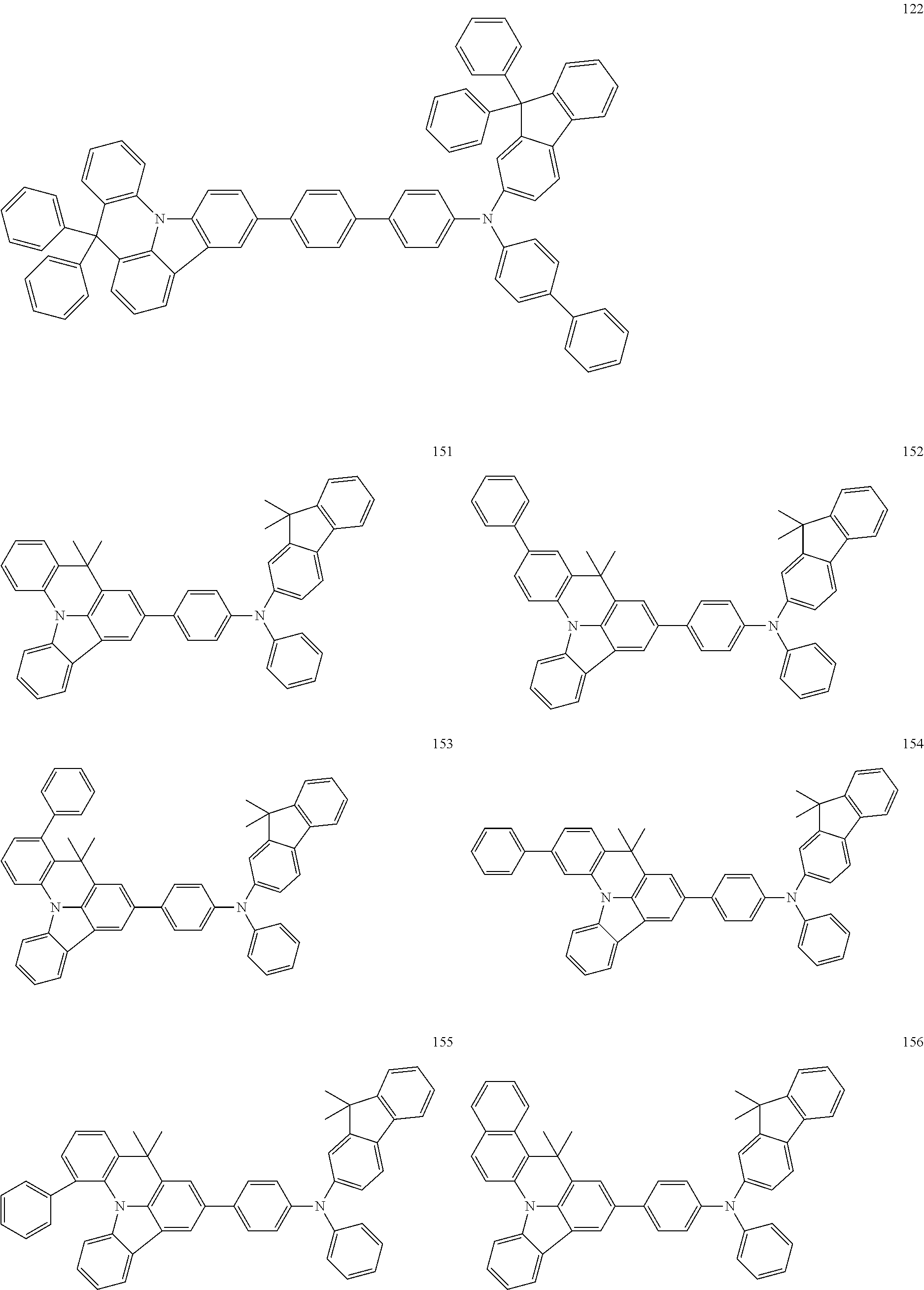

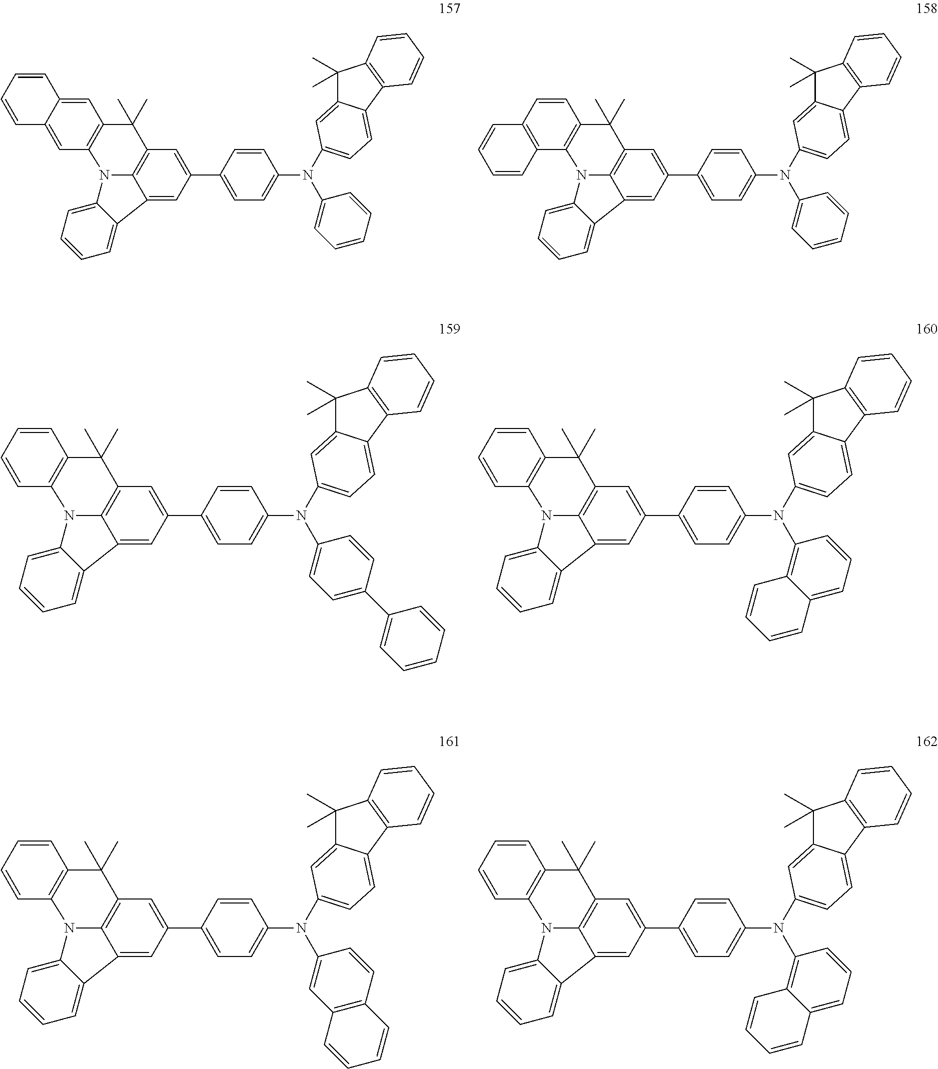

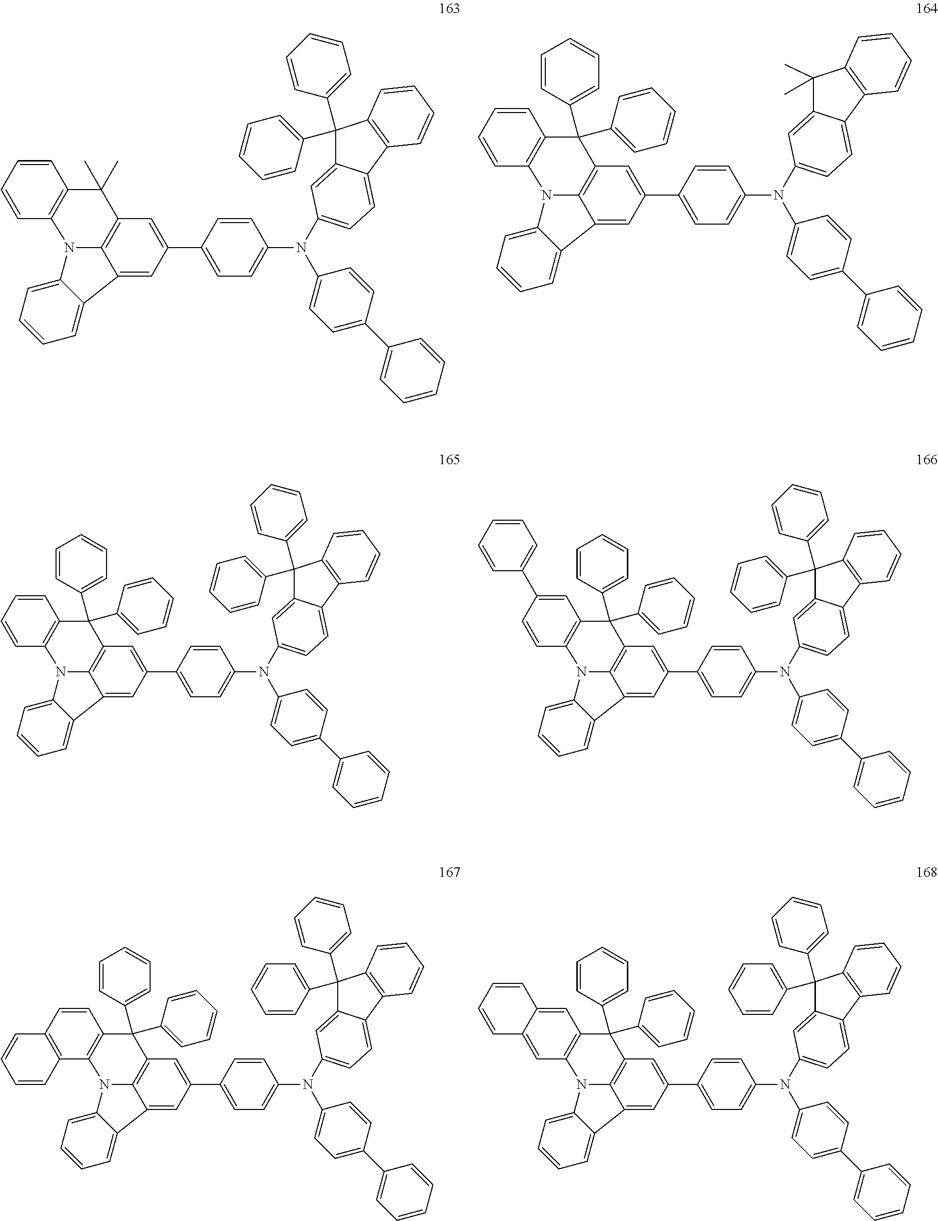

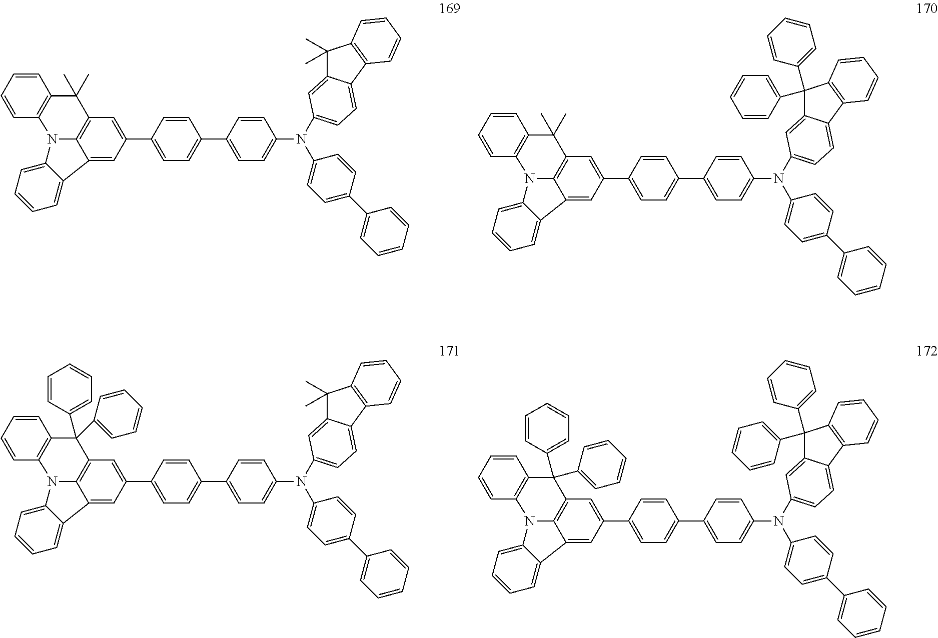 [SMILES: CC1(C)c2ccccc2-c2ccc(N(c3ccc(-c4ccccc4)cc3)c3ccc(-c4ccc(-c5cc6c7c(c5)c5ccccc5n7-c5ccccc5C6(C)C)cc4)cc3)cc21 ; CC1(C)c2ccccc2-n2c3ccccc3c3cc(-c4ccc(-c5ccc(N(c6ccc(-c7ccccc7)cc6)c6ccc7c(c6)C(c6ccccc6)(c6ccccc6)c6ccccc6-7)cc5)cc4)cc1c32 ; CC1(C)c2ccccc2-c2ccc(N(c3ccc(-c4ccccc4)cc3)c3ccc(-c4ccc(-c5cc6c7c(c5)c5ccccc5n7-c5ccccc5C6(c5ccccc5)c5ccccc5)cc4)cc3)cc21 ; c1ccc(-c2ccc(N(c3ccc(-c4ccc(-c5cc6c7c(c5)c5ccccc5n7-c5ccccc5C6(c5ccccc5)c5ccccc5)cc4)cc3)c3ccc4c(c3)C(c3ccccc3)(c3ccccc3)c3ccccc3-4)cc2)cc1]

The first compound may have a substituent with a high electron mobility, and thus may have an excellent electron transporting ability. The second compound may have a substituent with a high hole mobility, and thus may have an excellent hole transporting ability. In this regard, when the first compound (having an electron transporting ability) and the second compound (having a hole transporting ability) are both preset in an organic light-emitting device, an electron-hole balance may increase, compared to a situation having a compound with an electron transporting ability and a hole transporting ability in one molecule. Thus, a lifespan and efficiency of an electric device, e.g., the organic light-emitting device including the first compound and the second compound, may improve.

In an implementation, the first compound represented by one of Formulae 1-1 to 1-3 and the second compound represented by one of Formulae 2-1 and 2-2 may have excellent thermal stability. Thus, when a layer including the first compound and the second compound is formed, the layer may not be easily deformed by heat, and a lifespan of an electric device, e.g., the organic light-emitting device including the first compound and the second compound, may increase.

The organic layer 150 may include both the first compound and the second compound. In an implementation, the first compound may be included in the organic layer 150, and the second compound may be included in the electron transport region, which is disposed between the emission layer and the second electrode 190. In an implementation, both the first compound and second compound may be included in the emission layer of the organic layer 150, and further, the second compound may be included in the electron transport region, which is disposed between the emission layer and the second electrode 190. In an implementation, the second compound included in the emission layer and the second compound included in the electron transport region may be identical to or different from each other.

When both the first compound and second compound are included in the emission layer, a region where holes and electrons combine with each other may be shifted toward an interface of the emission layer and the electron transport region, thereby improving the lifespan of the organic light-emitting device.

For example, the emission layer in the organic layer 150 may include a host and a dopant.

An amount of the dopant in the emission layer may be, e.g., about 0.01 parts to about 15 parts by weight, based on 100 parts by weight of the host, but embodiments are not limited thereto.

A thickness of the emission layer may be in a range of about 100 Å to about 1,000 Å, e.g., about 200 Å to about 600 Å. When the thickness of the emission layer is within this range, excellent light-emission characteristics may be obtained without a substantial increase in driving voltage.

In an implementation, in the emission layer, the host may include the first compound and the second compound, and the dopant may include at least one of a phosphorescent dopant and a fluorescent dopant.

In an implementation, the phosphorescent dopant may include at least one organometallic compound including a metal selected from iridium (Ir), platinum (Pt), osmium (Os), titanium (Ti), zirconium (Zr), hafnium (Hf), europium (Eu), terbium (Tb), thulium (Tm), rhodium (Rh), and copper (Cu).

For example, the phosphorescent dopant may include an organometallic complex that is represented by Formula 401:

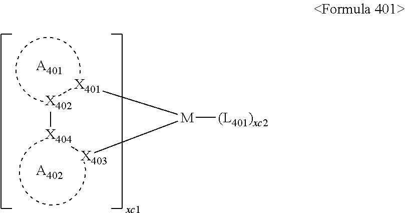

In Formula 401,

M may be selected from iridium (Ir), platinum (Pt), osmium (Os), titanium (Ti), zirconium (Zr), hafnium (Hf), europium (Eu), terbium (Tb), and thulium (Tm);

X₄₀₁ to X₄₀₄ may be each independently nitrogen or carbon;

rings A₄₀₁ and A₄₀₂ may be each independently selected from a substituted or unsubstituted benzene, a substituted or unsubstituted naphthalene, a substituted or unsubstituted fluorene, a substituted or unsubstituted spiro-fluorene, a substituted or unsubstituted indene, a substituted or unsubstituted pyrrole, a substituted or unsubstituted thiophene, a substituted or unsubstituted furan, a substituted or unsubstituted imidazole, a substituted or unsubstituted pyrazole, a substituted or unsubstituted thiazole, a substituted or unsubstituted isothiazole, a substituted or unsubstituted oxazole, a substituted or unsubstituted isoxazole, a substituted or unsubstituted pyridine, a substituted or unsubstituted pyrazine, a substituted or unsubstituted pyrimidine, a substituted or unsubstituted pyridazine, a substituted or unsubstituted quinoline, a substituted or unsubstituted isoquinoline, a substituted or unsubstituted benzoquinoline, a substituted or unsubstituted quinoxaline, a substituted or unsubstituted quinazoline, a substituted or unsubstituted carbazole, a substituted or unsubstituted benzimidazole, a substituted or unsubstituted benzofuran, a substituted or unsubstituted benzothiophene, a substituted or unsubstituted isobenzothiophene, a substituted or unsubstituted benzoxazole, a substituted or unsubstituted isobenzoxazole, a substituted or unsubstituted triazole, a substituted or unsubstituted oxadiazole, a substituted or unsubstituted triazine, a substituted or unsubstituted dibenzofuran, and a substituted or unsubstituted dibenzothiophene;

at least one substituent of the substituted benzene, substituted naphthalene, substituted fluorene, substituted spiro-fluorene, substituted indene, substituted pyrrole, substituted thiophene, substituted furan, substituted imidazole, substituted pyrazole, substituted thiazole, substituted isothiazole, substituted oxazole, substituted isoxazole, substituted pyridine, substituted pyrazine, substituted pyrimidine, substituted pyridazine, substituted quinoline, substituted isoquinoline, substituted benzoquinoline, substituted quinoxaline, substituted quinazoline, substituted carbazole, substituted benzimidazole, substituted benzofuran, substituted benzothiophene, substituted isobenzothiophene, substituted benzoxazole, substituted isobenzoxazole, substituted triazole, substituted oxadiazole, substituted triazine, substituted dibenzofuran, and substituted dibenzothiophene is selected from

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₄₀₁)(Q₄₀₂), —Si(Q₄₀₃)(Q₄₀₄)(Q₄₀₅), and —B(Q₄₀₆)(Q₄₀₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₄₁₁)(Q₄₁₂), —Si(Q₄₁₃)(Q₄₁₄)(Q₄₁₅), and —B(Q₄₁₆)(Q₄₁₇); and

—N(Q₄₂₁)(Q₄₂₂), —Si(Q₄₂₃)(Q₄₂₄)(Q₄₂₅), and —B(Q₄₂₆)(Q₄₂₇);

L₄₀₁ is an organic ligand;

xc1 is 1, 2, or 3; and

xc2 is 0, 1, 2, or 3.

Q₄₀₁ to Q₄₀₇, Q₄₁₁ to Q₄₁₇, and Q₄₂₁ to Q₄₂₇ are the same as defined in connection with Q₁ provided herein.

L₄₀₁ may be an arbitrary monovalent, divalent, or trivalent organic ligand. For example, L₄₀₁ may be selected from a halogen ligand (for example, Cl or F), a diketone ligand (for example, acetylacetonate, 1,3-diphenyl-1,3-propandionate, 2,2,6,6-tetramethyl-3,5-heptandionate, or hexafluoroacetonate), a carboxylic acid ligand (for example, picolinate, dimethyl-3-pyrazolecarboxylate, or benzoate), a carbon monooxide ligand, an isonitrile ligand, a cyano ligand, and a phosphorous ligand (for example, phosphine, or phosphate), but embodiments are not limited thereto.

When A₄₀₁ in Formula 401 has a plurality of substituents, the plurality of substituents of A₄₀₁ may bind to each other to form a saturated or unsaturated ring.

When A₄₀₂ in Formula 401 has a plurality of substituents, the plurality of substituents of A₄₀₂ may bind to each other to form a saturated or unsaturated ring.

When xc1 in Formula 401 is two or more, a plurality of ligands

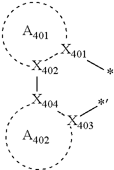

in Formula 401 may be identical to or different from each other. In Formula 401, when xc1 is 2 or more. A₄₀₁ and A₄₀₂ may be directly connected or connected via a linking group (for example, a C₁-C₅ alkylene group, —N(R′)— (wherein R′ is a C₁-C₁₀ alkyl group or a C₆-C₂₀ aryl group), or —C(═O)—) to another adjacent ligand of A₄₀₁ and A₄₀₂, respectively.

The phosphorescent dopant may include at least one selected from Compounds PD1 to PD74 below, but embodiments are not limited thereto:

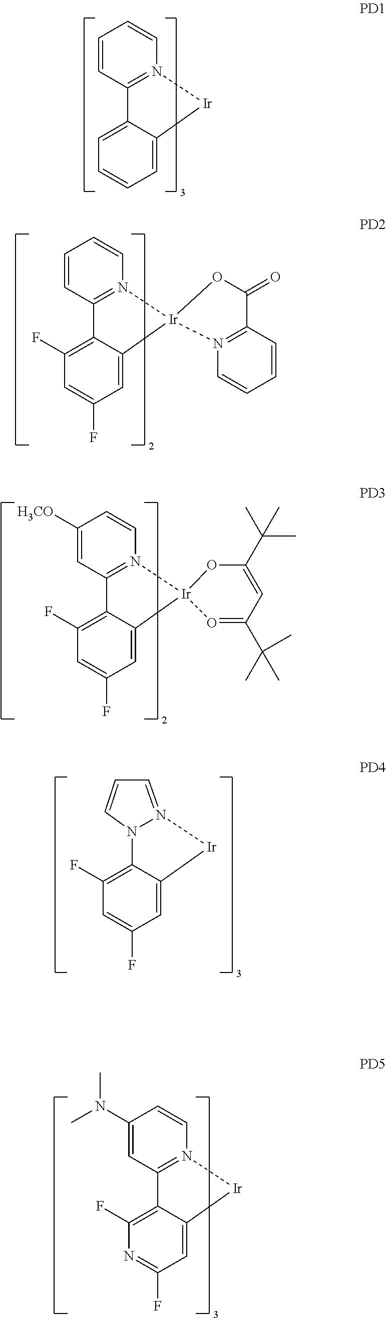

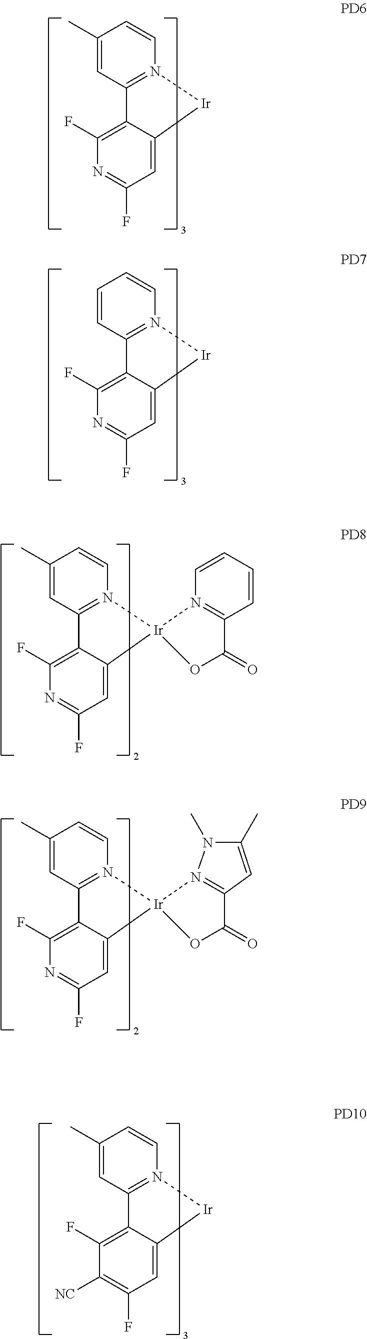

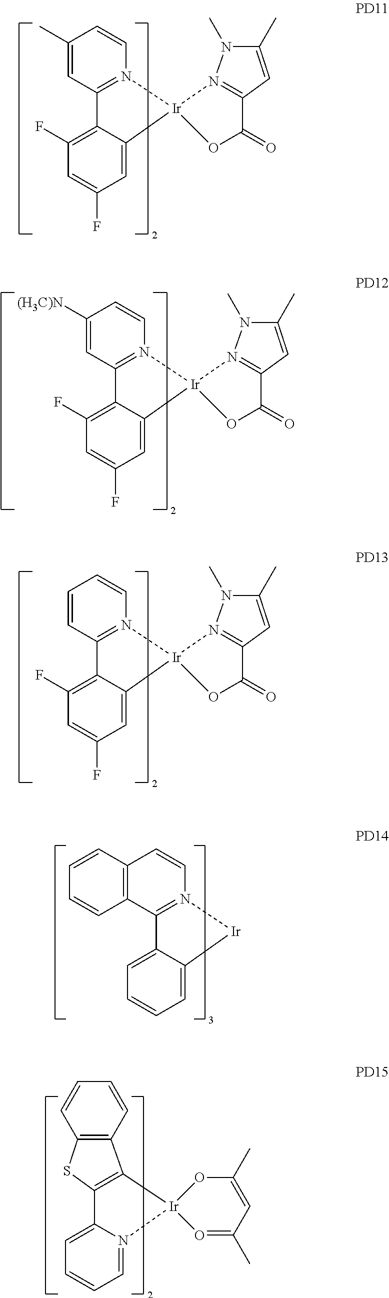

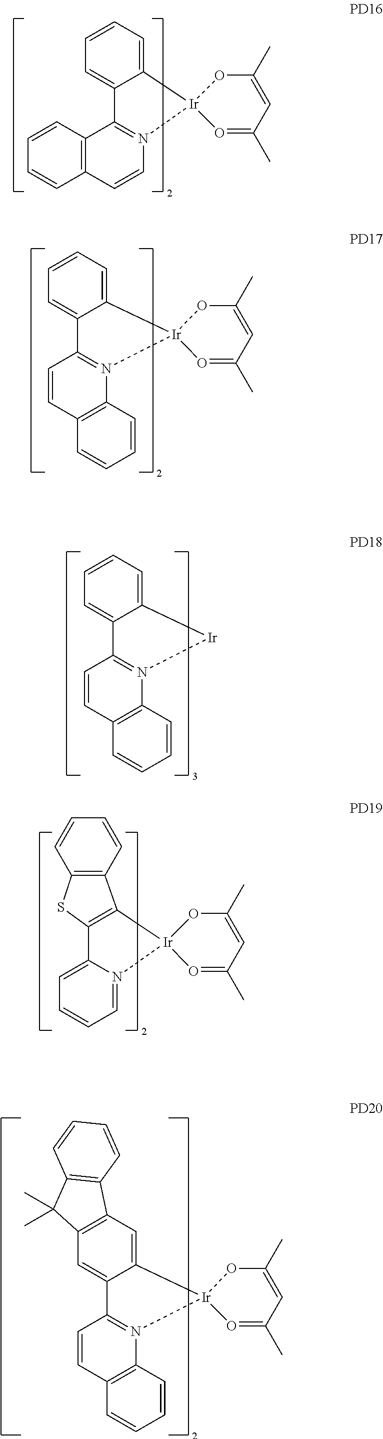

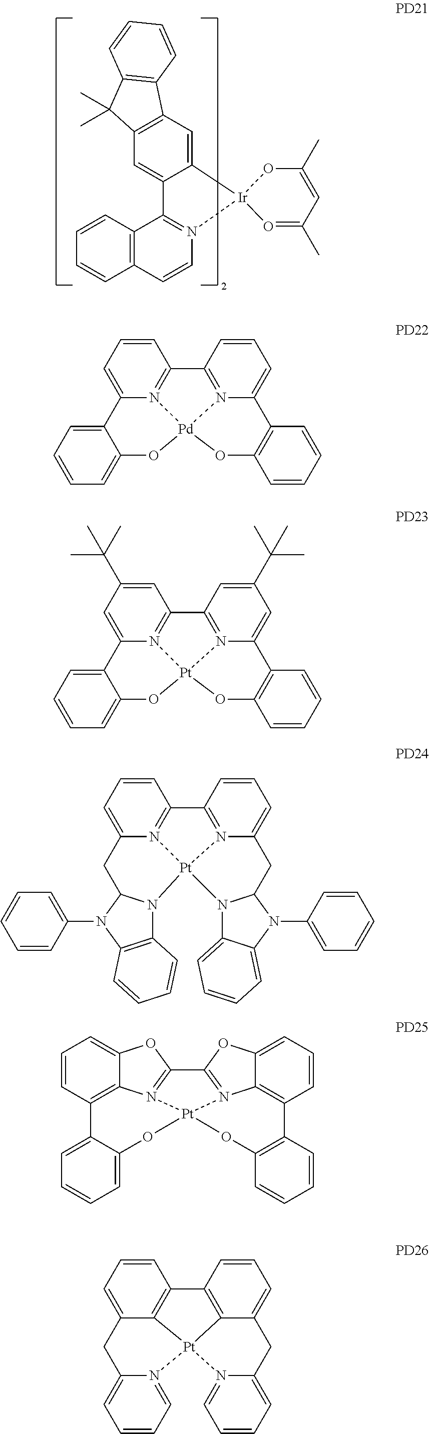

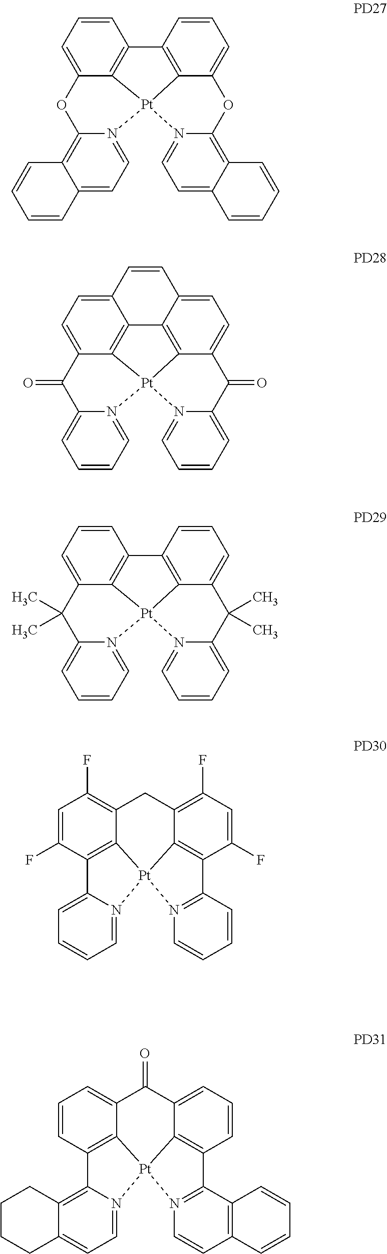

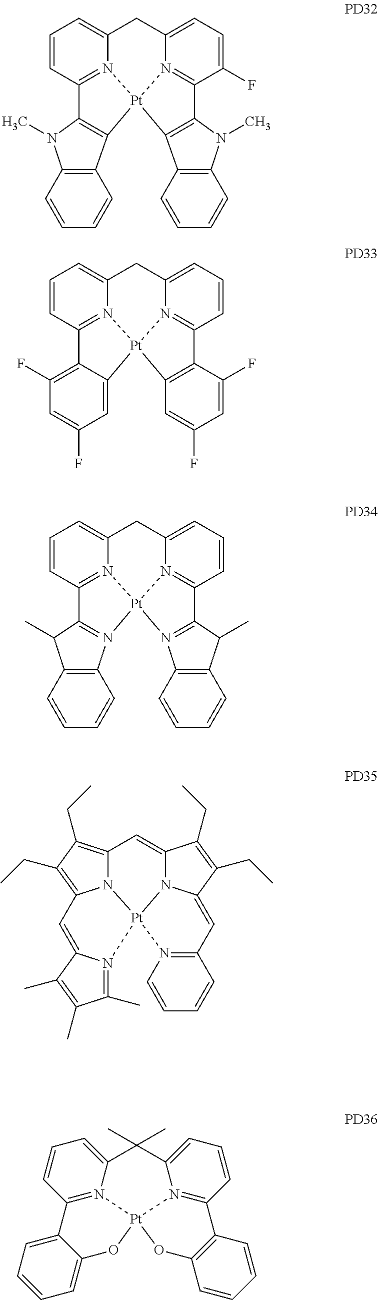

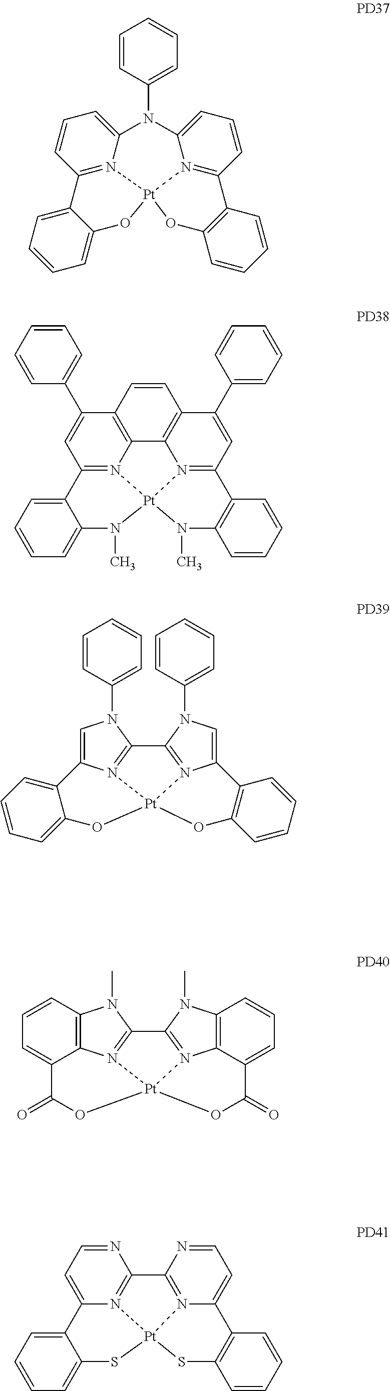

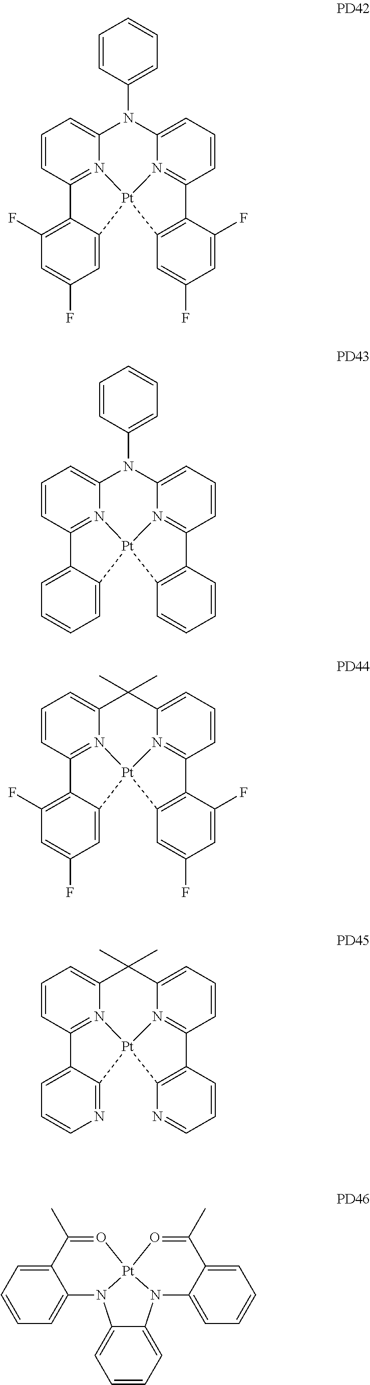

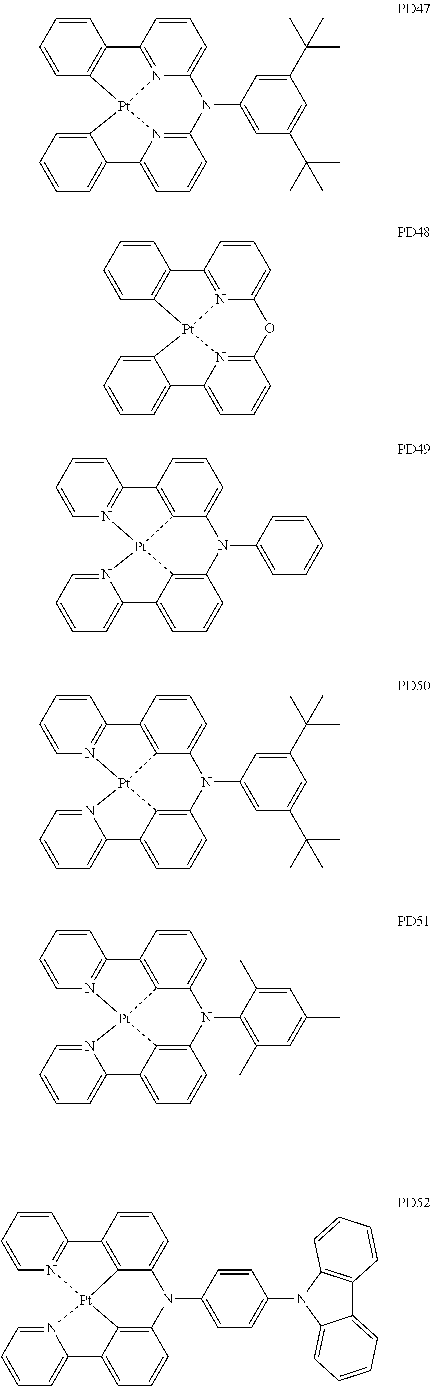

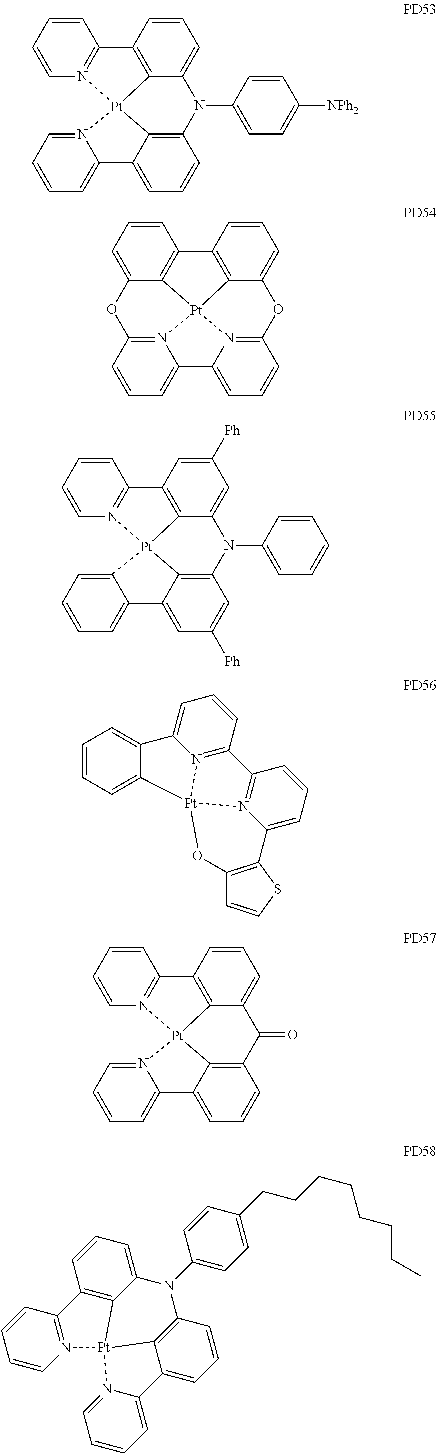

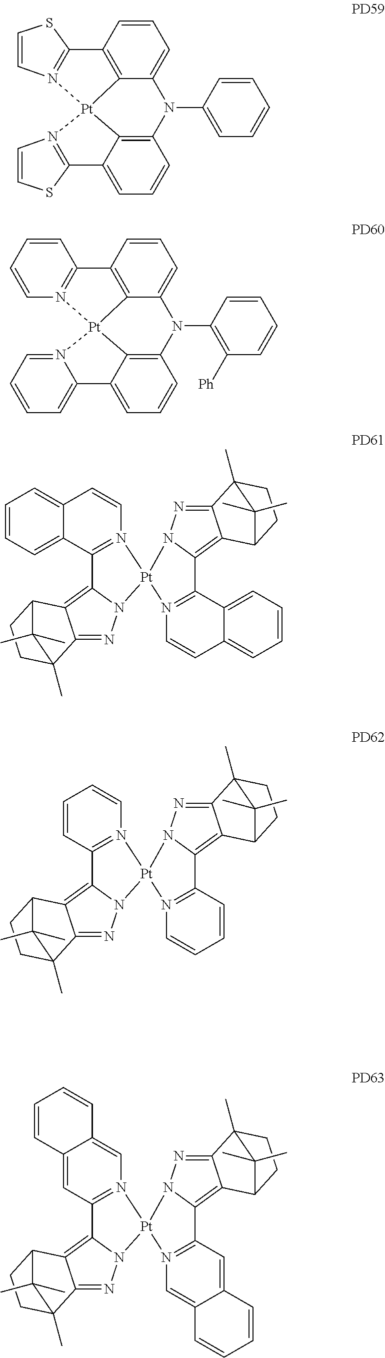

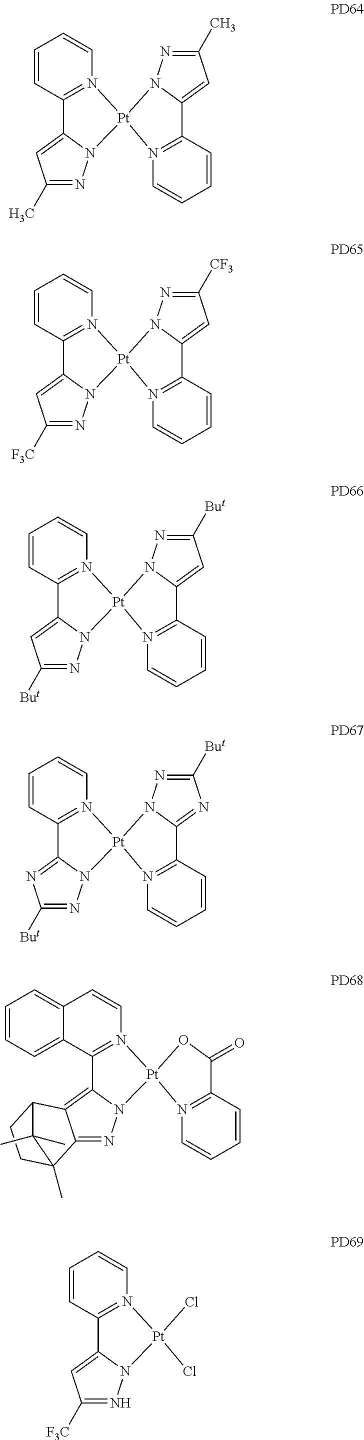

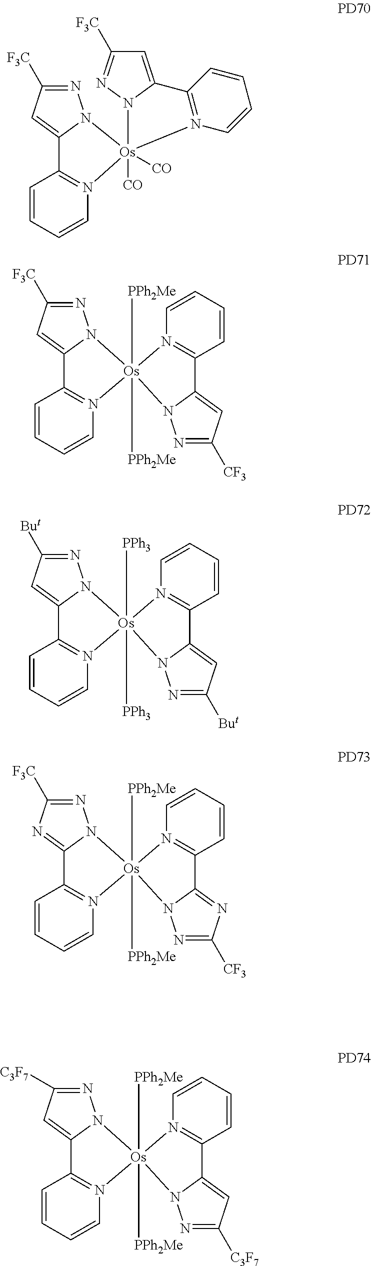

In some embodiments, the phosphorescent dopant may include PtOEP below:

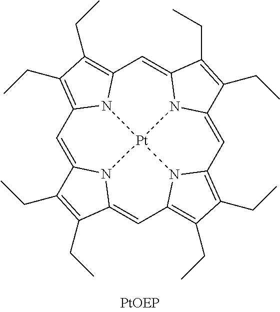

The fluorescent dopant may include at least one selected from DPAVBi, BDAVBi, TBPe, DCM, DCJTB, Coumarin 6, and C545T.

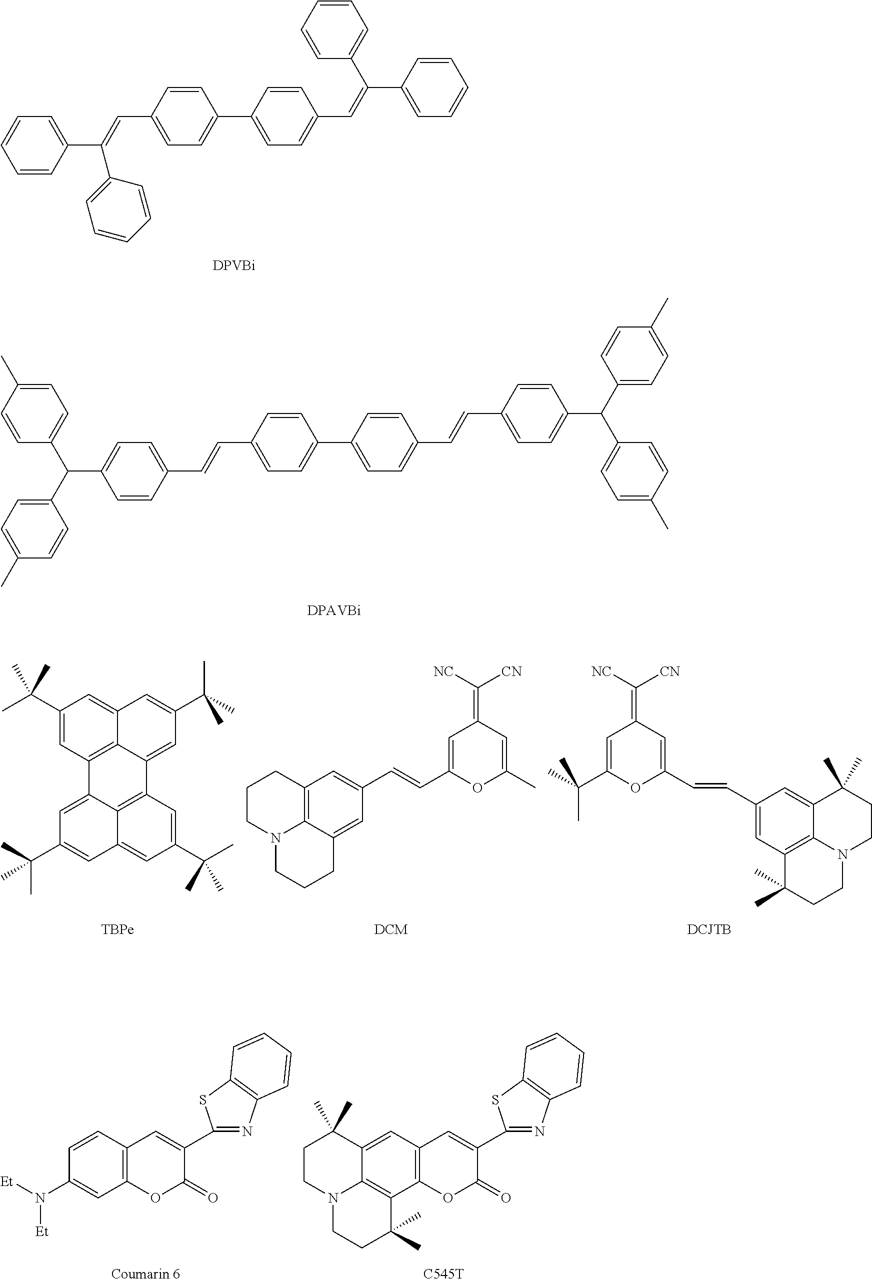

Alternatively, the fluorescent dopant may include a compound represented by Formula 501:

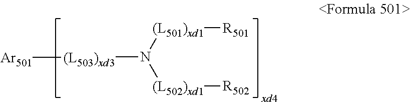

wherein in Formula 501,

Ar₅₀₁ may be selected from a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene, and an indenoanthracene; and

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene and an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₅₀₁)(Q₅₀₂)(Q₅₀₃) (where, Q₅₀₁ to Q₅₀₃ may be each independently selected from a hydrogen, a C₁-C₆₀ alkyl group, a C₂-C₆₀ alkenyl group, a C₆-C₆₀ aryl group, and a C₁-C₆₀ heteroaryl group);

L₅₀₁ to L₅₀₃ may be the same as defined in connection with L₂₀₁ provided herein;

R₅₀₁ and R₅₀₂ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, a triazinyl group, a dibenzofuranyl group, and a dibenzothiophenyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group and a dibenzofuranyl group, and a dibenzothiophenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, C₁-C₂₀ alkyl group, C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a dibenzofuranyl group, and a dibenzothiophenyl group;

xd1 to xd3 are each independently selected from 0, 1, 2, and 3; and

xd4 is selected from 1, 2, 3, and 4.

A weight ratio of the first compound and the second compound may be selected in a range of about 10:90 to about 90:10. For example, a weight ratio of the first compound and the second compound may be about 80:20, about 70:30, about 60:40, about 50:50, about 40:60, about 30:70, or about 20:80. In particular, for example, a weight ratio of the first compound and the second compound may be about 5:5, but embodiments are not limited thereto. When a weight ratio of the first compound and the second compound is within these ranges, a hole-electron transport balance in the emission layer may be effective.

The hole transport region may include at least one selected from a hole injection layer (HIL), a hole transport layer (HTL), a buffer layer, and an electron blocking layer (EBL), and the electron transport region may include at least one selected from a hole blocking layer (HBL), an electron transport layer (ETL), and an electron injection layer (EIL), but embodiments are not limited thereto.

The hole transport region may have a single-layered structure formed of a single material, a single-layered structure formed of a plurality of different materials, or a multi-layered structure having a plurality of layers formed of a plurality of different materials.

For example, the hole transport region may have a single-layered structure formed of a plurality of different materials, or a structure of hole injection layer/hole transport layer, a structure of hole injection layer/hole transport layer/buffer layer, a structure of hole injection layer/buffer layer, a structure of hole transport layer/buffer layer, a structure of hole injection layer/hole transport layer/electron blocking layer, or a structure of hole transport layer/electron blocking layer, wherein layers of each structure are sequentially stacked from the first electrode 110 in this stated order, but embodiments are not limited thereto.

When the hole transport region includes a hole injection layer, the hole injection layer may be formed on the first electrode 110 by using various methods, such as vacuum deposition, spin coating, casting, Langmuir-Blodgett (LB) method, ink-jet printing, laser-printing, or laser-induced thermal imaging (LITI).

When a hole injection layer is formed by vacuum deposition, the vacuum deposition may be, for example, performed at a temperature of about 100° C. to about 500° C., a vacuum degree of about 10⁻⁸ torr to about 10⁻³ torr, and a deposition rate of about 0.01 Å/sec to about 100 Å/sec in consideration of a compound for a hole injection layer to be deposited, and the structure of a hole injection layer to be formed.

When a hole injection layer is formed by spin coating, the spin coating may be performed at a coating rate of about 2000 rpm to about 5000 rpm and at a temperature of about 80° C. to 200° C. in consideration of a compound for a hole injection layer to be deposited, and the structure of a hole injection layer to be formed.

When the hole transport region includes a hole transport layer, the hole transport layer may be formed on the first electrode 110 or the hole injection layer by using various methods, such as vacuum deposition, spin coating, casting, LB method, ink-jet printing, laser-printing, or LITI. When the hole transport layer is formed by vacuum-deposition or spin coating, conditions for vacuum-deposition and coating may be similar to the above-described vacuum-deposition and coating conditions for forming the hole injection layer.

The hole transport region may include at least one of m-MTDATA, TDATA, 2-TNATA, NPB, β-NPB, TPD, spiro-TPD, spiro-NPB, methylated-NPB, TAPC, HMTPD, 4,4′,4″-tris(N-carbazolyl)triphenylamine) (TCTA), polyaniline/dodecylbenzenesulfonic acid (Pani/DBSA), poly(3,4-ethylenedioxythiophene)/Poly(4-styrenesulfonate) (PEDOT/PSS), polyaniline/camphor sulfonicacid (Pani/CSA), polyaniline)/poly(4-styrenesulfonate) (PANI/PSS), a compound represented by Formula 201, and a compound represented by Formula 202:

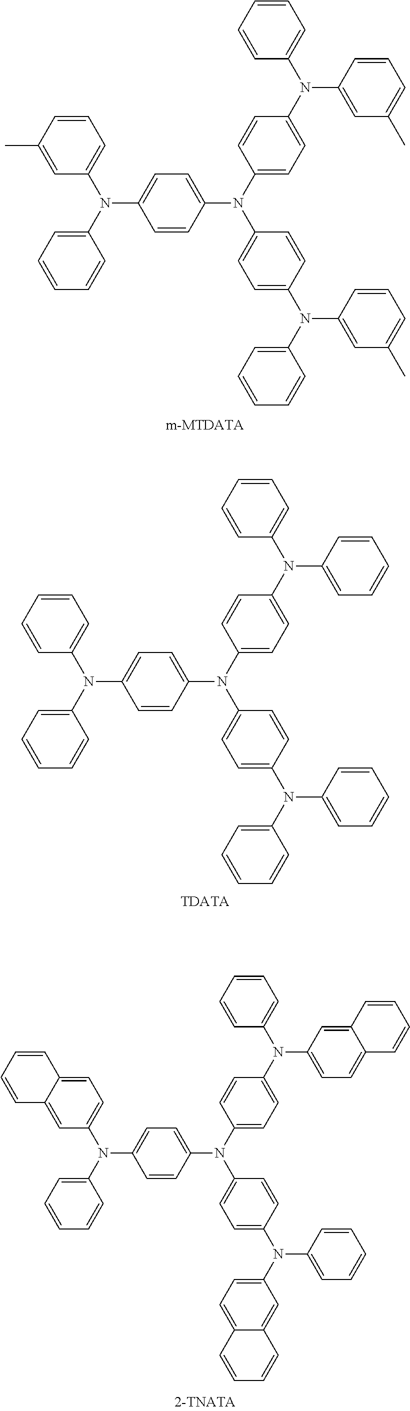

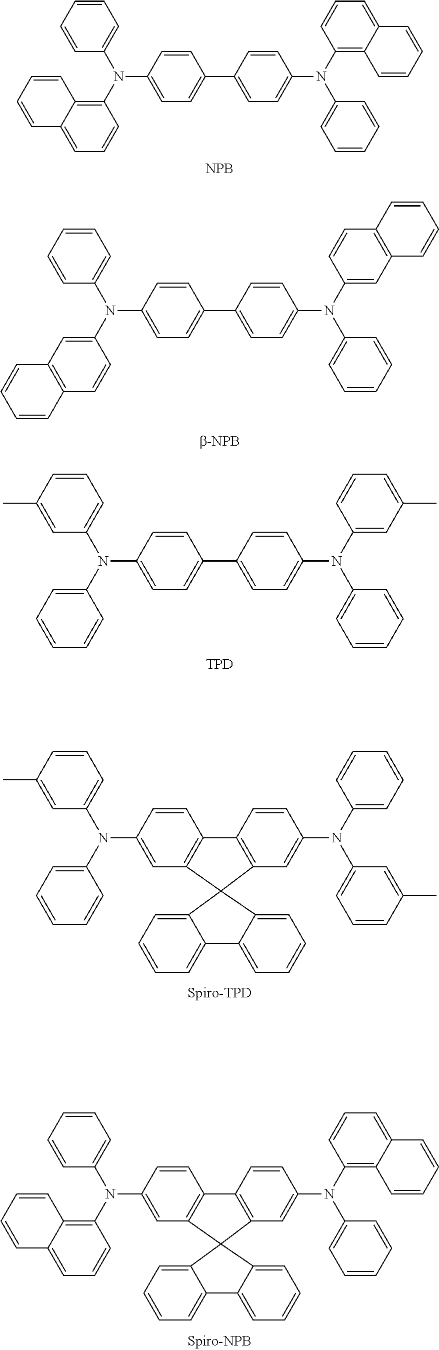

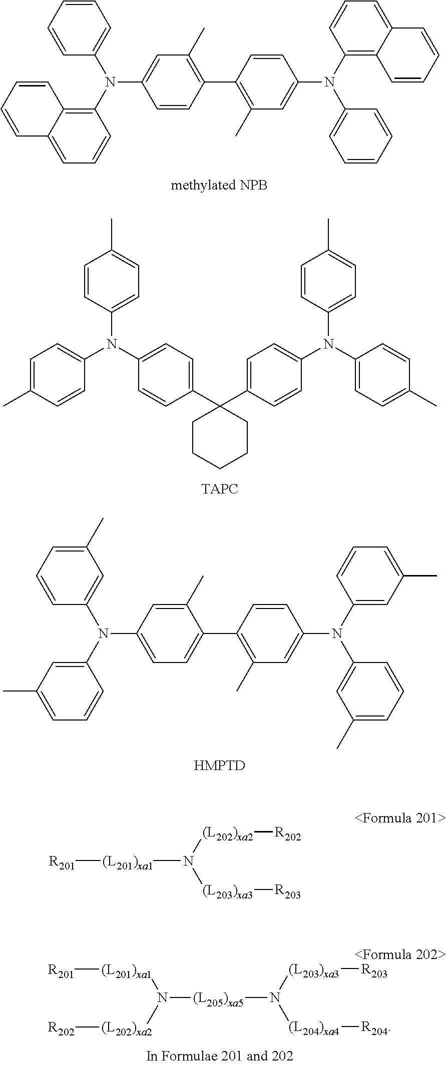

L₂₀₁ to L₂₀₅ are each independently the same as defined in connection with L₁ to L₃ provided herein;

xa1 to xa4 are each independently selected from 0, 1, 2, and 3;

xa5 is selected from 1, 2, 3, 4, and 5;

R₂₀₁ to R₂₀₄ are each independently selected from a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group.

In some embodiments, in Formulae 201 and 202,

L₂₀₁ to L₂₀₅ may be each independently selected from

a phenylene group, a naphthylene group, a fluorenylene group, a spiro-fluorenylene group, a benzofluorene group, a dibenzofluorene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, an isoindolyl group, a quinolinyl group, an isoquinolinyl group, a quinoxalinyl group, a quinazolinyl group, a carbazolyl group, and a triazinyl group;

xa1 to xa4 may be each independently selected from 0, 1, and 2;

xa5 may be selected from 1, 2, and 3;

R₂₀₁ to R₂₀₄ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an azulenyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, but embodiments are not limited thereto:

The compound represented by Formula 201 may be represented by Formula 201A:

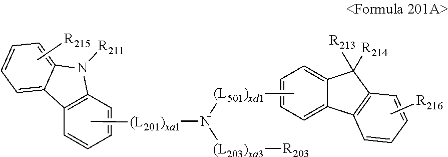

In some embodiments, the compound represented by Formula 201 may be represented by Formula 201A-1, but embodiments are not limited thereto:

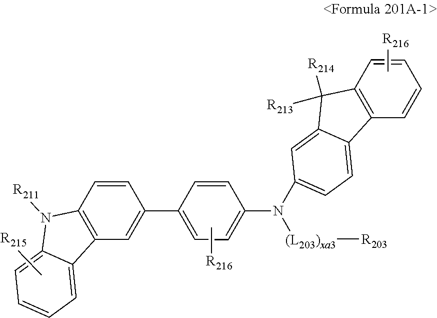

In some embodiments, the compound represented by Formula 202 may be represented by Formula 202A, but embodiments are not limited thereto:

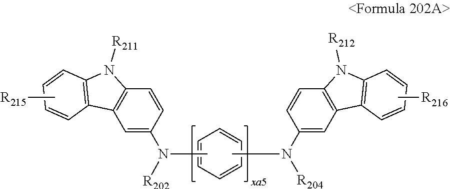

In Formulae 201A, 201A-1, and 202A, L₂₀₁ to L₂₀₃, xa1 to xa3, xa5, and R₂₀₂ to R₂₀₄ are the same as described herein, R₂₁₁ and R₂₁₂ are each independently the same as defined in connection with R₂₀₃ provided herein, and R₂₁₃ to R₂₁₆ may be selected from each independently a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group.

In some embodiments, in Formulae 201A, 201A-1, and 202A,

L₂₀₁ to L₂₀₃ may be each independently selected from

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xa1 to xa3 may be each independently selected from 0 and 1;

R₂₀₃, R₂₀₄, R₂₁₁ and R₂₁₂ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, carboxylic acid a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₃ and R₂₁₄ may be each independently selected from

a C₁-C₂₀ alkyl group and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₅ and R₂₁₆ may be each independently selected from

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, and

xa5 may be selected from 1 and 2.

In Formulae 201A and 201A-1, R₂₁₃ and R₂₁₄ may link to each other to form a saturated ring or an unsaturated ring.

The compound represented by Formula 201 and the compound represented by Formula 202 may include Compounds HT1 to HT20, but embodiments are not limited thereto.

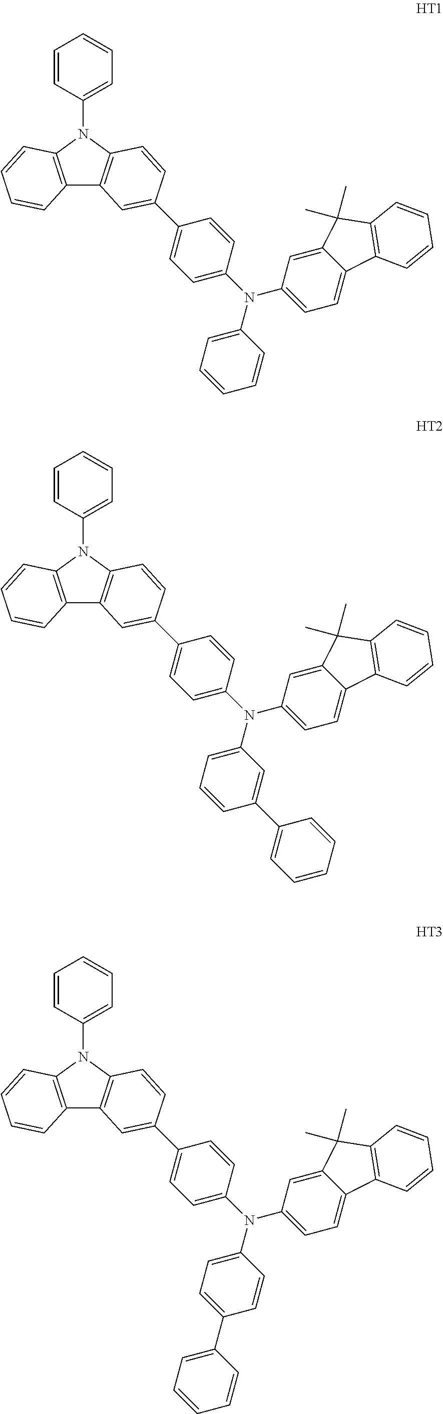 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

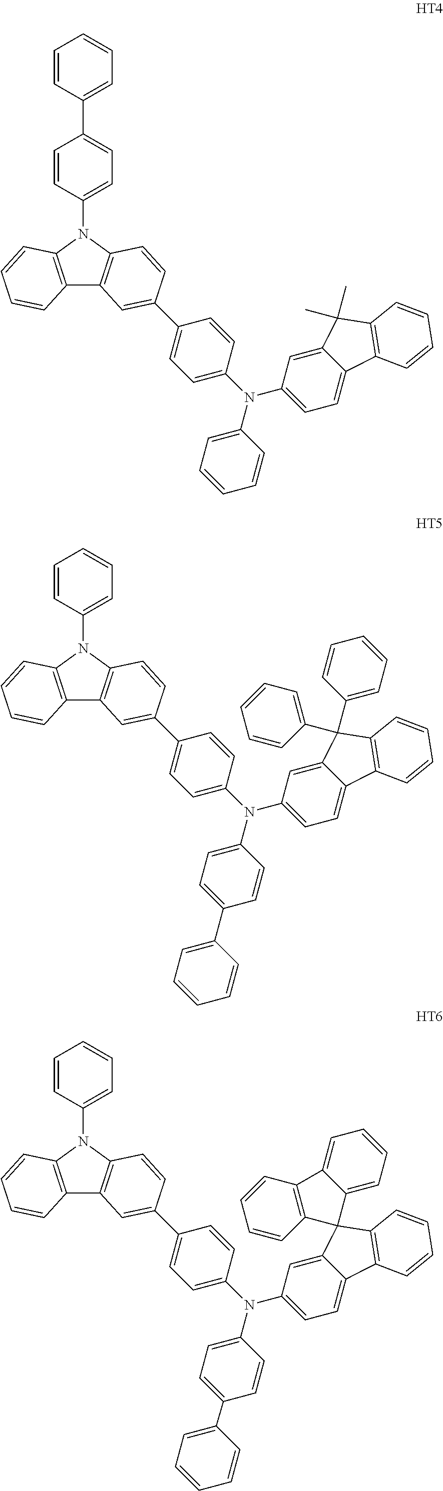 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

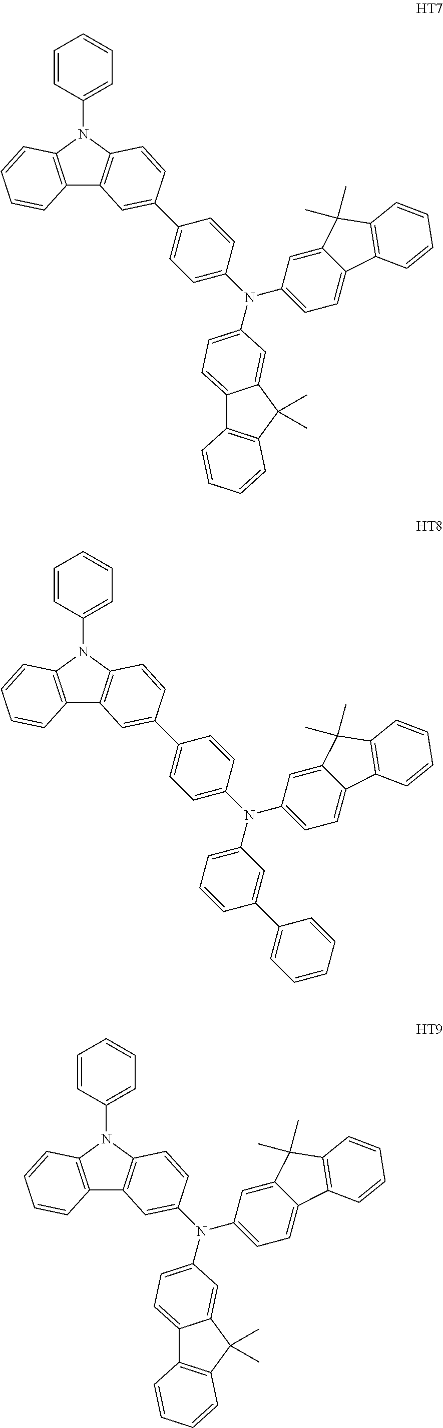 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

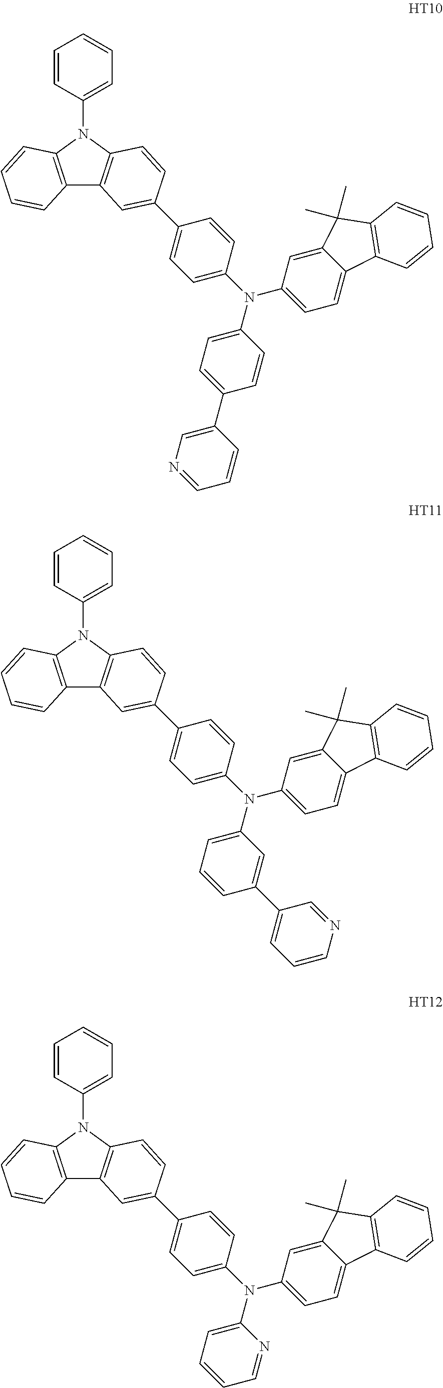 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

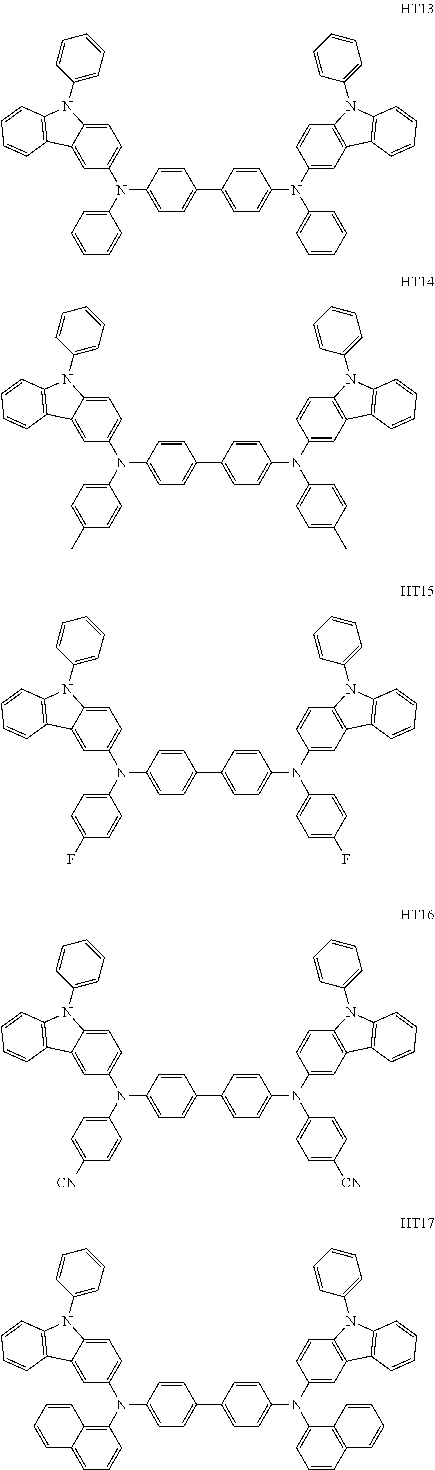

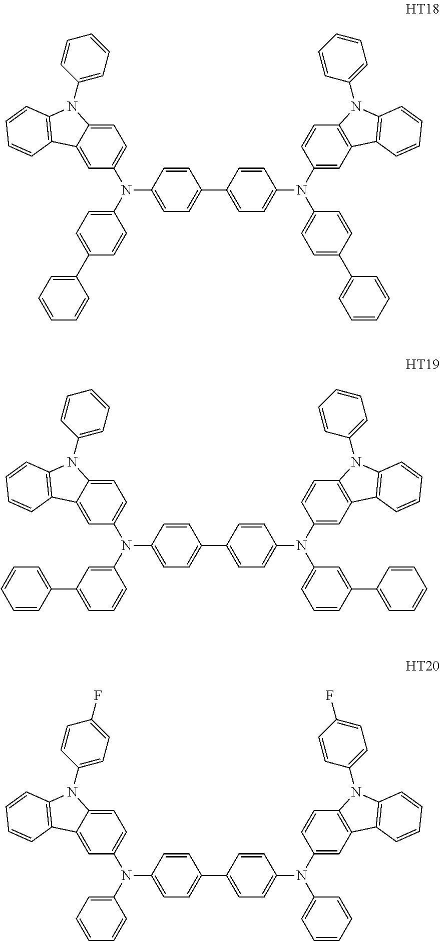 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10000 Å, for example, about 100 Å to about 1000 Å. When the hole transport region includes a hole injection layer and a hole transport layer, the thickness of the hole injection layer may be in a range of about 100 Å to about 10000 Å, and for example, about 100 Å to about 1000 Å, and the thickness of the hole transport layer may be in a range of about 50 Å to about 2000 Å, and for example, about 100 Å to about 1500 Å. When the thicknesses of the hole transport region, the hole injection layer, and the hole transport layer are within these ranges, excellent hole transport characteristics may be obtained without a substantial increase in driving voltage.

The hole transport region may further include, in addition to the mentioned materials above, a charge-generating material to improve conductive properties. The charge-generating material may be homogeneously or non-homogeneously dispersed throughout the hole transport region.

The charge-generating material may be, for example, a p-dopant. The p-dopant may be one selected from a quinone derivative, a metal oxide, and a cyano group-containing compound, but embodiments are not limited thereto. For example, non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide, and Compound HT-D1 illustrated below, but embodiments are not limited thereto.

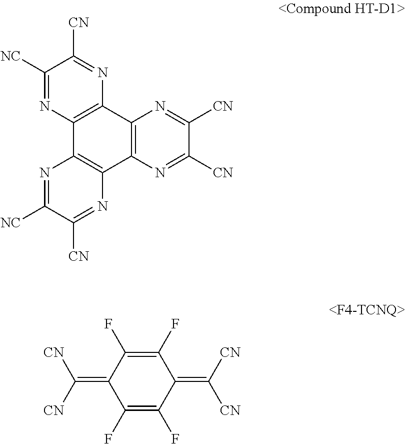

The hole transport region may further include, in addition to the hole injection layer and the hole transport layer, at least one selected from a buffer layer and an electron blocking layer. Since the buffer layer may compensate for an optical resonance distance according to a wavelength of light emitted from the emission layer, light-emission efficiency of a formed organic light-emitting device may be improved. For use as a material included in the buffer layer, materials that are included in the hole transport region may be used. The electron blocking layer prevents injection of electrons from the electron transport region.

In some embodiments, mCP may be used as a material for forming the electron blocking layer, but embodiments are not limited thereto.

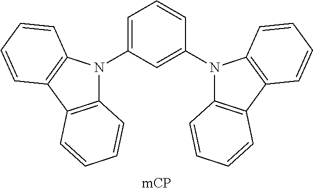 [SMILES: c1cc(-n2c3ccccc3c3ccccc32)cc(-n2c3ccccc3c3ccccc32)c1]

The electron transport region may include at least one selected from a hole blocking layer, an electron transport layer (ETL), and an electron injection layer, but embodiments are not limited thereto.

For example, the electron transport region may have a structure of electron transport layer/electron injection layer or a structure of hole blocking layer/electron transport layer/electron injection layer, wherein layers of each structure are sequentially stacked from the emission layer in the stated order, but embodiments are not limited thereto.

The electron transport region may include a hole blocking layer. The hole blocking layer may be formed, when the emission layer includes a phosphorescent dopant, to prevent diffusion of excitons or holes into an electron transport layer.

When the electron transport region includes a hole blocking layer, the hole blocking layer may be formed on the emission layer by using various methods, such as vacuum-deposition, spin coating, casting, LB method, ink-jet printing, laser-printing, or LITI. When the hole blocking layer is formed by vacuum-deposition or spin coating, deposition and coating conditions for the hole blocking layer may be determined by referring to the deposition and coating conditions for the hole injection layer.

The hole blocking layer may include, for example, at least one selected from BCP and Bphen, but embodiments are not limited thereto.

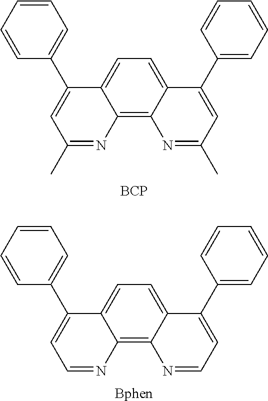

A thickness of the hole blocking layer may be in a range of about 20 Å to about 1000 Å, for example, about 30 Å to about 300 Å. When the thickness of the hole blocking layer is within this range, excellent hole blocking characteristics may be obtained without a substantial increase in driving voltage.

The electron transport region may include an electron transport layer. The electron transport layer may be formed on the emission layer or the hole blocking layer by using various methods, such as vacuum deposition, spin coating, casting, LB method, ink-jet printing, laser-printing, or LITI. When the electron transport layer is formed by using vacuum deposition or spin coating, vacuum deposition and coating conditions for the electron transport layer may be determined by referring to the vacuum deposition and coating conditions for the hole injection layer.

The electron transport layer may include at least one selected from BCP, Bphen, Alq₃, BAlq, TAZ, and NTAZ.

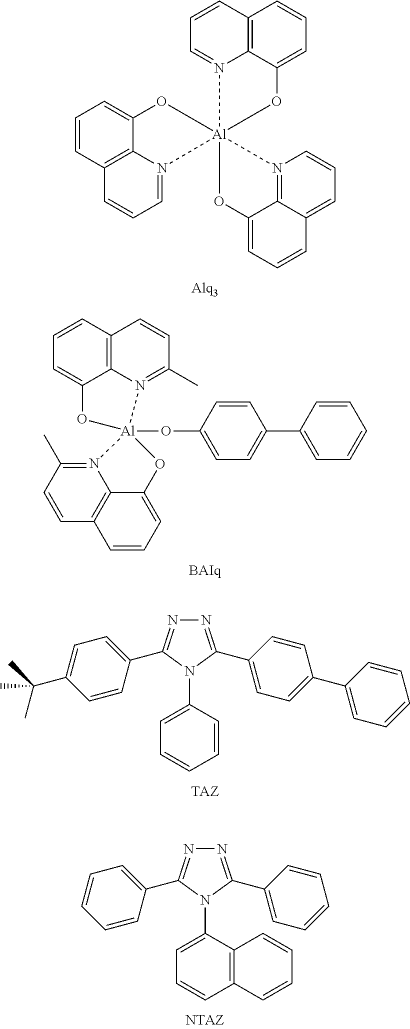

In some embodiments, the electron transport layer may include at least one compound selected from a compound represented by Formula 601 and a compound represented by Formula 602 illustrated below:

Ar₆₀₁-[(L₆₀₁)ₓₑ₁-E₆₀₁]ₓₑ₂ <Formula 601>

wherein in Formula 601,

Ar₆₀₁ may be selected from

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, and an indenoanthracene;

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, naphthacene, a picene, a perylene, a pentaphene, and an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, and —Si(Q₃₀₁)(Q₃₀₂)(Q₃₀₃),

wherein Q₃₀₁ to Q₃₀₃ may be each independently selected from a hydrogen, a C₁-C₆₀ alkyl group, a C₂-C₆₀ alkenyl group, a C₆-C₆₀ aryl group, and a C₁-C₆₀ heteroaryl group;

L₆₀₁ may be the same as defined in connection with L₂₀₁;

E₆₀₁ may be selected from

a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group; and

a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group;

xe1 may be selected from 0, 1, 2, and 3; and

xe2 may be selected from 1, 2, 3, and 4.

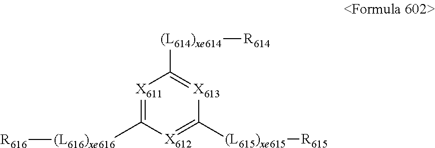

wherein, in Formula 602,

X₆₁₁ may be N or C-(L₆₁₁)ₓₑ₆₁₁-R₆₁₁, X₆₁₂ may be N or C-(L₆₁₂)ₓₑ₆₁₂-R₆₁₂, X₆₁₃ may be N or C-(L₆₁₃)ₓₑ₆₁₃-R₆₁₃, and at least one selected from X₆₁₁ to X₆₁₃ may be N;

L₆₁₁ to L₆₁₆ may be each the same as defined in connection with L₂₀₁ provided herein;

R₆₁₁ to R₆₁₆ may be each independently selected from

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xe611 to xe616 may be each independently selected from 0, 1, 2, and 3.

The compound represented by Formula 601 and the compound represented by Formula 602 may each be selected from Compounds ET1 to ET15 illustrated below:

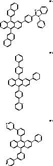 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

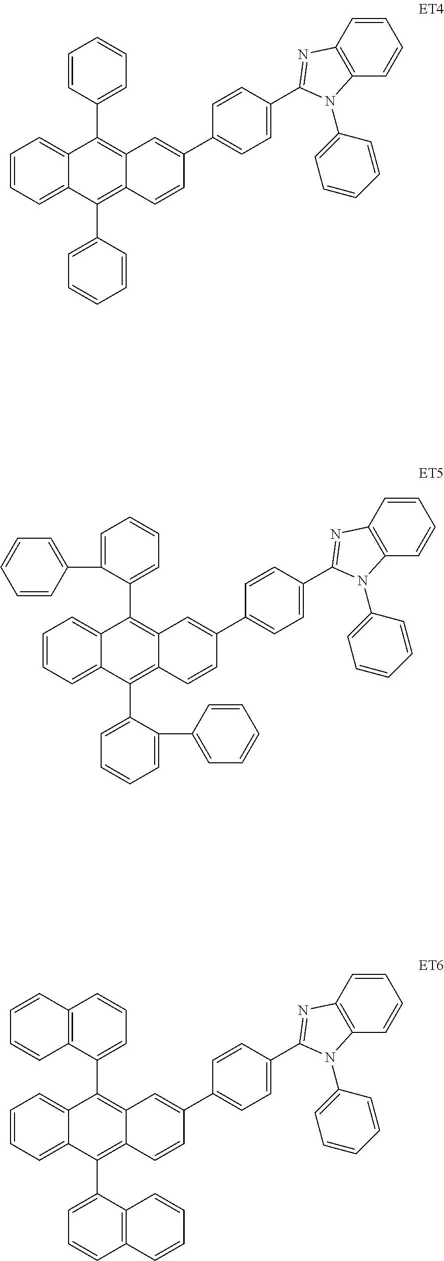 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

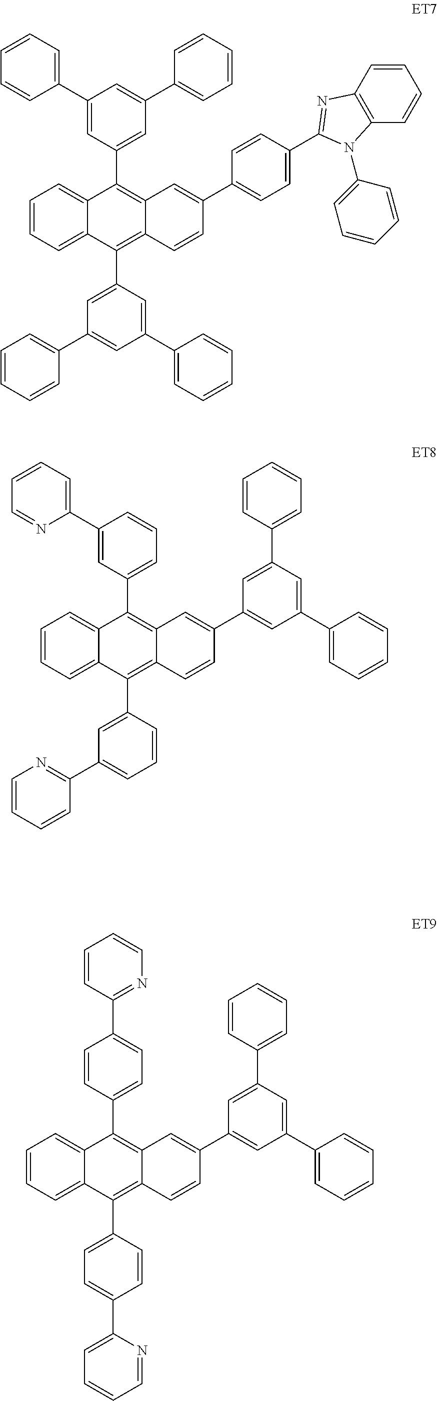 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

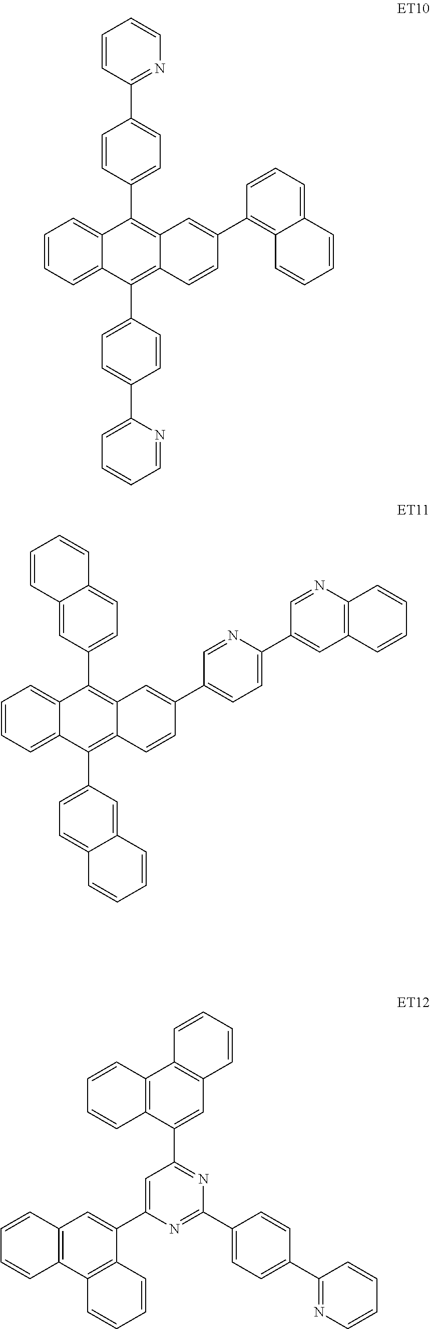 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2ccc(-c3nc(-c4cc5ccccc5c5ccccc45)cc(-c4cc5ccccc5c5ccccc45)n3)cc2)nc1]

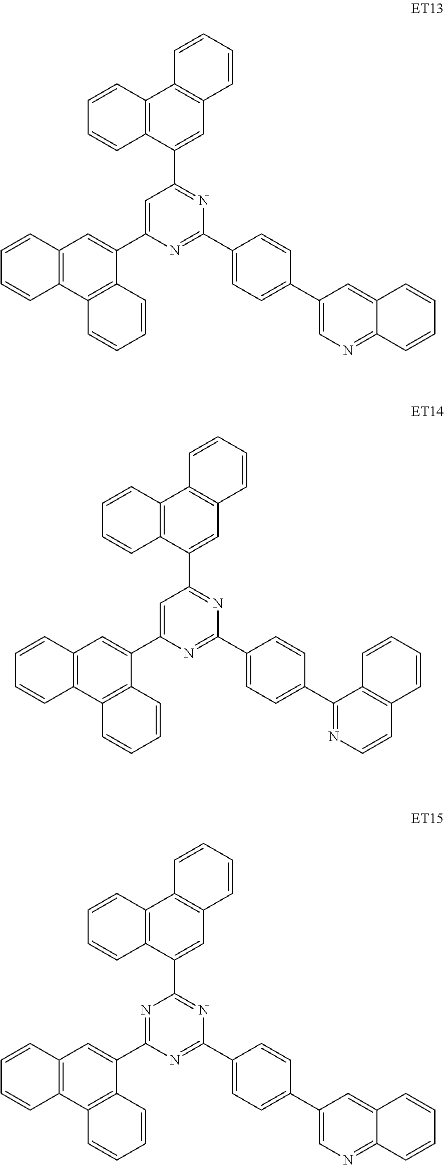 [SMILES: c1ccc2ncc(-c3ccc(-c4nc(-c5cc6ccccc6c6ccccc56)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

A thickness of the electron transport layer may be in a range of about 100 Å to about 1000 Å, for example, about 150 Å to about 500 Å. When the thickness of the electron transport layer is within this range, excellent electron transport characteristics may be obtained without a substantial increase in driving voltage.

The electron transport layer may further include a metal-containing material in addition to the materials described above.

The metal-containing material may include a Li complex. The Li complex may include, for example, Compound ET-D1 (lithium quinolate, LiQ) or ET-D2.

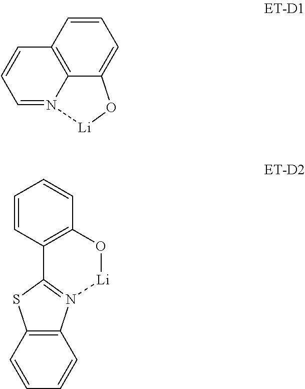

The electron transport region may include an electron injection layer that facilitates electron injection from the second electrode 190.

The electron injection layer may be formed on the electron transport layer by using various methods, such as vacuum-deposition, spin coating, casting, LB method, ink-jet printing, laser-printing, or LITI. When the electron injection layer is formed by vacuum-deposition or spin coating, vacuum-deposition and coating conditions for the electron injection layer may be determined by referring to the vacuum-deposition and coating conditions for the hole injection layer.

The electron injection layer may include at least one selected from, LiF, NaCl, CsF, Li₂O, BaO, and LiQ.

A thickness of the electron injection layer may be in a range of about 1 Å to about 100 Å, for example, about 3 Å to about 90 Å. When the thickness of the electron injection layer is within this range, excellent electron injection characteristics may be obtained without a substantial increase in driving voltage.

The second electrode 190 is disposed on the organic layer 150. The second electrode 190 may be a cathode that is an electron injection electrode, and in this regard, a material for forming the second electrode 190 may be a material having a low work function, and such a material may be metal, alloy, an electrically conductive compound, or a mixture thereof. Examples of the second electrode 190 are such as lithium (Li), magnesium (Mg), aluminum (Al), aluminum-lithium (Al—Li), calcium (Ca), magnesium-indium (Mg—In), or magnesium-silver (Mg—Ag). In some embodiments, the material for forming the second electrode 190 may be ITO or IZO. The second electrode 190 may be a reflective electrode, a semi-transmissive electrode, or a transmissive electrode.

Hereinbefore, the organic light-emitting device has been described with reference to FIG. 1, but embodiments are not limited thereto.

A C₁-C₆₀ alkyl group used herein refers to a linear or branched aliphatic C1-C60 monovalent hydrocarbon group, and examples of the C₁-C₆₀ alkyl group include a methyl group, an ethyl group, a propyl group, an isobutyl group, a sec-butyl group, a ter-butyl group, a pentyl group, an iso-amyl group, and a hexyl group. A C₁-C₆₀ alkylene group used herein refers to a divalent group having the same structure as a C₁-C₆₀ alkyl group.

A C₁-C₆₀ alkoxy group used herein refers to a monovalent group represented by —OA₁₀₁ (wherein A₁₀₁ is the C₁-C₆₀ alkyl group), and examples thereof are a methoxy group, an ethoxy group and an isopropyloxy group.

A C₂-C₆₀ alkenyl group used herein refers to a hydrocarbon group formed by substituting at least one carbon double bond in the middle or terminal of the C₂-C₆₀ alkyl group, and examples thereof are an ethenyl group, a propenyl group, and a butenyl group. A C₂-C₆₀ alkenylene group used herein refers to a divalent group having the same structure as a C₂-C₆₀ alkenyl group.

A C₂-C₆₀ alkynyl group used herein refers to a hydrocarbon group formed by substituting at least one carbon triple bond in the middle or terminal of the C₂-C₆₀ alkyl group, and examples thereof are such as an ethynyl group or a propynyl group. A C₂-C₆₀ alkynylene group used herein refers to a divalent group having the same structure as a C₂-C₆₀ alkynyl group.

A C₃-C₁₀ cycloalkyl group used herein refers to a monovalent monocyclic saturated hydrocarbon group including 3 to 10 carbon atoms, and examples thereof are a cyclopropyl group, a cyclobutyl group, a cyclopentyl group, a cyclohexyl group, and a cycloheptyl group. A C₃-C₁₀ cycloalkylene group used herein refers to a divalent group having the same structure as a C₃-C₁₀ cycloalkyl group.

A C₁-C₁₀ heterocycloalkyl group used herein refers to a monovalent monocyclic group including at least one hetero atom selected from N, O, P, and S as a ring-forming atom and 1 to 10 carbon atoms, and examples thereof are a tetrahydrofuranyl group and a tetrahydrothiophenyl group. A C₁-C₁₀ heterocycloalkylene group used herein refers to a divalent group having the same structure as a C₁-C₁₀ heterocycloalkyl group.

A C₃-C₁₀ cycloalkenyl group used herein refers to a monovalent monocyclic group including 3 to 10 carbon atoms and at least one double bond in the ring thereof and does not have aromacity, and examples thereof are such as a cyclopentenyl group, a cyclohexenyl group, or a cycloheptenyl group. A C₃-C₁₀ cycloalkenylene group used herein refers to a divalent group having the same structure as a C₃-C₁₀ cycloalkenyl group.

A C₁-C₁₀ heterocycloalkenyl group used herein refers to a monovalent monocyclic group including at least one hetero atom selected from N, O, P, and S as a ring-forming atom, 1 to 10 carbon atoms, and at least one double bond in its ring. Examples of the C₁-C₁₀ heterocycloalkenyl group include 2,3-dihydrofuranyl group and 2,3-dihydro thiophenyl group. A C₁-C₁₀ heterocycloalkenylene group used herein refers to a divalent group having the same structure as a C₁-C₁₀ heterocycloalkenyl group.

A C₆-C₆₀ aryl group used herein refers to a monovalent group including a carbocyclic aromatic system having 6 to 60 carbon atoms, and a C₆-C₆₀ arylene group used herein refers to a divalent group including a carbocyclic aromatic system having 6 to 60 carbon atoms. Examples of the C₆-C₆₀ aryl group are a phenyl group, a naphthyl group, an anthracenyl group, a phenanthrenyl group, a pyrenyl group, and a chrysenyl group. When the C₆-C₆₀ aryl group and the C₆-C₆₀ arylene group each include a plurality of rings, the rings may be fused to each other.

A C₁-C₆₀ heteroaryl group used herein refers to a monovalent group having a carbocyclic aromatic system including at least one hetero atom selected from N, O, P, and S as a ring-forming atom and 1 to 60 carbon atoms. A C₁-C₆₀ heteroarylene group used herein refers to a divalent group having a carbocyclic aromatic system including at least one hetero atom selected from N, O, P, and S as a ring-forming atom and 1 to 60 carbon atoms. Examples of the C₁-C₆₀ heteroaryl group are a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

A C₆-C₆₀ aryloxy group used herein indicates —OA₁₀₂ (wherein A₁₀₂ is the C₆-C₆₀ aryl group), and a C₆-C₆₀ arylthio group used herein indicates —SA₁₀₃ (wherein A₁₀₃ is the C₆-C₆₀ aryl group).

A monovalent non-aromatic condensed polycyclic group used herein refers to a monovalent group that has two or more rings condensed to each other, only carbon atoms (for example, the number of carbon atoms may be in a range of 8 to 60) as ring forming atoms, wherein the molecular structure as a whole is non-aromatic in the entire molecular structure. A example of the monovalent non-aromatic condensed polycyclic group is a fluorenyl group. A divalent non-aromatic condensed polycyclic group used herein refers to a divalent group having the same structure as the monovalent non-aromatic condensed polycyclic group.

A monovalent non-aromatic condensed heteropolycyclic group used herein refers to a monovalent group that has two or more rings condensed to each other, the number of carbon atoms may be in a range of 1 to 60, at least one heteroatom selected from N, O, P, and S is included as a ring forming atom, wherein the molecular structure as a whole is non-aromatic in the entire molecular structure. The monovalent non-aromatic condensed heteropolycyclic group includes a carbazolyl group. A divalent non-aromatic condensed hetero-polycyclic group used herein refers to a divalent group having the same structure as the monovalent non-aromatic condensed hetero-polycyclic group.

At least one substituent of the substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group may be selected from

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇);

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₁-C₆₀ alkenyl group, a C₁-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇); and

—Si(Q₃₁)(Q₃₂)(Q₃₃), —B(Q₃₄)(Q₃₅) and —N(Q₃₆)(Q₃₇),

wherein Q₁ to Q₇, Q₁₁ to Q₁₇, Q₂₁ to Q₂₇, and Q₃₁ to Q₃₇ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

In some embodiments, at least one substituent of the substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group and substituted monovalent non-aromatic condensed heteropolycyclic group may be selected from

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₁₁)(Q₁₂), —B(Q₁₃)(Q₁₄), and —Si(Q₁₅)(Q₁₆)(Q₁₇);

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group;

a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, C₁-C₆₀ alkyl group, C₂-C₆₀ alkenyl group, C₂-C₆₀ alkynyl group, C₁-C₆₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₂₁)(Q₂₂), —B(Q₂₃)(Q₂₄), and —Si(Q₂₅)(Q₂₆)(Q₂₇); and

—N(Q₃₁)(Q₃₂), —B(Q₃₃)(Q₃₄), and —Si(Q₃₅)(Q₃₆)(Q₃₇),

wherein Q₁ to Q₇, Q₁₁ to Q₁₇, Q₂₁ to Q₂₇ and Q₃₁ to Q₃₇ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, but embodiments are not limited thereto.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments.

Further, it will be understood that the embodiments are not limited to the particular details described in the Examples and Comparative Examples.

### EXAMPLE

### Synthesis Example 1

### Synthesis of Compound 1

Compound 1 was synthesized via Reaction Scheme 1 below:

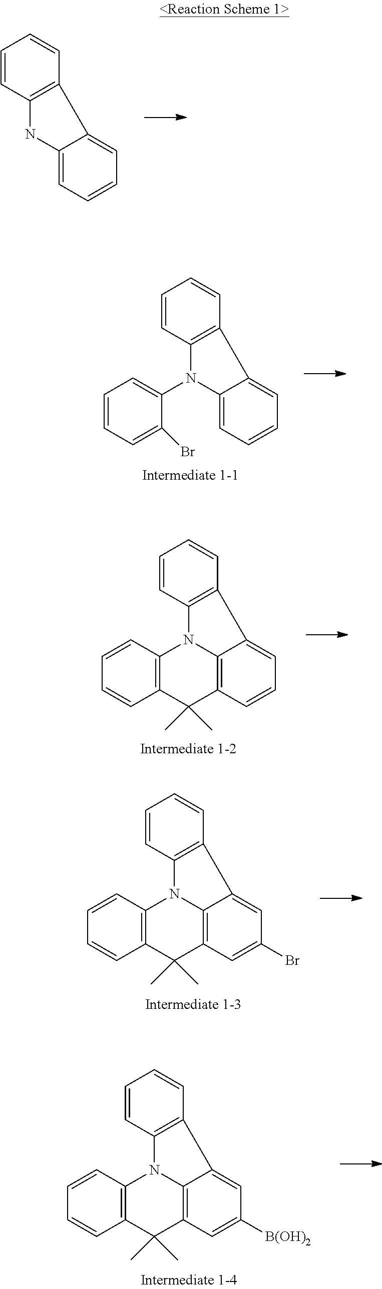 [SMILES: c1ccc2c(c1)[nH]c1ccccc12 ; Brc1ccccc1-n1c2ccccc2c2ccccc21 ; CC1(C)c2ccccc2-n2c3ccccc3c3cccc1c32 ; CC1(C)c2ccccc2-n2c3ccccc3c3cc(Br)cc1c32 ; CC1(C)c2ccccc2-n2c3ccccc3c3cc(B(O)O)cc1c32]

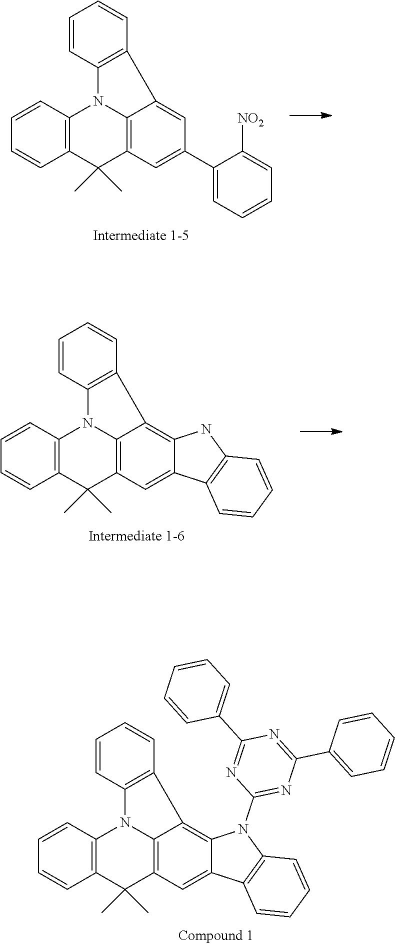 [SMILES: CC1(C)c2ccccc2-n2c3ccccc3c3cc(-c4ccccc4[N+](=O)[O-])cc1c32 ; CC1(C)c2ccccc2-n2c3ccccc3c3c4[nH]c5ccccc5c4cc1c32 ; CC1(C)c2ccccc2-n2c3ccccc3c3c2c1cc1c2ccccc2n(-c2nc(-c4ccccc4)nc(-c4ccccc4)n2)c13]

Synthesis of Intermediate 1-1

20 g (119.61 mmol) of carbazole, 67.68 g (239.22 mmol) of 2-bromoiodobenzene, 11.40 g (59.81 mmol) of copper iodide, and 33.06 g (239.22 mmol) of potassium carbonate were dissolved in xylene under a nitrogen atmosphere, and the mixture was refluxed while stirring. After 12 hours, the mixture was cooled to ambient temperature, distilled water was added thereto, and the mixture was subjected to extraction using methylene chloride (MC), dried using magnesium sulfate, and distilled under reduced pressure. The resultant was purified using column chromatography to obtain 32.64 g (101.67 mmol, 85% yield) of Intermediate 1-1.

Synthesis of Intermediate 1-2

20 g (62.30 mmol) of Intermediate 1-1 was dissolved in 100 ml of THF, and 24.91 ml (62.30 mmol, 2.5 M in hexane) of n-buLi was slowly added thereto at −78° C. After stirring for 2 hours, 4.70 ml (80.99 mmol) of acetone was added thereto, and the mixture was slowly heated to ambient temperature. Then, a NaHCO₃ aqueous solution was added thereto, and the mixture was subjected to extraction using MC. The resultant was dried using magnesium sulfate, distilled under reduced pressure, and added to a separate two-neck flask to be mixed with 100 ml of acetic acid. An HCl aqueous solution having the same amount as the catalyst (5 mol %, 12 N) was added thereto, and the mixture was refluxed while stirring. After 12 hours, the mixture was cooled to ambient temperature, and distilled water was added thereto. The mixture was subjected to extraction using MC, dried using magnesium sulfate, and distilled under reduced pressure. The resultant was purified using column chromatography to obtain 11.47 g (40.50 mmol, 65% yield) of Intermediate 1-2.

Synthesis of Intermediate 1-3

20 g (70.64 mmol) of Intermediate 1-2 was dissolved in 200 ml of dimethylformamide (DMF), and then 13.83 g (77.70 mmol) of N-bromosuccinimide (NBS) was added thereto. After the mixture was stirred at ambient temperature for 10 hours, the organic solvent was distilled under reduced pressure, and distilled water was added thereto. Then, the resultant was subjected to extraction using ethyl acetate (EA). The resultant was dried using magnesium sulfate, distilled under reduced pressure, and purified using column chromatography to obtain 22.19 g (61.45 mmol, 87% yield) of Intermediate 1-3.

Synthesis of Intermediate 1-4

20 g (55.39 mmol) of Intermediate 1-3 was dissolved in 200 ml of THF, and 22.15 ml (55.39 mmol, 2.5 M in hexane) of n-buLi was slowly added thereto at −78° C. After stirring for 1 hour, 8.02 ml (72.01 mmol) of trimethyl borate was added thereto, and the mixture was heated to ambient temperature and stirred for 12 hours. Distilled water was added thereto, and the mixture was subjected to extraction using EA, dried using magnesium sulfate, and distilled under reduced pressure. The resultant was purified using column chromatography to obtain 10.87 g (33.24 mmol, 60% yield) of Intermediate 1-4.

Synthesis of Intermediate 1-5

20 g (61.14 mmol) of Intermediate 1-4, 14.81 g (73.36 mmol) of bromo-2-nitrobenzene, 1.78 g (1.53 mmol) of tetrakis(triphenylphosphine)palladium(0) (Pd(PPh₃)₄), 49.98 ml (101.89 mmol) of 2 M K₂CO₃ aqueous solution, 160 ml of toluene, and 60 ml of ethanol were refluxed while stirring. After 4 hours, the mixture was cooled to ambient temperature, and distilled water was added thereto. The mixture was subjected to extraction using EA, dried using magnesium sulfate, and distilled under reduced pressure. The resultant was purified using column chromatography to obtain 18.78 g (46.46 mmol, 76% yield) of Intermediate 1-5.

Synthesis of Intermediate 1-6

10 g (24.74 mmol) of Intermediate 1-5 was mixed with 100 ml of triethylphosphite, and the mixture was stirred at 180° C. After 10 hours, the mixture was cooled to ambient temperature, and the organic solvent was distilled under reduced pressure. Distilled water was added thereto, and the mixture was subjected to extraction using EA, dried using magnesium sulfate, and distilled under reduced pressure. The resultant was purified using column chromatography to obtain 5.51 g (14.85 mmol, 60% yield) of Intermediate 1-6.

Synthesis of Compound 1

10 g (26.92 mmol) of Intermediate 1-6 was dissolved in 100 ml of DMF, and the solution was added to a reactor in which 1.62 g (40.38 mmol, 60% dispersion in mineral oil) of NaH was dissolved in 100 ml of DMF. After one hour, 8.65 g (32.31 mmol) of 2-chloro-4,6-diphenyltriazine dissolved in 100 ml of DMF was added thereto. The mixture was stirred for 12 hours, and then distilled water was added thereto to obtain a solid. The solid was filtered under reduced pressure and recrystallized using EA and DMF to obtain 8.77 g (14.54 mmol, 54% yield) of Compound 1.

MS: m/z 603.24 [M]⁺

¹H NMR (CDCl₃) δ 8.55 (1H), 8.32 (1H), 8.28 (4H), 8.12 (1H), 7.94 (1H), 7.63 (1H), 7.51 (4H), 7.50 (1H), 7.41 (2H), 7.40 (1H), 7.37 (1H), 7.33 (1H), 7.30 (1H), 7.29 (1H), 7.26 (1H), 7.25 (1H), 1.72 (6H)

### Synthesis Example 2

### Synthesis of Compound 2

Compound 2 (52% yield) was prepared in the same manner as in Synthesis Example 1, except that benzophenone was used instead of acetone in the synthesis of Intermediate 1-2.

MS: m/z 727.27 [M]⁺

¹H NMR (CDCl₃) δ 8.55 (1H), 8.28 (4H), 8.25 (1H), 8.12 (1H), 7.94 (1H), 7.63 (1H), 7.51 (4H), 7.50 (1H), 7.41 (2H), 7.39 (1H), 7.33 (6H), 7.29 (1H), 7.26 (2H), 7.25 (1H), 7.23 (1H), 7.22 (1H), 7.11 (4H)

### Synthesis Example 3

### Synthesis of Compound 3

Compound 3 was synthesized via Reaction Scheme 2 below:

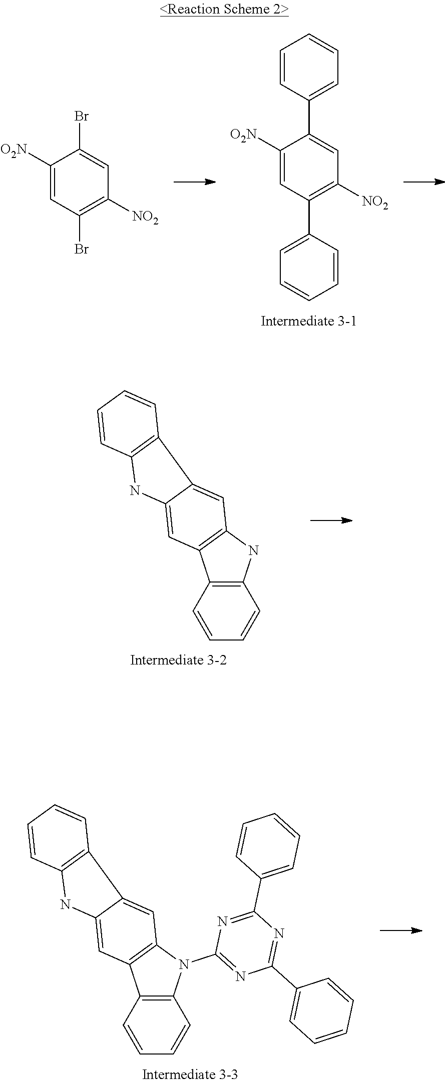 [SMILES: O=[N+]([O-])c1cc(Br)c([N+](=O)[O-])cc1Br ; O=[N+]([O-])c1cc(-c2ccccc2)c([N+](=O)[O-])cc1-c1ccccc1 ; c1ccc2c(c1)[nH]c1cc3c(cc12)[nH]c1ccccc13 ; c1ccc(-c2nc(-c3ccccc3)nc(-n3c4ccccc4c4cc5[nH]c6ccccc6c5cc43)n2)cc1]

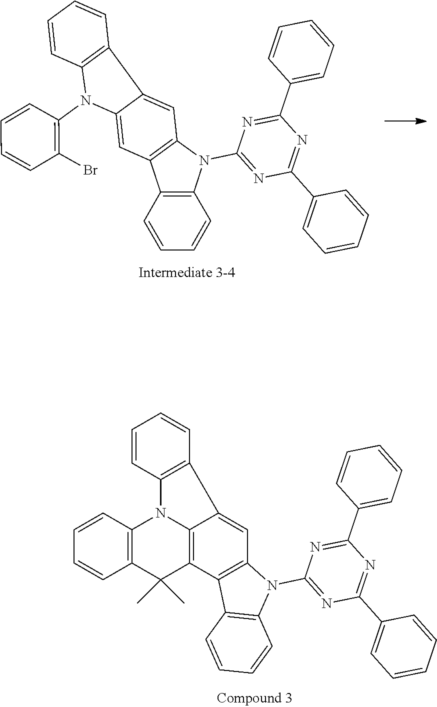 [SMILES: Brc1ccccc1-n1c2ccccc2c2cc3c(cc21)c1ccccc1n3-c1nc(-c2ccccc2)nc(-c2ccccc2)n1 ; CC1(C)c2ccccc2-n2c3ccccc3c3cc4c(c1c32)c1ccccc1n4-c1nc(-c2ccccc2)nc(-c2ccccc2)n1]

Synthesis of Intermediate 3-1

20 g (61.76 mmol) of 1,4-dibromo-2,5-dinitrobenzene, 18.83 g (154.40 mmol) of 1-phenylboronic acid, 4.32 g (3.71 mmol) of Pd(PPh₃)₄, 90.88 ml (185.28 mmol) of 2 M K₂CO₃ aqueous solution, 200 ml of toluene, and 100 ml of ethanol were mixed and refluxed while stirring. After 10 hours, the mixture was cooled to ambient temperature, and distilled water was added thereto. The mixture was subjected to extraction using EA, dried using magnesium sulfate, and distilled under reduced pressure. The resultant was purified using column chromatography to obtain 17.79 g (55.58 mmol, 90% yield) of Intermediate 3-1.

Synthesis of Intermediate 3-2

Intermediate 3-2 was prepared in the same manner as in the synthesis of Intermediate 1-6 of Synthesis Example 1, except that Intermediate 3-1 was used instead of Intermediate 1-5.

Synthesis of Intermediate 3-3

Intermediate 3-3 was prepared in the same manner as in the synthesis of Compound 1 of Synthesis Example 1, except that Intermediate 3-2 was used instead of Intermediate 1-6.

Synthesis of Intermediate 3-4

Intermediate 3-4 was prepared in the same manner as in the synthesis of Intermediate 1-1 of Synthesis Example 1, except that Intermediate 3-3 was used instead of carbazole.

Synthesis of Compound 3

Compound 3 (56% yield) was prepared in the same manner as in the synthesis of Intermediate 1-2 of Synthesis Example 1, except that Intermediate 3-4 was used instead of Intermediate 1-1.

MS: m/z 603.24 [M]⁺

¹H NMR (CDCl₃) δ 8.55 (1H), 8.28 (4H), 8.12 (1H), 7.94 (1H), 7.63 (1H), 7.51 (4H), 7.50 (1H), 7.41 (2H), 7.40 (1H), 7.37 (2H), 7.33 (1H), 7.30 (1H), 7.29 (1H), 7.26 (1H), 7.25 (1H), 1.72 (6H)

### Synthesis Example 4

### Synthesis of Compound 4

Compound 4 (60% yield) was prepared in the same manner as in Synthesis Example 1, except that 2-(4-chlorophenyl)-4,6-diphenyl-triazine was used instead of 2-chloro-4,6-diphenyl-triazine in the synthesis of Compound 1.

MS: m/z 679.27 [M]⁺

¹H NMR (CDCl₃) δ 8.55 (1H), 8.32 (1H), 8.28 (4H), 8.12 (1H), 7.94 (1H), 7.79 (2H), 7.68 (2H), 7.63 (1H), 7.51 (4H), 7.50 (1H), 7.41 (2H), 7.40 (1H), 7.37 (1H), 7.33 (1H), 7.30 (1H), 7.29 (1H), 7.26 (1H), 7.25 (1H), 1.72 (6H)

### Synthesis Example 5

### Synthesis of Compound 10

Compound 10 was synthesized via Reaction Scheme 3 below:

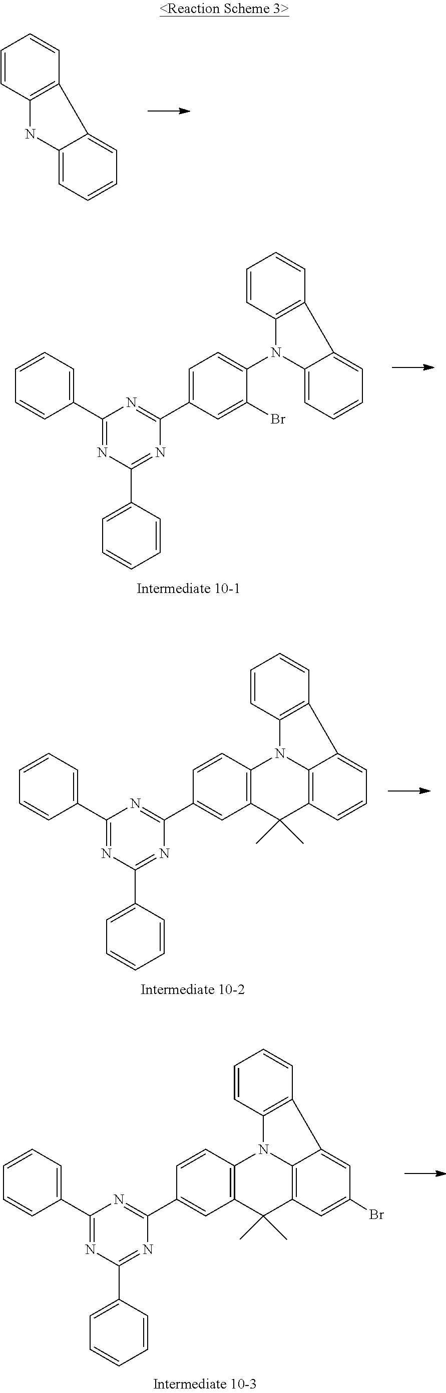 [SMILES: c1ccc2c(c1)[nH]c1ccccc12 ; Brc1cc(-c2nc(-c3ccccc3)nc(-c3ccccc3)n2)ccc1-n1c2ccccc2c2ccccc21 ; CC1(C)c2cc(-c3nc(-c4ccccc4)nc(-c4ccccc4)n3)ccc2-n2c3ccccc3c3cccc1c32 ; CC1(C)c2cc(-c3nc(-c4ccccc4)nc(-c4ccccc4)n3)ccc2-n2c3ccccc3c3cc(Br)cc1c32]

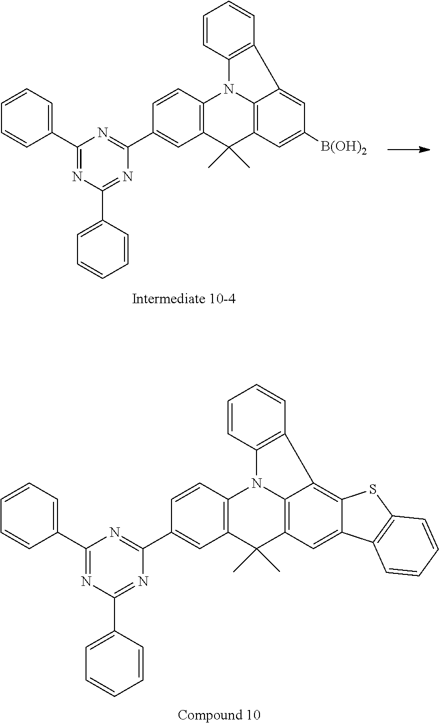 [SMILES: CC1(C)c2cc(-c3nc(-c4ccccc4)nc(-c4ccccc4)n3)ccc2-n2c3ccccc3c3cc(B(O)O)cc1c32 ; CC1(C)c2cc(-c3nc(-c4ccccc4)nc(-c4ccccc4)n3)ccc2-n2c3ccccc3c3c4sc5ccccc5c4cc1c32]

Synthesis of Intermediate 10-1

Intermediate 10-1 was prepared in the same manner as in the synthesis of Intermediate 1-1 of Synthesis Example 1, except that 2-(3-bromo-4-idophenyl)-4,6-diphenyl-1,3,5-triazine was used instead of 2-bromoidobenzene.

Synthesis of Intermediates 10-2, 10-3, and 10-4

Intermediates 10-2, 10-3, and 10-4 were sequentially prepared in the same manner as in the synthesis of Intermediates 1-2, 1-3, and 1-4 of Synthesis Example 1, except that Intermediate 10-1 was used instead of Intermediate 1-1.

Synthesis of Compound 10

Compound 10 (48% yield) was prepared in the same manner as in the synthesis of Intermediate 1-5 of Synthesis Example 1, except that Intermediate 10-4 was used instead of Intermediate 1-4, and 2-bromobenzenethiol was used instead of bromo-2-nitrobenzene.

MS: m/z 620.20 [M]⁺

¹H NMR (CDCl₃) δ 8.45 (1H), 8.28 (4H), 8.12 (1H), 7.98 (1H), 7.86 (1H), 7.68 (1H), 7.63 (1H), 7.61 (1H), 7.60 (1H), 7.52 (1H), 7.51 (4H), 7.50 (2H), 7.41 (2H), 7.29 (1H), 1.72 (6H)

### Synthesis Example 6

### Synthesis of Compound 11

Compound 11 (50% yield) was prepared in the same manner as in Synthesis Example 10, except that 2-bromophenol was used instead of 2-bromobenzenethiol in the synthesis of Compound 10.

MS: m/z 604.23 [M]⁺

¹H NMR (CDCl₃) δ 8.28 (4H), 8.12 (1H), 7.89 (1H), 7.86 (1H), 7.66 (1H), 7.63 (1H), 7.61 (1H), 7.60 (1H), 7.51 (4H), 7.50 (1H), 7.41 (2H), 7.38 (1H), 7.36 (1H), 7.32 (1H), 7.29 (1H), 1.72 (6H)

### Synthesis Example 7

### Synthesis of Compound 14

Compound 14 was synthesized via Reaction Scheme 4 below:

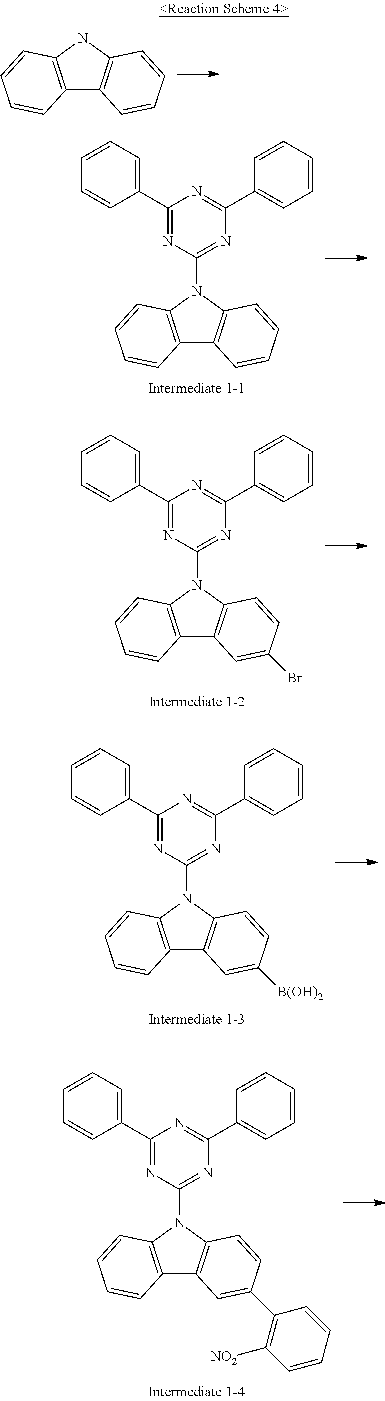

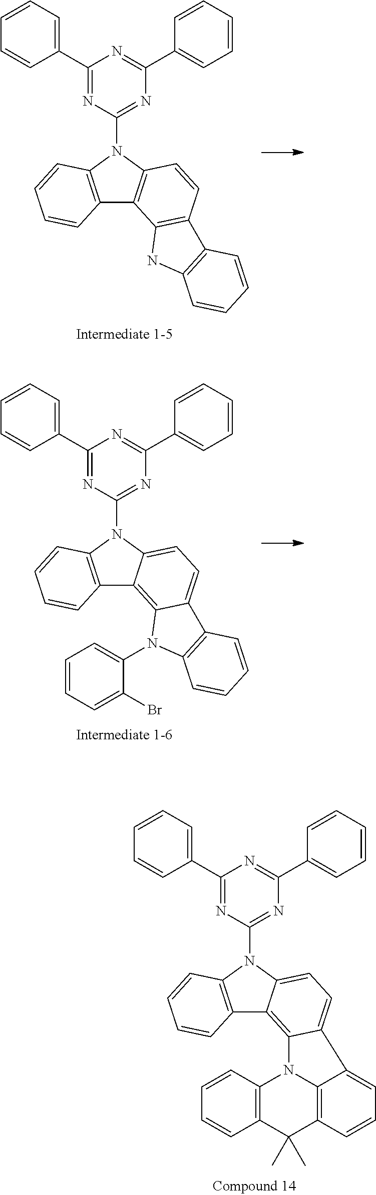 [SMILES: c1ccc(-c2nc(-c3ccccc3)nc(-n3c4ccccc4c4c5[nH]c6ccccc6c5ccc43)n2)cc1 ; Brc1ccccc1-n1c2ccccc2c2ccc3c(c4ccccc4n3-c3nc(-c4ccccc4)nc(-c4ccccc4)n3)c21 ; CC1(C)c2ccccc2-n2c3c1cccc3c1ccc3c(c4ccccc4n3-c3nc(-c4ccccc4)nc(-c4ccccc4)n3)c12]

Synthesis of Intermediate 1-1

20 g (119.61 mmol) of carbazole was dissolved in 100 ml of DMF, and the solution was added to a reactor in which 7.07 g (179.42 mmol, 60% dispersion in mineral oil) of NaH was dissolved in 100 ml of DMF. After one hour, 38.42 g (143.53 mmol) of 2-chloro-4,6-diphenyltriazine dissolved in 100 ml of DMF was added thereto. The mixture was stirred for 12 hours, and then distilled water was added thereto to obtain a solid. The solid was filtered under reduced pressure and recrystallized using EA and DMF to obtain 25.74 g (64.59 mmol, 54% yield) of Intermediate 1-1.

Synthesis of Intermediate 1-2

20 g (50.19 mmol) of Intermediate 1-1 was dissolved in 200 ml of DMF, and then 9.83 g (55.21 mmol) of N-bromosuccinimide (NBS) was added thereto. After the mixture was stirred at ambient temperature for 10 hours, the organic solvent was distilled under reduced pressure, and distilled water was added thereto. Then, the resultant was subjected to extraction using ethyl acetate (EA). The resultant was dried using magnesium sulfate, distilled under reduced pressure, and purified using column chromatography to obtain 22.04 g (41.90 mmol, 92% yield) of Intermediate 1-2.

Synthesis of Intermediate 1-3

20 g (41.90 mmol) of Intermediate 1-2 was dissolved in 200 ml of THF, and 16.76 ml (41.90 mmol, 2.5 M in hexane) of n-buLi was slowly added thereto at −78° C. After stirring for 1 hour, 6.07 ml (54.47 mmol) of trimethyl borate was added thereto, and the mixture was heated to ambient temperature and stirred for 12 hours. Distilled water was added thereto, and the mixture was subjected to extraction using EA, dried using magnesium sulfate, and distilled under reduced pressure. The resultant was purified using column chromatography to obtain 7.41 g (16.67 mmol, 40% yield) of Intermediate 1-3.

Synthesis of Intermediate 1-4

10 g (22.61 mmol) of Intermediate 1-3, 5.48 g (27.13 mmol) of bromo-2-nitrobenzene, 0.79 g (0.68 mmol) of tetrakis(triphenylphosphine)palladium(0) (Pd(PPh₃)₄), 22.18 ml (45.22 mmol) of 2 M K₂CO₃ aqueous solution, 80 ml of toluene, and 30 ml of ethanol were refluxed while stirring. After 4 hours, the mixture was cooled to ambient temperature, and distilled water was added thereto. The mixture was subjected to extraction using EA, dried using magnesium sulfate, and distilled under reduced pressure. The resultant was purified using column chromatography to obtain 8.69 g (16.73 mmol, 74% yield) of Intermediate 1-4.

Synthesis of Intermediate 1-5

10 g (19.25 mmol) of Intermediate 1-4 was mixed with 100 ml of triethylphosphite, and the mixture was stirred at 180° C. After 10 hours, the mixture was cooled to ambient temperature, and the organic solvent was distilled under reduced pressure. Distilled water was added thereto, and the mixture was subjected to extraction using EA, dried using magnesium sulfate, and distilled under reduced pressure. The resultant was purified using column chromatography to obtain 5.62 g (11.55 mmol, 60% yield) of Intermediate 1-5.

Synthesis of Intermediate 1-6

10 g (20.55 mmol) of Intermediate 1-5, 11.63 g (41.11 mmol) of 2-bromoiodobenzene, 1.96 g (10.28 mmol) of copper iodide, and 5.68 g (41.11 mmol) of potassium carbonate were dissolved in xylene under a nitrogen atmosphere, and the mixture was refluxed while stirring. After 12 hours, the mixture was cooled to ambient temperature, distilled water was added thereto, and the mixture was subjected to extraction using methylene chloride (MC), dried using magnesium sulfate, and distilled under reduced pressure. The resultant was purified using column chromatography to obtain 5.55 g (8.63 mmol, 42% yield) of Intermediate 1-6.

Synthesis of Compound 14

10 g (15.56 mmol) of Intermediate 1-6 was dissolved in 100 ml of THF, and 6.22 ml (15.56 mmol, 2.5 M in hexane) of n-buLi was slowly added thereto at −78° C. After stirring for 2 hour, 1.20 ml (20.23 mmol) of acetone was added thereto, and the mixture was slowly heated to ambient temperature. Then, a NaHCO₃ aqueous solution was added thereto, and the mixture was subjected to extraction using MC. The resultant was dried using magnesium sulfate, distilled under reduced pressure, and added to a separate two-neck flask to be mixed with 100 ml of acetic acid. An HCl aqueous solution having the same amount as the catalyst (5 mol %, 12 N) was added thereto, and the mixture was refluxed while stirring. After 12 hours, the mixture was cooled to ambient temperature, and distilled water was added thereto. The mixture was subjected to extraction using MC, dried using magnesium sulfate, and distilled under reduced pressure. The resultant was purified using column chromatography to obtain 5.45 g (9.03 mmol, 58% yield) of Compound 14.

MS: m/z 603.24 [M]⁺

¹H NMR (CDCl₃) δ 7.55 (2H), 7.48 (4H), 7.40 (1H), 7.37 (1H), 7.32 (4H), 7.22 (2H), 7.20 (2H), 7.10 (2H), 7.08 (1H), 7.00 (2H), 6.95 (1H), 6.92 (1H), 1.67 (6H)

### Synthesis Example 8

### Synthesis of Compound 15

10 g (15.56 mmol) of Intermediate 1-6 prepared in the same manner as in Synthesis Example 7 was mixed with 100 ml of THF, and 6.22 ml (15.56 mmol, 2.5 M in hexane) of n-buLi was slowly added thereto at −78° C. After stirring for 2 hour, a solution in which 3.69 g (20.23 mmol) of benzophenone dissolved in 50 ml of THF was added thereto, and the mixture was slowly heated to ambient temperature. Then, a NaHCO₃ aqueous solution was added thereto, and the mixture was subjected to extraction using MC. The resultant was dried using magnesium sulfate, distilled under reduced pressure, and added to a separate two-neck flask to be mixed with 100 ml of acetic acid. An HCl aqueous solution having the same amount as the catalyst (5 mol %, 12 N) was added thereto, and the mixture was refluxed while stirring. After 12 hours, the mixture was cooled to ambient temperature, and distilled water was added thereto. The mixture was subjected to extraction using MC, dried using magnesium sulfate, and distilled under reduced pressure. The resultant was purified using column chromatography to obtain 6.12 g (8.40 mmol, 54% yield) of Compound 15.

MS: m/z 727.27 [M]⁺

¹H NMR (CDCl₃) δ 7.55 (2H), 7.48 (4H), 7.40 (1H), 7.36 (1H), 7.32 (4H), 7.22 (2H), 7.14 (4H), 7.10 (4H), 7.08 (1H), 7.07 (2H), 7.06 (4H), 7.00 (2H), 6.88 (2H)

### Synthesis Example 9

### Synthesis of Compound 16

Compound 16 was synthesized via Reaction Scheme 5 below:

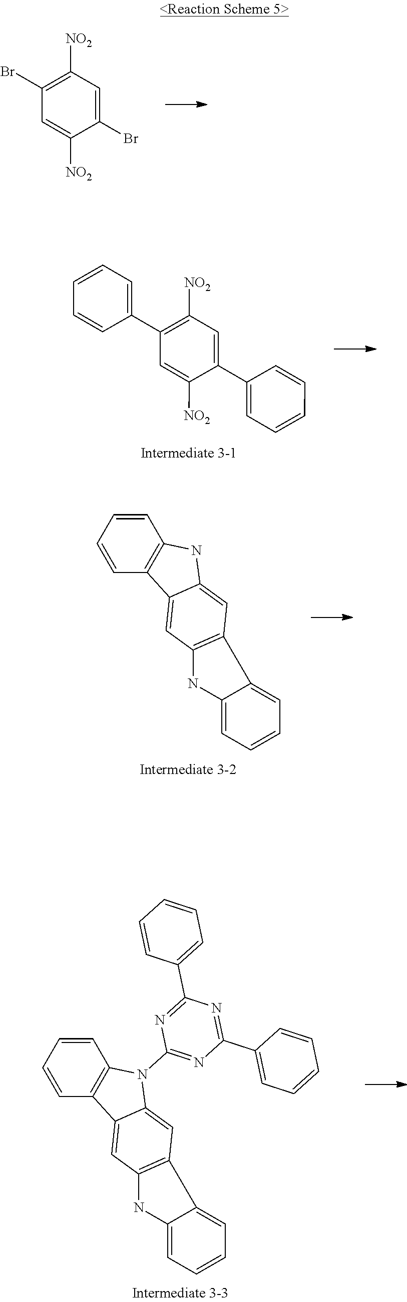 [SMILES: O=[N+]([O-])c1cc(Br)c([N+](=O)[O-])cc1Br ; O=[N+]([O-])c1cc(-c2ccccc2)c([N+](=O)[O-])cc1-c1ccccc1 ; c1ccc2c(c1)[nH]c1cc3c(cc12)[nH]c1ccccc13 ; c1ccc(-c2nc(-c3ccccc3)nc(-n3c4ccccc4c4cc5[nH]c6ccccc6c5cc43)n2)cc1]

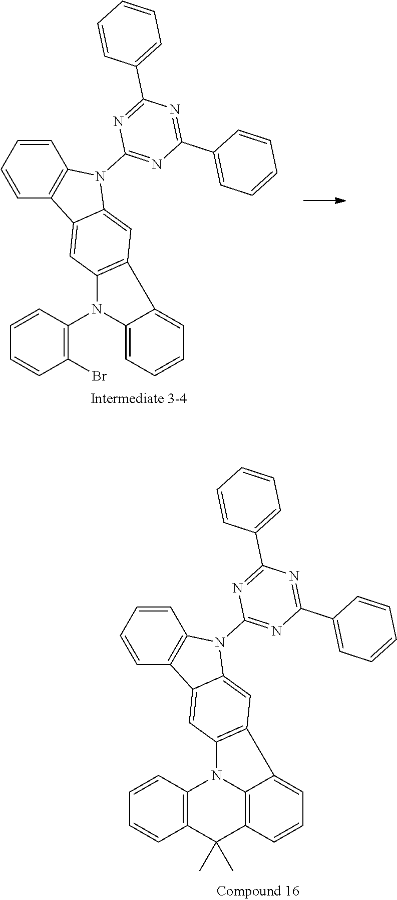 [SMILES: Brc1ccccc1-n1c2ccccc2c2cc3c(cc21)c1ccccc1n3-c1nc(-c2ccccc2)nc(-c2ccccc2)n1 ; CC1(C)c2ccccc2-n2c3cc4c5ccccc5n(-c5nc(-c6ccccc6)nc(-c6ccccc6)n5)c4cc3c3cccc1c32]

Synthesis of Intermediate 3-1

20 g (61.36 mmol) of 1,4-dibromo-2,5-dinitrobenzene, 18.7 g (153.40 mmol) of 1-phenylboronic acid, 4.30 g (3.68 mmol) of Pd(PPh₃)₄, 90.29 ml (184.08 mmol) of 2 M K₂CO₃ aqueous solution, 200 ml of toluene, and 100 ml of ethanol were mixed and refluxed while stirring. After 10 hours, the mixture was cooled to ambient temperature, and distilled water was added thereto. The mixture was subjected to extraction using EA, dried using magnesium sulfate, and distilled under reduced pressure. The resultant was purified using column chromatography to obtain 16.99 g (53.38 mmol, 87% yield) of Intermediate 3-2.

Synthesis of Intermediate 3-2

9.27 g (36.44 mmol, 58% yield) of Intermediate 3-2 was prepared in the same manner as in the synthesis of Intermediate 1-5 of Synthesis Example 7, except that 20 g (62.83 mmol) of Intermediate 3-1 and 200 ml of triethylphosphite were used instead of 10 g of Intermediate 1-4 and 100 ml of triethylphosphite.

Synthesis of Intermediate 3-3

20 g (78.65 mmol) of Intermediate 3-2 was dissolved in 100 ml of DMF, and the solution was added to a reactor in which 4.65 g (117.98 mmol, 60% dispersion in mineral oil) of NaH was dissolved in 100 ml of DMF. After one hour, 37.90 g (141.57 mmol) of 2-chloro-4,6-diphenyltriazine dissolved in 100 ml of DMF was added thereto. The mixture was stirred for 12 hours, and then distilled water was added thereto to obtain a solid. The solid was filtered under reduced pressure and recrystallized using EA and DMF to obtain 10.71 g (22.02 mmol, 28% yield) of Intermediate 3-3.

Synthesis of Intermediate 3-4

5.28 g (8.22 mmol, 40% yield) of Intermediate 3-4 was prepared in the same manner as in the synthesis of Intermediate 1-4 of Synthesis Example 7, except that Intermediate 3-3 was used instead of Intermediate 1-5 of Synthesis Example 7.

Synthesis of Compound 16

5.07 g (8.40 mmol, 54% yield) of Compound 16 was prepared in the same manner as in the synthesis of Compound 14 of Synthesis Example 7, except that Intermediate 3-4 was used instead of Intermediate 1-6 of Synthesis Example 7.

MS: m/z 603.24 [M]⁺

¹H NMR (CDCl₃) δ 7.55 (2H), 7.48 (4H), 7.40 (2H), 7.37 (1H), 7.32 (4H), 7.22 (2H), 7.20 (2H), 7.10 (2H), 7.08 (1H), 7.00 (1H), 6.95 (1H), 6.92 (1H), 1.67 (6H)

### Synthesis Example 10

### Synthesis of Compound 17

Compound 17 was synthesized via Reaction Scheme 6 below:

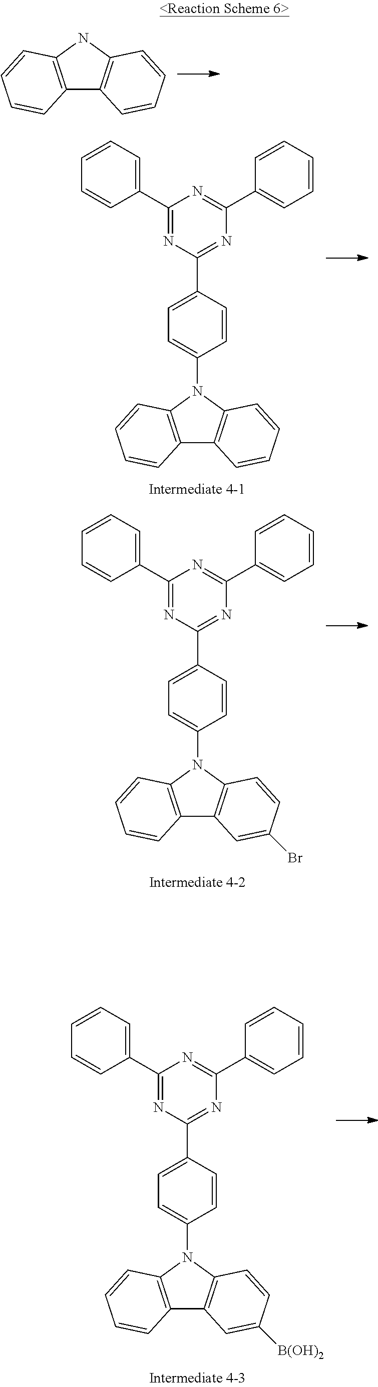

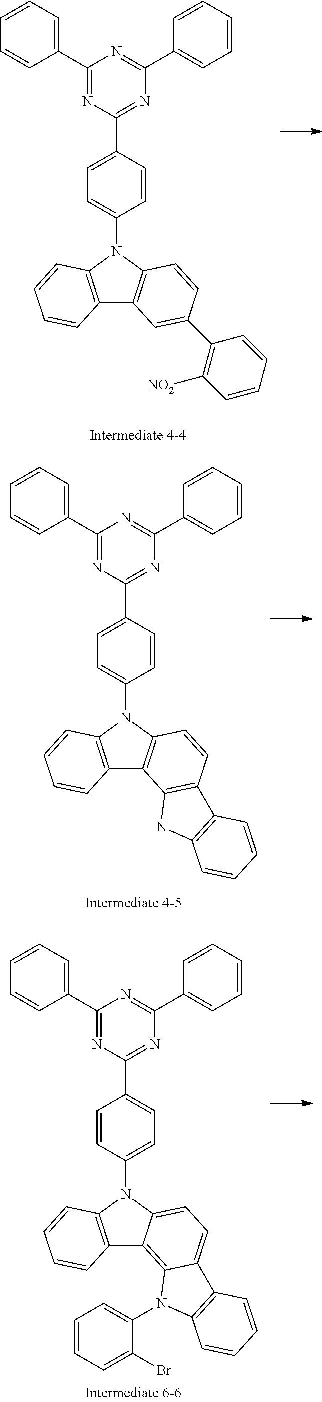 [SMILES: O=[N+]([O-])c1ccccc1-c1ccc2c(c1)c1ccccc1n2-c1ccc(-c2nc(-c3ccccc3)nc(-c3ccccc3)n2)cc1 ; c1ccc(-c2nc(-c3ccccc3)nc(-c3ccc(-n4c5ccccc5c5c6[nH]c7ccccc7c6ccc54)cc3)n2)cc1 ; Brc1ccccc1-n1c2ccccc2c2ccc3c(c4ccccc4n3-c3ccc(-c4nc(-c5ccccc5)nc(-c5ccccc5)n4)cc3)c21]

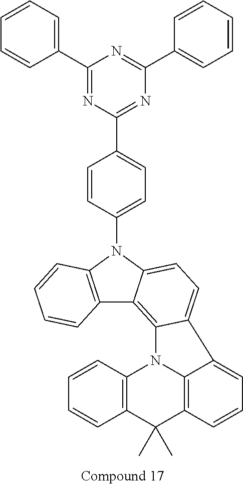 [SMILES: CC1(C)c2ccccc2-n2c3c1cccc3c1ccc3c(c4ccccc4n3-c3ccc(-c4nc(-c5ccccc5)nc(-c5ccccc5)n4)cc3)c12]

Synthesis of Intermediate 4-1

31.79 g (66.98 mmol, 56% yield) of Intermediate 4-1 was prepared in the same manner as in the synthesis of Intermediate 1-1 of Synthesis Example 7, except that 49.35 g (143.53 mmol) of 2-(4-chlorophenyl)-4,6-diphenyltriazine was used instead of 2-chloro-4,6-diphenyltriazine.

Synthesis of Intermediate 4-2

20.99 g (37.93 mmol, 90% yield) of Intermediate 4-2 was prepared in the same manner as in the synthesis of Intermediate 1-2 of Synthesis Example 7, except that 20 g (42.14 mmol) of Intermediate 4-1 was used instead of Intermediate 1-1 of Synthesis Example 7, and an amount of NBS was changed to 9.00 g (50.57 mmol).

Synthesis of Intermediate 4-3

20 g (36.14 mmol) of Intermediate 4-2 was dissolved in 200 ml of THF, and 14.45 ml (41.90 mmol, 2.5 M in hexane) of n-buLi was slowly added thereto at −78° C. After stirring for 1 hour, 5.23 ml (46.98 mmol) of trimethylborate was added thereto, and the mixture was slowly heated to ambient temperature and stirred for 12 hours. Distilled water was added thereto, and the mixture was subjected to extraction using EA, dried using magnesium sulfate, and distilled under reduced pressure. The resultant was purified using column chromatography to obtain 7.49 g (14.45 mmol, 40% yield) of Intermediate 4-3.

Synthesis of Intermediate 4-4

10 g (19.29 mmol) of Intermediate 4-3, 4.67 g (23.15 mmol) of bromo-2-nitrobenzene, 0.68 g (0.58 mmol) of (Pd(PPh₃)₄), 18.92 ml (38.58 mmol) of 2 M K₂CO₃ aqueous solution, 80 ml of toluene, and 30 ml of ethanol were refluxed while stirring. After 4 hours, the mixture was cooled to ambient temperature, and distilled water was added thereto. The mixture was subjected to extraction using EA, dried using magnesium sulfate, and distilled under reduced pressure. The resultant was purified using column chromatography to obtain 8.27 g (13.89 mmol, 72% yield) of Intermediate 4-4.

Synthesis of Intermediate 4-5

5.67 g (10.07 mmol, 60% yield) of Intermediate 4-5 was prepared in the same manner as in the synthesis of Intermediate 1-5 of Synthesis Example 7, except that 10 g (16.79 mmol) of Intermediate 4-4 was used instead of Intermediate 1-4 of Synthesis Example 7.

Synthesis of Intermediate 4-6

10 g (17.77 mmol) of Intermediate 4-5, 10.06 g (35.55 mmol) of 2-bromoiodobenzene, 1.69 g (8.89 mmol) of copper iodide, and 4.91 g (35.55 mmol) of potassium carbonate were dissolved in xylene under a nitrogen atmosphere, and the mixture was refluxed while stirring. After 12 hours, the mixture was cooled to ambient temperature, distilled water was added thereto, and the mixture was subjected to extraction using methylene chloride (MC), dried using magnesium sulfate, and distilled under reduced pressure. The resultant was purified using column chromatography to obtain 11 g (7.11 mmol, 40% yield) of Intermediate 4-6.

Synthesis of Compound 17

10 g (13.91 mmol) of Intermediate 4-6 was dissolved in 100 ml of THF, and 5.56 ml (13.91 mmol, 2.5 M in hexane) of n-buLi was slowly added thereto at −78° C. After stirring for 2 hours, 1.05 ml (18.09 mmol) of acetone was added thereto, and the mixture was slowly heated to ambient temperature. Then, a NaHCO₃ aqueous solution was added thereto, and the mixture was subjected to extraction using MC. The resultant was dried using magnesium sulfate, distilled under reduced pressure, and added to a separate two-neck flask to be mixed with 100 ml of acetic acid. An HCl aqueous solution having the same amount as the catalyst (5 mol %, 12 N) was added thereto, and the mixture was refluxed while stirring. After 12 hours, the mixture was cooled to ambient temperature, and distilled water was added thereto. The mixture was subjected to extraction using MC, dried using magnesium sulfate, and distilled under reduced pressure. The resultant was purified using column chromatography to obtain 5.68 g (8.35 mmol, 60% yield) of Compound 17.

MS: m/z 679.27 [M]⁺

¹H NMR (CDCl₃) δ 7.55 (2H), 7.50 (2H), 7.48 (4H), 7.40 (1H), 7.37 (1H), 7.32 (4H), 7.30 (2H), 7.22 (2H), 7.20 (2H), 7.10 (2H), 7.08 (1H), 7.00 (2H), 6.95 (1H), 6.92 (1H), 1.67 (6H)

### Synthesis Example 11

### Synthesis of Compound 23

Compound 23 was synthesized via Reaction Scheme 7 below:

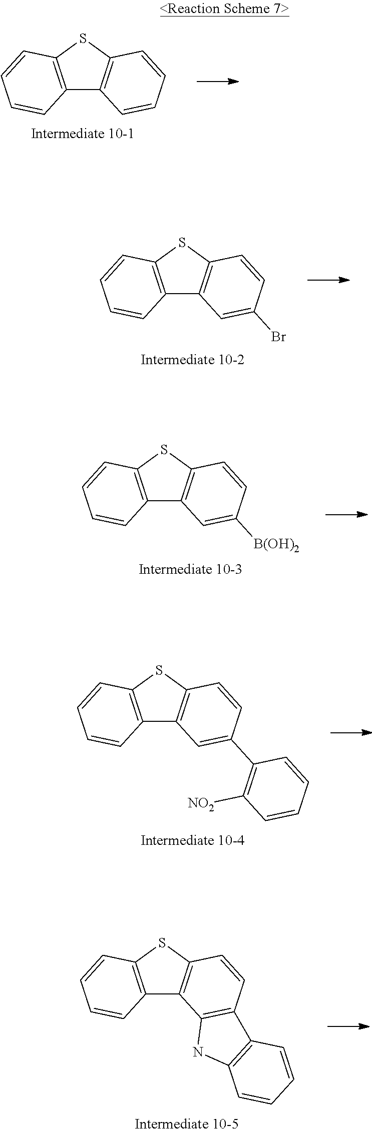 [SMILES: c1ccc2c(c1)sc1ccccc12 ; Brc1ccc2sc3ccccc3c2c1 ; OB(O)c1ccc2sc3ccccc3c2c1 ; O=[N+]([O-])c1ccccc1-c1ccc2sc3ccccc3c2c1 ; c1ccc2c(c1)[nH]c1c2ccc2sc3ccccc3c21]

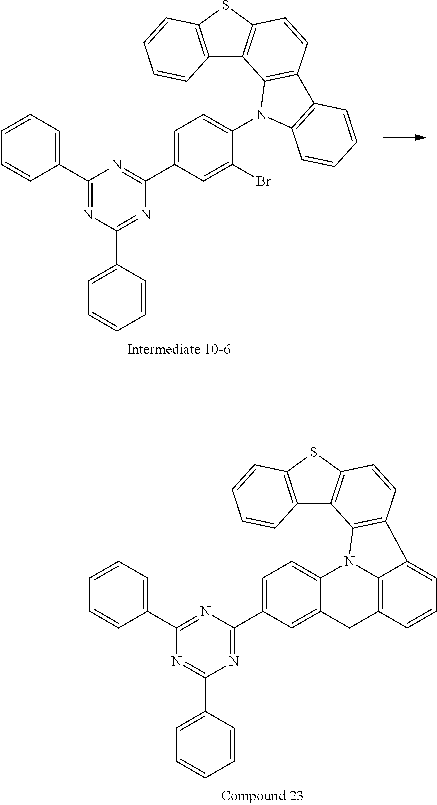 [SMILES: Brc1cc(-c2nc(-c3ccccc3)nc(-c3ccccc3)n2)ccc1-n1c2ccccc2c2ccc3sc4ccccc4c3c21 ; c1ccc(-c2nc(-c3ccccc3)nc(-c3ccc4c(c3)Cc3cccc5c6ccc7sc8ccccc8c7c6n-4c35)n2)cc1]

Synthesis of Intermediate 10-2

Intermediate 10-2 was prepared in the same manner as in the synthesis of Intermediate 1-2 of Synthesis Example 7, except that Intermediate 10-1 was used instead of Interemediate 1-1 of Synthesis Example 7.

Synthesis of Intermediate 10-3

Intermediate 10-3 was prepared in the same manner as in the synthesis of Intermediate 1-3 of Synthesis Example 7, except that Intermediate 10-2 was used instead of Interemediate 1-2 of Synthesis Example 7.

Synthesis of Intermediate 10-4

Intermediate 10-4 was prepared in the same manner as in the synthesis of Intermediate 1-4 of Synthesis Example 7, except that Intermediate 10-3 was used instead of Interemediate 1-3 of Synthesis Example 7.

Synthesis of Intermediate 10-5

Intermediate 10-5 was prepared in the same manner as in the synthesis of Intermediate 1-5 of Synthesis Example 7, except that Intermediate 10-4 was used instead of Interemediate 1-4 of Synthesis Example 7.

Synthesis of Intermediate 10-6

Intermediate 10-6 was prepared in the same manner as in the synthesis of Intermediate 1-6 of Synthesis Example 7, except that Intermediate 10-5 was used instead of Intermediate 1-5 of Synthesis Example 7, and 2-(4-bromo-3-iodo-phenyl)-4,6-diophenyl-triazine was used instead of 2-bromoiodobenzene.

Synthesis of Compound 23

Compound 23 (52% yield) was prepared in the same manner as in the synthesis of Compound 14 of Synthesis Example 7, except that Intermediate 10-6 was used instead of Intermediate 1-6 of Synthesis Example 7.

MS: m/z 620.20 [M]⁺

¹H NMR (CDCl₃) δ 7.86 (2H), 7.78 (1H), 7.48 (4H), 7.37 (1H), 7.33 (1H), 7.32 (4H), 7.30 (2H), 7.22 (2H), 7.20 (1H), 6.95 (1H), 6.92 (1H), 1.67 (6H)

### Synthesis Example 12

### Synthesis of Compound 24

Compound 24 (54% yield) was prepared in the same manner as in the synthesis of Synthesis Example 11, except that Intermediate 11-1 was used instead of Intermediate 10-1 of Synthesis Example 7.

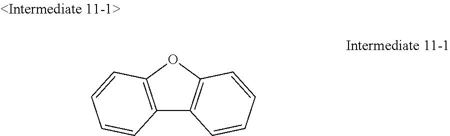 [SMILES: c1ccc2c(c1)oc1ccccc12]

MS: m/z 604.23 [M]⁺

¹H NMR (CDCl₃) δ 7.49 (1H), 7.48 (4H), 7.42 (2H), 7.37 (1H), 7.32 (4H), 7.30 (2H), 7.22 (2H), 7.20 (1H), 7.19 (2H), 7.13 (1H), 6.95 (1H), 6.92 (1H), 1.67 (6H)

### Synthesis Example 13

### Synthesis of Compound 27

Compound 27 was synthesized via Reaction Scheme 13 below:

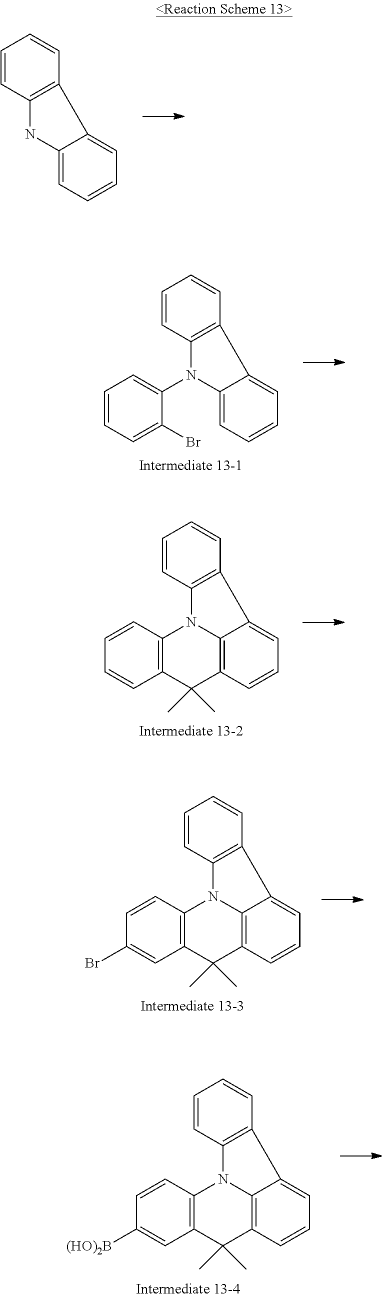 [SMILES: c1ccc2c(c1)[nH]c1ccccc12 ; Brc1ccccc1-n1c2ccccc2c2ccccc21 ; CC1(C)c2ccccc2-n2c3ccccc3c3cccc1c32 ; CC1(C)c2cc(Br)ccc2-n2c3ccccc3c3cccc1c32 ; CC1(C)c2cc(B(O)O)ccc2-n2c3ccccc3c3cccc1c32]

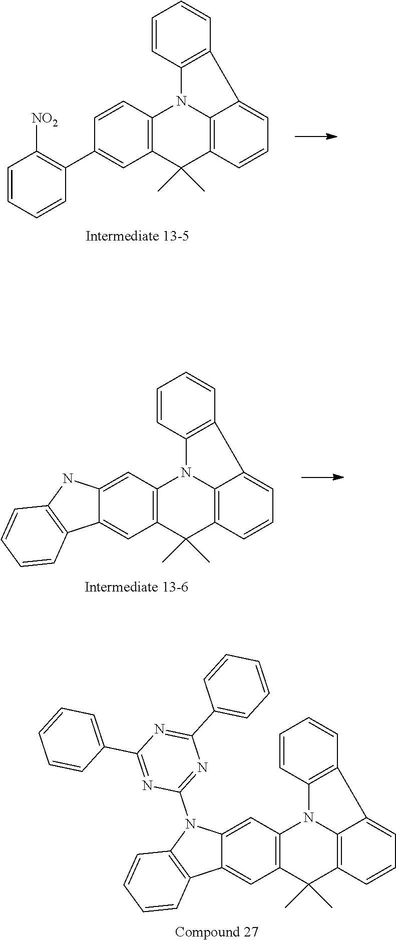 [SMILES: CC1(C)c2cc(-c3ccccc3[N+](=O)[O-])ccc2-n2c3ccccc3c3cccc1c32 ; CC1(C)c2cc3c(cc2-n2c4ccccc4c4cccc1c42)[nH]c1ccccc13 ; CC1(C)c2cc3c4ccccc4n(-c4nc(-c5ccccc5)nc(-c5ccccc5)n4)c3cc2-n2c3ccccc3c3cccc1c32]

Synthesis of Intermediate 13-2

Intermediate 13-2 was prepared in the same manner as in the synthesis of Intermediate 1-2 of Synthesis Example 1, except that Intermediate 13-1 was used instead of Intermediate 1-1 of Synthesis Example 1.

Synthesis of Intermediate 13-3

Intermediate 13-3 was prepared in the same manner as in the synthesis of Intermediate 1-3 of Synthesis Example 1, except that Intermediate 13-2 was used instead of Intermediate 1-2 of Synthesis Example 1.

Synthesis of Intermediate 13-4

Intermediate 13-4 was prepared in the same manner as in the synthesis of Intermediate 1-4 of Synthesis Example 1, except that Intermediate 13-3 was used instead of Intermediate 1-3 of Synthesis Example 1.

Synthesis of Intermediate 13-5

Intermediate 13-5 was prepared in the same manner as in the synthesis of Intermediate 1-4 of Synthesis Example 1, except that Intermediate 13-4 was used instead of Intermediate 1-4 of Synthesis Example 1.

Synthesis of Intermediate 13-6

Intermediate 13-6 was prepared in the same manner as in the synthesis of Intermediate 1-6 of Synthesis Example 1, except that Intermediate 13-5 was used instead of Intermediate 1-5 of Synthesis Example 1.

Synthesis of Compound 27

Compound 27 (48% yield) was prepared in the same manner as in the synthesis of Compound 1 of Synthesis Example 1, except that Intermediate 13-6 was used instead of Intermediate 1-6 of Synthesis Example 1.

MS: m/z 603.24 [M]⁺

¹H NMR (CDCl₃) δ 8.96 (1H), 8.45 (1H), 8.36 (4H), 8.19 (2H), 7.58 (2H), 7.51 (1H), 7.50 (8H), 7.24 (1H), 7.20 (2H), 6.98 (1H), 1.69 (6H)

### Synthesis Example 14

### Synthesis of Compound 101

Compound 101 was synthesized via Reaction Scheme 14 below:

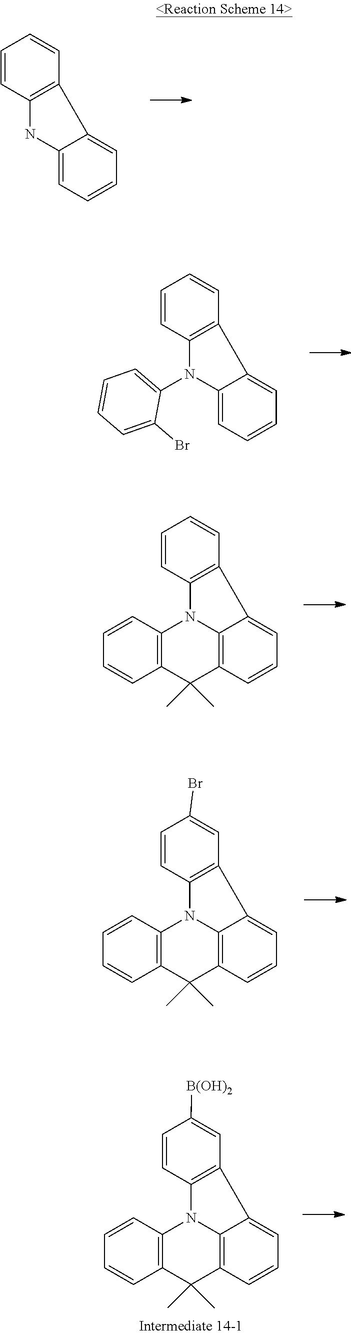 [SMILES: c1ccc2c(c1)[nH]c1ccccc12 ; Brc1ccccc1-n1c2ccccc2c2ccccc21 ; CC1(C)c2ccccc2-n2c3ccccc3c3cccc1c32 ; CC1(C)c2ccccc2-n2c3ccc(Br)cc3c3cccc1c32 ; CC1(C)c2ccccc2-n2c3ccc(B(O)O)cc3c3cccc1c32]

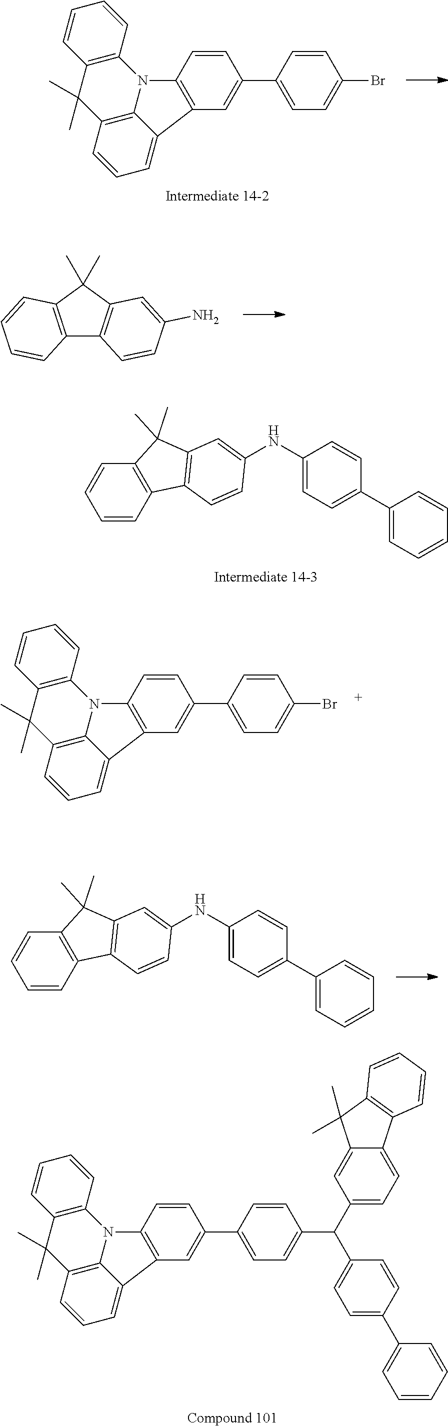

Synthesis of Intermediate 14-1

Intermediate 14-1 (55% yield) was prepared in the same manner as in the synthesis of Intermediate 1-4.

Synthesis of Intermediate 14-2

1 eq. of Intermediate 14-1 prepared in the synthesis above was dissolved in THF, 1.1 eq. of l-bromo-4-iodobenzene, 0.03 eq. of Pd(PPh₃)₄, 3 eq. of NaOH, and water were added thereto, and the mixture was refluxed while stirring. When the reaction was completed, the mixture was subjected to extraction using ether and water. A supernatant obtained therefrom was dired using MgSO₄ and concentrated. Then, an organic material thus obtained was purified through a silica gel column and then recrystallized to obtain Intermediate 14-2 (52% yield).

Synthesis of Intermediate 14-3

1 eq. of 9,9-dimethyl-9H-fluorene-2-amine, 1.1 eq. of 4-bromo-1,1′-biphenyl, 0.05 eq. of Pd₂(dba)₃, 0.1 eq. of P(t-Bu)₃, 3 eq. of NaOt-Bu, and 10.5 mL of toluene were added to a round-bottom flask, and the mixture was allowed to react at a temperature of 100° C. When the reaction was completed, the mixture was subjected to extraction using ether and water. A supernatant obtained therefrom was dired using MgSO₄ and concentrated. Then, an organic material thus obtained was purified through a silica gel column and then recrystallized to obtain Intermediate 14-3 (67% yield).

Synthesis of Compound 101

10.5 g (24 mmol) of Intermediate 14-2, 7.2 g (20 mmol) of Intermediate 14-3, 0.92 g (1.2 mmol) of Pd₂(dba)₃, 0.4 g (2 mmol) of P(t-Bu)₃, 5.8 g (60 mmol) of NaOt-Bu, and 210 mL of toluene were added to a round-bottom flask, and the mixture was allowed to react at a temperature of 100° C. When the reaction was completed, the mixture was subjected to extraction using ether and water. A supernatant obtained therefrom was dired using MgSO₄ and concentrated. Then, an organic material thus obtained was purified through a silica gel column and then recrystallized to obtain 14.6 g of Compound 101 (85% yield).

MS: m/z 718.33 [M]⁺

¹H NMR (CDCl₃) δ 8.45 (1H), 7.99 (1H), 7.90 (1H), 7.89 (1H), 7.86 (1H), 7.77 (1H), 7.75 (2H), 7.76 (1H), 7.55 (5H), 7.49 (2H), 7.41 (1H), 7.38 (1H), 7.37 (4H), 7.33 (1H), 7.32 (1H), 7.28 (1H), 7.26 (1H), 7.25 (1H), 7.24 (1H), 7.16 (1H), 6.98 (1H), 1.69 (12H)

### Example 1

A indium tin oxide (ITO) glass substrate (available from Corning) having a sheet resistance and a thickness of 15 Ω/cm² and 1,200 Å was cut to a size of 50 mm×50 mm×0.5 mm, sonicated in isopropyl alcohol and pure water for 10 minutes each, and then cleaned with UV and ozone for 30 minutes. The ITO glass substrate was then mounted on a vacuum depositor.

2-TNATA was deposited on the ITO glass substrate to form a hole injection layer having a thickness of 600 Å, NPB was deposited on the hole injection layer to form a hole transport layer having a thickness of 200 Å, and then Compound 1 and Compound 101 (a host, including Compound 1 and Compound 101 at a weight ratio of 1:1) and PD1 (8 wt %) (a dopant) were co-deposited on the hole transport layer to form an emission layer having a thickness of 300 Å.

ET1 was deposited on the emission layer to form an electron transport layer having a thickness of 200 Å, ET-D1 was deposited on the electron transport layer to form an electron injection layer having a thickness of 10 Å, and Al was deposited on the electrode injection layer to form a cathode having a thickness of 1,000 Å, thereby completing the manufacture of an organic light-emitting device.

### Example 2

An organic light-emitting device was manufactured in the same manner as in Example 1, except that Compound 2 and Compound 101 were used as a host instead of Compound 1 and Compound 101 in the formation of the emission layer.

### Example 3

An organic light-emitting device was manufactured in the same manner as in Example 1, except that Compound 3 and Compound 101 were used as a host instead of Compound 1 and Compound 101 in the formation of the emission layer.

### Example 4

An organic light-emitting device was manufactured in the same manner as in Example 1, except that Compound 4 and Compound 101 were used as a host instead of Compound 1 and Compound 101 in the formation of the emission layer.

### Example 5

An organic light-emitting device was manufactured in the same manner as in Example 1, except that Compound 10 and Compound 101 were used as a host instead of Compound 1 and Compound 101 in the formation of the emission layer.

### Example 6

An organic light-emitting device was manufactured in the same manner as in Example 1, except that Compound 11 and Compound 101 were used as a host instead of Compound 1 and Compound 101 in the formation of the emission layer.

### Example 7

An organic light-emitting device was manufactured in the same manner as in Example 1, except that Compound 14 and Compound 101 were used as a host instead of Compound 1 and Compound 101 in the formation of the emission layer.

### Example 8

An organic light-emitting device was manufactured in the same manner as in Example 1, except that Compound 15 and Compound 101 were used as a host instead of Compound 1 and Compound 101 in the formation of the emission layer.

### Example 9

An organic light-emitting device was manufactured in the same manner as in Example 1, except that Compound 16 and Compound 101 were used as a host instead of Compound 1 and Compound 101 in the formation of the emission layer.

### Example 10

An organic light-emitting device was manufactured in the same manner as in Example 1, except that Compound 17 and Compound 101 were used as a host instead of Compound 1 and Compound 101 in the formation of the emission layer.

### Example 11

An organic light-emitting device was manufactured in the same manner as in Example 1, except that Compound 23 and Compound 101 were used as a host instead of Compound 1 and Compound 101 in the formation of the emission layer.

### Example 12

An organic light-emitting device was manufactured in the same manner as in Example 1, except that Compound 24 and Compound 101 were used as a host instead of Compound 1 and Compound 101 in the formation of the emission layer.

### Example 13

An organic light-emitting device was manufactured in the same manner as in Example 1, except that Compound 27 and Compound 101 were used as a host instead of Compound 1 and Compound 101 in the formation of the emission layer.

### Comparative Example 1

An organic light-emitting device was manufactured in the same manner as in Example 1, except that CPB was used as a host instead of Compound 1 and Compound 101 in the formation of the emission layer.

### Comparative Example 2

An organic light-emitting device was manufactured in the same manner as in Example 1, except that CPB and Compound 1 were used as a host instead of Compound 1 and Compound 101 in the formation of the emission layer.

### Comparative Example 3

An organic light-emitting device was manufactured in the same manner as in Example 9, except that CPB and Compound 16 were used as a host instead of Compound 16 and Compound 101 in the formation of the emission layer.

### Comparative Example 4

An organic light-emitting device was manufactured in the same manner as in Example 1, except that Compound A and Compound 101 were used as a host instead of Compound 1 and Compound 101 in the formation of the emission layer.

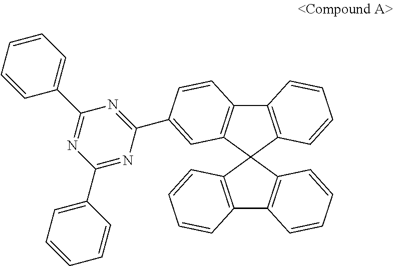 [SMILES: c1ccc(-c2nc(-c3ccccc3)nc(-c3ccc4c(c3)C3(c5ccccc5-c5ccccc53)c3ccccc3-4)n2)cc1]

### Evaluation Example 1

Driving voltages, efficiencies, and color coordinates of the organic light-emitting devices of Examples 1 to 13 and Comparative Examples 1 to 4 were evaluated by supplying power with a voltage and current meter (Kethley Source-Measure Unit (SMU) 236) and using a luminance meter (PR650 Spectroscan, available from Photo Research, Inc.). The results are shown in Table 1. Lifetime T95 was measured as the time (hour) taken until a measured initial luminance (assumed as 100% @10 mA/cm²) is reduced to 95%

TABLE 1

| | | | Driving | | Color | | Lifespan |
|---|---|---|---|---|---|---|---|
| | Emission layer | | voltage | Efficiency | coordinate | | T95 |
| | Host 1 | Host 2 | (V) | (cd/A) | CIEx | CIEy | (hr) |
| Example 1 | Compound 1 | Compound 101 | 4.0 | 28.4 | 0.312 | 0.602 | 190 |
| Example 2 | Compound 2 | Compound 101 | 3.9 | 32.1 | 0.312 | 0.604 | 200 |
| Example 3 | Compound 3 | Compound 101 | 4.0 | 28.4 | 0.311 | 0.602 | 240 |
| Example 4 | Compound 4 | Compound 101 | 4.4 | 25.0 | 0.311 | 0.604 | 220 |
| Example 5 | Compound 10 | Compound 101 | 4.8 | 25.9 | 0.312 | 0.602 | 200 |
| Example 6 | Compound 11 | Compound 101 | 4.6 | 26.9 | 0.312 | 0.604 | 220 |
| Example 7 | Compound 14 | Compound 101 | 4.0 | 25.1 | 0.312 | 0.604 | 210 |
| Example 8 | Compound 15 | Compound 101 | 4.1 | 28.5 | 0.312 | 0.602 | 250 |
| Example 9 | Compound 16 | Compound 101 | 4.2 | 27.3 | 0.312 | 0.604 | 320 |
| Example 10 | Compound 17 | Compound 101 | 4.3 | 29.5 | 0.311 | 0.603 | 250 |
| Example 11 | Compound 23 | Compound 101 | 4.4 | 28.2 | 0.314 | 0.602 | 220 |
| Example 12 | Compound 24 | Compound 101 | 4.2 | 26.3 | 0.314 | 0.604 | 240 |
| Example 13 | Compound 27 | Compound 101 | 4.5 | 28.1 | 0.312 | 0.603 | 180 |
| Comparative | CBP | | 5.5 | 25.2 | 0.312 | 0.605 | 80 |
| Example 1 | | | | | | | |
| Comparative | Compound 1 | CBP | 4.9 | 24.8 | 0.311 | 0.604 | 70 |
| Example 2 | | | | | | | |
| Comparative | Compound 16 | CBP | 5.0 | 25.7 | 0.310 | 0.607 | 80 |
| Example 3 | | | | | | | |
| Comparative | Compound A | Compound 101 | 4.7 | 22.5 | 0.313 | 0.602 | 120 |
| Example 4 | | | | | | | |

Referring to Table 1, it may be seen that the driving voltages, luminance, efficiencies, and lifespans (T95) of the organic light-emitting devices manufactured according to Examples 1 to 13 were better than those of the organic light-emitting devices manufactured according to Comparative Examples 1 to 4.

As described above, according to the one or more of the above exemplary embodiments, the organic light-emitting device may have a high efficiency and long lifespan.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode facing the first electrode; and
an organic layer between the first electrode and the second electrode, the organic layer including an emission layer,
wherein the organic layer includes a first compound and a second compound, the first compound being represented by one of the following Formulae 1-1 to 1-3, and the second compound being represented by one of the following Formulae 2-1 and 2-2: 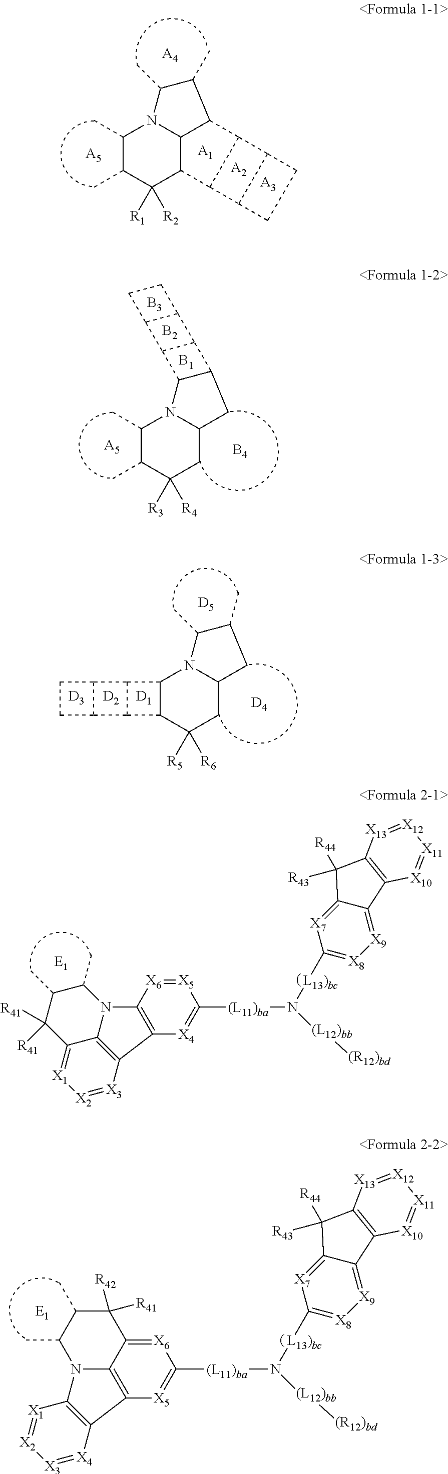
wherein, in Formulae 1-1 to 1-3, 2-1, and 2-2,
ring A₁, ring A₂, and ring A₃ are condensed together, ring B₁, ring B₂, and ring B₃ are condensed together, and ring D₁, ring D₂, and ring D₃ are condensed together;
ring A₂, ring B₂, and ring D₂ are each independently represented by Formula 3, where, in Formula 3, Y₁ is O, S, or N-(L₁)ₐₐ-(R₁₁)_{ab}; 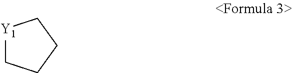
rings A₁, A₃ to A₅, B₁, B₃ to B₅, D₁, D₃ to D₅, and E₁ are each independently a substituted or unsubstituted benzene ring or a substituted or unsubstituted naphthalene ring;
X₁ is N or C(R₅₁), X₂ is N or C(R₅₂), X₃ is N or C(R₅₃), X₄ is N or C(R₅₄), X₅ is N or C(R₅₅), X₆ is N or C(R₅₆), X₇ is N or C(R₅₇), X₈ is N or C(R₅₈), X₉ is N or C(R₅₉), X₁₀ is N or C(R₆₁), X₁₁ is N or C(R₆₂), X₁₂ is N or C(R₆₂), and X₁₃ is N or C(R₆₃);
R₁ to R₆ and R₄₁ to R₄₄ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₆₀ heterocycloalkyl group, a substituted or unsubstituted C₃-C₁₀ cycloalkenyl group, a substituted or unsubstituted C₁-C₆₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, and a substituted or unsubstituted monovalent non-aromatic condensed heteropolycyclic group, wherein R₁ and R₂, R₃ and R₄, R₅ and R₆, R₄₁ and R₄₂, and R₄₃ and R₄₄ are non-ring forming substituents, are not linked to each other, and do not form a ring;
L₁ and L₁₁ to L₁₃ are each independently selected from a substituted or unsubstituted C₃-C₁₀ cycloalkylene group, a substituted or unsubstituted C₁-C₁₀ heterocycloalkylene group, a substituted or unsubstituted C₃-C₁₀ cycloalkenylene group, a substituted or unsubstituted C₁-C₁₀ heterocycloalkenylene group, a substituted or unsubstituted C₆-C₆₀ arylene group, a substituted or unsubstituted C₁-C₆₀ heteroarylene group, a substituted or unsubstituted divalent non-aromatic condensed polycyclic group, and a substituted or unsubstituted divalent non-aromatic condensed heteropolycyclic group;
aa, ba, bb, and bc are each independently selected from 0, 1, 2, and 3, wherein, when aa is 0, *-(L₁)ₐₐ-*′ is a single bond, when ba is 0, *-(L₁₁)_{ba}-*′ is a single bond, when bb is 0, *-(L₁₂)_{bb}-*′ is a single bond, when bc is 0, *-(L₁₃)_{bc}-*′ is a single bond, when aa is 2 or greater, two or more L₁ are identical to or different from each other, when ba is 2 or greater, two or more L₁₁ are identical to or different from each other, when bb is 2 or greater, two or more L₁₂ are identical to or different from each other, and, when be is 2 or greater, two or more L₁₃ are identical to or different from each other;
R₁₁, R₁₂, and R₅₁ to R₆₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and —N(Q₆)(Q₇);
ab and bd are each independently selected from 1, 2, and 3, wherein, when ab is 2 or greater, two or more R₁₁ are identical to or different from each other, and, when bd is 2 or greater, two or more R₁₂ are identical to or different from each other;
at least one substituent of the substituted benzene ring, substituted naphthalene ring, substituted C₃-C₁₀ cycloalkylene group, substituted C₁-C₁₀ heterocycloalkylene group, substituted C₃-C₁₀ cycloalkenylene group, substituted C₁-C₁₀ heterocycloalkenylene group, substituted C₆-C₆₀ arylene group, substituted C₁-C₆₀ heteroarylene group, substituted divalent non-aromatic condensed polycyclic group, substituted divalent non-aromatic condensed heteropolycyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group is selected from:
a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₁₁)(Q₁₂)(Q₁₃), —B(Q₁₄)(Q₁₅), and —N(Q₁₆)(Q₁₇);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —Si(Q₂₁)(Q₂₂)(Q₂₃), —B(Q₂₄)(Q₂₅), and —N(Q₂₆)(Q₂₇); and
—Si(Q₃₁)(Q₃₂)(Q₃₃), —B(Q₃₄)(Q₃₅), and —N(Q₃₆)(Q₃₇),
wherein Q₁ to Q₇, Q₁₁ to Q₁₇, Q₂₁ to Q₂₇, and Q₃₁ to Q₃₇ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group.

2. The organic light-emitting device as claimed in claim 1, wherein the first compound is represented by one of the following Formulae 1-1(A), 1-1(B), 1-2(A), 1-2(B), 1-3(A), and 1-3(B): 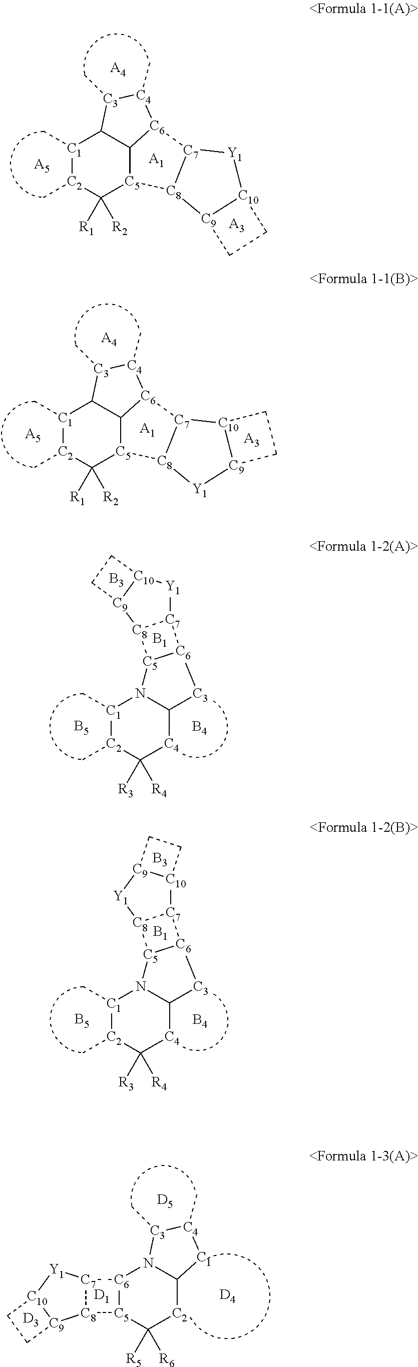 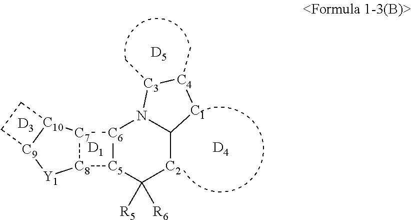
wherein, in Formulae 1-1(A), 1-1(B), 1-2(A), 1-2(B), 1-3(A), and 1-3(B), C₁ to C₁₀ are each independently numbered to indicate chemically distinct carbon atoms,
ring A₁ is represented by one of the following Formulae 5-1(1) and 5-1(2),
ring B₁ is represented by one of the following Formulae 5-2(1) to 5-2(5),
ring D₁ is represented by one of the following Formulae 5-3(1) to 5-3(5),
ring A₃ is represented by one of the following Formulae 6-1(1) to 6-1(4),
ring B₃ is represented by one of the following Formulae 6-2(1) to 6-2(4),
ring D₃ is represented by one of the following Formulae 6-3(1) to 6-3(4),
ring A₄ is represented by one of the following Formulae 7-1(1) to 7-1(4),
ring B₄ is represented by one of the following Formulae 7-2(1) to 7-2(3),
ring D₄ is represented by one of the following Formulae 7-3(1) to 7-3(3),
rings A₅ and B₅ are each independently represented by one of the following Formulae 8-1(1) to 8-1(4),
ring D₅ is represented by one of the following Formulae 8-3(1) to 8-3(4), 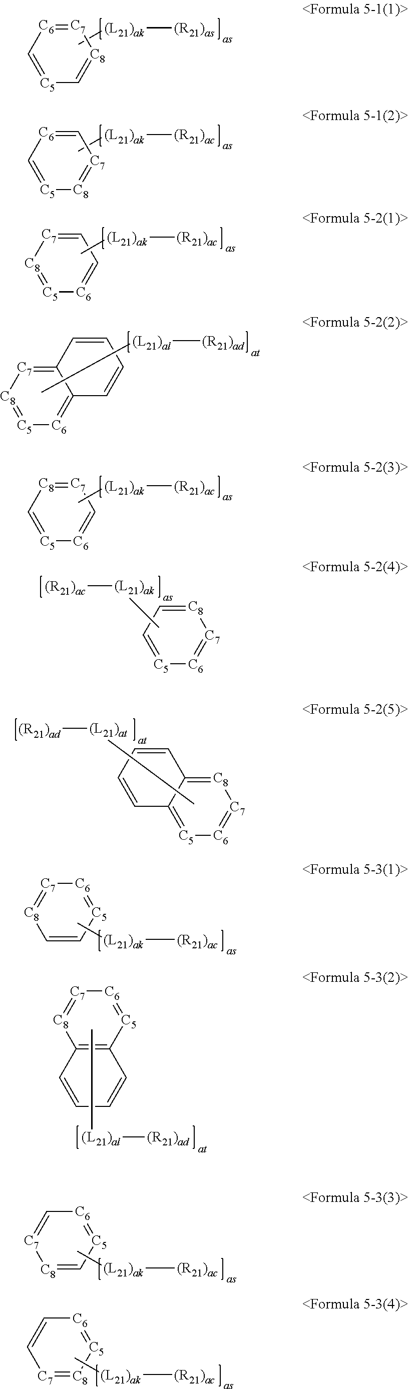 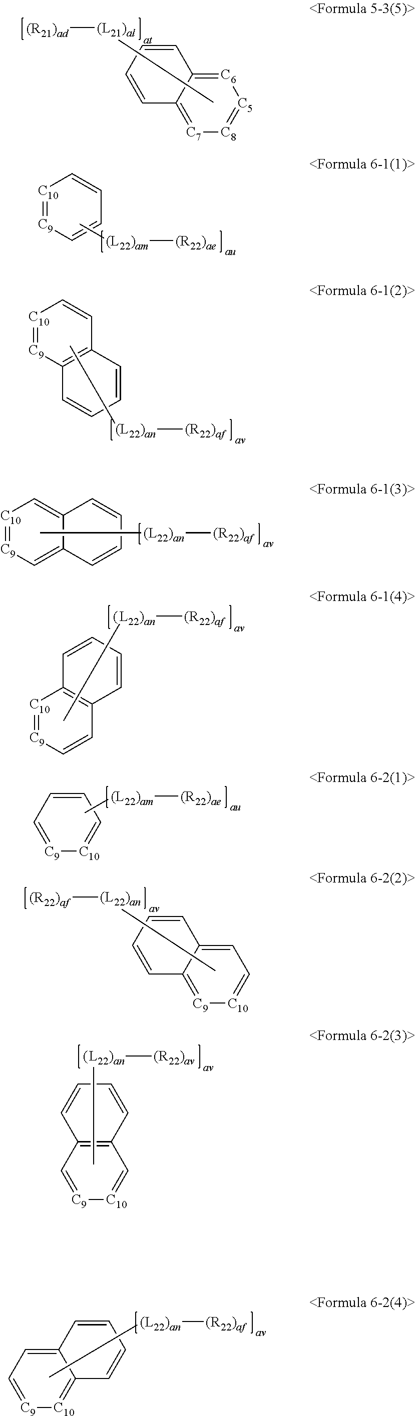 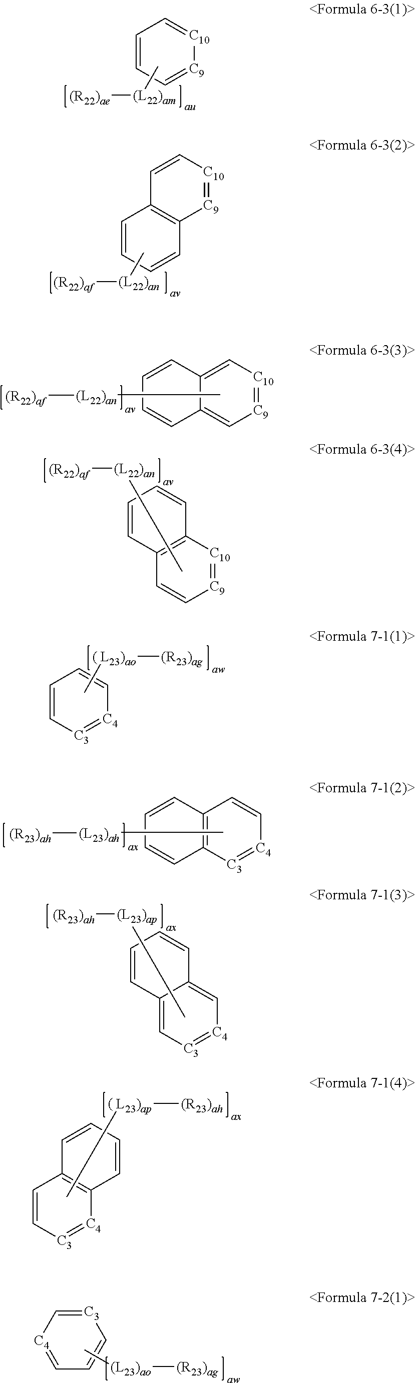 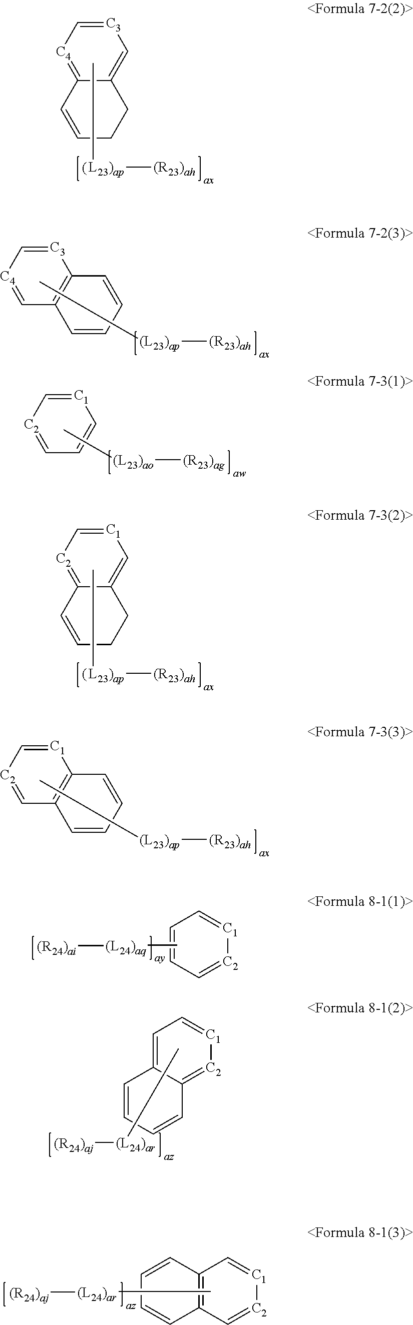 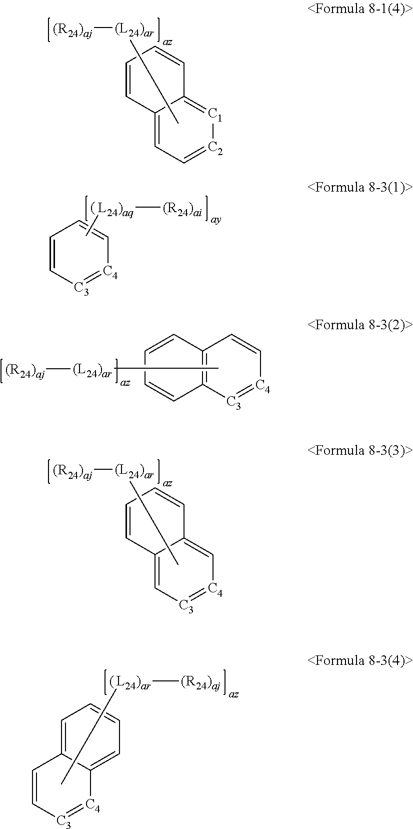
wherein, in Formulae 5-1(1) and 5-1(2), 5-2(1) to 5-2(5), 5-3(1) to 5-3(5), 6-1(1) to 6-1(4), 6-2(1) to 6-2(4), 6-3(1) to 6-3(4), 7-1(1) to 7-1(4), 7-2(1) to 7-2(3), 7-3(1) to 7-3(3), 8-1(1) to 8-1(4), and 8-3(1) to 8-3(4),
L₂₁ to L₂₄ are each defined the same as L₁ of Formula 3;
ak, al, am, an, ao, ap, aq, and ar are each independently selected from 0, 1, 2, and 3;
R₂₁ to R₂₄ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃), —B(Q₄)(Q₅), and —N(Q₆)(Q₇);
ac, ad, ae, af, ag, ah, ai, and aj are each independently selected from 0, 1, 2, and 3, wherein, when ac is 2 or greater, two or more R₂₁ are identical to or different from each other, when ad is 2 or greater, two or more R₂₁ are identical to or different from each other, when ae is 2 or greater, two or more R₂₂ are identical to or different from each other, when af is 2 or greater, two or more R₂₂ are identical to or different from each other, when ag is 2 or greater, two or more R₂₃ are identical to or different from each other, when ai is 2 or greater, two or more R₂₄ are identical to or different from each other, when ah is 2 or greater, two or more R₂₃ are identical to or different from each other, when ai is 2 or greater, two or more R₂₄ are identical to or different from each other, and when aj is 2 or greater, two or more R₂₄ are identical to or different from each other;
as is selected from 0, 1, and 2, wherein, when as is 2 or greater, two or more *-[(L₂₁)ₐₖ-(R₂₁)_{ac}] are identical to or different from each other;
at, au, aw, and ay are each independently selected from 0, 1, 2, 3, and 4, wherein, when at is 2 or greater, two or more *-[(L₂₁)_{ad}-(R₂₁)ₐₗ] are identical to or different from each other, when au is 2 or greater, two or more *-[(L₂₂)ₐₘ-(R₂₂)ₐₑ] are identical to or different from each other, when aw is 2 or greater, two or more *-[(L₂₃)ₐₒ-(R₂₃)_{ag}] are identical to or different from each other, and when ay is 2 or greater, two or more *-[(L₂₄)_{aq}-(R₂₄)ₐᵢ] are identical to or different from each other;
av, ax, and az are each independently selected from 0, 1, 2, 3, 4, 5, and 6, wherein, when av is 2 or greater, two or more *-[(L₂₂)ₐₙ-(R₂₂)_{af}] are identical to or different from each other, when ax is 2 or greater, two or more *-[(L₂₃)ₐₚ-(R₂₃)ₐₕ] are identical to or different from each other, and when az is 2 or greater, two or more *-[(L₂₄)ₐᵣ-(R₂₄)ₐⱼ] are identical to or different from each other; and
substituents of the substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₁-C₆₀ heteroaryl group, substituted monovalent non-aromatic condensed polycyclic group, and substituted monovalent non-aromatic condensed heteropolycyclic group, and Q₁ to Q₇ are the same as defined with respect to Formulae 1-1 to 1-3, 2-1, and 2-2.

3. The organic light-emitting device as claimed in claim 2, wherein the first compound is represented by Formula 1-1(A), 1-2(A), or 1-3(A), wherein, in Formulae 1-1(A), 1-2(A), and 1-3(A),
ring A₁ is represented by one of Formulae 5-1(1) and 5-1(2),
ring B₁ is represented by one of Formulae 5-2(1) to 5-2(3),
ring D₁ is represented by one of Formulae 5-3(1) to 5-3(3),
ring A₃ is represented by one of Formulae 6-1(1) and 6-1(2),
ring B₃ is represented by one of Formulae 6-2(1) and 6-2(2),
ring D₃ is represented by one of Formulae 6-3(1) to 6-3(4),
ring A₄ is represented by one of Formulae 7-1(1) and 7-1(3),
ring B₄ is represented by one of Formulae 7-2(1) and 7-2(3),
ring D₄ is represented by one of Formulae 7-3(1) and 7-3(2),
ring A₅ is represented by one of Formulae 8-1(1) and 8-1(3),
ring B₅ is represented by one of Formulae 8-2(1) to 8-2(3), and
ring D₅ is represented by one of Formulae 8-3(1) and 8-3(4).

4. The organic light-emitting device as claimed in claim 1, wherein R₁ to R₆ and R₄₁ to R₄₄ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, and a naphthyl group;
a phenyl group, a naphthyl group, a fluorenyl group, a phenanthrenyl group, an anthracenyl group, a fluoranthenyl group, a triphenylenyl group, a pyrenyl group, and a chrysenyl group; and
a phenyl group, a naphthyl group, a fluorenyl group, a phenanthrenyl group, an anthracenyl group, a fluoranthenyl group, a triphenylenyl group, a pyrenyl group, and a chrysenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, and a chrysenyl group.

5. The organic light-emitting device as claimed in claim 1, wherein L₁ and L₁₁ to L₁₃ are each independently selected from:
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group; and
a phenylene group, a pentalenylene group, an indenylene group, a naphthylene group, an azulenylene group, a heptalenylene group, an indacenylene group, an acenaphthylene group, a fluorenylene group, a spiro-fluorenylene group, a benzofluorenylene group, a dibenzofluorenylene group, a phenalenylene group, a phenanthrenylene group, an anthracenylene group, a fluoranthenylene group, a triphenylenylene group, a pyrenylene group, a chrysenylene group, a naphthacenylene group, a picenylene group, a perylenylene group, a pentaphenylene group, a hexacenylene group, a pentacenylene group, a rubicenylene group, a coronenylene group, an ovalenylene group, a pyrrolylene group, a thiophenylene group, a furanylene group, an imidazolylene group, a pyrazolylene group, a thiazolylene group, an isothiazolylene group, an oxazolylene group, an isoxazolylene group, a pyridinylene group, a pyrazinylene group, a pyrimidinylene group, a pyridazinylene group, an isoindolylene group, an indolylene group, an indazolylene group, a purinylene group, a quinolinylene group, an isoquinolinylene group, a benzoquinolinylene group, a phthalazinylene group, a naphthyridinylene group, a quinoxalinylene group, a quinazolinylene group, a cinnolinylene group, a carbazolylene group, a phenanthridinylene group, an acridinylene group, a phenanthrolinylene group, a phenazinylene group, a benzimidazolylene group, a benzofuranylene group, a benzothiophenylene group, an isobenzothiazolylene group, a benzoxazolylene group, an isobenzoxazolylene group, a triazolylene group, a tetrazolylene group, an oxadiazolylene group, a triazinylene group, a dibenzofuranylene group, a dibenzothiophenylene group, a benzocarbazolylene group, a dibenzocarbazolylene group, a thiadiazolylene group, an imidazopyridinylene group, and an imidazopyrimidinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a phenylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group.

6. The organic light-emitting device as claimed in claim 1, wherein L₁ and L₁₁ to L₁₃ are each independently selected from:
a phenylene group, a naphthylene group, a fluorenylene group, a phenanthrenylene group, an anthracenylene group, a triphenylenylene group, a pyrenylene group, and a chrysenylene group; and
a phenylene group, a naphthylene group, a fluorenylene group, a phenanthrenylene group, an anthracenylene group, a triphenylenylene group, a pyrenylene group, and a chrysenylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a triphenylenyl group, a pyrenyl group, and a chrysenyl group.

7. The organic light-emitting device as claimed in claim 1, wherein:
L₁, L₁₁, and L₁₂ are each independently a group represented by one of the following Formulae 5-1 to 5-16, and
aa and bb are each independently 0 or 1, ba is 1 or 2, and bc is 0: 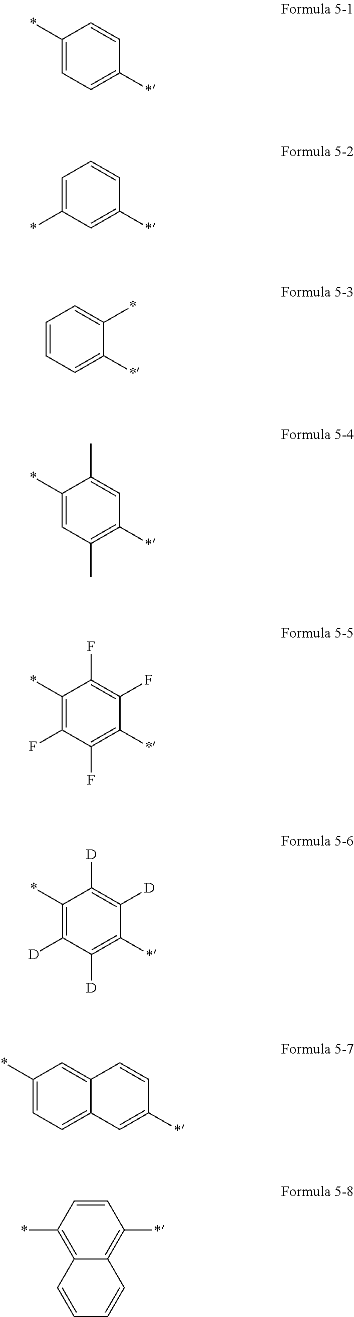 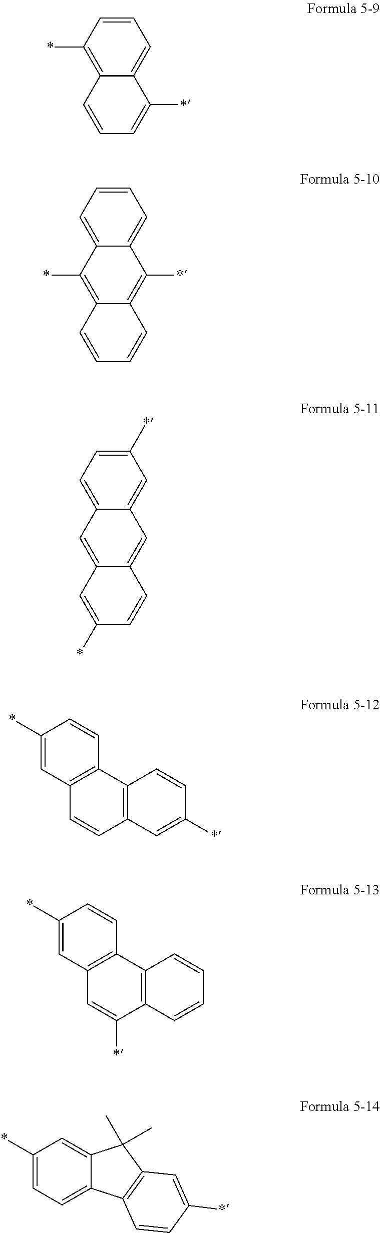 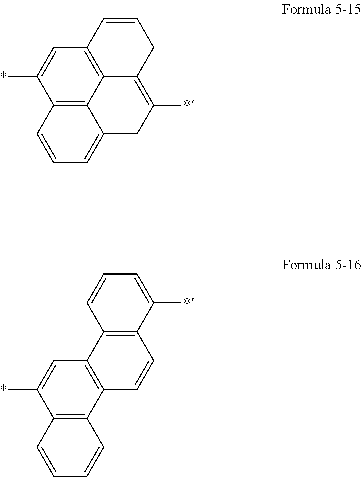
wherein, in Formulae 5-1 to 5-16, * and *′ are a binding site to a neighboring atom.

8. The organic light-emitting device as claimed in claim 2, wherein R₁₁ and R₂₁ to R₂₄ are each independently selected from:
a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinyl group, a benzimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group; and
a pyrrolyl group, an indolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, a quinolinyl group, an isoquinolinyl group, a benzoquinolinyl group, a quinoxalinyl group, a benzoquinoxalinyl group, a quinazolinyl group, a benzoquinazolinyl group, a phenanthrolinyl group, a benzimidazolyl group, an isobenzothiazolyl group, a benzoxazolyl group, an isobenzoxazolyl group, a triazolyl group, an oxadiazolyl group, a triazinyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, phenanthridinyl, acridinyl, phenanthrolinyl, phenazinyl, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group.

9. The organic light-emitting device as claimed in claim 2, wherein R₁₁ and R₂₁ to R₂₄ are each independently a group represented by one of the following Formulae 7-1 to 7-44: 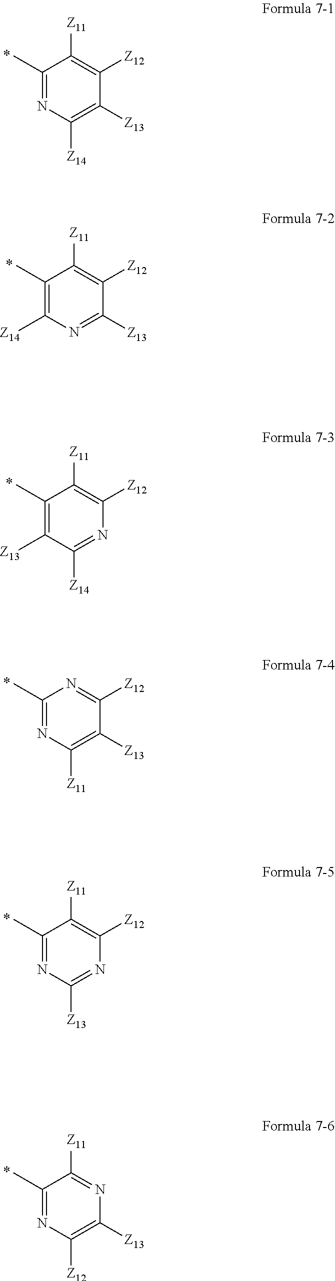 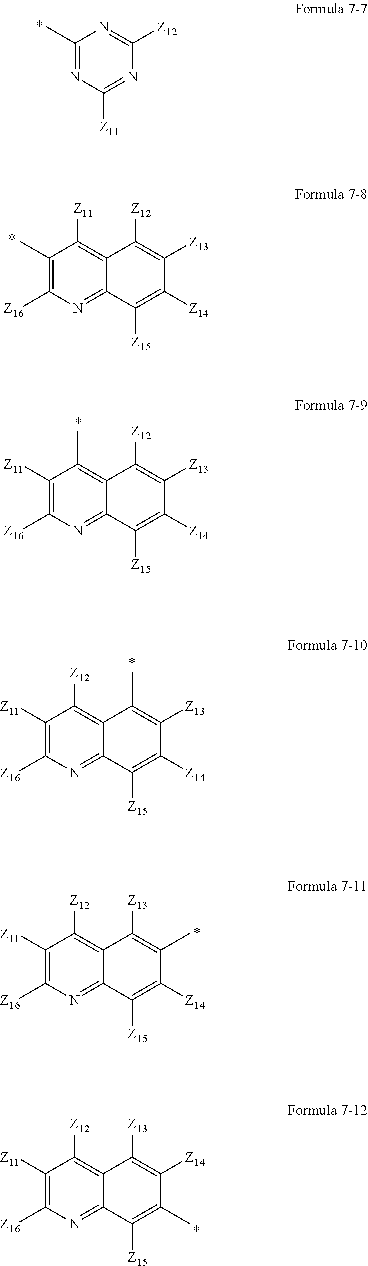 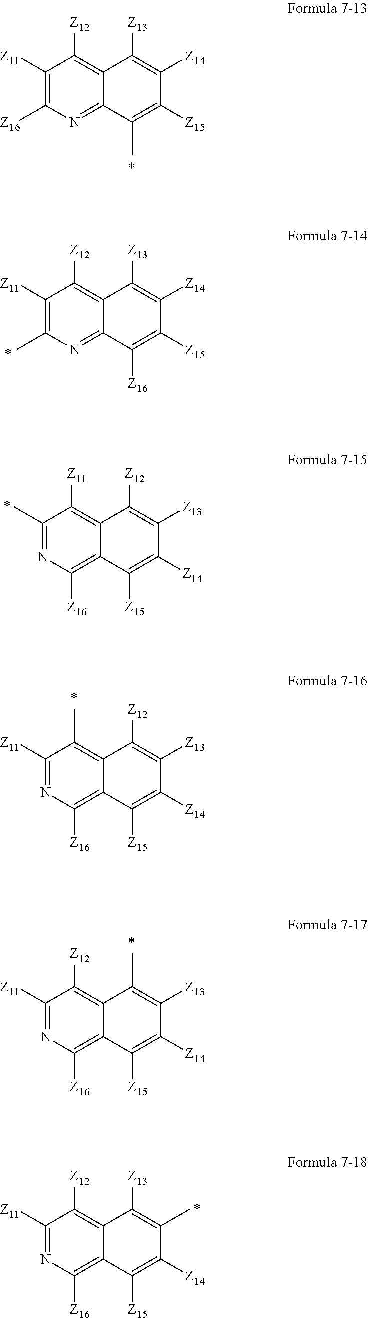 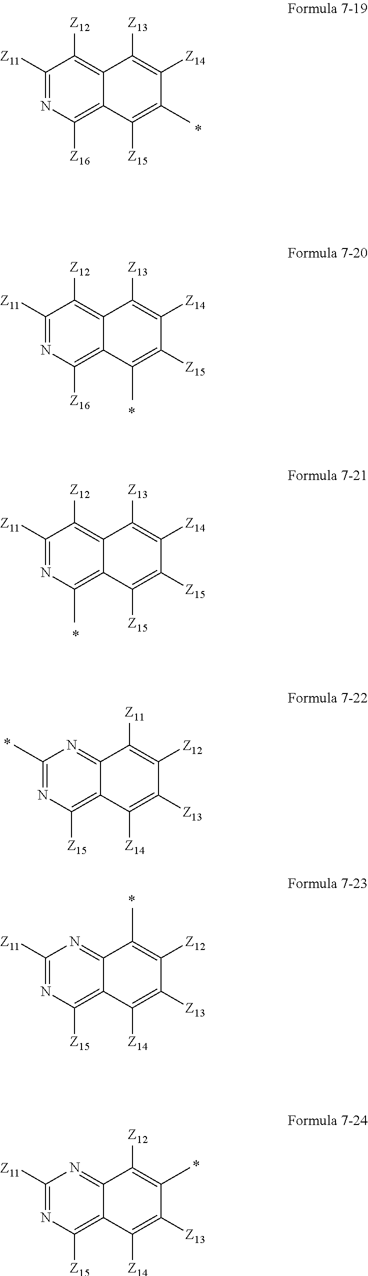 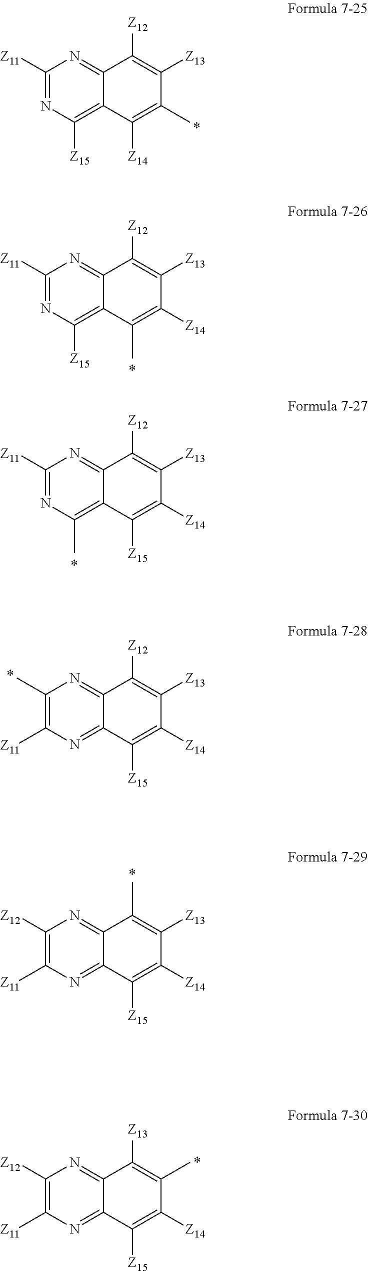 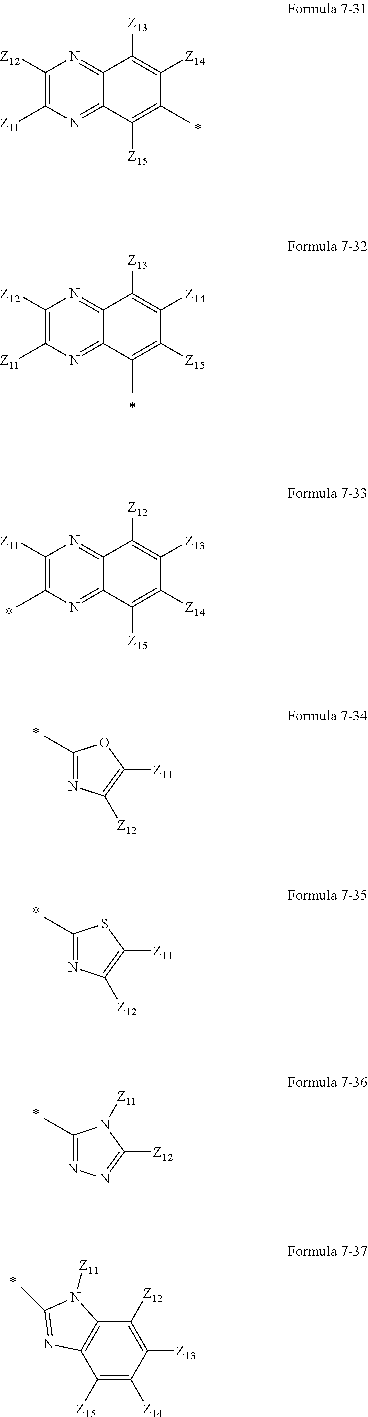 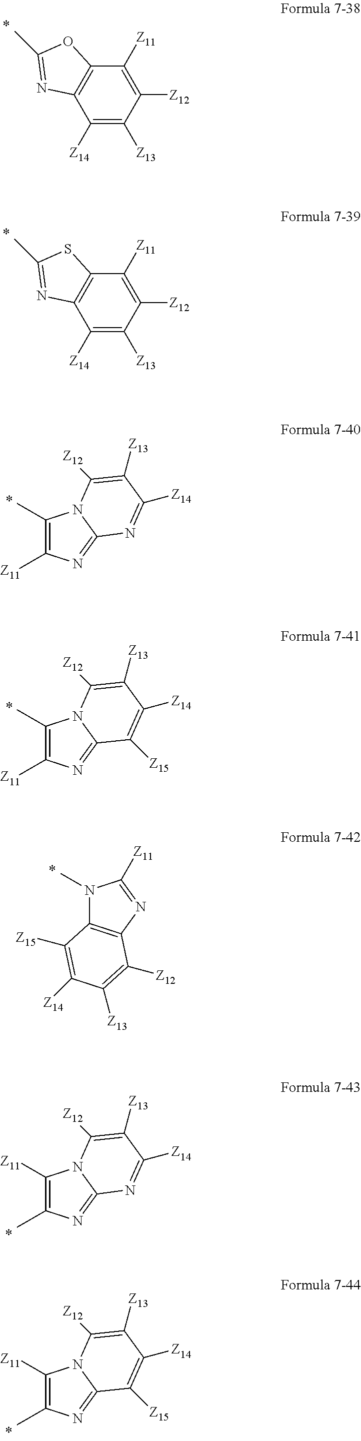
wherein, in Formulae 7-1 to 7-44,
Z₁₁ to Z₁₆ are each independently selected from a hydrogen, a deuterium, —F, —Cl, —Br, —I, a hydroxyl group, a cyano group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, phenanthridinyl, acridinyl, phenanthrolinyl, phenazinyl, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, and
* is a binding site to a neighboring atom.

10. The organic light-emitting device as claimed in claim 2, wherein, in Formula 3,
Y₁ is N-(L₁)ₐₐ-(R₁₁)_{ab},
L₁ is a group represented by one of the following Formulae 5-1 to 5-16,
aa is 0 or 1,
R₁₁ is a group represented by one of the following Formulae 8-1 to 8-11, and
ab is 1: 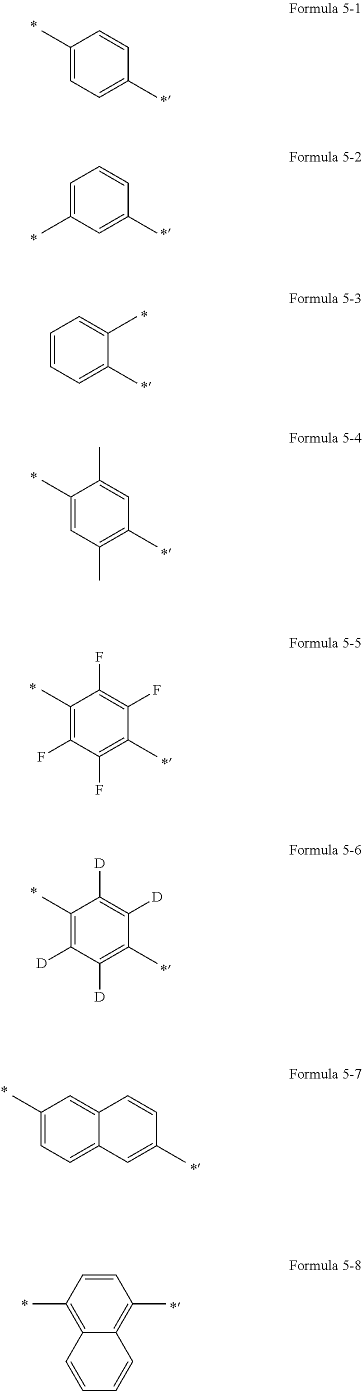 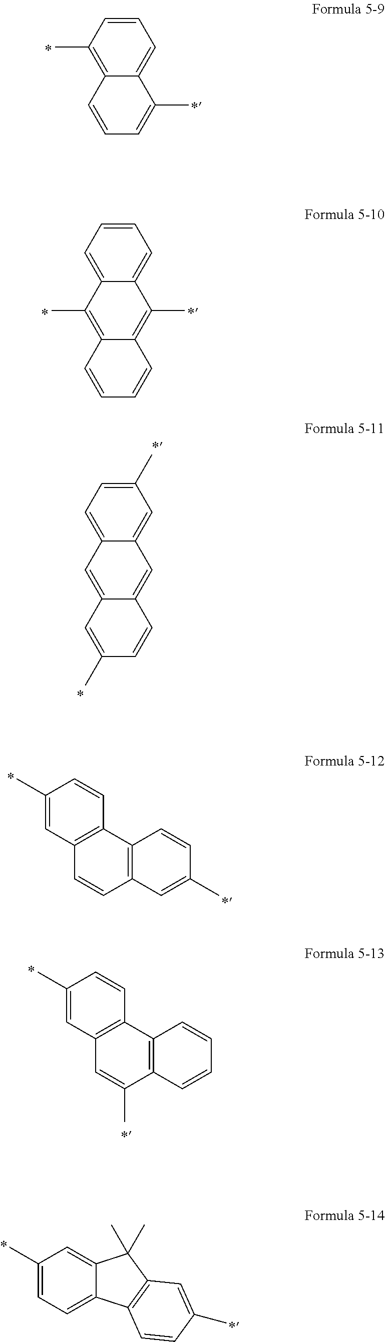 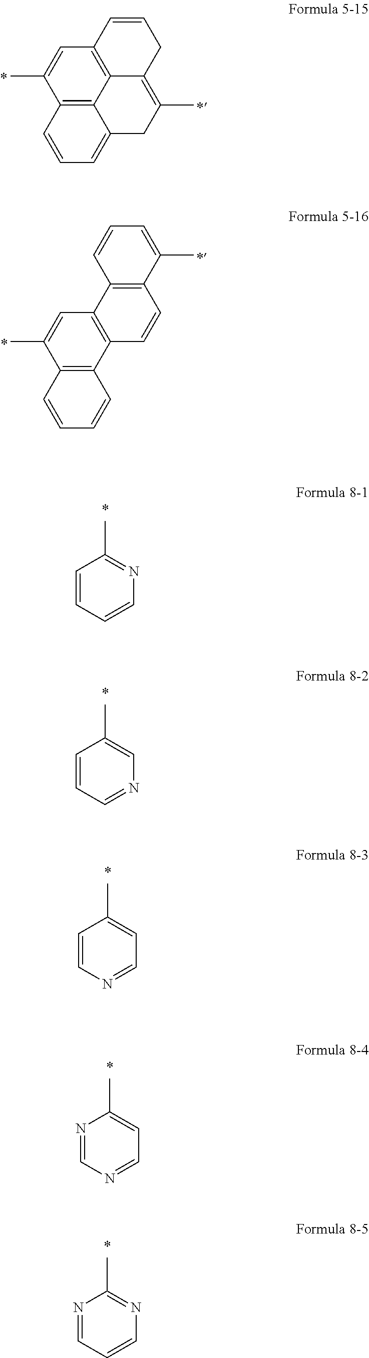 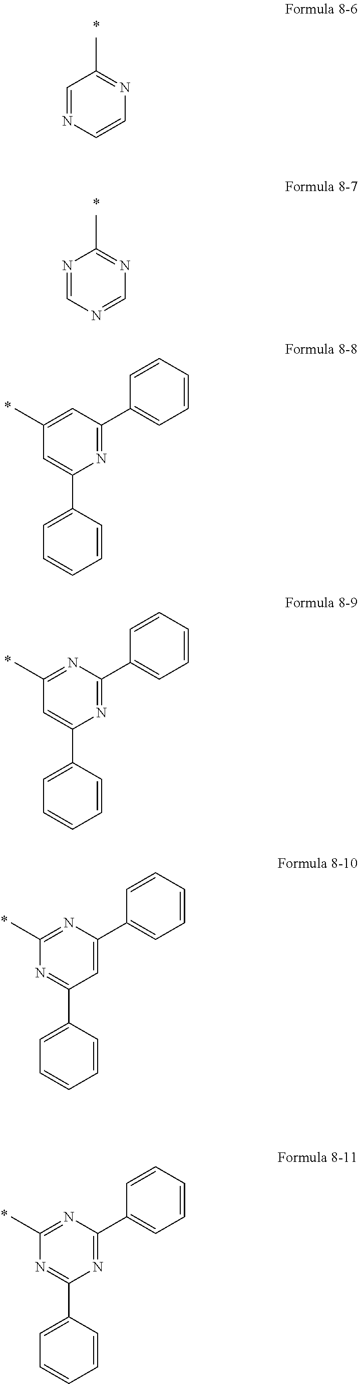
wherein, in Formulae 5-1 to 5-16 and 8-1 to 8-11, * and *′ are a binding site to a neighboring atom.

11. The organic light-emitting device as claimed in claim 2, wherein:
in Formula 3, Y₁ is S or O;
ring A₅ and ring B₅ are each independently represented by one of the following Formulae 8-1(1) to 8-1(4); and
ring D₅ is represented by one of the following Formulae 8-3(1) to 8-3(4): 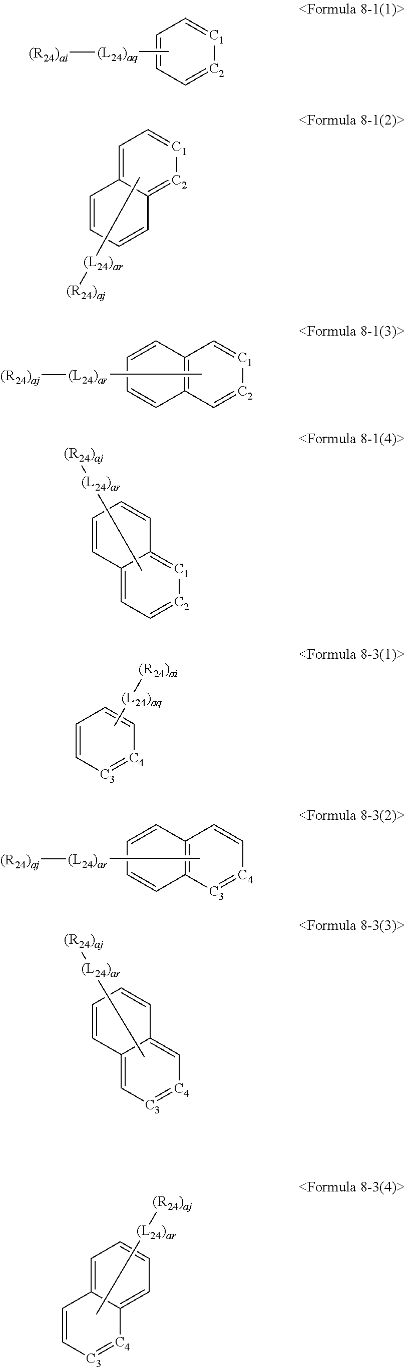
wherein, in Formulae 8-1(1) to 8-1(4) and Formulae 8-3(1) to 8-3(4),
L₂₄ is a group represented by one of the following Formulae 5-1 to 5-16;
aq and ar are each independently 0 or 1;
R₂₄ is a group represented by one of the following Formulae 8-1 to 8-11; and
ai and aj are each 1: 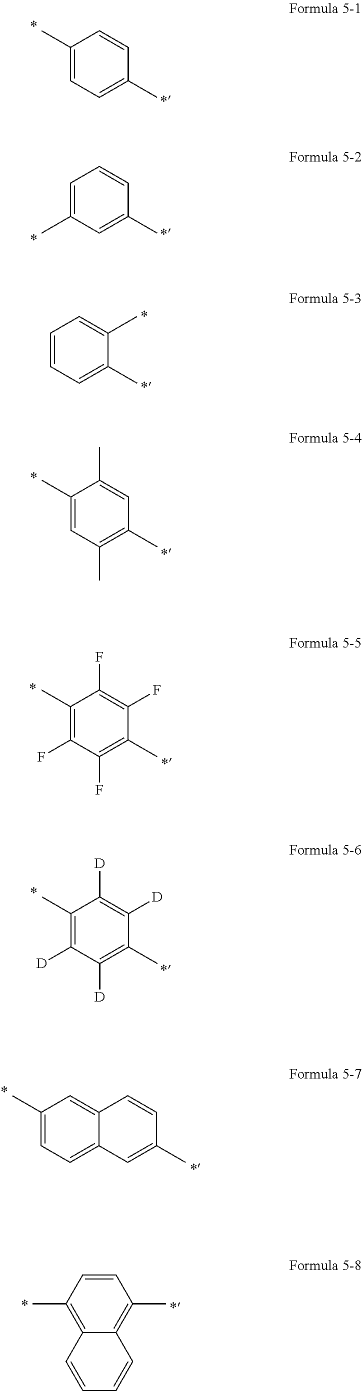 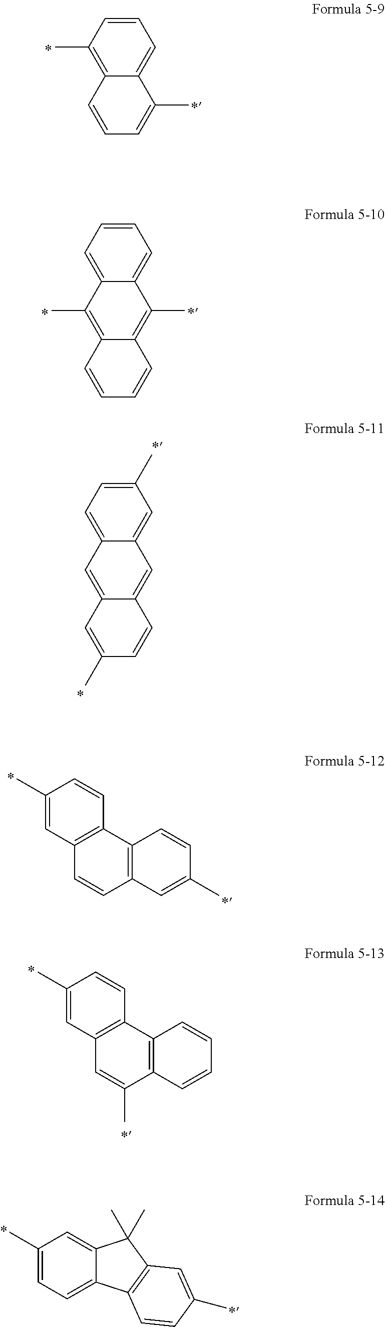 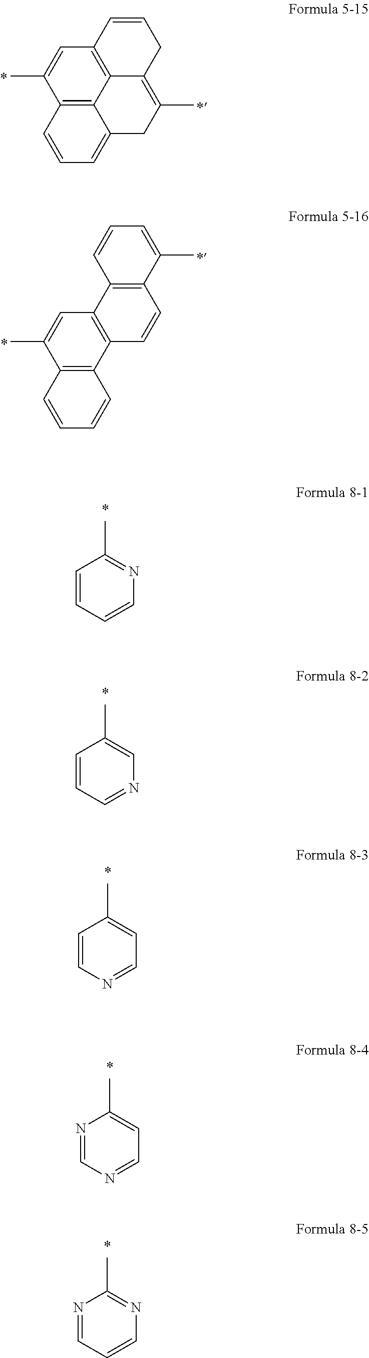 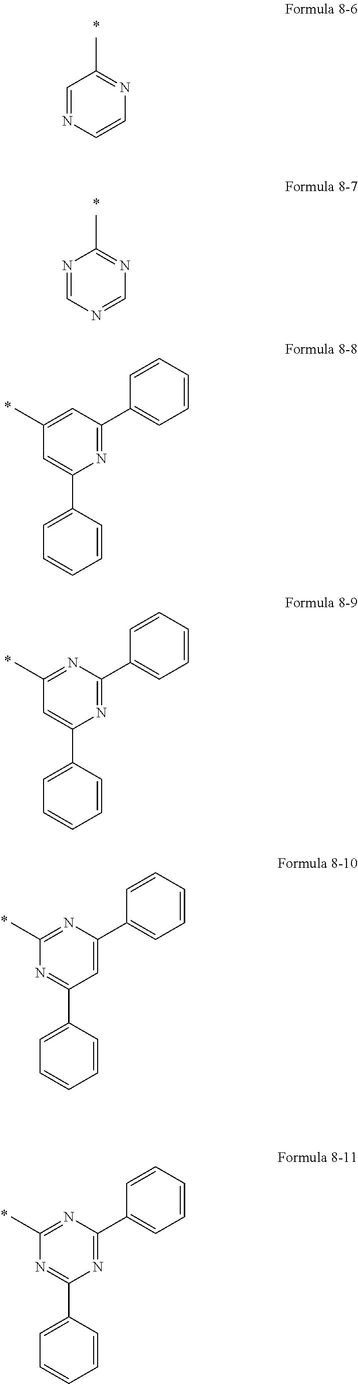
wherein, in Formulae 5-1 to 5-16 and 8-1 to 8-11, * and *′ are a binding site to a neighboring atom.

12. The organic light-emitting device as claimed in claim 2, wherein the second compound is represented by one of the following Formulae 2-1(A) and 2-2(A): 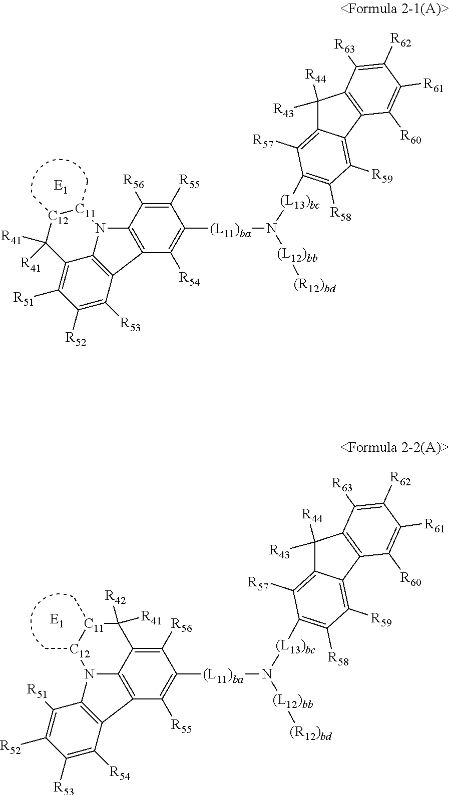
wherein, in Formulae 2-1(A) and 2-2(A),
C₁₁ and C₁₂ are each independently numbered to indicated chemically distinct carbon atoms,
ring E₁ is represented by one of the following Formulae 9-1(1) to 9-1(4), 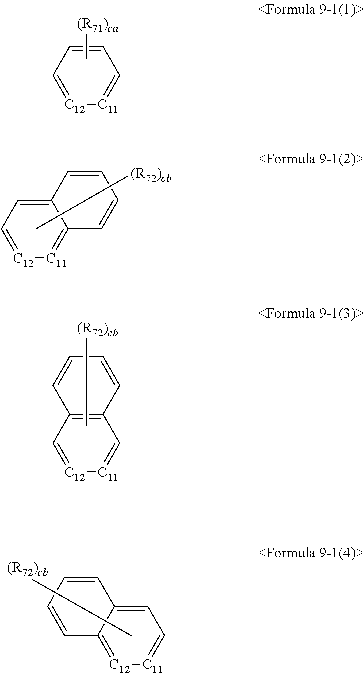
wherein, in Formulae 2-1(A), 2-2(A), and 9-1(1) to 9-1(4),
R₄₁ to R₄₄ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group,
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, and a naphthyl group;
a phenyl group, a naphthyl group, a fluorenyl group, a phenanthrenyl group, an anthracenyl group, a fluoranthenyl group, a triphenylenyl group, a pyrenyl group, and a chrysenyl group;
a phenyl group, a naphthyl group, a fluorenyl group, a phenanthrenyl group, an anthracenyl group, a fluoranthenyl group, a triphenylenyl group, a pyrenyl group, and a chrysenyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a phenanthrenyl group, an anthracenyl group, a fluoranthenyl group, a triphenylenyl group, a pyrenyl group, and a chrysenyl group;
R₁₂ is selected from:
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group; and
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, a dibenzocarbazolyl group, and —Si(Q₃₁)(Q₃₂)(Q₃₃),
wherein Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group;
bd is selected from 1, 2, and 3, wherein, when bd is 2 or greater, two or more R₁₂ are identical to or different from each other;
L₁₁ to L₁₃ are each independently a group represented by one of the following Formulae 5-1 to 5-16;
ba is 1 or 2, and bb and bc are each independently 0 or 1, wherein, when ba is 2, two L₁₁ are identical to or different from each other;
R₁₅ to R₆₃, R₇₁, and R₇₂ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₁-C₂₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃) —B(Q₄)(Q₅), and —N(Q₆)(Q₇);
ca is selected from 0, 1, 2, 3, and 4, wherein, when ca is 2 or greater, two or more R₇₁ are identical to or different from each other; and
cb is selected from 0, 1, 2, 3, 4, 5, and 6, wherein, when cb is 2 or greater, two or more R₇₂ are identical to or different from each other; 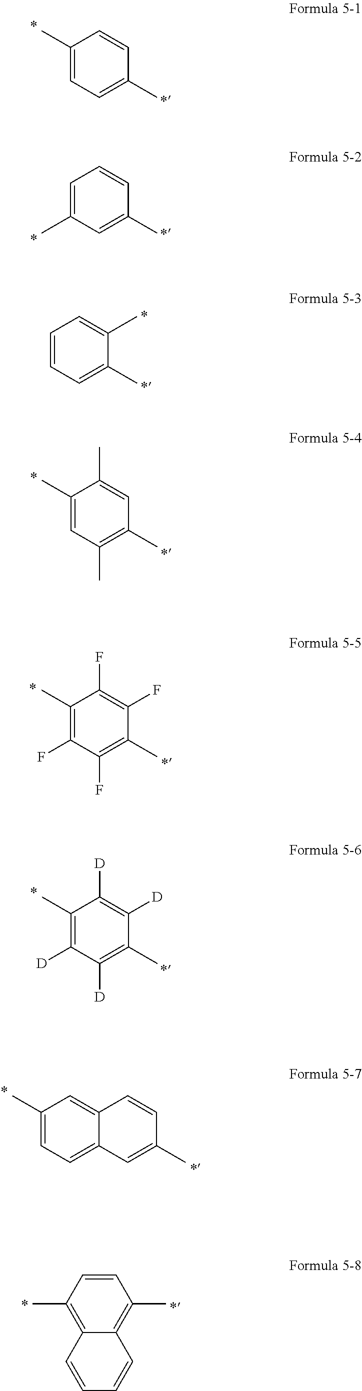 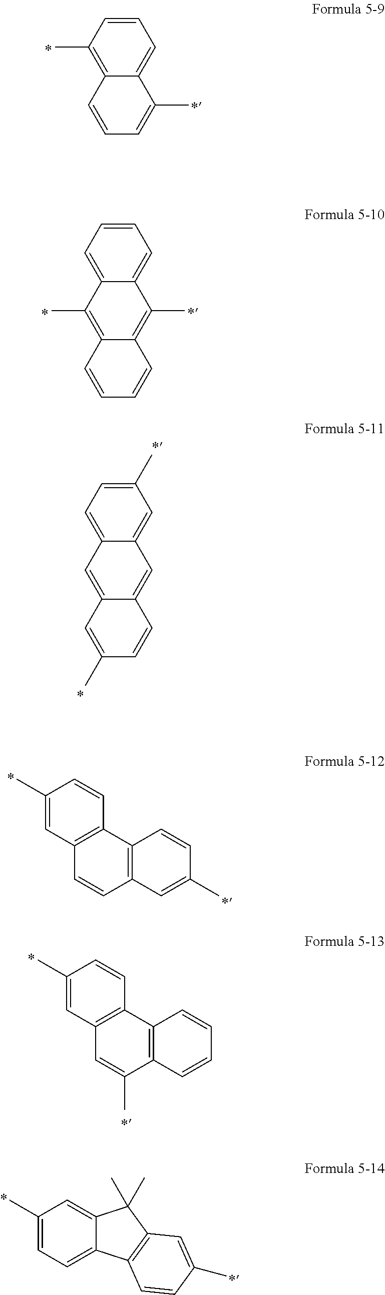 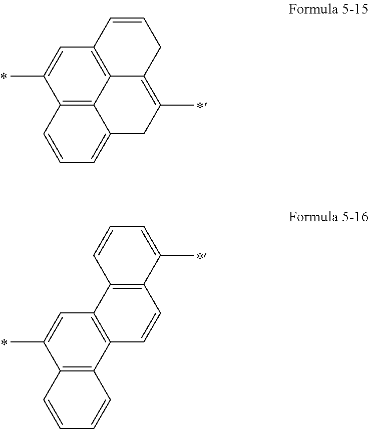
wherein, in Formulae 5-1 to 5-16, * and *′ are a binding site to a neighboring atom.

13. The organic light-emitting device as claimed in claim 12, wherein, in Formulae 2-1(A), 2-2(A), and 9-1(1) to 9-1(4),
R₁₂ is a group represented by one of the following Formulae 9-1 to 9-6, and
R₅₁ to R₆₃, R₇₁, and R₇₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, and a group represented by one of the following Formulae 10-1 to 10-17: 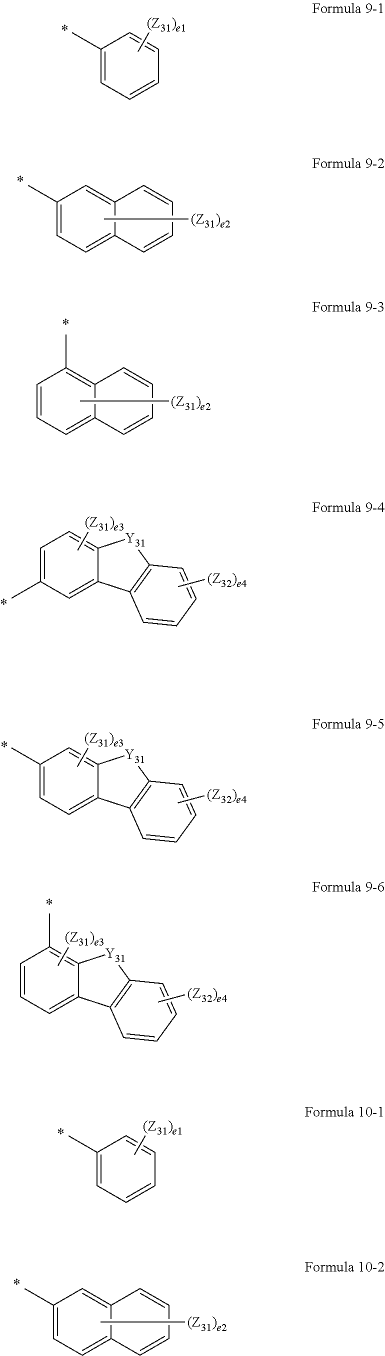 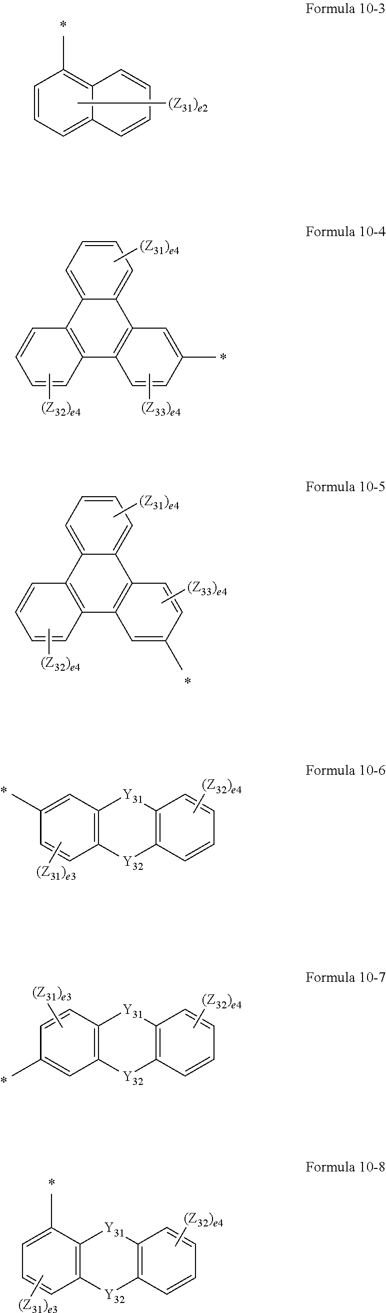 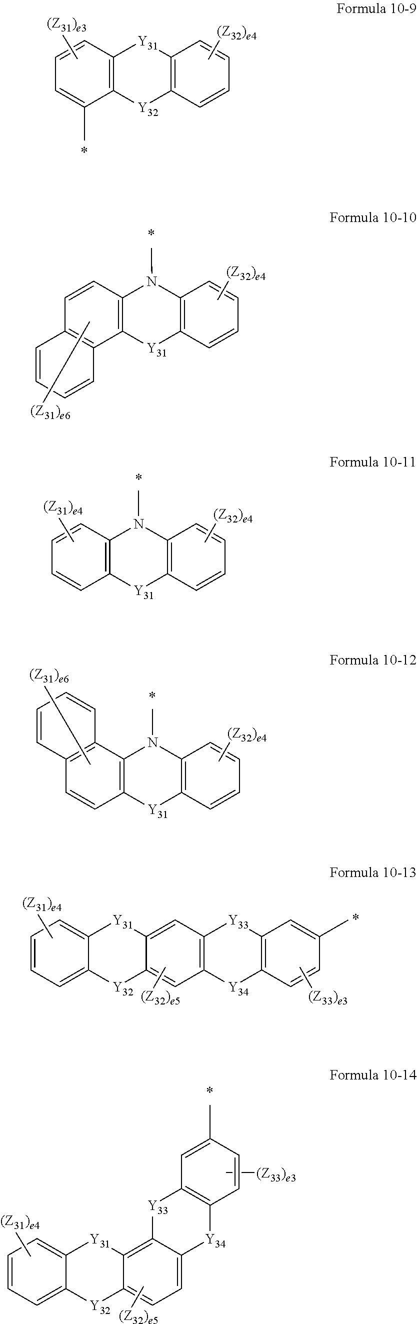 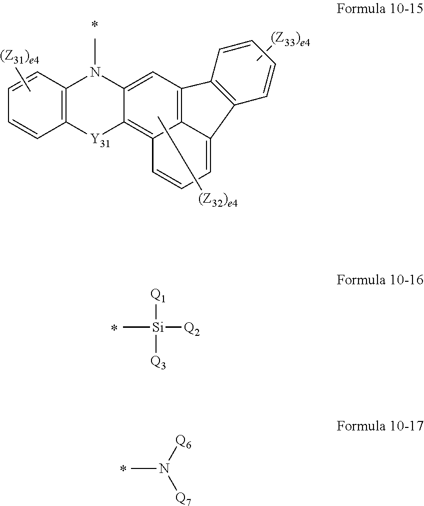
wherein, in Formulae 9-1 to 9-6,
Y₃₁ is C(Z₃₃)(Z₃₄) or N(Z₃₅);
Z₃₁ to Z₃₅ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, and a phosphoric acid or a salt thereof;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group;
a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a carbazolyl group, a benzocarbazolyl group, and a dibenzocarbazolyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, and a naphthyl group; and
—Si(Q₃₁)(Q₃₂)(Q₃₃), wherein Q₃₁ to Q₃₃ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, and a carbazolyl group,
e1 is an integer selected from 1 to 5, e2 is an integer selected from 1 to 7, e3 is an integer selected from 1 to 3, e4 is an integer selected from 1 to 4, and * is a binding site to a neighboring atom,
wherein, in Formulae 10-1 to 10-17,
Y₃₁ to Y₃₄ are each independently a single bond, O, S, C(Z₃₄)(Z₃₅), N(Z₃₆), or Si(Z₃₇)(Z₃₈);
Z₃₁ to Z₃₈ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;
a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, and a phosphoric acid or a salt thereof;
a C₆-C₂₀ aryl group, a C₁-C₂₀ heteroaryl group, a monovalent non-aromatic condensed polycyclic group, and a monovalent non-aromatic condensed heteropolycyclic group; and
a C₆-C₂₀ aryl group, a C₁-C₂₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group,
wherein Q₁ to Q₃, Q₆, and Q₇ of Formulae 10-16 and 10-17 are each independently selected from:
a C₆-C₂₀ aryl group, a C₁-C₂₀ heteroaryl group, a monovalent non-aromatic condensed polycyclic group, and a monovalent non-aromatic condensed heteropolycyclic group; and
a C₆-C₂₀ aryl group, a C₁-C₂₀ heteroaryl group, a monovalent non-aromatic condensed polycyclic group, and a monovalent non-aromatic condensed heteropolycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a C₆-C₂₀ aryl group, a C₁-C₂₀ heteroaryl group, a monovalent non-aromatic condensed polycyclic group, and a monovalent non-aromatic condensed heteropolycyclic group;
e1 is an integer selected from 1 to 5, e2 is an integer selected from 1 to 7, e3 is an integer selected from 1 to 3, e4 is an integer selected from 1 to 4, e5 is an integer of 1 or 2, e6 is an integer selected from 1 to 6, and * is a binding site to a neighboring atom.

14. The organic light-emitting device as claimed in claim 12, wherein, in Formulae 2-1(A), 2-2(A), and 9-1(1) to 9-1(4),
R₁₂ is a group represented by one of the following Formulae 11-1 to 11-15,
R₅₁ to R₆₃, R₇₁, and R₇₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a methyl group, an ethyl group, an n-propyl group, an iso-propyl group, an n-butyl group, a sec-butyl group, an iso-butyl group, a tert-butyl group, an n-pentyl group, an n-hexyl group, an n-heptyl group, an n-octyl group, and a group represented by one of the following Formulae 12-1 to 12-49: 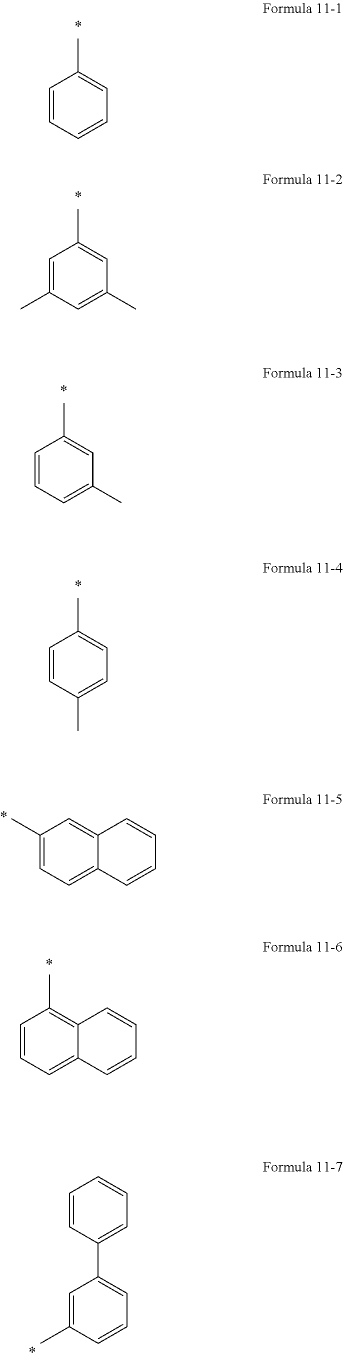 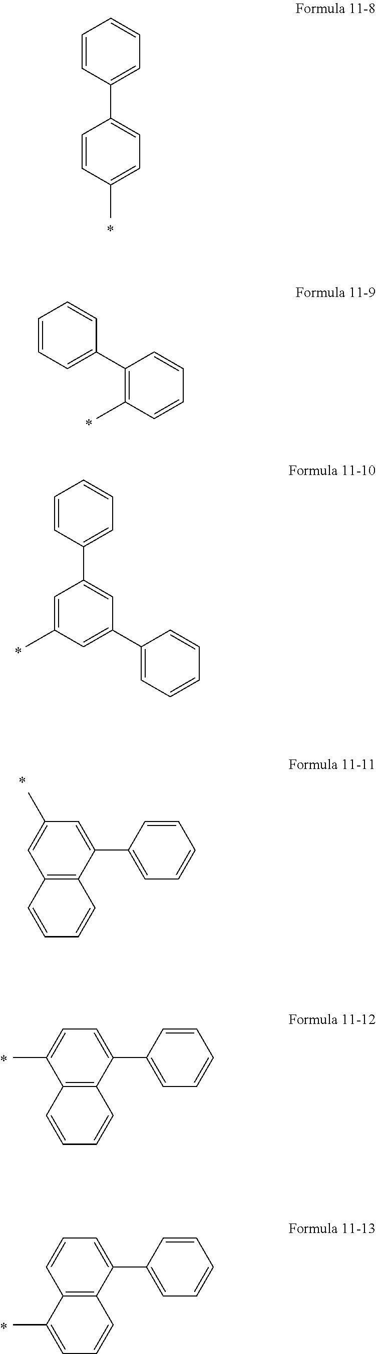 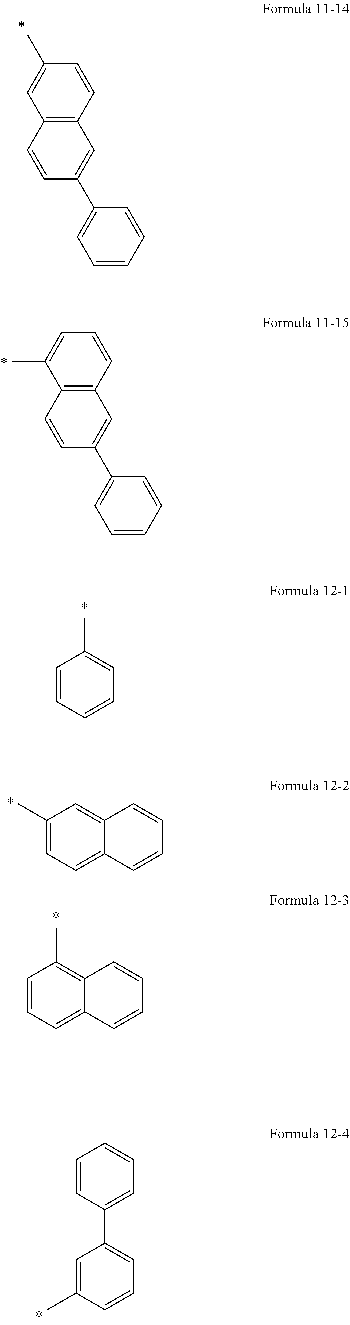 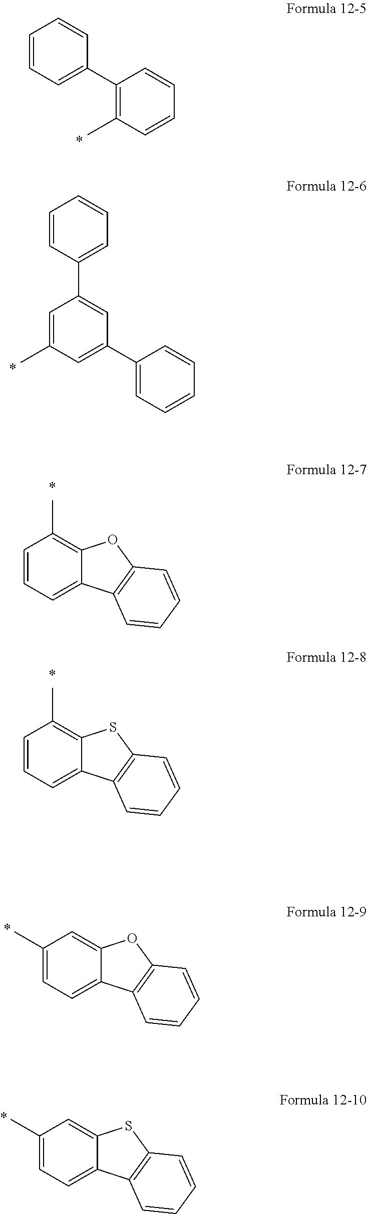 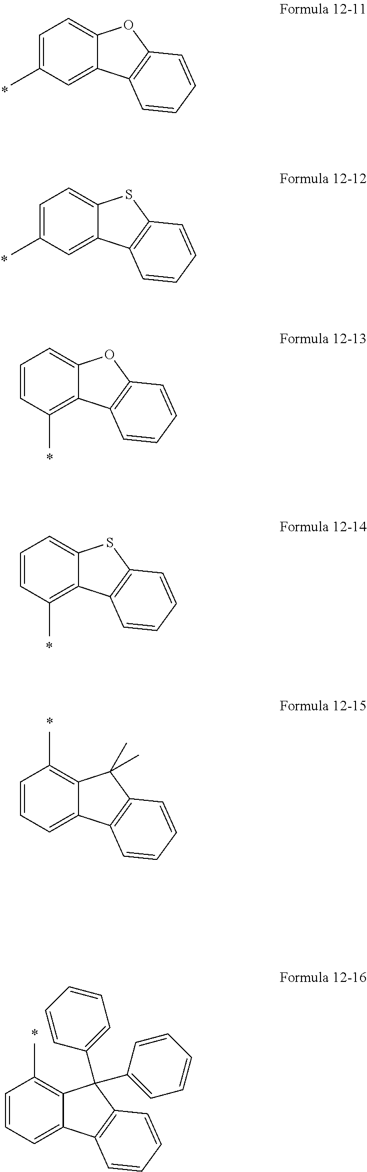 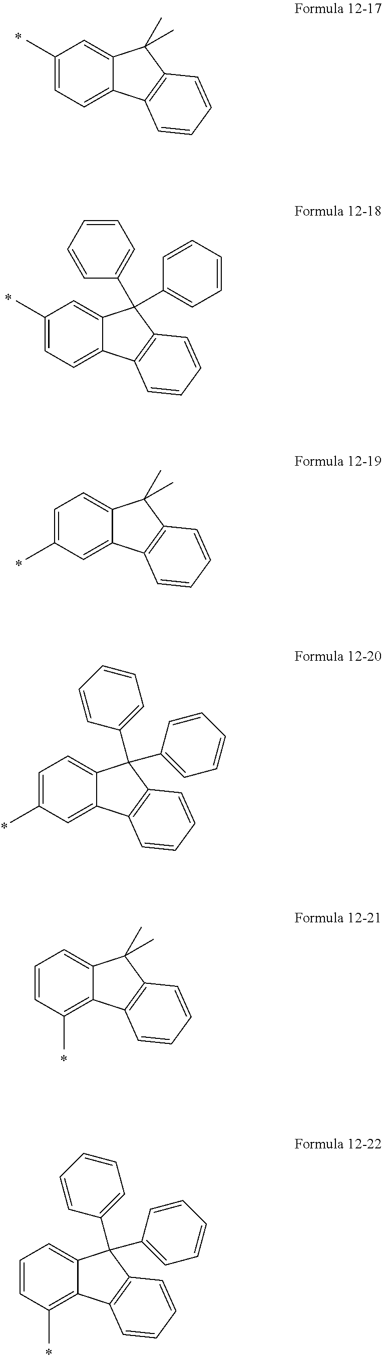 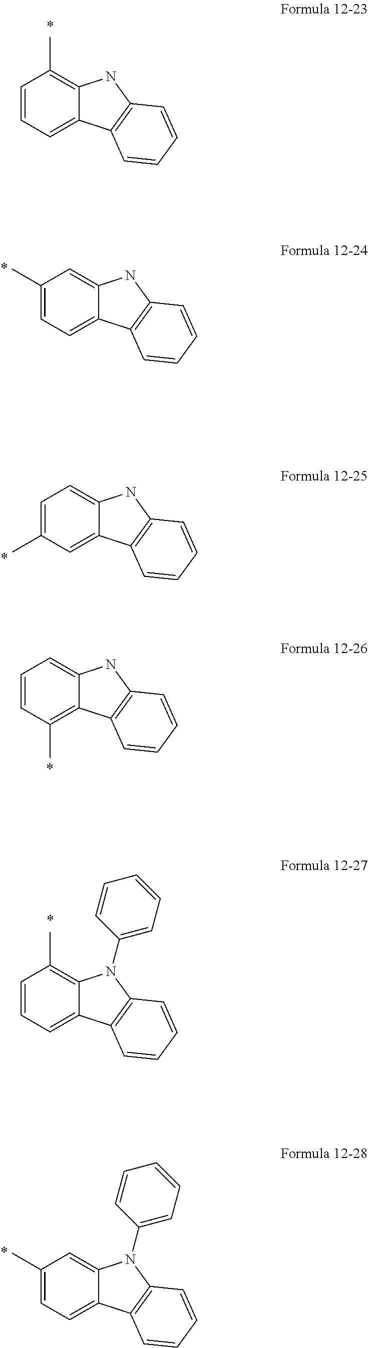 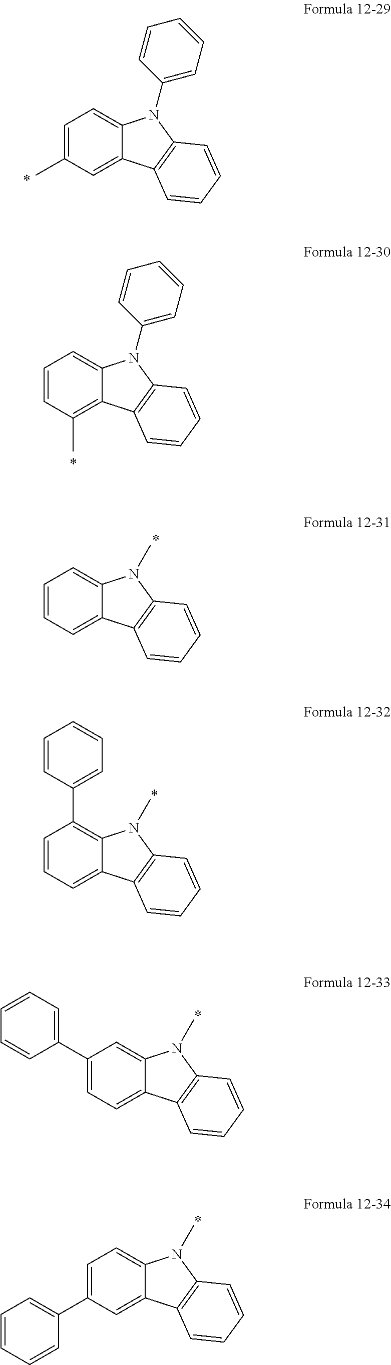 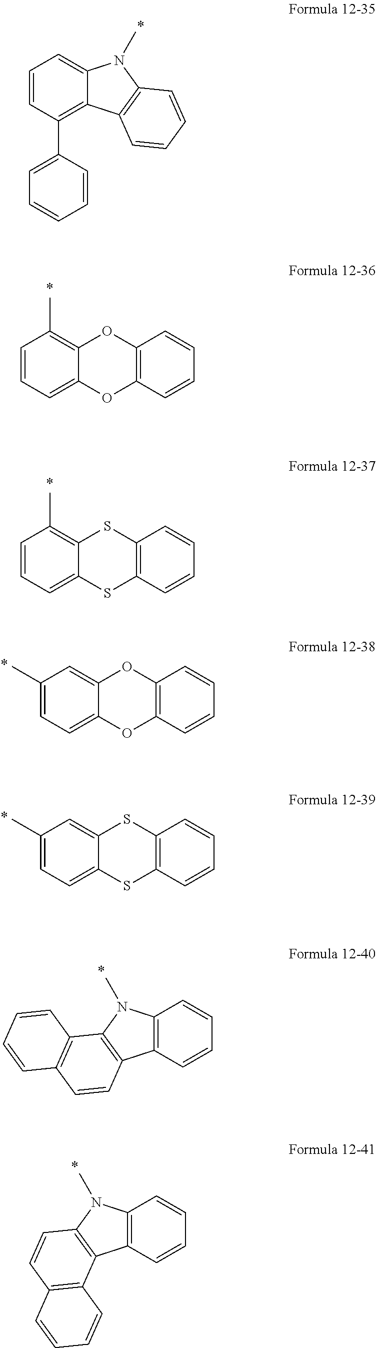 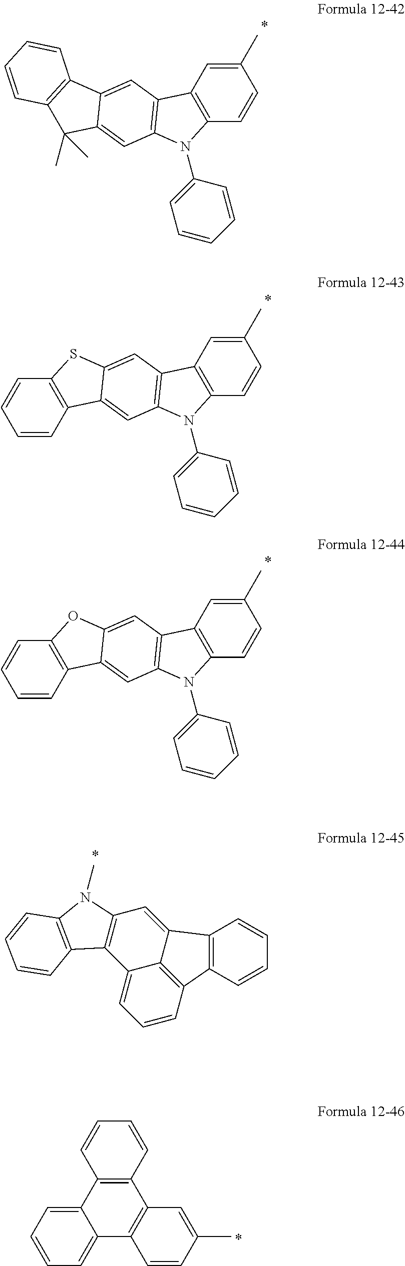 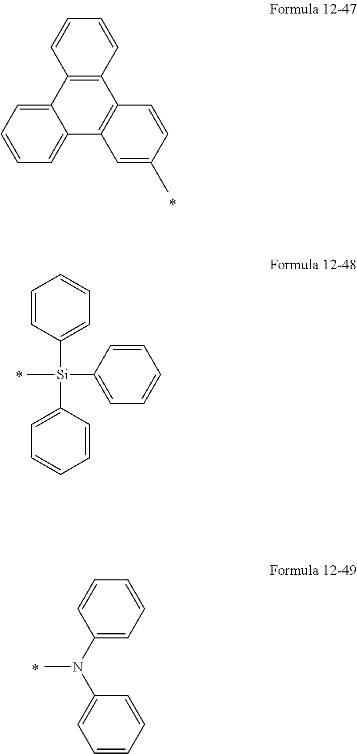
wherein, in Formulae 11-1 to 11-15 and Formulae 12-1 to 12-49, * is a binding site to a neighboring atom.

15. The organic light-emitting device as claimed in claim 1, wherein:
the first compound is represented by one of the following Formulae 1-1(A-1) to 1-1(A-20), 1-1(B-1) to 1-1(B-20), 1-2(A-1) to 1-2(A-27), 1-2(B-1) to 1-2(B-19), 1-3(A-1) to 1-3(A-29), and 1-3(B-1) to 1-3(B-27), and
the second compound is represented by one of the following Formulae 2-1(1) to 2-1(4) and 2-2(1) to 2-2(4): 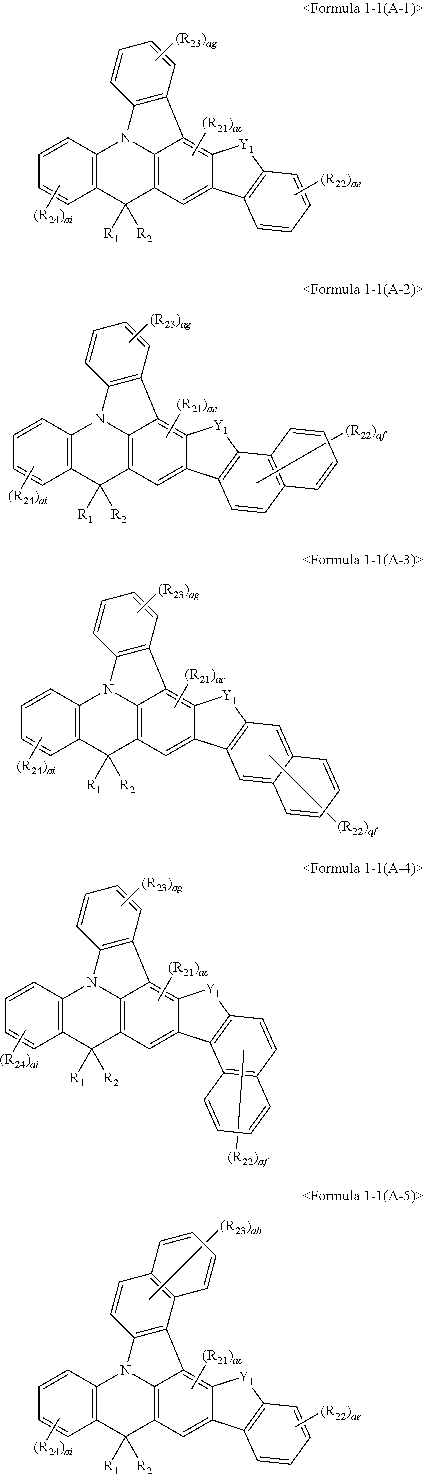 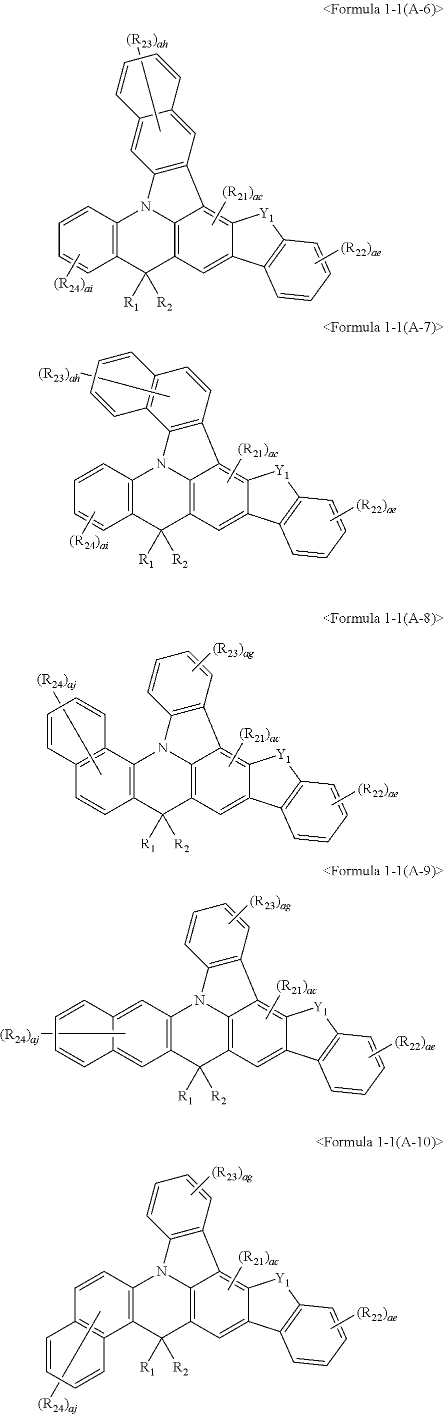 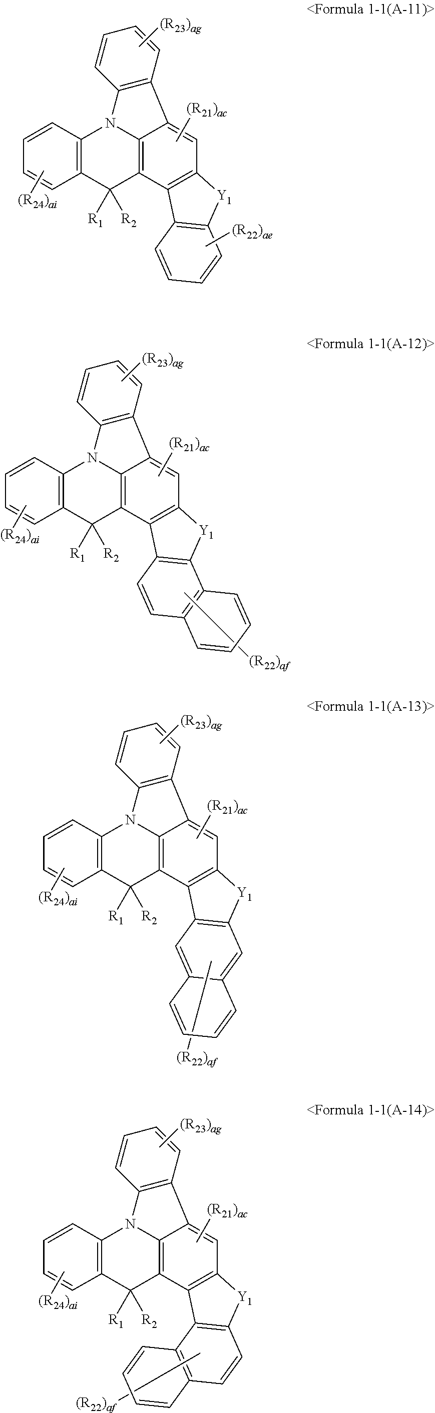 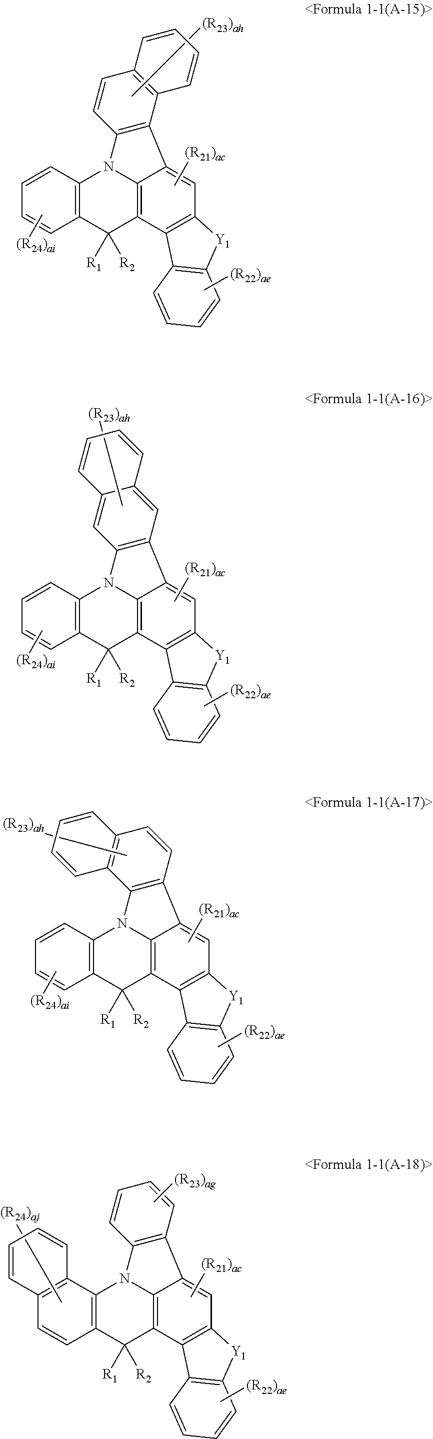 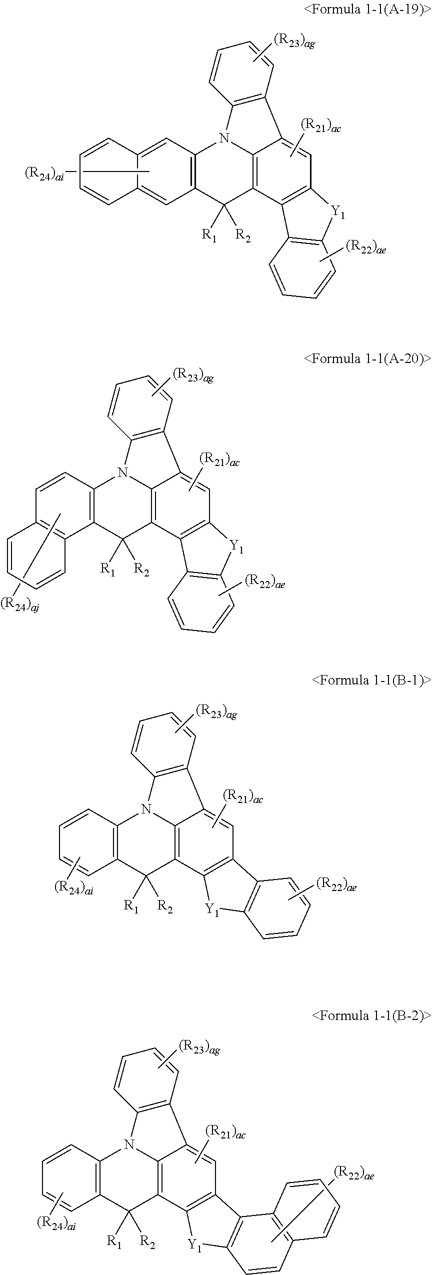 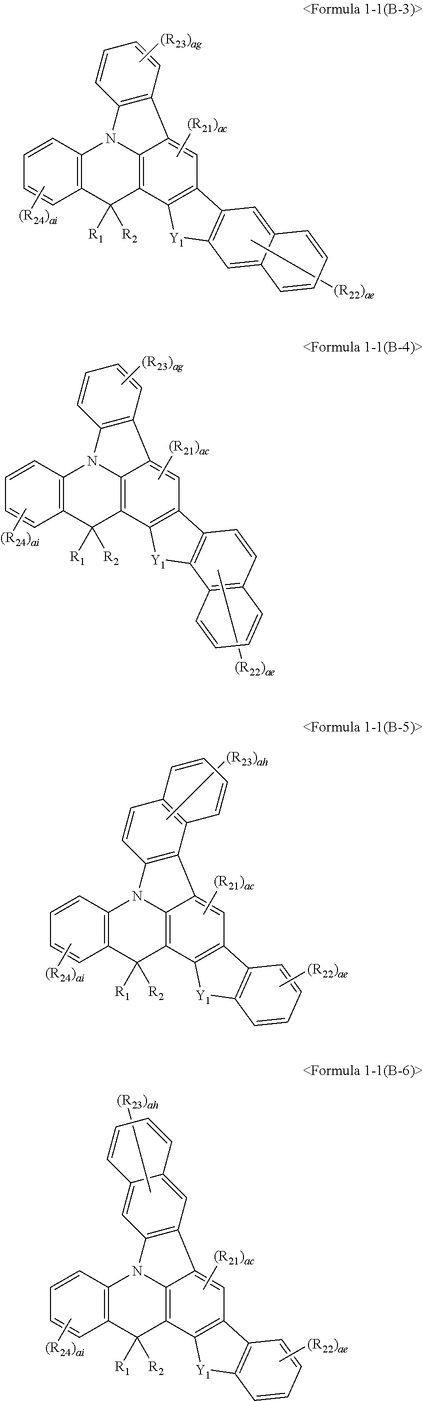 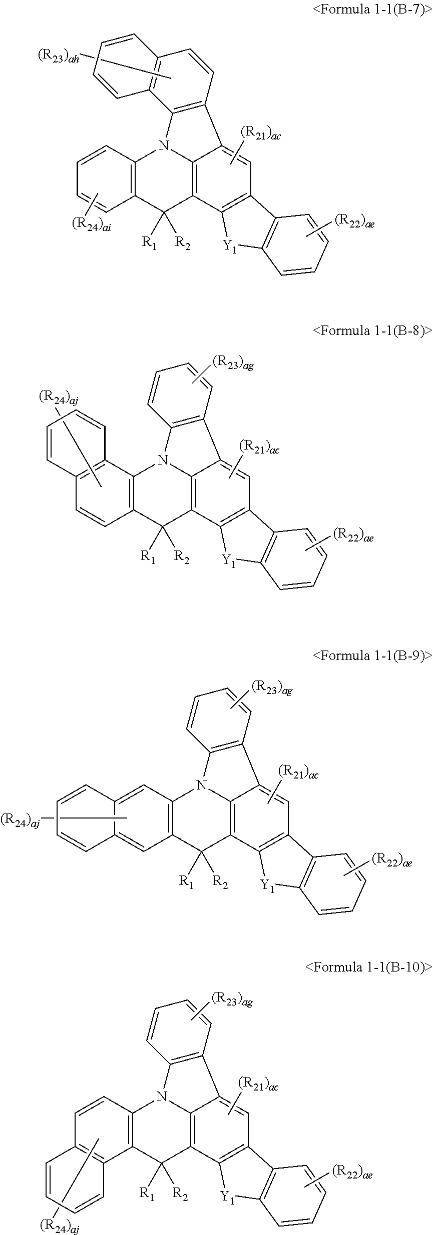 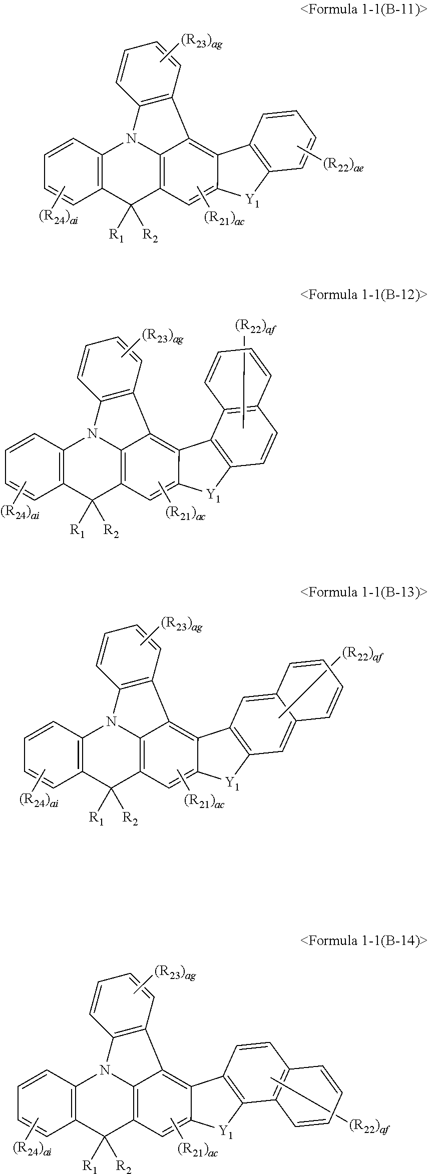 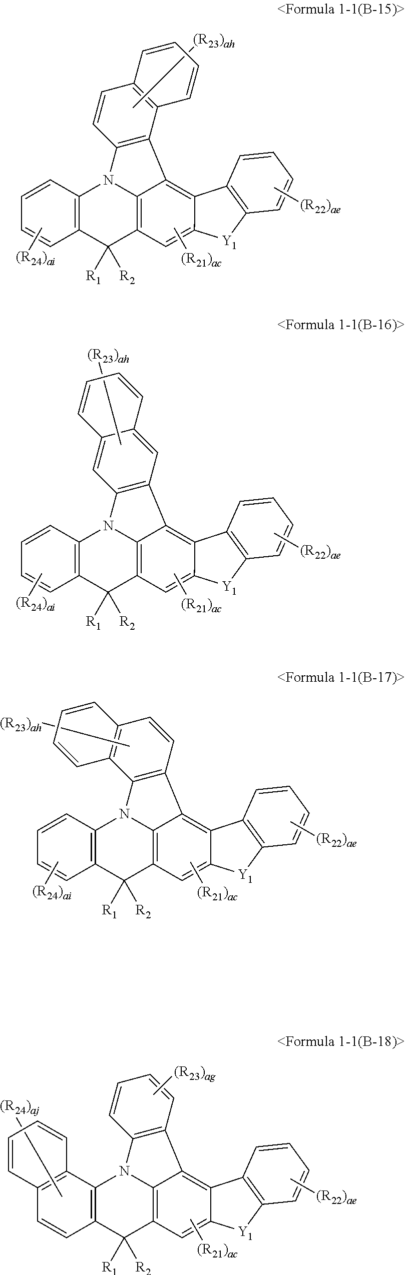 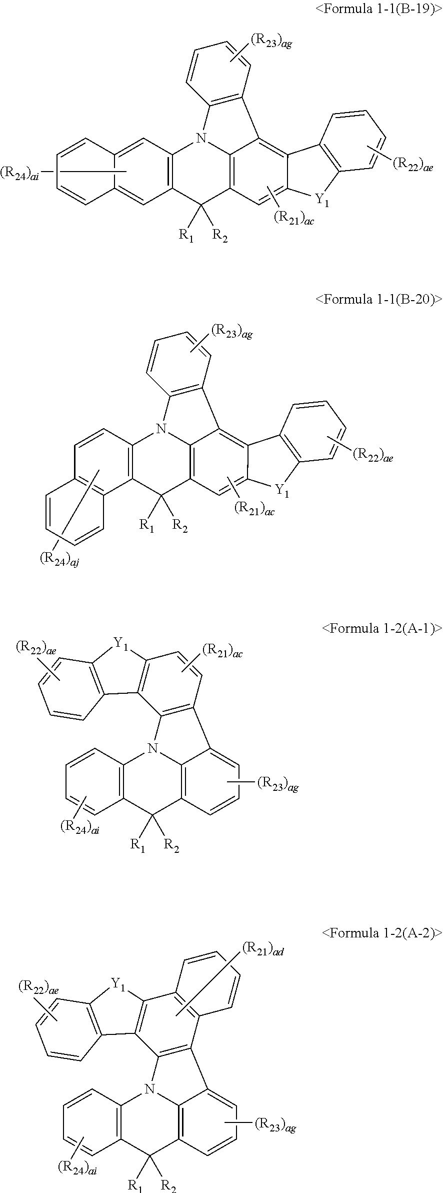 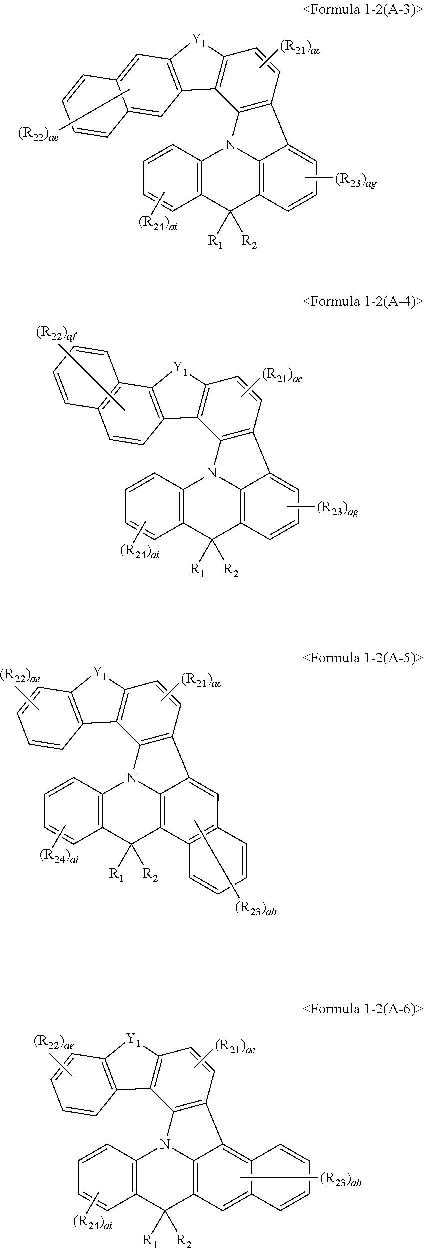 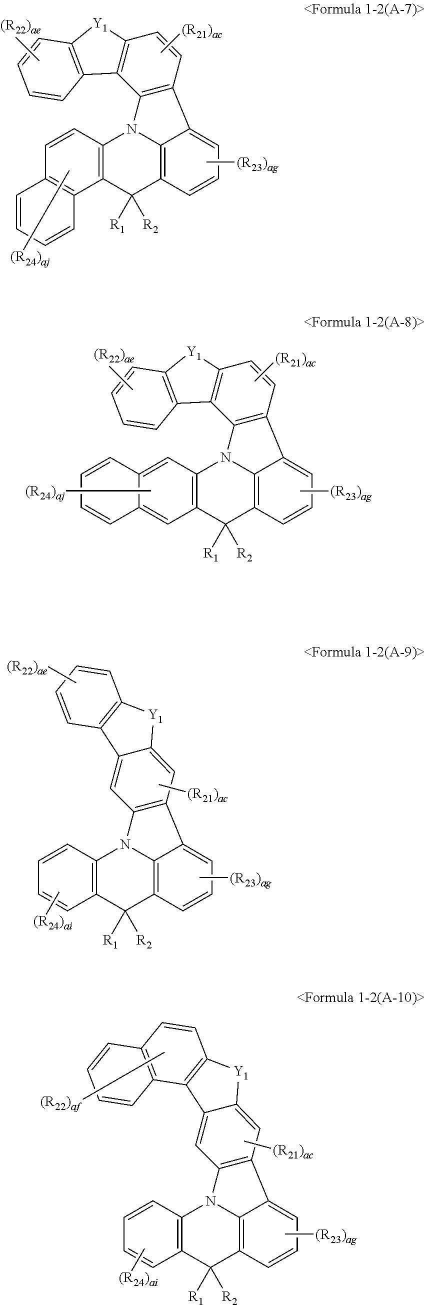 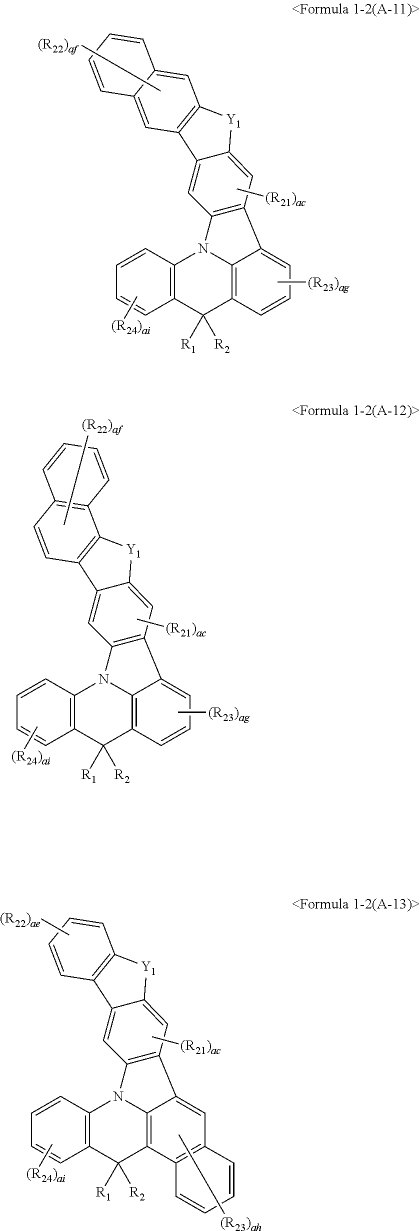 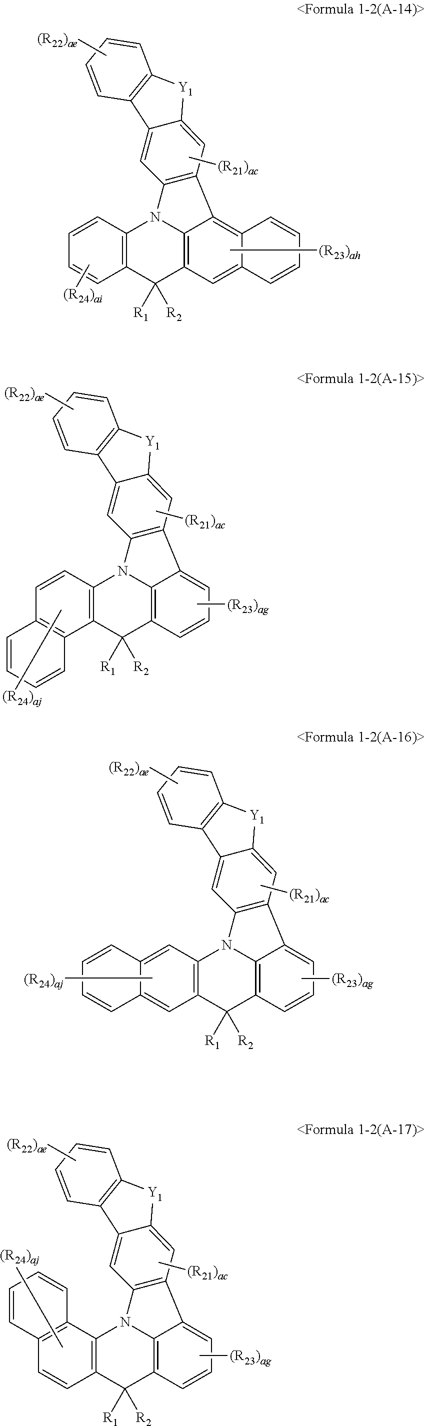 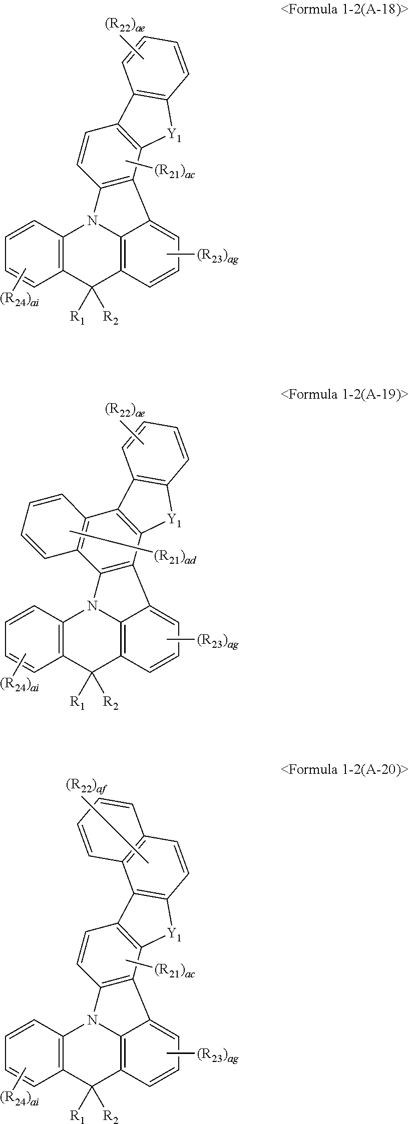 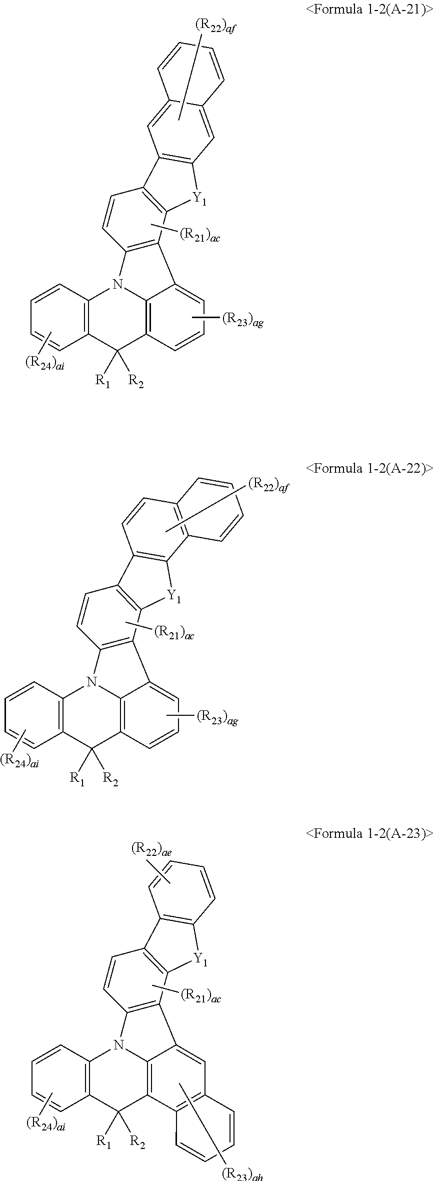 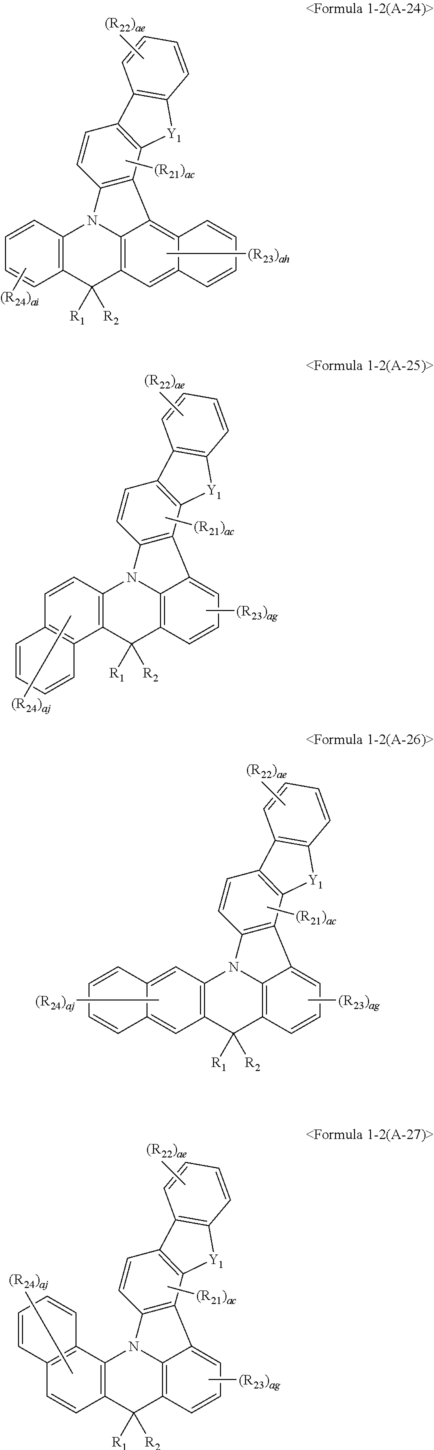 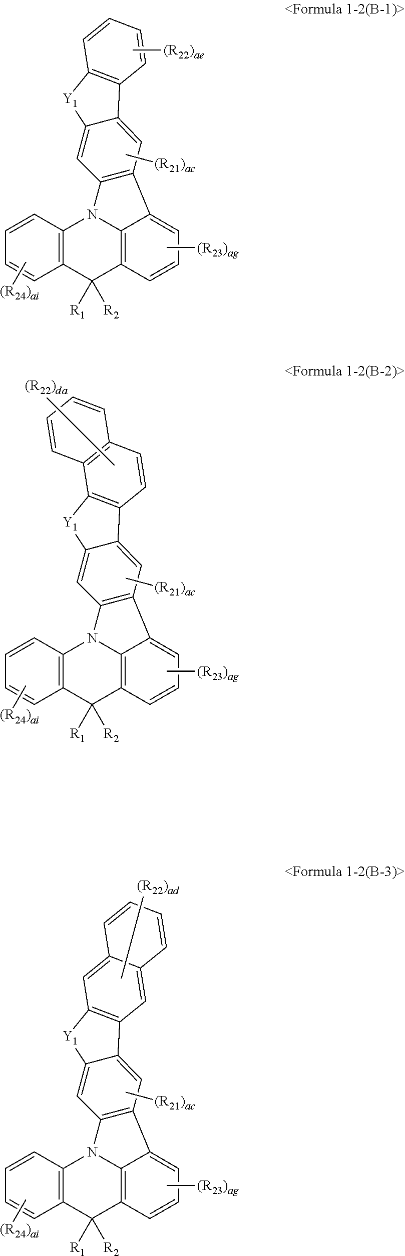 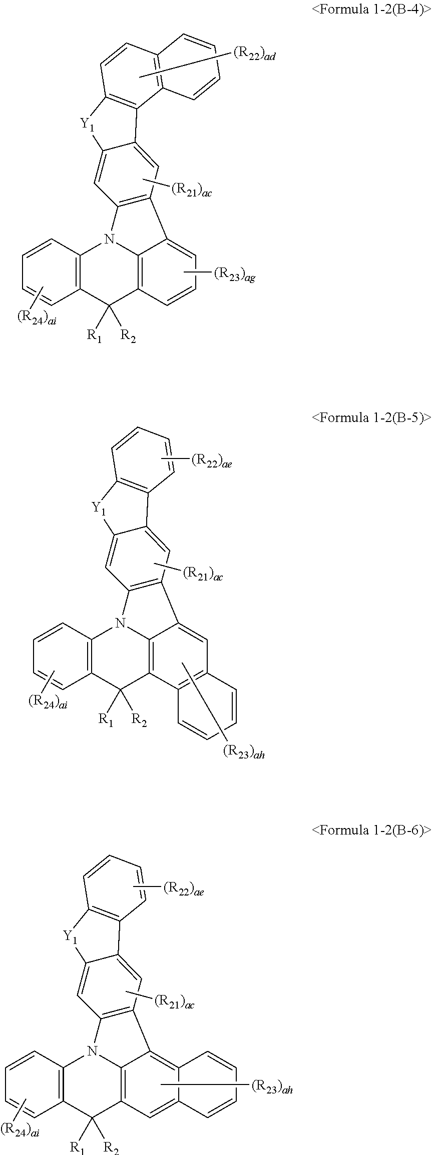 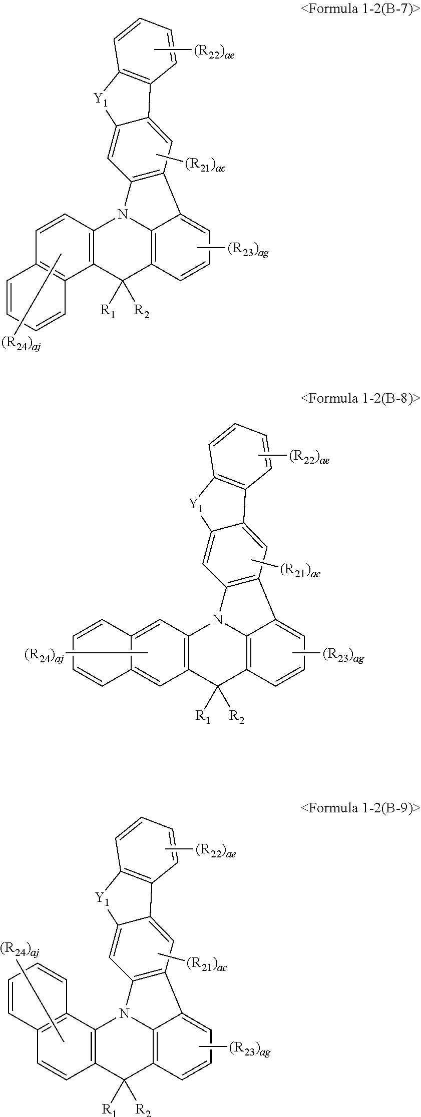 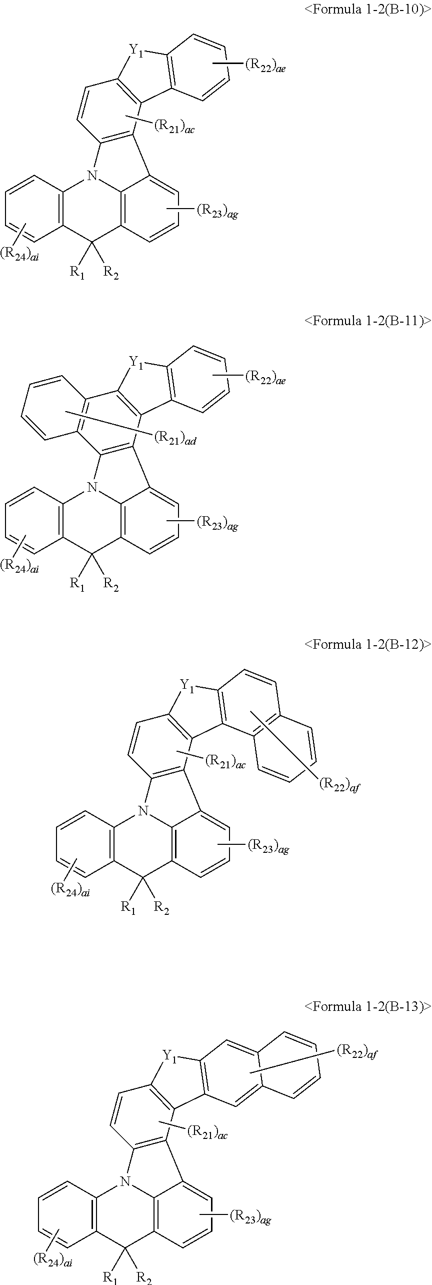 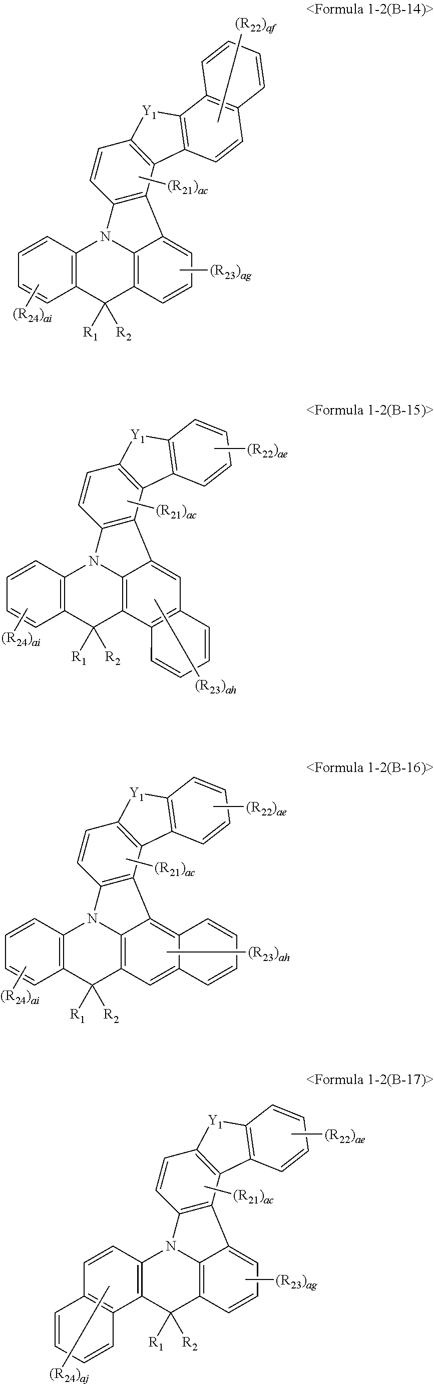 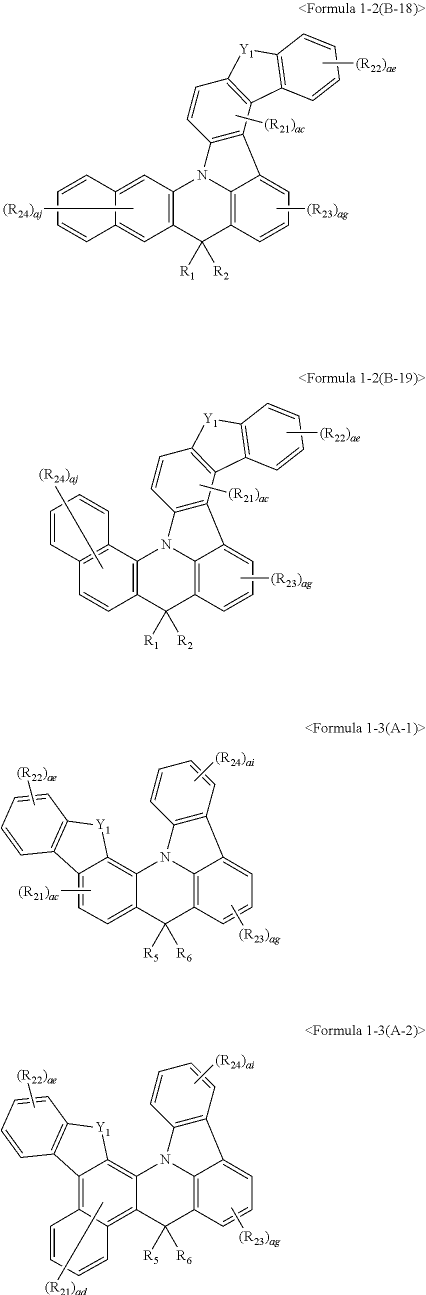 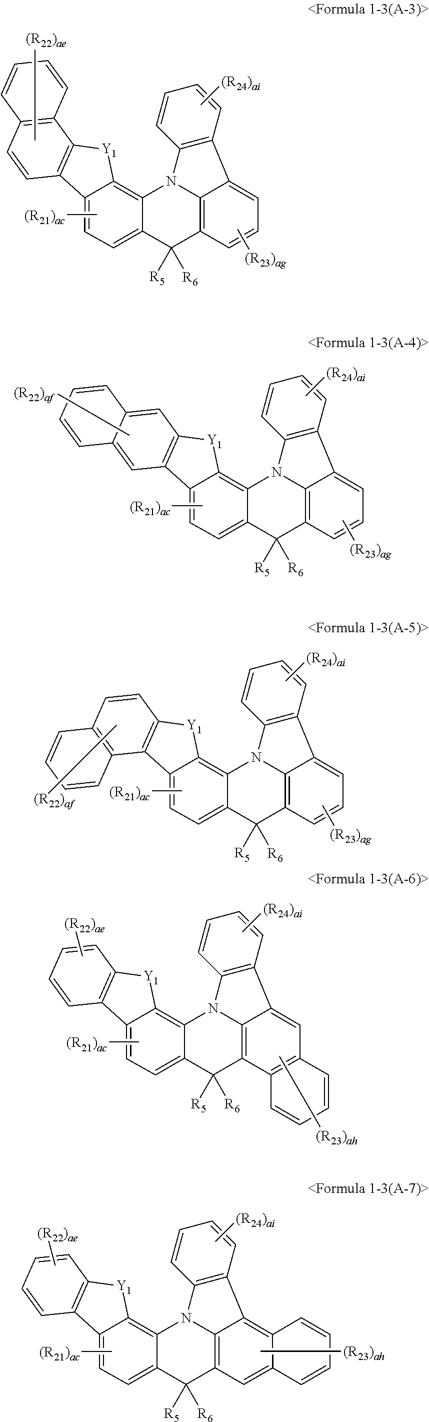 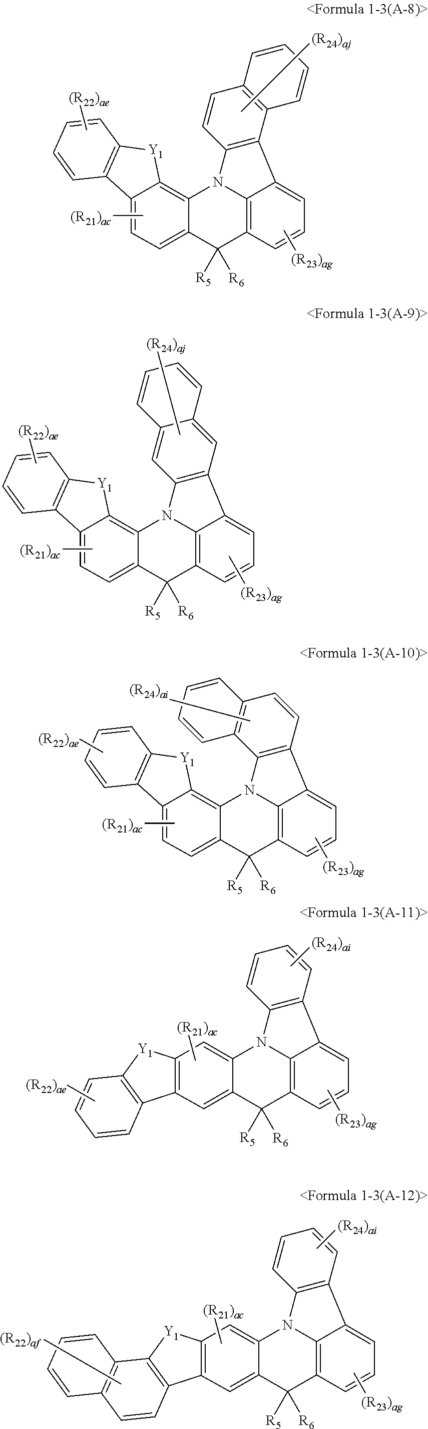 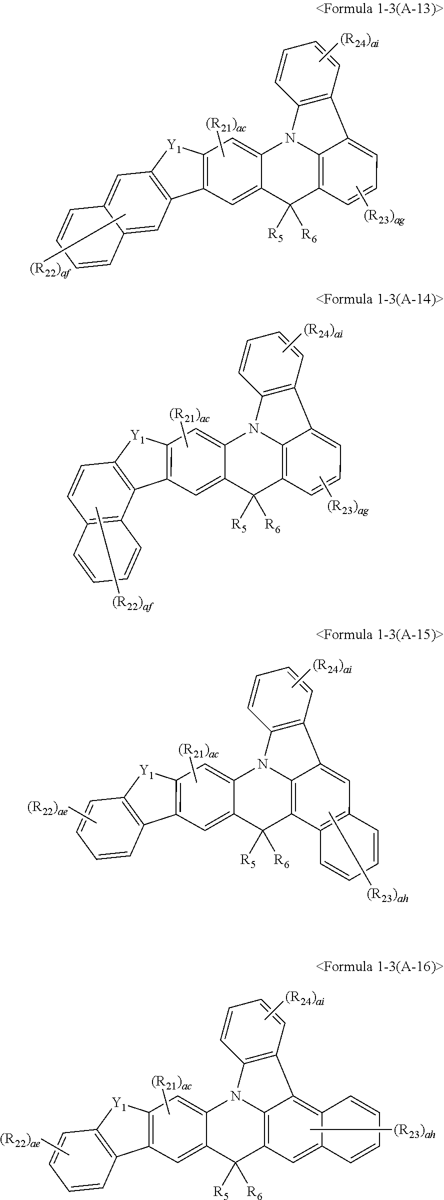 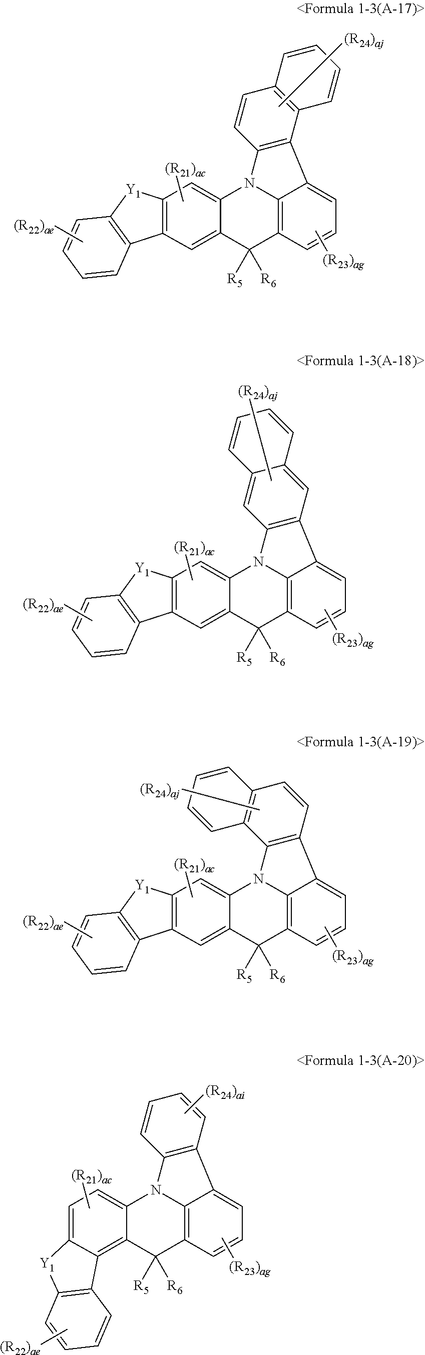 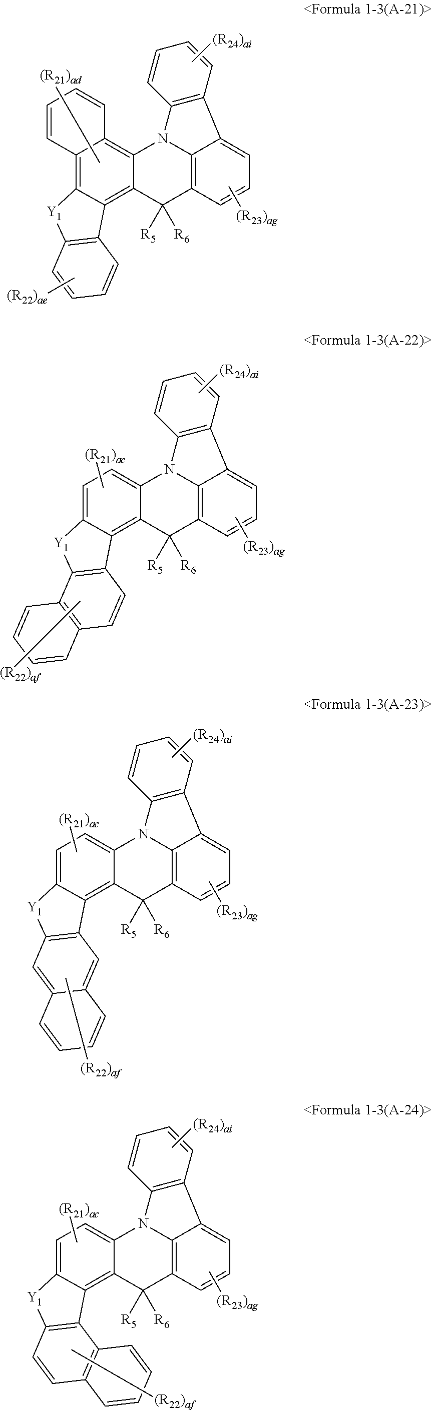 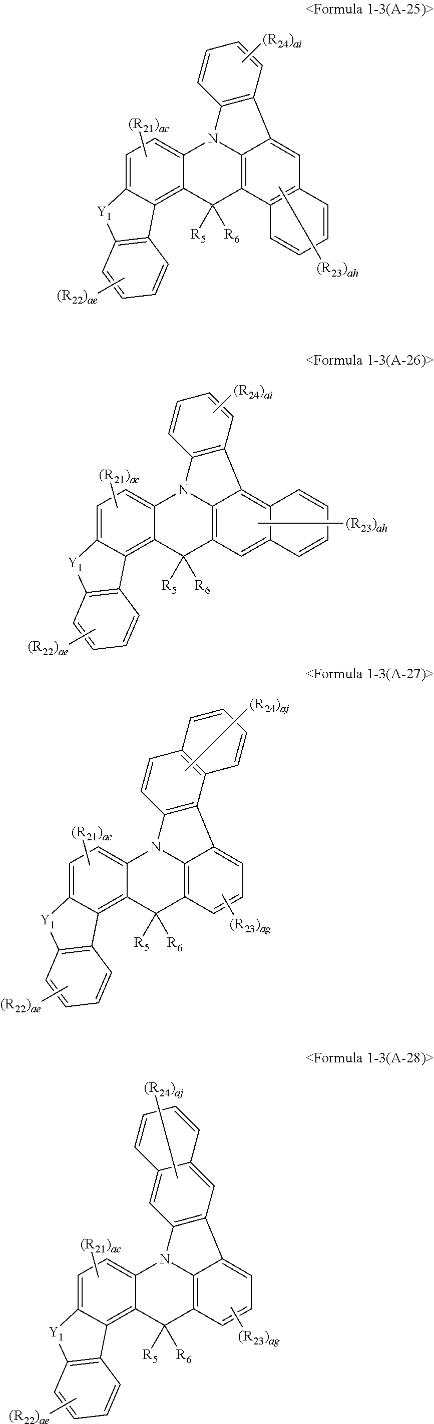 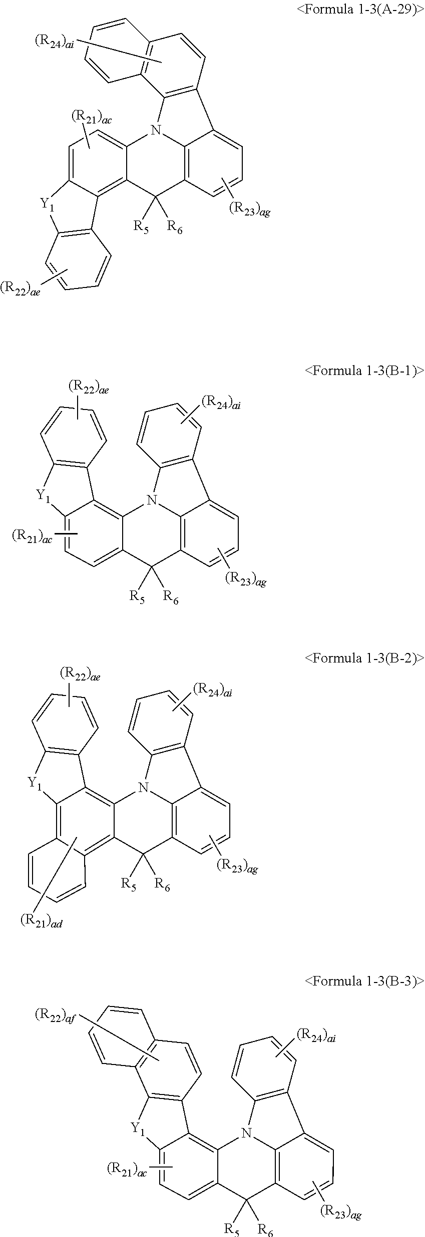 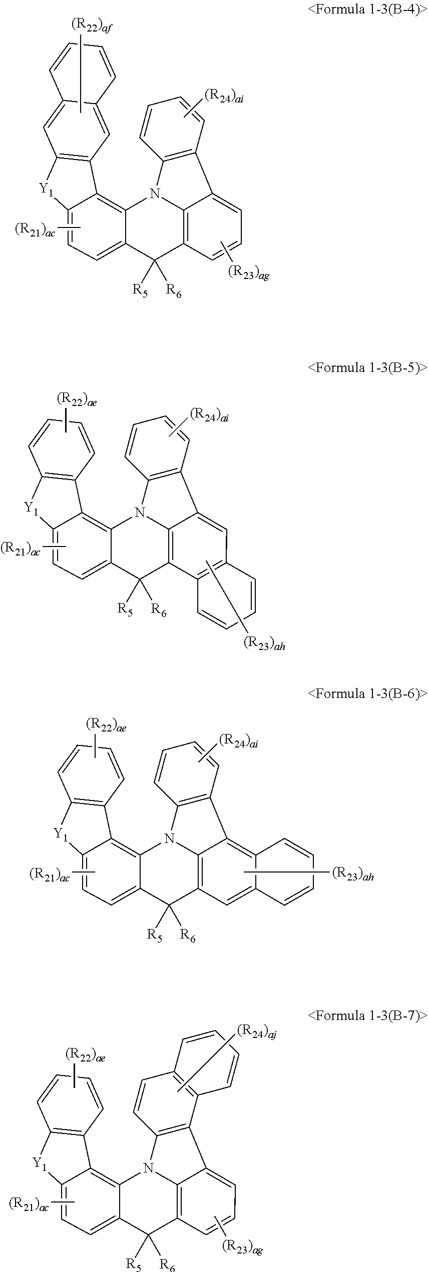 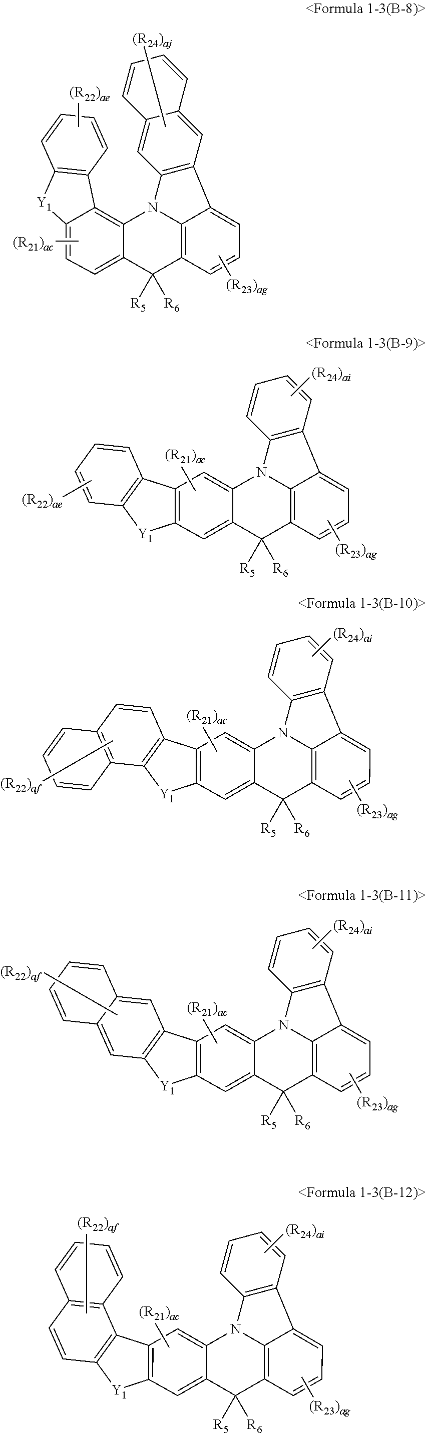 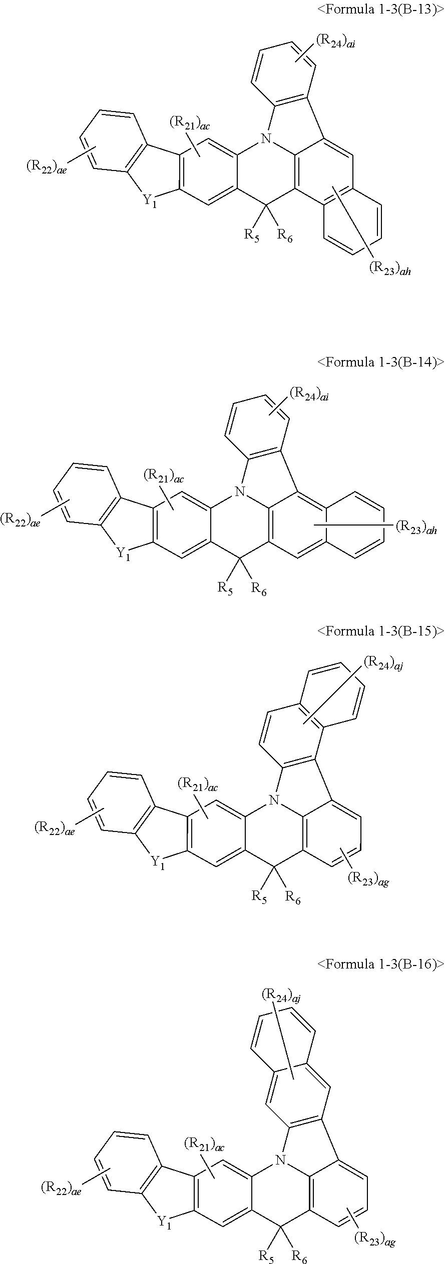 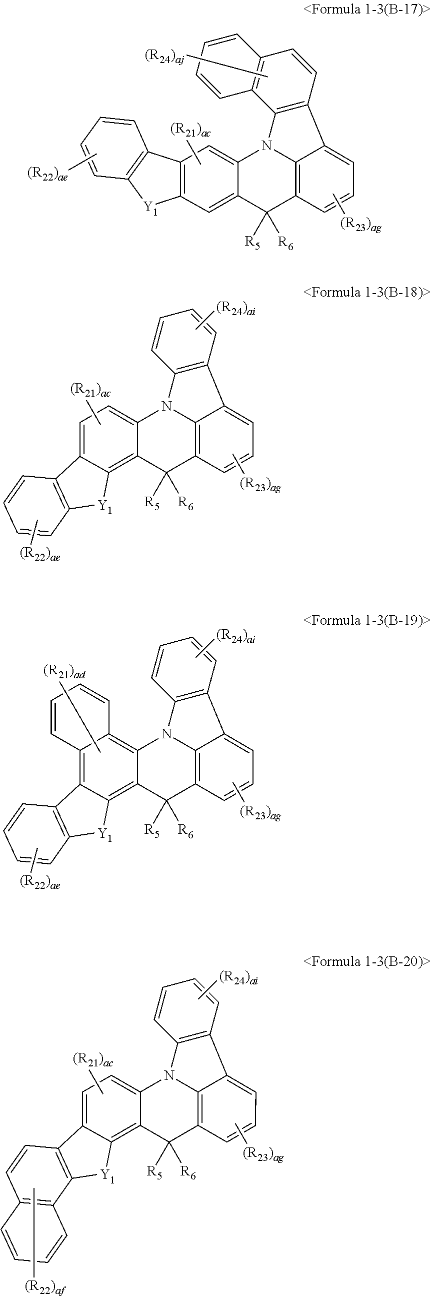 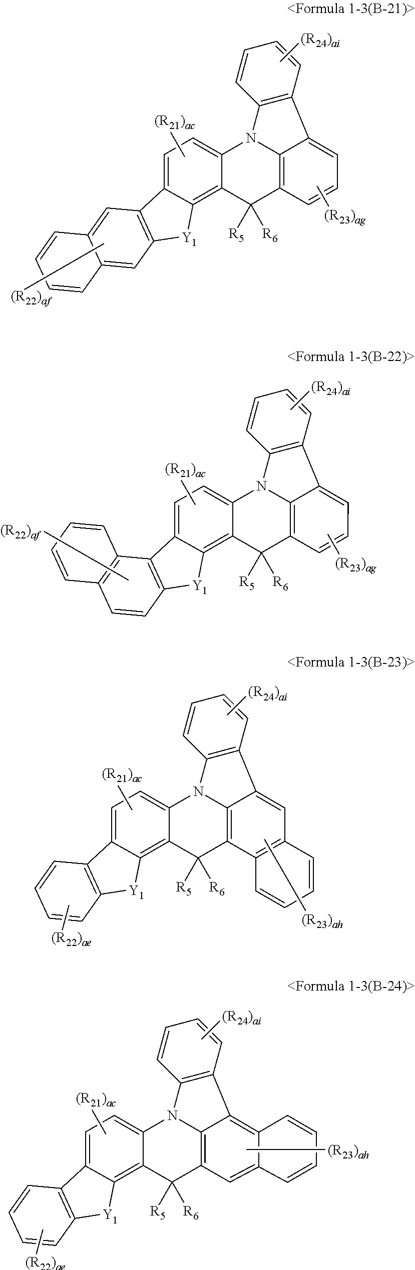 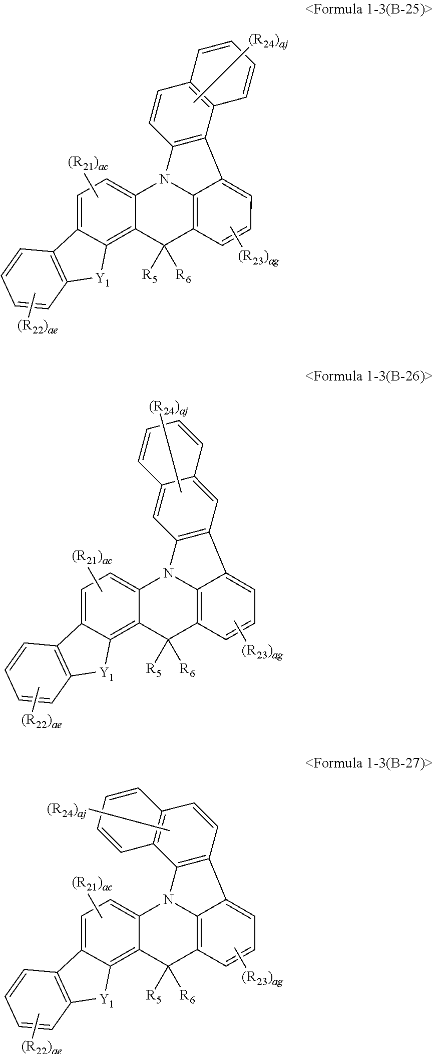 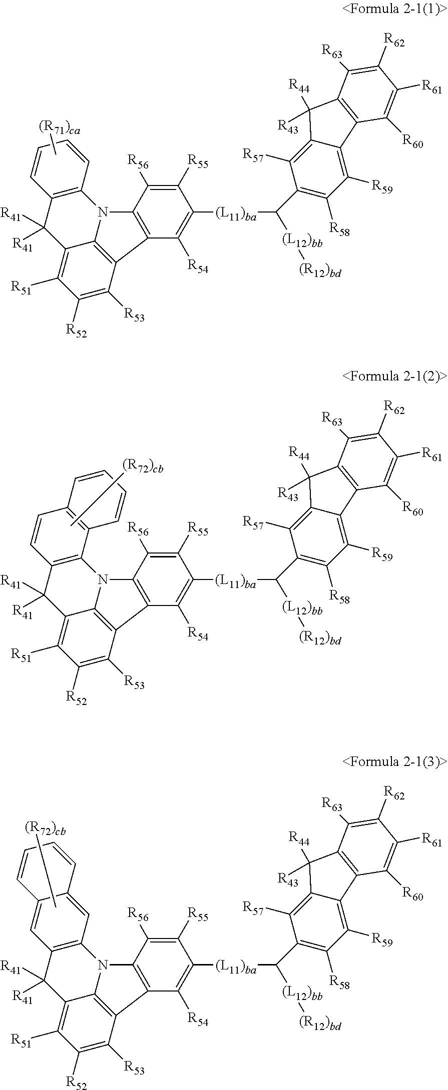 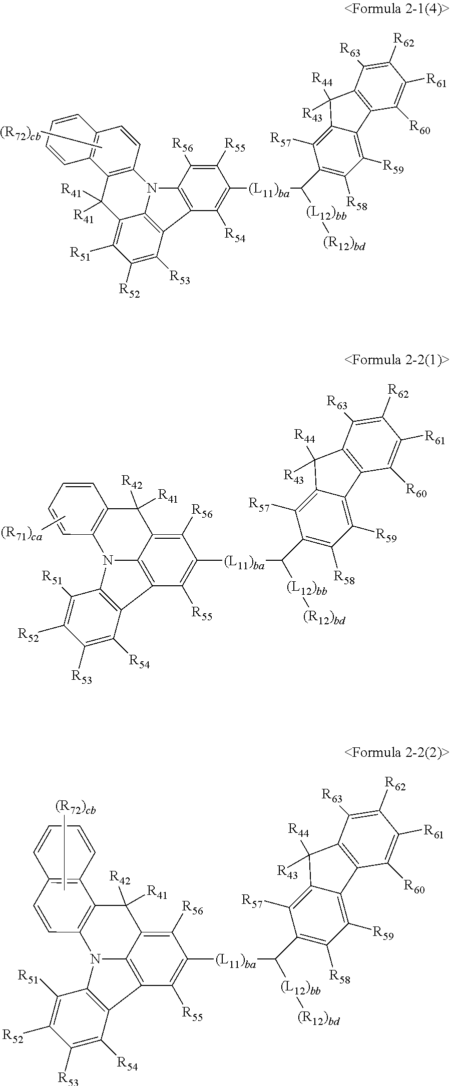 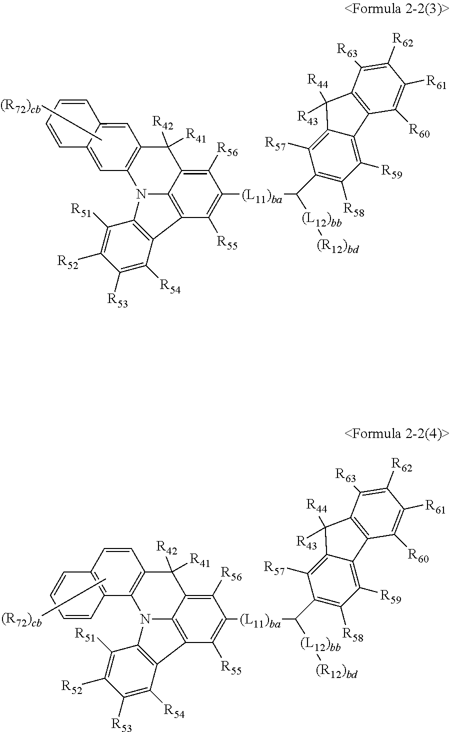
wherein, in Formulae 1-1(A-1) to 1-1(A-20), 1-1(B-1) to 1-1(B-20), 1-2(A-1) to 1-2(A-27), 1-2(B-1) to 1-2(B-19), 1-3(A-1) to 1-3(A-29), and 1-3(B-1) to 1-3(B-27),
descriptions of Y₁, and R₁ to R₆ are understood by referring to the descriptions as claimed in claim 1, R₂₁ to R₂₄ have a same definition as R₁₁, R₁₂, and R₅₁ to R₆₃ in claim 1;
ac is selected from 0, 1, and 2, wherein, when ac is 2 or greater, two or more R₂₁ are identical to or different from each other;
ad, ae, ag, and ai are each independently selected from 0, 1, 2, 3, and 4, wherein, when ad is 2 or greater, two or more R₂₁ are identical to or different from each other, when ae is 2 or greater, two or more R₂₂ are identical to or different from each other, when ag is 2 or greater, two or more R₂₃ are identical to or different from each other, and when ai is 2 or greater, two or more R₂₄ are identical to or different from each other; and
af, ah, and aj are each independently selected from 0, 1, 2, 3, 4, 5, and 6, wherein, when af is 2 or greater, two or more R₂₂ are identical to or different from each other, when ah is 2 or greater, two or more R₂₃ are identical to or different from each other, and when aj is 2 or greater, two or more R₂₄ are identical to or different from each other;
wherein, in Formulae 2-1(1) to 2-1(4) and 2-2(1) to 2-2(4),
descriptions of L₁₁, L₁₂, R₁₂ and R₄₁ to R₄₄ are understood by referring to the descriptions as claimed in claim 1;
R₅₁ to R₆₃ and R₇₁ and R₇₂ are each independently selected from:
a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₁-C₂₀ heteroaryl group, a substituted or unsubstituted monovalent non-aromatic condensed polycyclic group, a substituted or unsubstituted monovalent non-aromatic condensed heteropolycyclic group, —Si(Q₁)(Q₂)(Q₃) —B(Q₄)(Q₅), and —N(Q₆)(Q₇);
ba is 1 or 2, and bb is 0 or 1, wherein, when ba is 2, two L₁ are identical to or different from each other;
bd is selected from 1, 2, and 3, wherein, when bd is 2 or greater, two or more R₁₂ are identical to or different from each other;
ca is selected from 0, 1, 2, 3, and 4, wherein, when ca is 2 or greater, two or more R₇₁ are identical to or different from each other; and
cb is selected from 0, 1, 2, 3, 4, 5, and 6, wherein, when cb is 2 or greater, two or more R₇₂ are identical to or different from each other.

16. The organic light-emitting device as claimed in claim 1, wherein:
the first compound is one of the following Compounds 1 to 37, and
the second compound is one of the following Compounds 101 to 122 and 151 to 172:

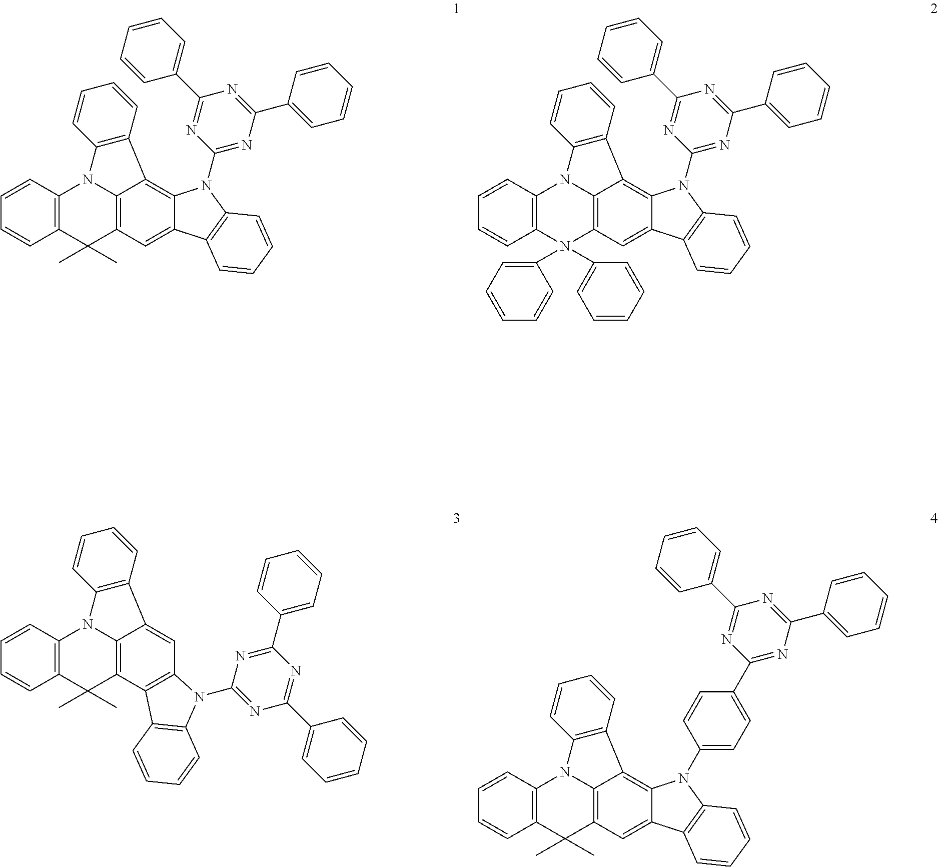

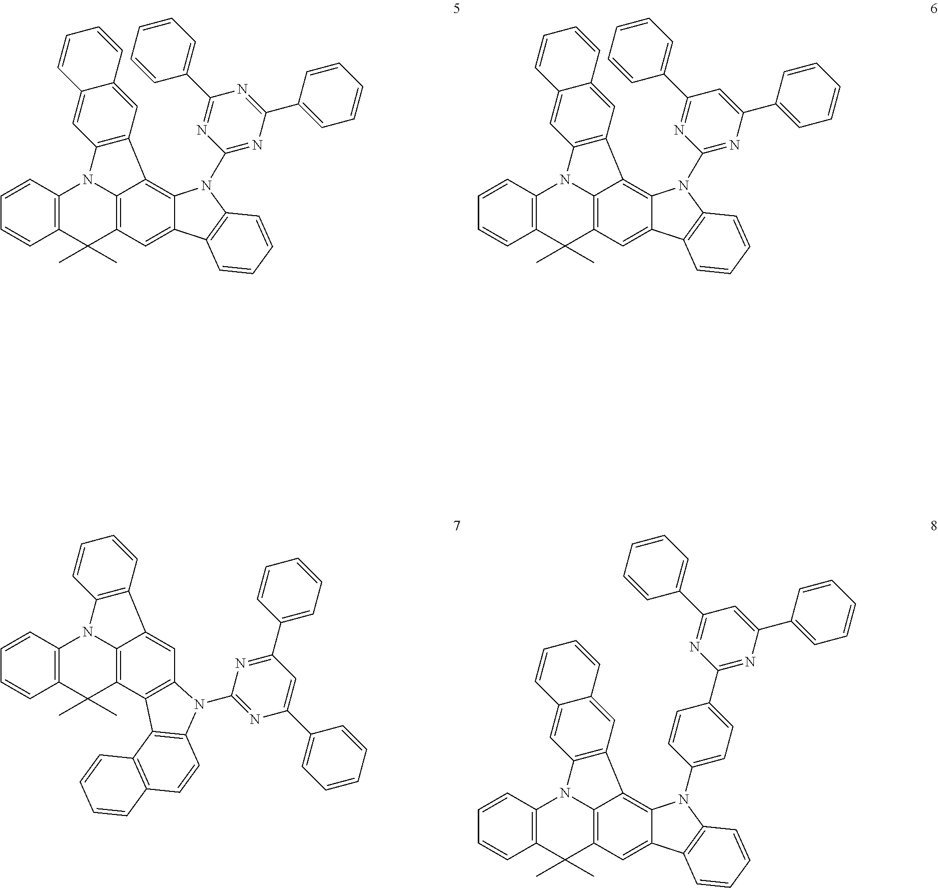 [SMILES: CC1(C)c2ccccc2-n2c3cc4ccccc4cc3c3c2c1cc1c2ccccc2n(-c2nc(-c4ccccc4)nc(-c4ccccc4)n2)c13 ; CC1(C)c2ccccc2-n2c3cc4ccccc4cc3c3c2c1cc1c2ccccc2n(-c2nc(-c4ccccc4)cc(-c4ccccc4)n2)c13 ; CC1(C)c2ccccc2-n2c3ccccc3c3cc4c(c1c32)c1c2ccccc2ccc1n4-c1nc(-c2ccccc2)cc(-c2ccccc2)n1 ; CC1(C)c2ccccc2-n2c3cc4ccccc4cc3c3c2c1cc1c2ccccc2n(-c2ccc(-c4nc(-c5ccccc5)cc(-c5ccccc5)n4)cc2)c13]

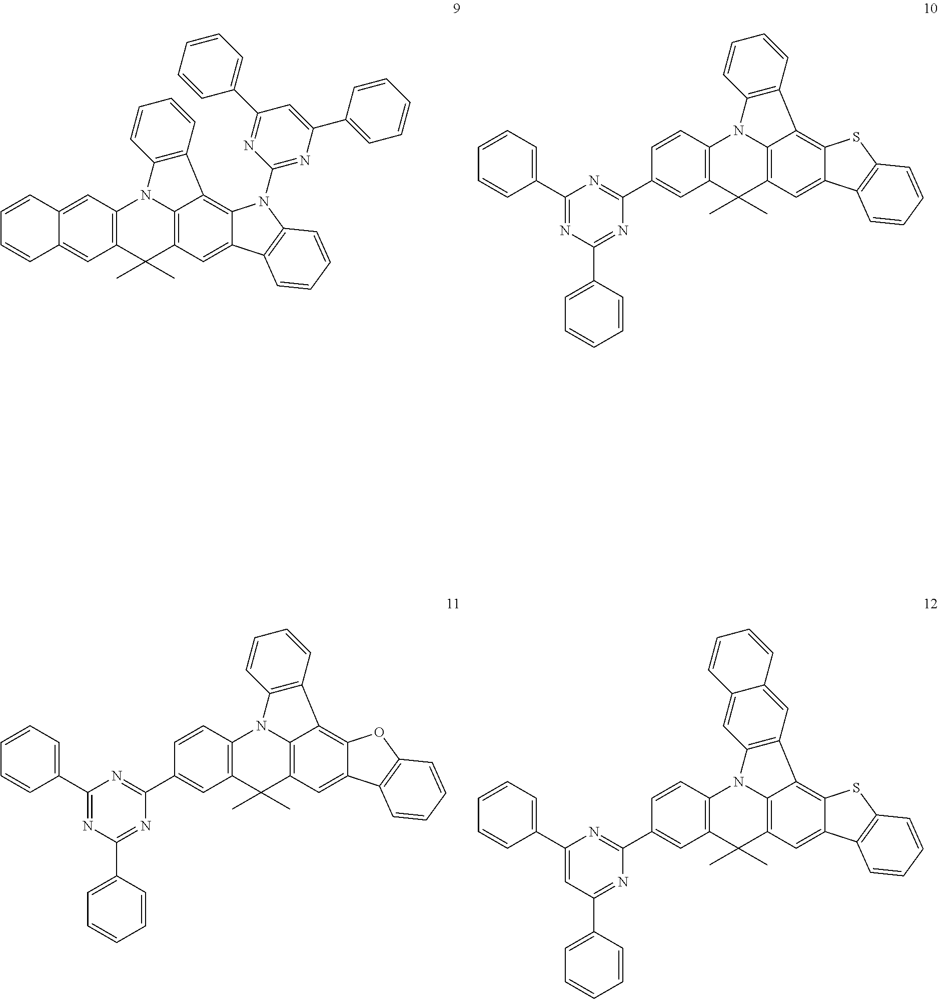

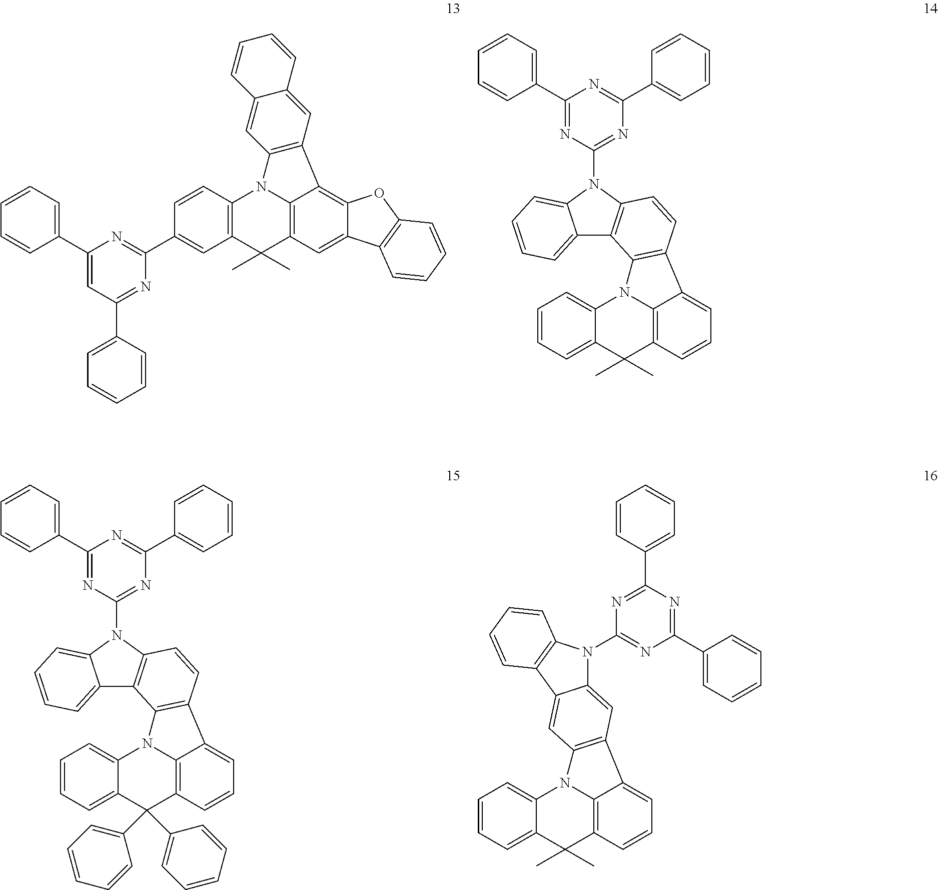 [SMILES: CC1(C)c2cc(-c3nc(-c4ccccc4)cc(-c4ccccc4)n3)ccc2-n2c3cc4ccccc4cc3c3c4oc5ccccc5c4cc1c32 ; CC1(C)c2ccccc2-n2c3c1cccc3c1ccc3c(c4ccccc4n3-c3nc(-c4ccccc4)nc(-c4ccccc4)n3)c12 ; c1ccc(-c2nc(-c3ccccc3)nc(-n3c4ccccc4c4c3ccc3c5cccc6c5n(c34)-c3ccccc3C6(c3ccccc3)c3ccccc3)n2)cc1 ; CC1(C)c2ccccc2-n2c3cc4c5ccccc5n(-c5nc(-c6ccccc6)nc(-c6ccccc6)n5)c4cc3c3cccc1c32]

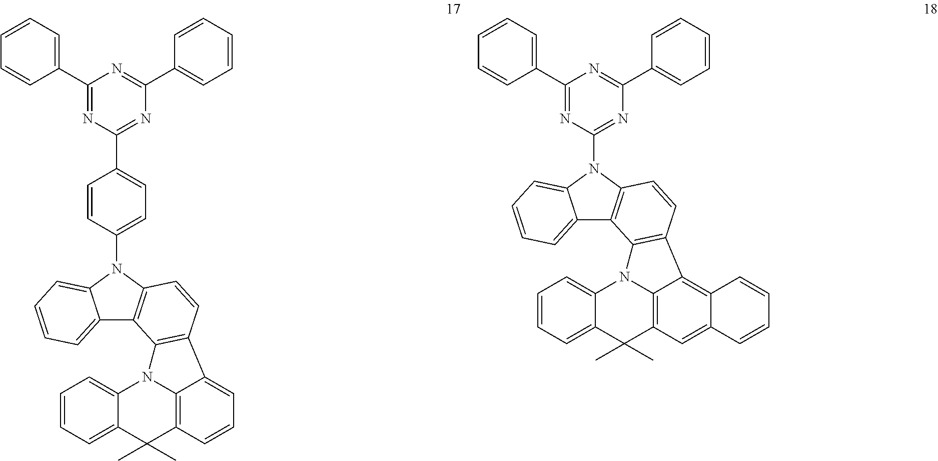 [SMILES: CC1(C)c2ccccc2-n2c3c1cccc3c1ccc3c(c4ccccc4n3-c3ccc(-c4nc(-c5ccccc5)nc(-c5ccccc5)n4)cc3)c12 ; CC1(C)c2ccccc2-n2c3c1cc1ccccc1c3c1ccc3c(c4ccccc4n3-c3nc(-c4ccccc4)nc(-c4ccccc4)n3)c12]

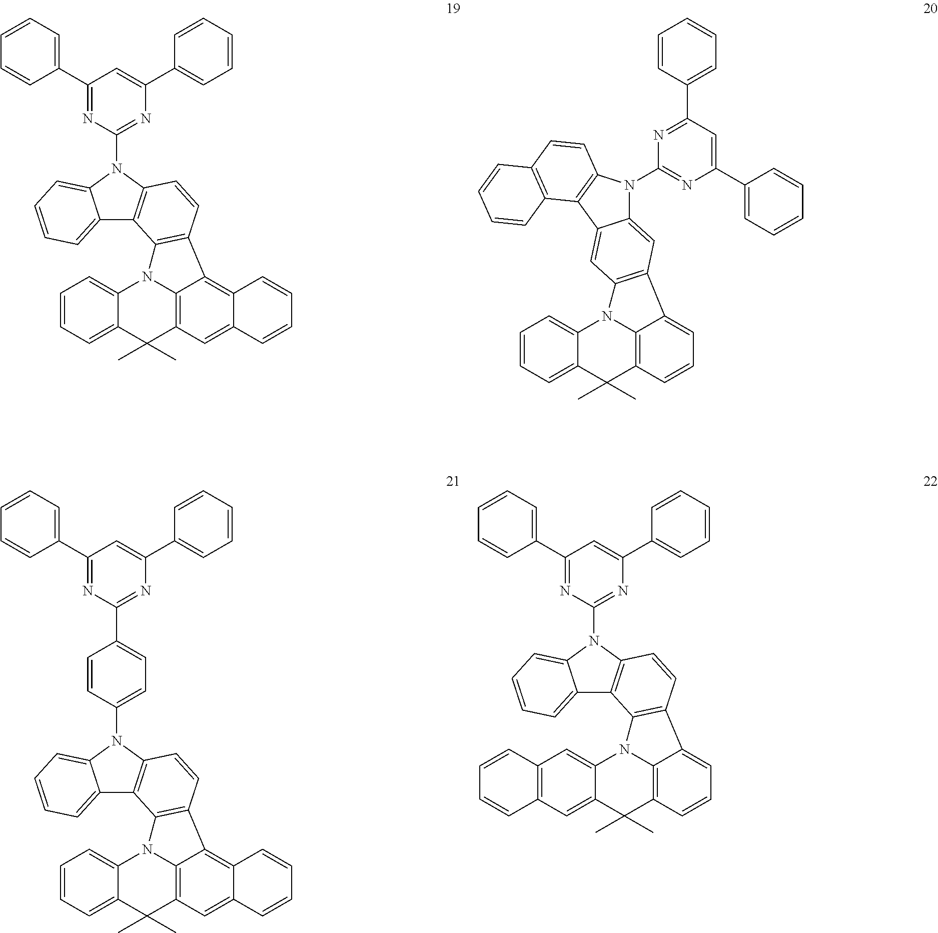 [SMILES: CC1(C)c2ccccc2-n2c3c1cc1ccccc1c3c1ccc3c(c4ccccc4n3-c3nc(-c4ccccc4)cc(-c4ccccc4)n3)c12 ; CC1(C)c2ccccc2-n2c3cc4c5c6ccccc6ccc5n(-c5nc(-c6ccccc6)cc(-c6ccccc6)n5)c4cc3c3cccc1c32 ; CC1(C)c2ccccc2-n2c3c1cc1ccccc1c3c1ccc3c(c4ccccc4n3-c3ccc(-c4nc(-c5ccccc5)cc(-c5ccccc5)n4)cc3)c12 ; CC1(C)c2cc3ccccc3cc2-n2c3c1cccc3c1ccc3c(c4ccccc4n3-c3nc(-c4ccccc4)cc(-c4ccccc4)n3)c12]

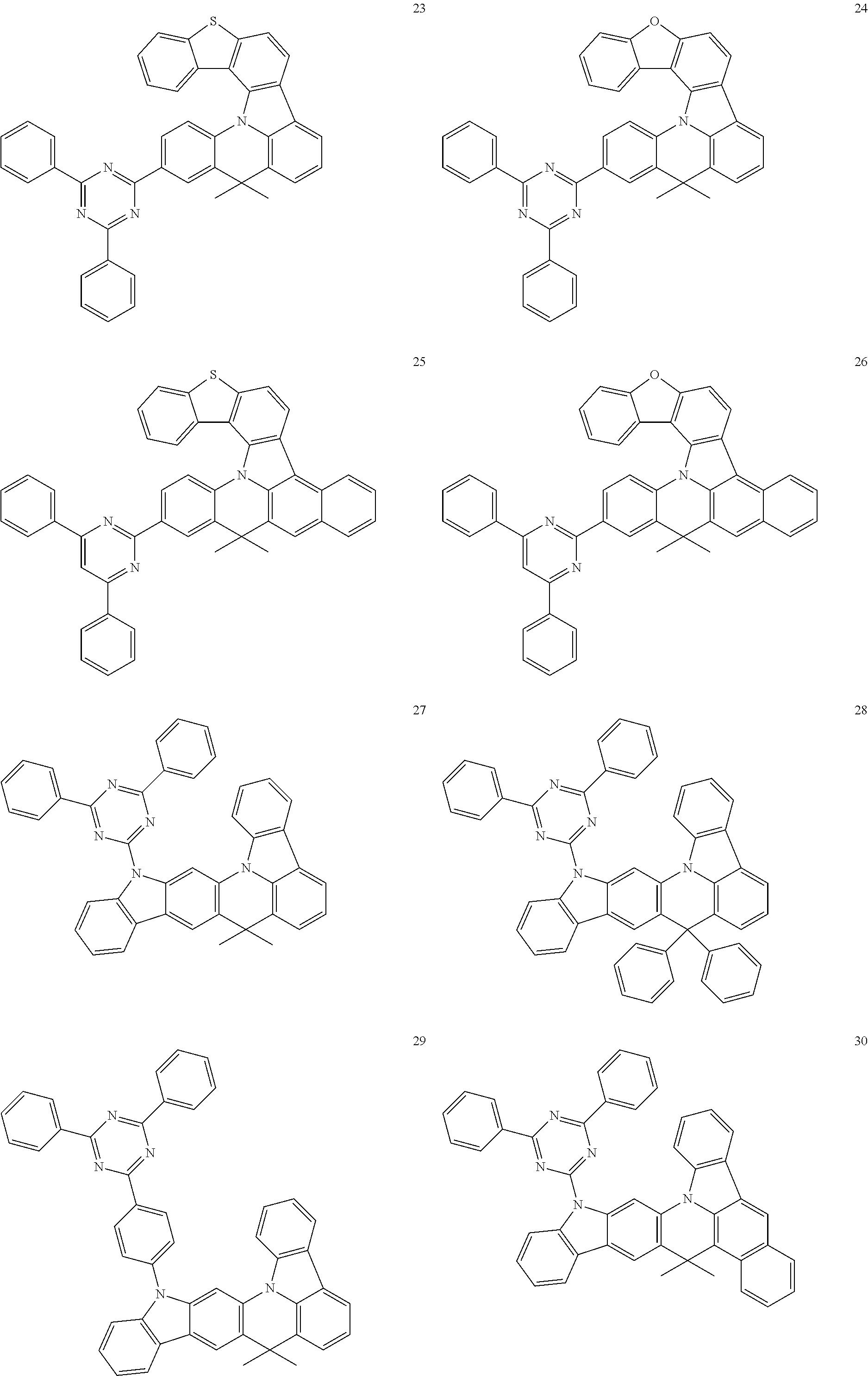

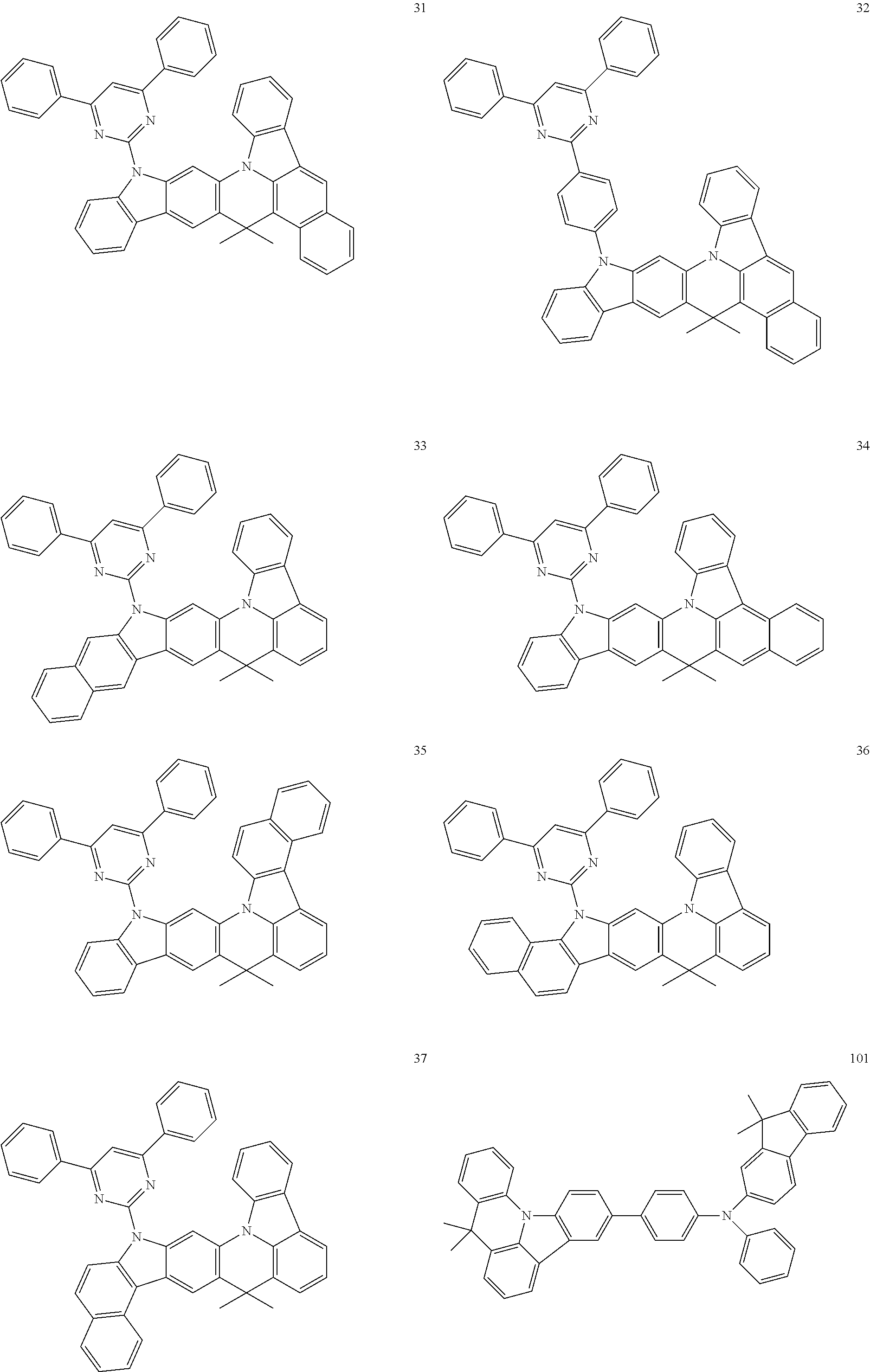

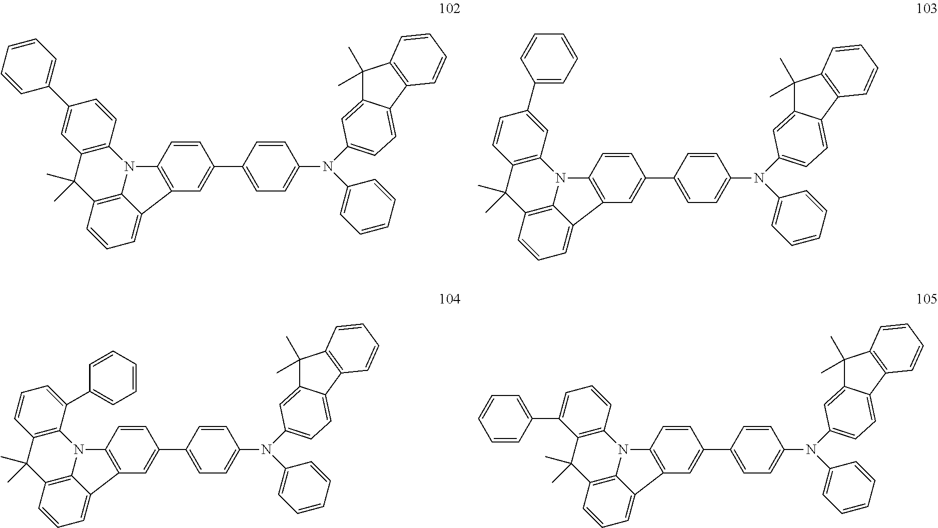 [SMILES: CC1(C)c2ccccc2-c2ccc(N(c3ccccc3)c3ccc(-c4ccc5c(c4)c4cccc6c4n5-c4ccc(-c5ccccc5)cc4C6(C)C)cc3)cc21 ; CC1(C)c2ccccc2-c2ccc(N(c3ccccc3)c3ccc(-c4ccc5c(c4)c4cccc6c4n5-c4cc(-c5ccccc5)ccc4C6(C)C)cc3)cc21 ; CC1(C)c2ccccc2-c2ccc(N(c3ccccc3)c3ccc(-c4ccc5c(c4)c4cccc6c4n5-c4c(-c5ccccc5)cccc4C6(C)C)cc3)cc21 ; CC1(C)c2ccccc2-c2ccc(N(c3ccccc3)c3ccc(-c4ccc5c(c4)c4cccc6c4n5-c4cccc(-c5ccccc5)c4C6(C)C)cc3)cc21]

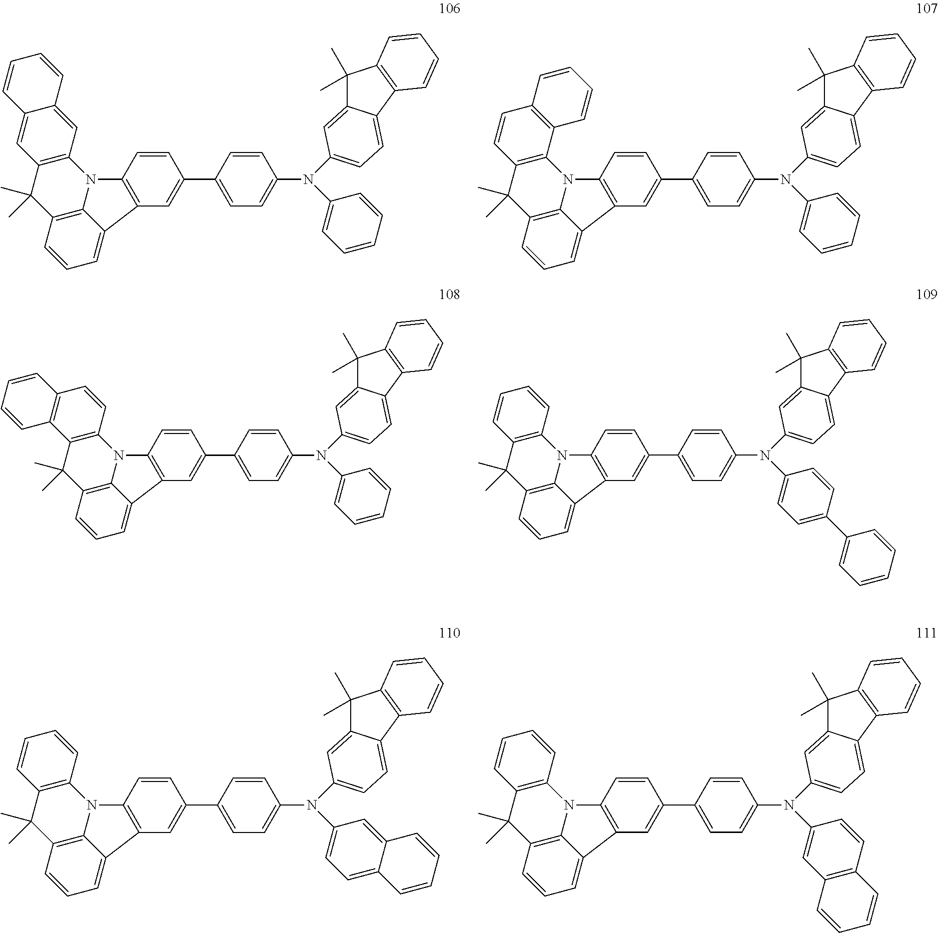

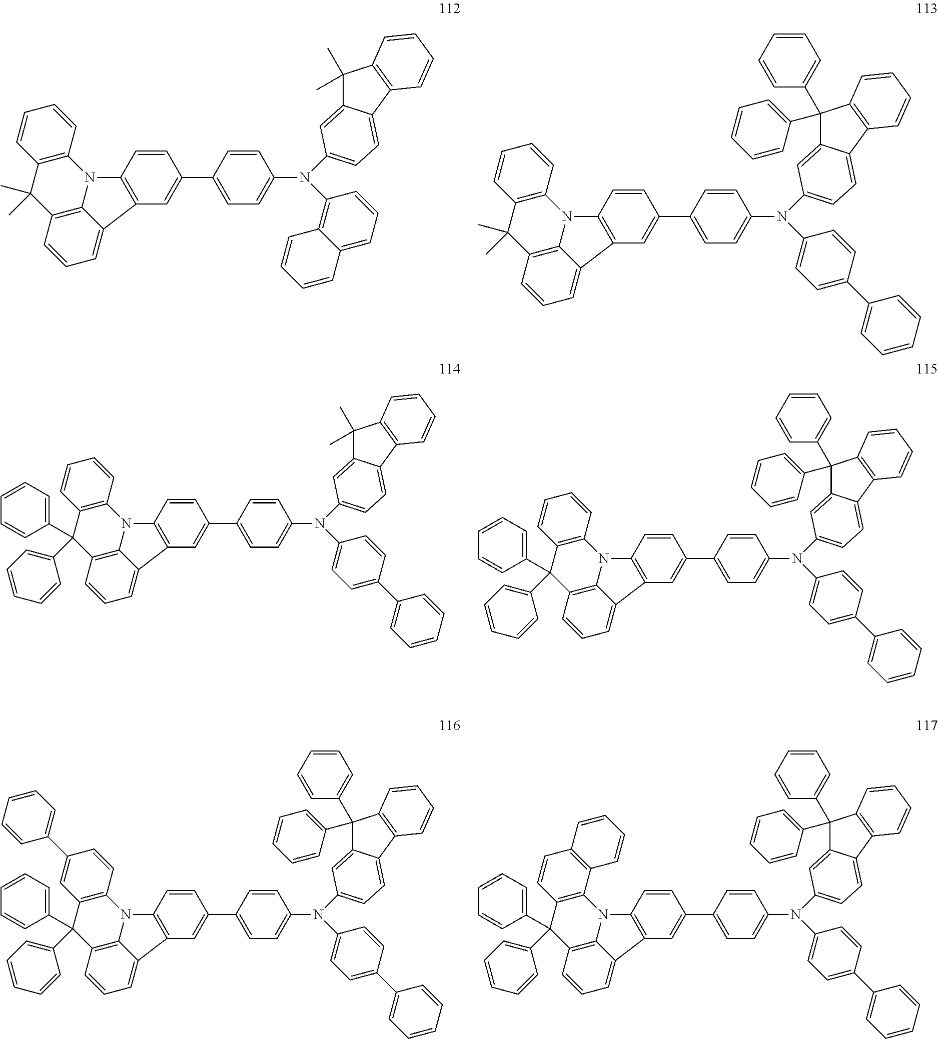

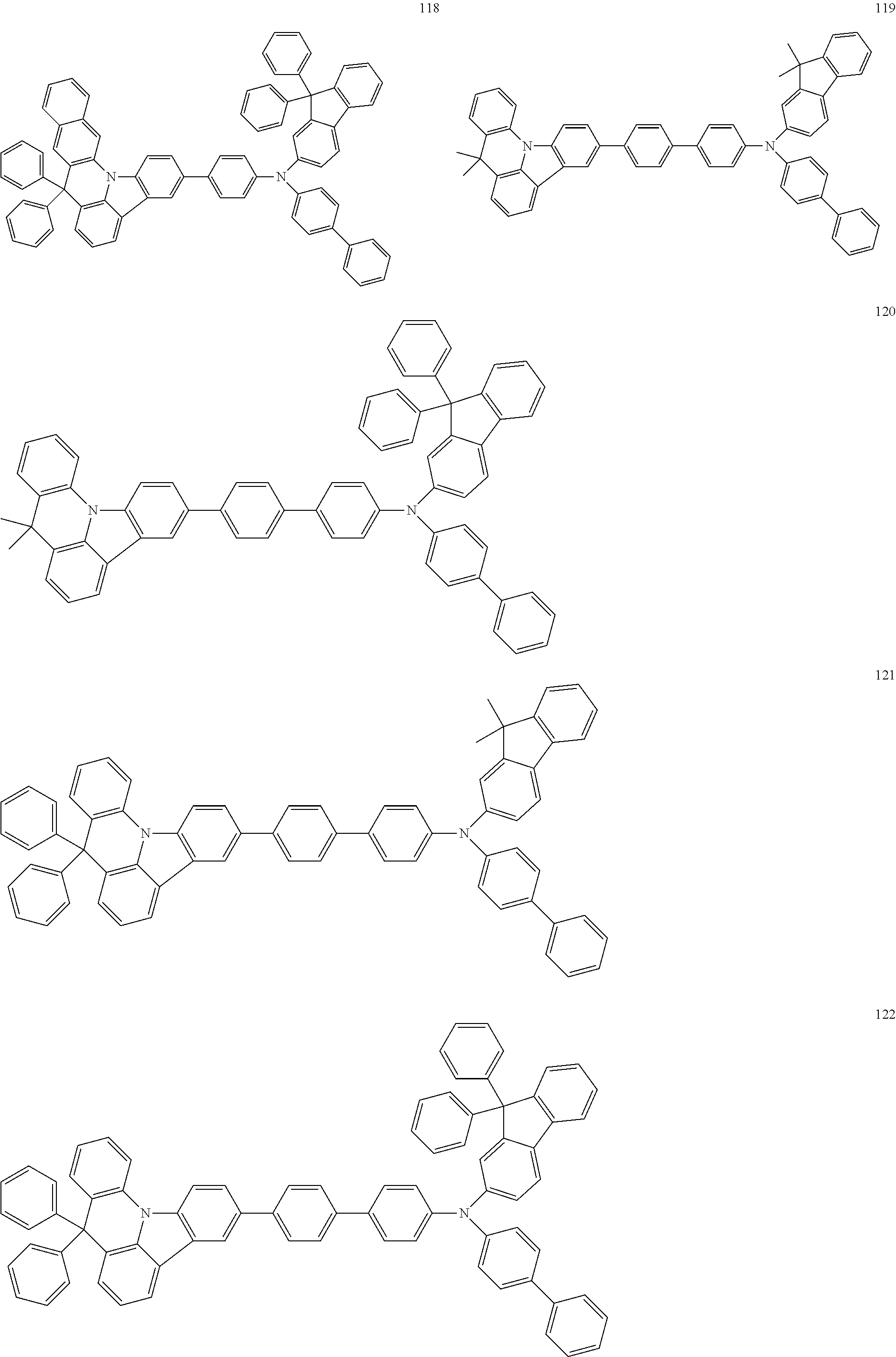

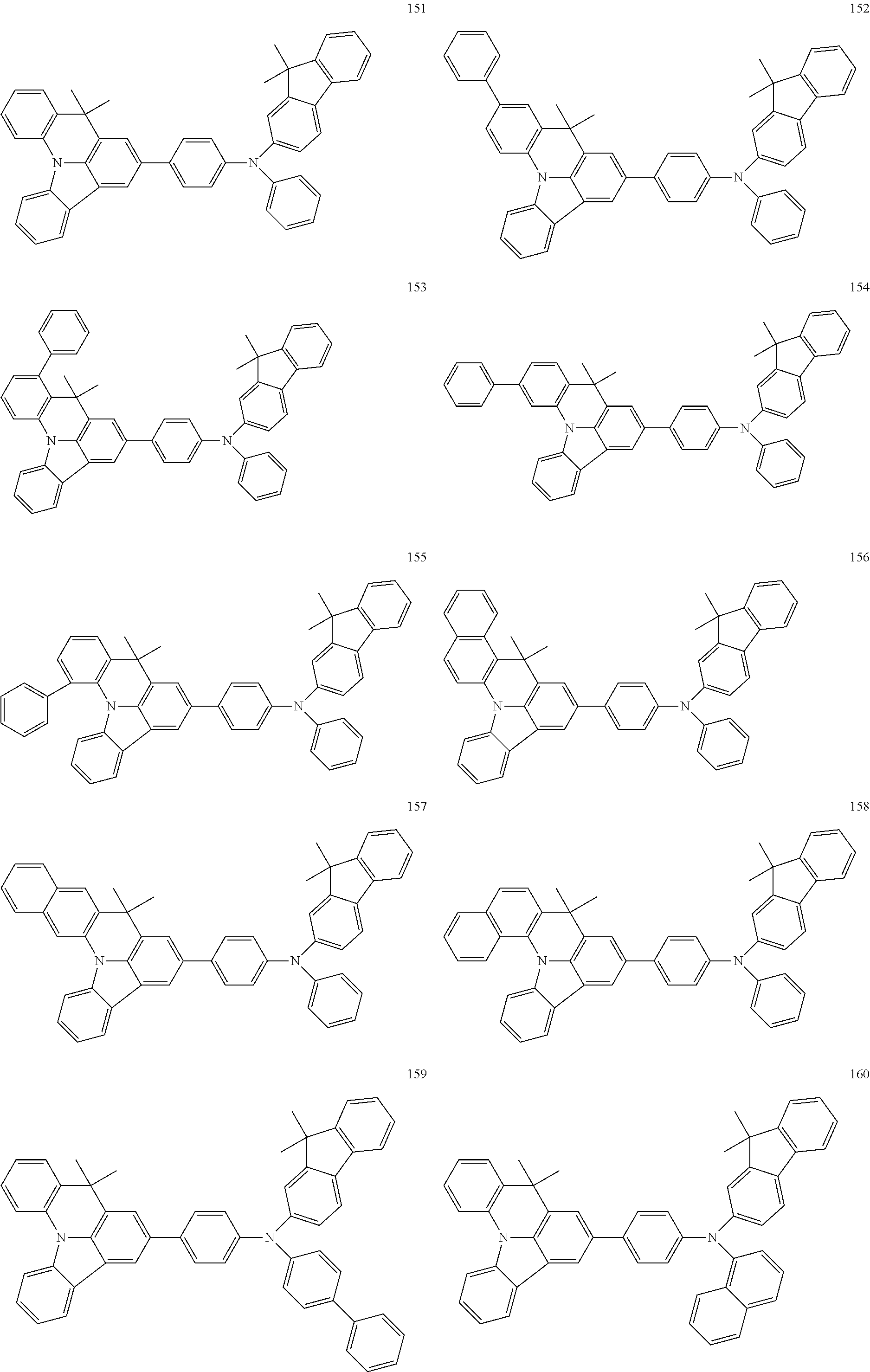

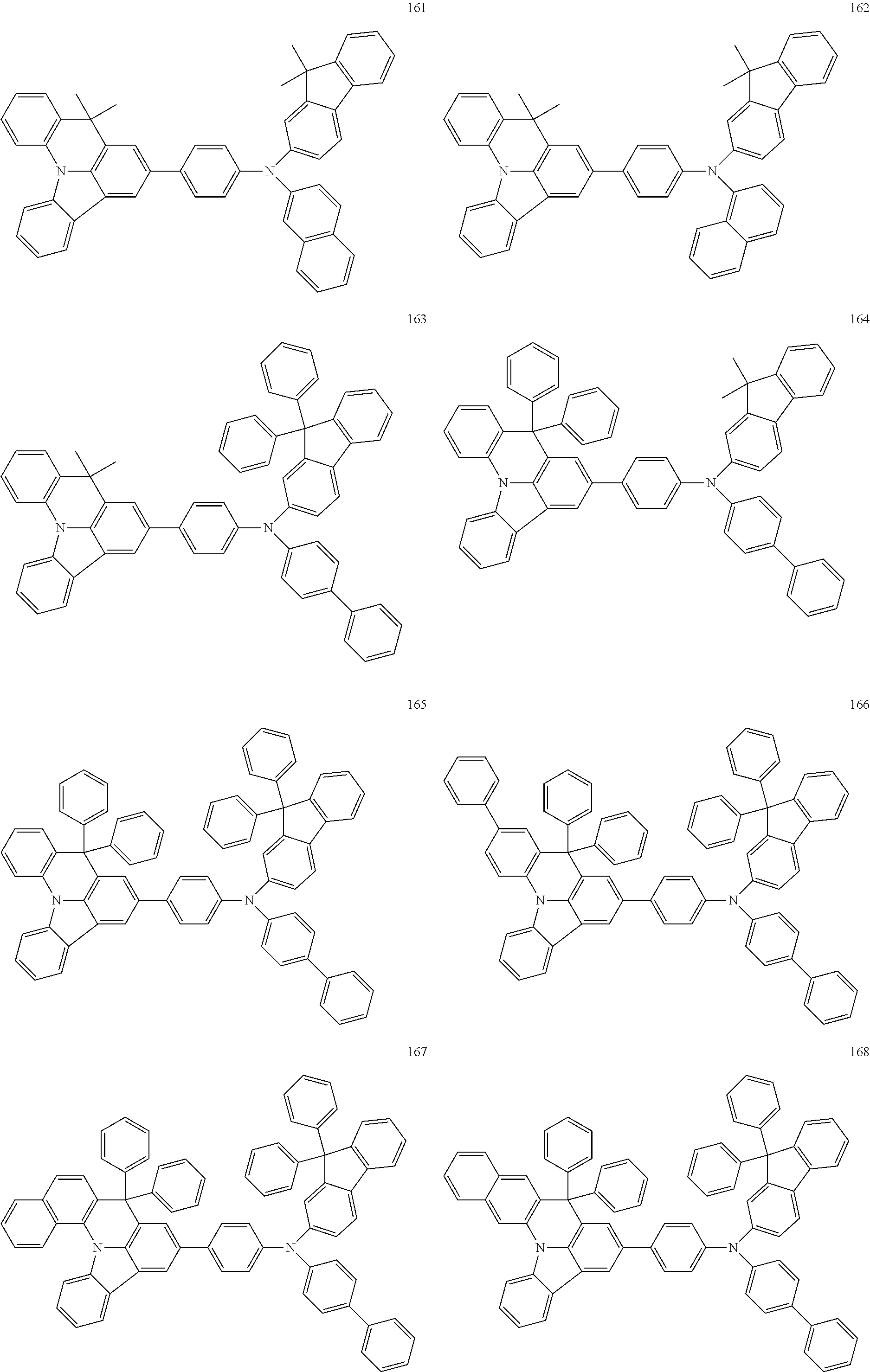

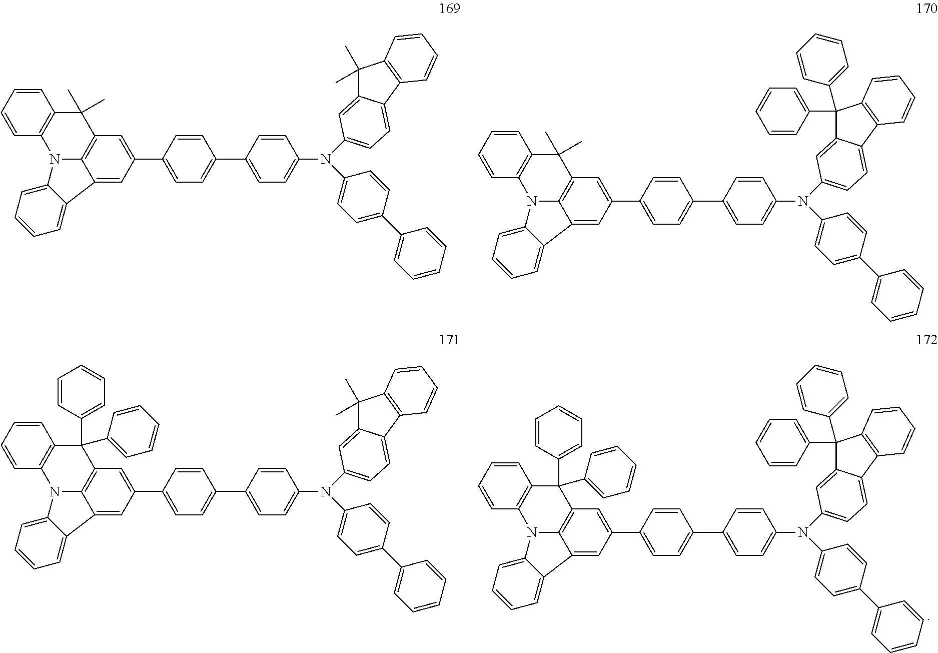 [SMILES: CC1(C)c2ccccc2-c2ccc(N(c3ccc(-c4ccccc4)cc3)c3ccc(-c4ccc(-c5cc6c7c(c5)c5ccccc5n7-c5ccccc5C6(C)C)cc4)cc3)cc21 ; CC1(C)c2ccccc2-n2c3ccccc3c3cc(-c4ccc(-c5ccc(N(c6ccc(-c7ccccc7)cc6)c6ccc7c(c6)C(c6ccccc6)(c6ccccc6)c6ccccc6-7)cc5)cc4)cc1c32 ; CC1(C)c2ccccc2-c2ccc(N(c3ccc(-c4ccccc4)cc3)c3ccc(-c4ccc(-c5cc6c7c(c5)c5ccccc5n7-c5ccccc5C6(c5ccccc5)c5ccccc5)cc4)cc3)cc21 ; c1ccc(-c2ccc(N(c3ccc(-c4ccc(-c5cc6c7c(c5)c5ccccc5n7-c5ccccc5C6(c5ccccc5)c5ccccc5)cc4)cc3)c3ccc4c(c3)C(c3ccccc3)(c3ccccc3)c3ccccc3-4)cc2)cc1]

17. The organic light-emitting device as claimed in claim 1, wherein
the first electrode is an anode,
the second electrode is a cathode, and
the organic layer includes:
a hole transport region between the first electrode and the emission layer, the hole transport region including at least one of a hole injection layer, a hole transport layer, a buffer layer, and an electron blocking layer and
an electron transport region between the emission layer and the second electrode, the electron transport region including at least one of a hole blocking layer, an electron transport layer, and an electron injection layer.

18. The organic light-emitting device as claimed in claim 1, wherein the first compound and the second compound are included in the emission layer.

19. The organic light-emitting device as claimed in claim 1, wherein a weight ratio of the first compound and the second compound is about 10:90 to about 90:10.

20. The organic light-emitting device as claimed in claim 18, wherein:
the emission layer includes a host and a dopant,
the host includes the first compound and the second compound, and
an amount of the host is greater than an amount of the dopant.
